(19) United States
(12) Patent Application Publication
(10) Pub. No.: US 2014/0364625 A1
(43) Pub. Date: Dec. 11, 2014

(54) NOVEL ORGANIC ELECTROLUMINESCENT COMPOUNDS AND ORGANIC ELECTROLUMINESCENT DEVICE USING THE SAME

(71) Applicant: Rohm and Haas Electronic Materials Korea Ltd., Chungcheongnam-do (KR)

(72) Inventors: Hee-Choon Ahn, Gyeonggi-do (KR); Young-Gil Kim, Gyeonggi-do (KR); Hee-Ryong Kang, Seoul (KR); Jeong-Eun Yang, Gyeonggi-do (KR); Hyo-Nim Shin, Gyeonggi-do (KR); Tae-Jin Lee, Seoul (KR); Young-Jun Cho, Gyeonggi-do (KR); Kyung-Joo Lee, Seoul (KR); Hyuck-Joo Kwon, Seoul (KR); Bong-Ok Kim, Seoul (KR)

(21) Appl. No.: 14/372,748

(22) PCT Filed: Jan. 16, 2013
(86) PCT No.: PCT/KR2013/000325

§ 371 Date: Jul. 16, 2014

(30) Foreign Application Priority Data
Jan. 16, 2012 (KR) 10-2012-0004841

(51) Int. Cl. H01L 51/00

(52) U.S. Cl. CPC H01L 51/0072; H01L 51/0074; H01L 51/0071; H01L 51/5012
USPC 548/418

(57) ABSTRACT

The present invention relates to a novel organic electroluminescent compound and an organic electroluminescent device comprising the same. Using the organic electroluminescent compounds of the present invention as a phosphorescent host material, a hole transport material, and a mixed host material, it is possible to manufacture an OLED device with improved current efficiency.

### TECHNICAL FIELD

The present invention relates to novel organic electroluminescent compounds and organic electroluminescent device using the same.

### BACKGROUND ART

An electroluminescent (EL) device is a self-light-emitting device which has advantages in that it provides a wider viewing angle, a greater contrast ratio, and a faster response time. An organic EL device was first developed by Eastman Kodak, by using small aromatic diamine molecules, and aluminum complexes as materials for forming a light-emitting layer [Appl. Phys. Lett. 51, 913, 1987].

The most important factor determining luminous efficiency in an organic EL device is the light-emitting material. Until now, fluorescent materials have been widely used as a light-emitting material. However, in view of electroluminescent mechanisms, since phosphorescent materials theoretically enhance luminous efficiency by four (4) times compared to fluorescent materials, development of phosphorescent light-emitting materials are widely being researched. Indium(III) complexes have been widely known as phosphorescent materials, including bis(2-(2′-benzothienyl)-pyridinato-N,C3′)iridium(acetylacetonate) ((acac)Ir(btp)₂), tris(2-phenylpyridine)iridium (Ir(ppy)₃) and bis(4,6-difluorophenylpyridinato-N,C2)picolinate iridium (Firpic) as red, green and blue materials, respectively.

Until now, 4,4′-N,N′-dicarbazol-biphenyl (CBP) was the most widely known host material for phosphorescent substances in conventional technologies. Further, an organic EL device using bathocuproine (BCP) and aluminum(III)bis(2-methyl-8-quinolinate)(4-phenylphenolate) (BAlq) for a hole blocking layer is also known, and Pioneer (Japan) et al. developed a high performance organic EL device employing a derivative of BAlq as a host material.

Though these materials provide good light-emitting characteristics, they have the following disadvantages: (1) Due to their low glass transition temperature and poor thermal stability, degradation may occur during a high-temperature deposition process in a vacuum. (2) The power efficiency of an organic EL device is given by [(π/voltage)×current efficiency], and power efficiency is inversely proportional to voltage. An organic EL device comprising phosphorescent host materials provides a higher current efficiency (cd/A) than one comprising fluorescent materials. However, it has a higher driving voltage, and thus, there is less advantages in terms of power efficiency (Im/W). (3) Further, the operating lifespan of the organic EL device is short, and luminous efficiency still needs improvement.

Meanwhile, copper phthalocyanine (CuPc), 4,4′-bis[N-(1-naphthyl)-N-phenylamino]biphenyl (NPB), N,N′-diphenyl-N,N′-bis(3-methylphenyl)-(1,1′-biphenyl)-4,4′-diamine (TPD), 4,4′,4″-tris(3-methylphenylphenylamino)triphenylamine (MTDATA), etc. were used as a hole injection and transport material. However, a device using these materials is problematic in quantum efficiency and operating lifespan. It is because, when an organic EL device is driven under high current, thermal stress occurs between an anode and a hole injection layer. The thermal stress significantly reduces the operating lifespan of the device. Further, since the organic material used in the hole injection layer has very high hole mobility, the hole-electron charge balance may be broken and quantum efficiency (cd/A) may decrease.

US Patent Application Laid-Open No. 2011/0279020 A1 discloses a organic electroluminescent compound in which two carbazole groups are bonded to each other via carbon-carbon single bond. However, it does not disclose a fused carbazole compound which is, at the nitrogen position, directly linked to a carbazole, fluorene, dibenzofuran, dibenzothiophene, or dibenzosilole group; nor a fused carbazole compound which is, at the nitrogen position, directly linked to an aryl group substituted with a carbazole, fluorene, dibenzofuran, dibenzothiophene, or dibenzosilole group.

### DISCLOSURE OF INVENTION

### Technical Problem

The objective of the present invention is to provide an organic electroluminescent compound imparting high luminous efficiency and a long operating lifespan to a device, and having suitable color coordinate; and an organic electroluminescent device having high efficiency and a long lifespan, using said compound in a light-emitting layer or a hole transport layer.

### Solution to Problem

The present inventors found that the objective above is achievable by an organic electroluminescent compound represented by the following formula 1:

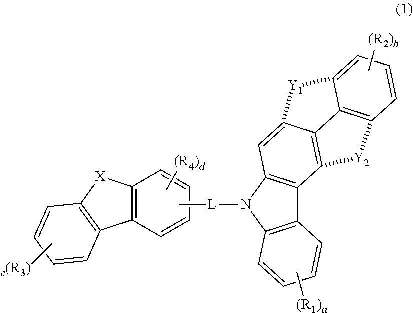

wherein

L represents a single bond, or a substituted or unsubstituted (C6-C30)arylene group;

X represents —O—, —S—, —N(R₅)—, —C(R₆)(R₇)— or —Si(R₈)(R₉)—;

Y₁ and Y₂ each independently represent —O—, —S—, —C(R₁₀)(R₁₁)—, —Si(R₁₂)(R₁₃)— or —N(R₁₄)—, provided that Y₁ and Y₂ do not simultaneously exist;

R₁ to R₄ each independently represent hydrogen, deuterium, a halogen, a substituted or unsubstituted (C1-C30)alkyl group, a substituted or unsubstituted (C6-C30)aryl group, a substituted or unsubstituted 3- to 30-membered heteroaryl group, —NR₁₅R₁₆, or —SiR₁₇R₁₈R₁₉; or are linked to an adjacent substituent(s) to form a mono- or polycyclic, 3- to 30-membered alicyclic or aromatic ring whose carbon atom(s) may be replaced with at least one hetero atom selected from nitrogen, oxygen and sulfur;

R₅ to R₁₄, and R₁₅ to R₁₉ each independently represent hydrogen, deuterium, a halogen, a substituted or unsubstituted (C1-C30)alkyl group, a substituted or unsubstituted (C6-C30)aryl group, or a substituted or unsubstituted 3- to 30-membered heteroaryl group; or are linked to an adjacent substituent(s) to form a mono- or polycyclic, 3- to 30-membered alicyclic or aromatic ring whose carbon atom(s) may be replaced with at least one hetero atom selected from nitrogen, oxygen and sulfur;

a, b and c each independently represent an integer of 1 to 4; where a, b or c is an integer of 2 or more, each of R₁, R₂ and R₃ may be the same or different;

d represents an integer of 1 to 3; where d is an integer of 2 or more, each of R₄ may be the same or different; and

the heteroaryl group contains at least one hetero atom selected from B, N, O, S, P(═O), Si and P.

### Advantageous Effects of Invention

The organic electroluminescent compounds according to the present invention have high luminous efficiency and good lifespan characteristics, and thus could provide an organic electroluminescent device having long operating lifespan.

In addition, using the organic electroluminescent compounds of the present invention as a phosphorescent host material, a hole transport material, and a mixed host material, it is possible to manufacture an OLED device with improved current efficiency.

### MODE FOR THE INVENTION

Hereinafter, the present invention will be described in detail. However, the following description is intended to explain the invention, and is not meant in any way to restrict the scope of the invention.

The present invention relates to an organic electroluminescent compound represented by formula 1, above, an organic electroluminescent material comprising the compound, and an organic electroluminescent device comprising the material.

Hereinafter, the organic electroluminescent compound represented by the above formula 1 will be described in detail.

Herein, “alkyl” includes methyl, ethyl, n-propyl, isopropyl, n-butyl, isobutyl, tert-butyl, etc.; “alkenyl” includes vinyl, 1-propenyl, 2-propenyl, 1-butenyl, 2-butenyl, 3-butenyl, 2-methylbut-2-enyl, etc.; “alkynyl” includes ethynyl, 1-propynyl, 2-propynyl, 1-butynyl, 2-butynyl, 3-butynyl, 1-methylpent-2-ynyl, etc.; “cycloalkyl” includes cyclopropyl, cyclobutyl, cyclopentyl, cyclohexyl, etc.; “5- to 7-membered heterocycloalkyl” is a cycloalkyl having at least one heteroatom selected from B, N, O, S, P(═O), Si and P, preferably O, S and N, and 5 to 7 ring backbone atoms, and includes tetrahydrofuran, pyrrolidine, thiolan, tetrahydropyran, etc.; “aryl(ene)” is a monocyclic or fused ring derived from an aromatic hydrocarbon, and includes phenyl, biphenyl, terphenyl, naphthyl, binaphthyl, phenyl naphthyl, naphthyl phenyl, fluorenyl, phenyl fluorenyl, benzofluorenyl, dibenzofluorenyl, phenanthrenyl, phenyl phenanthrenyl, anthracenyl, indenyl, triphenylenyl, pyrenyl, tetracenyl, perylenyl, chrysenyl, naphthacenyl, fluoranthenyl, etc.; “3- to 30-membered heteroaryl(ene)” is an aryl group having at least one, preferably 1 to 4 heteroatom selected from the group consisting of B, N, O, S, P(═O), Si and P, and 3 to 30 ring backbone atoms; is a monocyclic ring, or a fused ring condensed with at least one benzene ring; may be partially saturated; may be one formed by linking at least one heteroaryl or aryl group to a heteroaryl group via a single bond(s); and includes a monocyclic ring-type heteroaryl such as furyl, thiophenyl, pyrrolyl, imidazolyl, pyrazolyl, thiazolyl, thiadiazolyl, isothiazolyl, isoxazolyl, oxazolyl, oxadiazolyl, triazinyl, tetrazinyl, triazolyl, tetrazolyl, furazanyl, pyridyl, pyrazinyl, pyrimidinyl, pyridazinyl, etc., and a fused ring-type heteroaryl such as benzofuranyl, benzothiophenyl, isobenzofuranyl, dibenzofuranyl, dibenzothiophenyl, benzoimidazolyl, benzothiazolyl, benzoisothiazolyl, benzoisoxazolyl, benzoxazolyl, isoindolyl, indolyl, indazolyl, benzothiadiazolyl, quinolyl, isoquinolyl, cinnolinyl, quinazolinyl, quinoxalinyl, carbazolyl, phenoxazinyl, phenanthridinyl, benzodioxolyl, etc. Further, “halogen” includes F, Cl, Br and I.

The organic electroluminescent compound of the present invention includes compounds represented by any one of formulae 2 to 6.

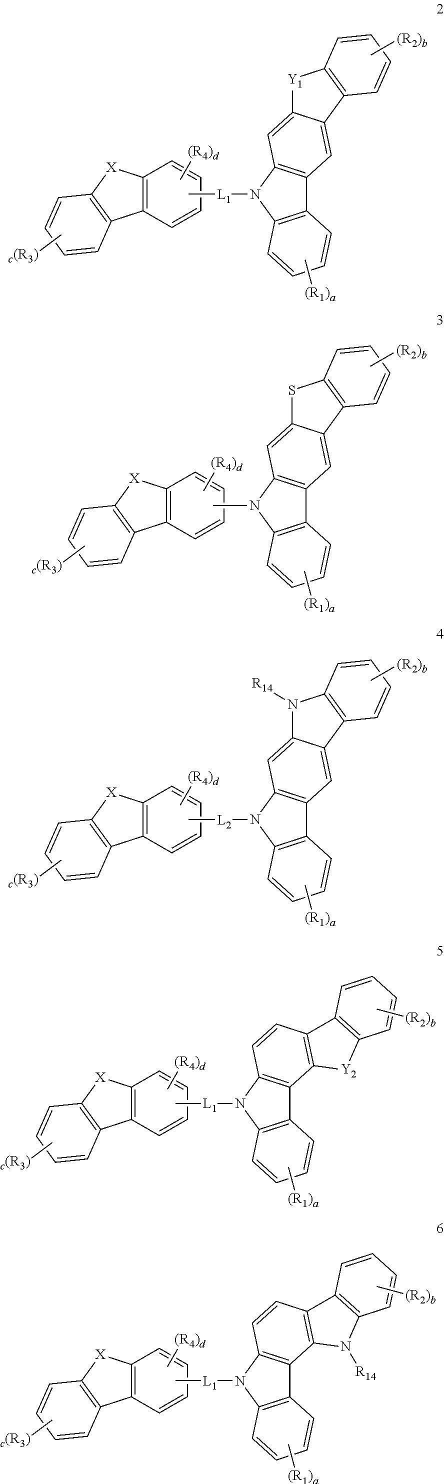

In formulae (2) to (6) above, Y₁ represents —O—, —C(R₁₀)(R₁₁)— or —Si(R₁₂)(R₁₃)—; L₁ represents a single bond, or a substituted or unsubstituted (C6-C30)arylene group; L₂ represents a substituted or unsubstituted (C6-C30)arylene group; Y₂ represents —O—, —S—, —C(R₁₀)(R₁₁)— or —Si(R₁₂)(R₁₃)—; and X, R₁ to R₄, R₁₄, a, b, c and d are as defined in formula 1.

Herein, “substituted” in the expression “substituted or unsubstituted” means that a hydrogen atom in a certain functional group is replaced with another atom or group, i.e., a substituent.

In L, R₁ to R₄, R₅ to R₁₄, and R₁₅ to R₁₉ of formula 1, the substituents of the substituted groups each independently are at least one selected from the group consisting of deuterium; a halogen; a (C1-C30)alkyl group; a halo(C1-C30)alkyl group; a (C6-C30)aryl group unsubstituted or substituted with a 3- to 30-membered heteroaryl group; a 3- to 30-membered heteroaryl group unsubstituted or substituted with a (C6-C30)aryl group; a (C3-C30)cycloalkyl group; a 5- to 7-membered heterocycloalkyl group; a tri(C1-C30)alkylsilyl group; a tri(C6-C30)arylsilyl group; a di(C1-C30)alkyl(C6-C30)arylsilyl group; a (C1-C30)alkyl di(C6-C30)arylsilyl group; a (C2-C30)alkenyl group; a (C2-C30)alkynyl group; a cyano group; a carbazolyl group; a di(C1-C30)alkylamino group; a di(C6-C30)arylamino group; a (C1-C30)alkyl(C6-C30)arylamino group; a di(C6-C30)arylboronyl group; a di(C1-C30)alkylboronyl group; a (C1-C30)alkyl(C6-C30)arylboronyl group; a (C6-C30)aryl(C1-C30)alkyl group; a (C1-C30)alkyl(C6-C30)aryl group; a carboxyl group; a nitro group; and a hydroxyl group, preferably are at least one selected from the group consisting of deuterium, a halogen, a (C1-C10)alkyl group, and a (C6-C20)aryl group, more preferably are at least one selected from the group consisting of deuterium, a halogen, a (C1-C6)alkyl group, and a (C6-C12)aryl group.

In formula 1 above, L represents a single bond, or a substituted or unsubstituted (C6-C30)arylene group, preferably a single bond, or a substituted or unsubstituted (C6-C20)arylene group, more preferably a single bond, or a (C6-C12)arylene group.

X represents —O—, —S—, —N(R₅)—, —C(R₆)(R₇)— or —Si(R₈)(R₉)—.

Y₁ and Y₂ each independently represent —O—, —S—, —C(R₁₀)(R₁₁)—, —Si(R₁₂)(R₁₃)— or —N(R₁₄)—, provided that Y₁ and Y₂ do not simultaneously exist.

R₁ to R₄ each independently represent hydrogen, deuterium, a halogen, a substituted or unsubstituted (C1-C30)alkyl group, a substituted or unsubstituted (C6-C30)aryl group, a substituted or unsubstituted 3- to 30-membered heteroaryl group, —NR₁₅R₁₆, or —SiR₁₇R₁₈R₁₉; or are linked to an adjacent substituent(s) to form a mono- or polycyclic, 3- to 30-membered alicyclic or aromatic ring whose carbon atom(s) may be replaced with at least one hetero atom selected from nitrogen, oxygen and sulfur.

Preferably, R₁ to R₄ each independently represent hydrogen, a substituted or unsubstituted (C1-C10)alkyl group, a substituted or unsubstituted (C6-C20)aryl group, a substituted or unsubstituted 5- to 20-membered heteroaryl group, —NR₁₅R₁₆, or —SiR₁₇R₁₈R₁₉; or are linked to an adjacent substituent(s) to form a mono- or polycyclic, 5- to 20-membered alicyclic or aromatic ring.

More preferably, R₁ to R₄ each independently represent hydrogen; a (C1-C6)alkyl group; a (C6-C12)aryl group unsubstituted or substituted with a (C1-C6)alkyl group; a 5- to 13-membered heteroaryl group unsubstituted or substituted with a (C6-C12)aryl group; —NR₁₅R₁₆; or —SiR₁₇R₁₈R₁₉, or are linked to an adjacent substituent(s) to form a mono- or polycyclic, 5- to 13-membered alicyclic or aromatic ring.

R₅ to R₁₄, and R₁₅ to R₁₉ each independently represent hydrogen, deuterium, a halogen, a substituted or unsubstituted (C1-C30)alkyl group, a substituted or unsubstituted (C6-C30)aryl group, or a substituted or unsubstituted 3- to 30-membered heteroaryl group; or are linked to an adjacent substituent(s) to form a mono- or polycyclic, 3- to 30-membered alicyclic or aromatic ring whose carbon atom(s) may be replaced with at least one hetero atom selected from nitrogen, oxygen and sulfur.

Preferably, R₅ to R₁₄, and R₁₅ to R₁₉ each independently represent a substituted or unsubstituted (C1-C10)alkyl group, a substituted or unsubstituted (C6-C20)aryl group, or a substituted or unsubstituted 5- to 20-membered heteroaryl group; or are linked to an adjacent substituent(s) to form a mono- or polycyclic, 5- to 20-membered alicyclic or aromatic ring.

More preferably, R₅ to R₁₄, and R₁₅ to R₁₉ each independently represent a (C1-C6)alkyl group; a (C6-C12)aryl group unsubstituted or substituted with deuterium, a halogen, or a (C1-C6)alkyl group; or a 5- to 13-membered heteroaryl group unsubstituted or substituted with a (C6-C12)aryl group, or are linked to an adjacent substituent(s) to form a mono- or polycyclic, 5- to 13-membered alicyclic or aromatic ring.

According to one embodiment of the present invention in formula 1 above, L represents a single bond, or a substituted or unsubstituted (C6-C20)arylene group; X represents —O—, —S—, —N(R₅)—, —C(R₆)(R₇)— or —Si(R₈)(R₉)—; Y₁ and Y₂ each independently represent —O—, —S—, —C(R₁₀)(R₁₁)—, —Si(R₁₂)(R₁₃)— or —N(R₁₄)—, provided that Y₁ and Y₂ do not simultaneously exist; R₁ to R₄ each independently represent hydrogen, a substituted or unsubstituted (C1-C10)alkyl group, a substituted or unsubstituted (C6-C20)aryl group, a substituted or unsubstituted 5- to 20-membered heteroaryl group, —NR₁₅R₁₆, or —SiR₁₇R₁₈R₁₉; or are linked to an adjacent substituent(s) to form a mono- or polycyclic, 5- to 20-membered alicyclic or aromatic ring; and R₅ to R₁₄, and R₁₅ to R₁₉ each independently represent a substituted or unsubstituted (C1-C10)alkyl group, a substituted or unsubstituted (C6-C20)aryl group, or a substituted or unsubstituted 5- to 20-membered heteroaryl group; or are linked to an adjacent substituent(s) to form a mono- or polycyclic, 5- to 20-membered alicyclic or aromatic ring.

According to another embodiment of the present invention in formula 1 above, L represents a single bond, or a (C6-C12)arylene group, X represents —O—, —S—, —N(R₅)—, —C(R₆)(R₇)— or —Si(R₈)(R₉)—, Y₁ and Y₂ each independently represent —O—, —S—, —C(R₁₀)(R₁₁)—, —Si(R₁₂)(R₁₃)— or —N(R₁₄)—, provided that Y₁ and Y₂ do not simultaneously exist, R₁ to R₄ each independently represent hydrogen; a (C1-C6)alkyl group; a (C6-C12)aryl group unsubstituted or substituted with a (C1-C6)alkyl group; or a 5- to 13-membered heteroaryl group unsubstituted or substituted with a (C6-C12)aryl group; —NR₁₅R₁₆; or —SiR₁₇R₁₈R₁₉, or are linked to an adjacent substituent(s) to form a mono- or polycyclic, 5- to 13-membered alicyclic or aromatic ring, and R₅ to R₁₄, and R₁₅ to R₁₉ each independently represent a (C1-C6)alkyl group; a (C6-C12)aryl group unsubstituted or substituted with deuterium, a halogen, or a (C1-C6)alkyl group; or a 5- to 13-membered heteroaryl group unsubstituted or substituted with a (C6-C12)aryl group, or are linked to an adjacent substituent(s) to form a mono- or polycyclic, 5- to 13-membered alicyclic or aromatic ring.

Specifically, In formulae 2 to 6 above, L₁ represents a single bond, or a (C6-C30)arylene group; L₂ represents a (C6-C30)arylene group; X represents —O—, —S—, —N(R₅)—, —C(R₆)(R₇)— or —Si(R₈)(R₉)—; R₁ to R₄ each independently represent hydrogen, deuterium, a halogen, a (C1-C30)alkyl group, a substituted or unsubstituted (C6-C30)aryl group, a substituted or unsubstituted 3- to 30-membered heteroaryl group, —NR₁₅R₁₆, or —SiR₁₇R₁₈R₁₉; or are linked to an adjacent substituent(s) to form a mono- or polycyclic, 3- to 30-membered alicyclic or aromatic ring whose carbon atom(s) may be replaced with at least one hetero atom selected from nitrogen, oxygen and sulfur; R₅ to R₁₄ each independently represent a (C1-C30)alkyl group, a substituted or unsubstituted (C6-C30)aryl group, or a substituted or unsubstituted 3- to 30-membered heteroaryl group; or R₆ and R₇, R₁₀ and R₁₁ are linked to each other to form a mono- or polycyclic, 3- to 30-membered alicyclic or aromatic ring; R₁₅ to R₁₉ each independently represent a (C1-C30)alkyl group, a (C6-C30)aryl group, or a 3- to 30-membered heteroaryl group; and the arylene group in L₁ and L₂, and the alkyl, aryl, and heteroaryl groups in R₁ to R₄, R₅ to R₁₄, and R₁₅ to R₁₉ can be further substituted with at least one selected from the group consisting of deuterium; a halogen; a (C1-C30)alkyl group; a halo(C1-C30)alkyl group; a (C6-C30)aryl group unsubstituted or substituted with a 3- to 30-membered heteroaryl group; a 3- to 30-membered heteroaryl group unsubstituted or substituted with a (C6-C30)aryl group; a (C3-C30)cycloalkyl group; a (C6-C30)aryl(C1-C30)alkyl group; and a (C1-C30)alkyl(C6-C30)aryl group.

The representative organic electroluminescent compounds of the present invention include the following compounds, but not limited thereto:

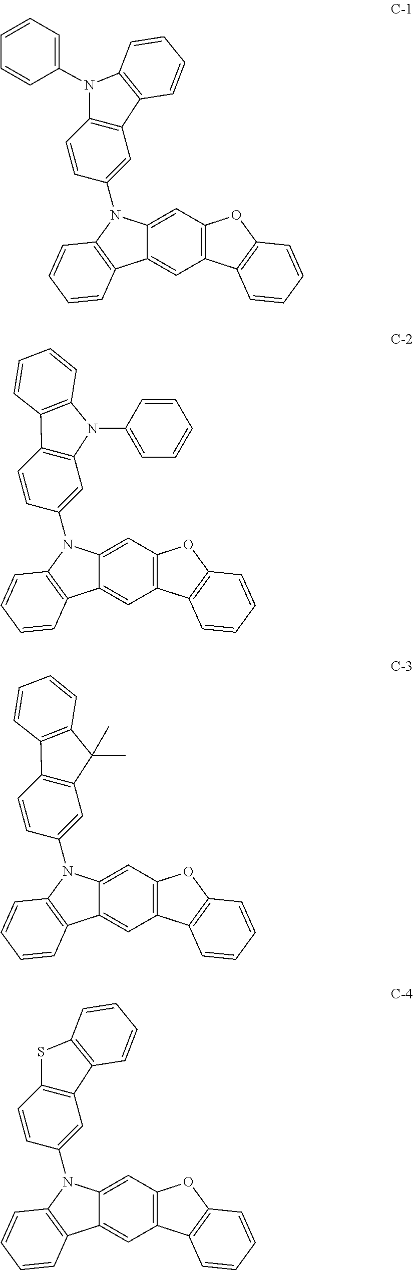 [SMILES: c1ccc(-n2c3ccccc3c3cc(-n4c5ccccc5c5cc6c(cc54)oc4ccccc46)ccc32)cc1 ; c1ccc(-n2c3ccccc3c3ccc(-n4c5ccccc5c5cc6c(cc54)oc4ccccc46)cc32)cc1 ; CC1(C)c2ccccc2-c2ccc(-n3c4ccccc4c4cc5c(cc43)oc3ccccc35)cc21 ; c1ccc2c(c1)oc1cc3c(cc12)c1ccccc1n3-c1ccc2sc3ccccc3c2c1]

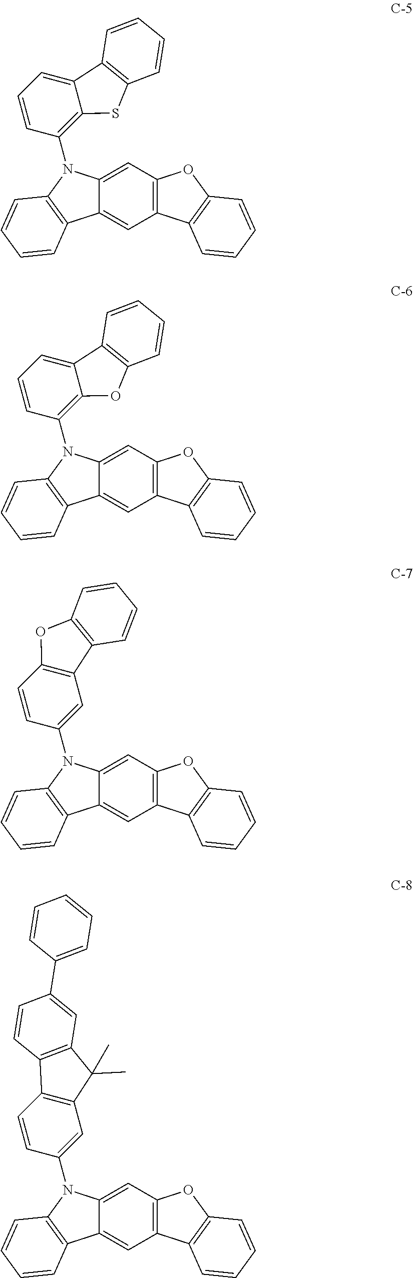 [SMILES: c1ccc2c(c1)oc1cc3c(cc12)c1ccccc1n3-c1cccc2c1sc1ccccc12 ; c1ccc2c(c1)oc1cc3c(cc12)c1ccccc1n3-c1cccc2c1oc1ccccc12 ; c1ccc2c(c1)oc1ccc(-n3c4ccccc4c4cc5c(cc43)oc3ccccc35)cc12 ; CC1(C)c2cc(-c3ccccc3)ccc2-c2ccc(-n3c4ccccc4c4cc5c(cc43)oc3ccccc35)cc21]

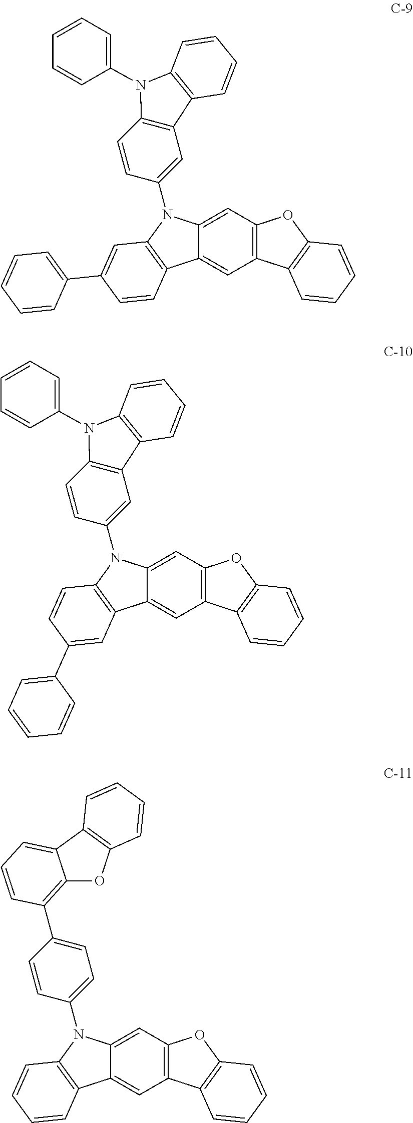 [SMILES: c1ccc(-c2ccc3c4cc5c(cc4n(-c4ccc6c(c4)c4ccccc4n6-c4ccccc4)c3c2)oc2ccccc25)cc1 ; c1ccc(-c2ccc3c(c2)c2cc4c(cc2n3-c2ccc3c(c2)c2ccccc2n3-c2ccccc2)oc2ccccc24)cc1 ; c1ccc2c(c1)oc1cc3c(cc12)c1ccccc1n3-c1ccc(-c2cccc3c2oc2ccccc23)cc1]

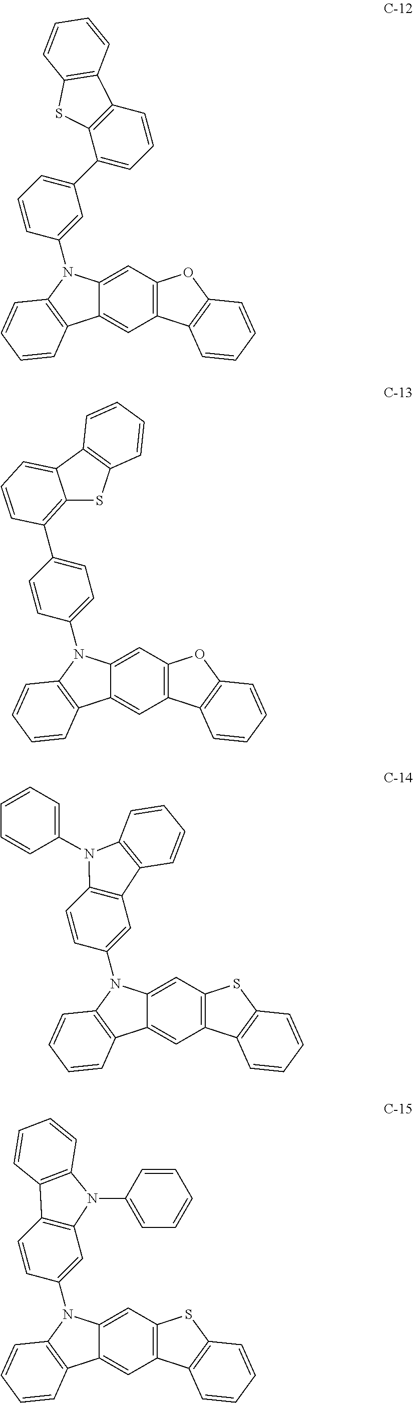

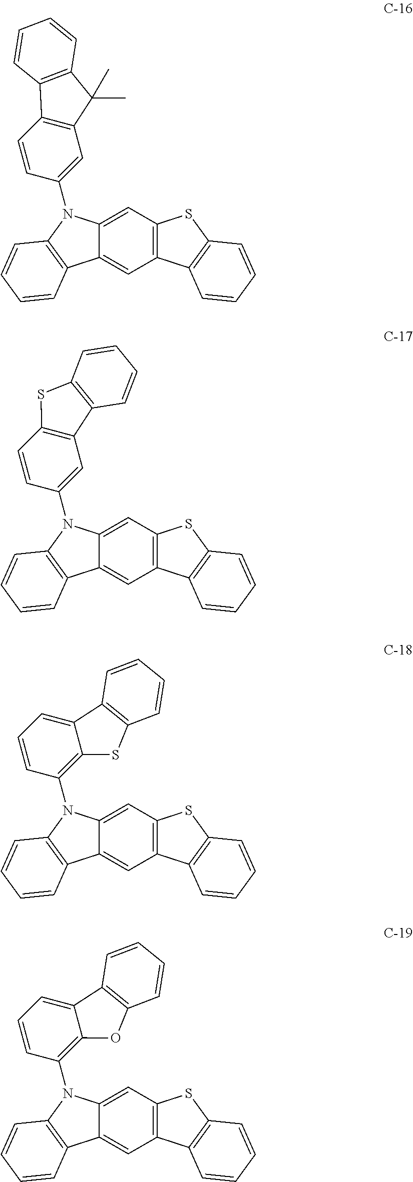 [SMILES: CC1(C)c2ccccc2-c2ccc(-n3c4ccccc4c4cc5c(cc43)sc3ccccc35)cc21 ; c1ccc2c(c1)sc1ccc(-n3c4ccccc4c4cc5c(cc43)sc3ccccc35)cc12 ; c1ccc2c(c1)sc1cc3c(cc12)c1ccccc1n3-c1cccc2c1sc1ccccc12 ; c1ccc2c(c1)oc1c(-n3c4ccccc4c4cc5c(cc43)sc3ccccc35)cccc12]

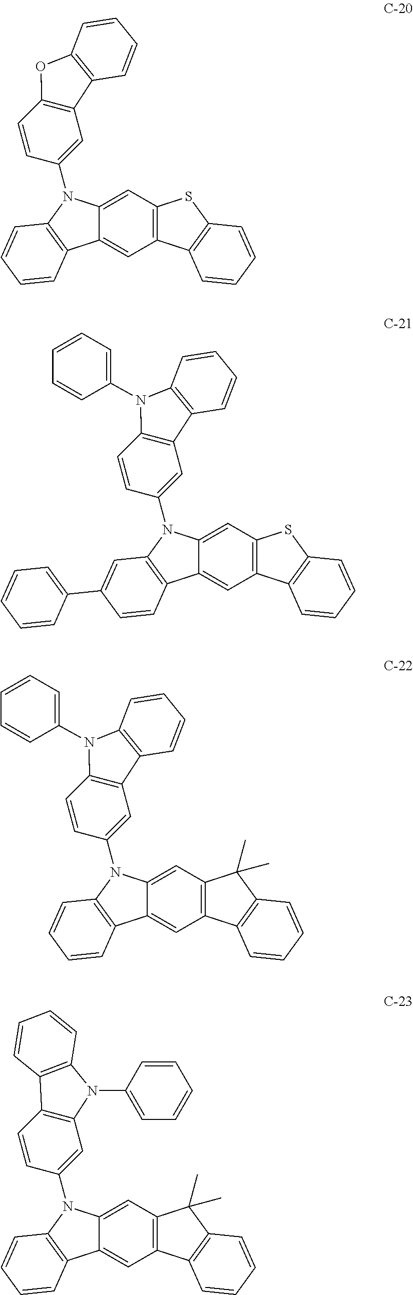 [SMILES: c1ccc2c(c1)oc1ccc(-n3c4ccccc4c4cc5c(cc43)sc3ccccc35)cc12 ; c1ccc(-c2ccc3c4cc5c(cc4n(-c4ccc6c(c4)c4ccccc4n6-c4ccccc4)c3c2)sc2ccccc25)cc1 ; CC1(C)c2ccccc2-c2cc3c4ccccc4n(-c4ccc5c(c4)c4ccccc4n5-c4ccccc4)c3cc21 ; CC1(C)c2ccccc2-c2cc3c4ccccc4n(-c4ccc5c6ccccc6n(-c6ccccc6)c5c4)c3cc21]

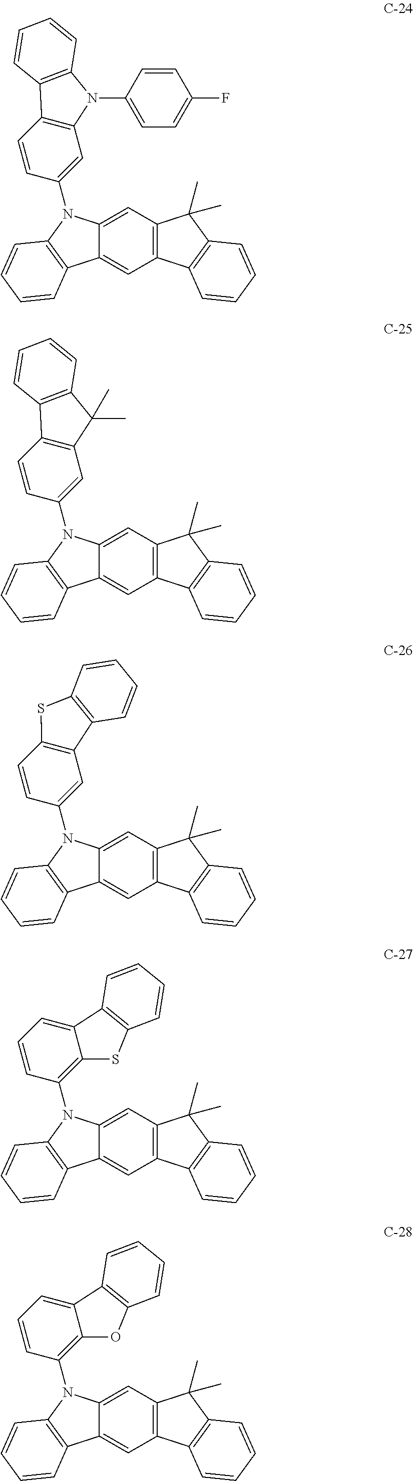

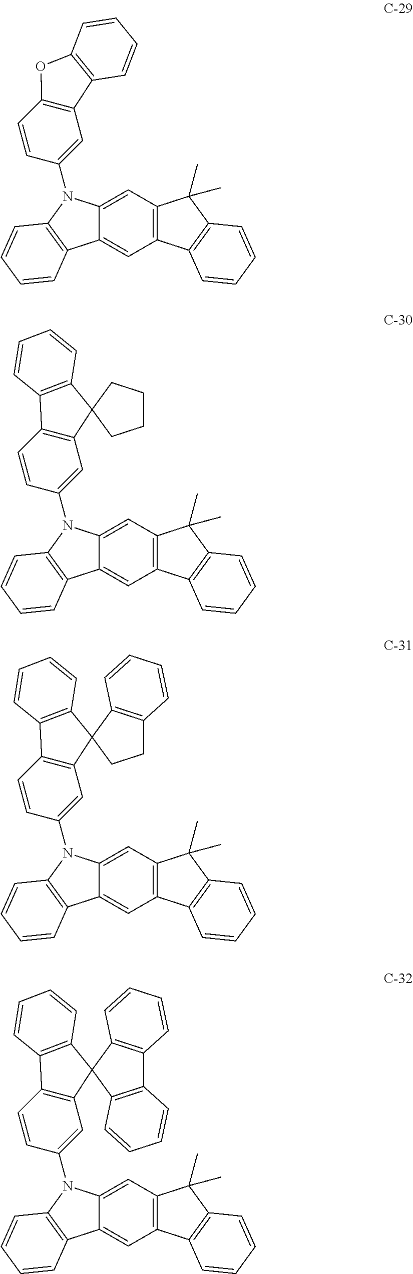 [SMILES: CC1(C)c2ccccc2-c2cc3c4ccccc4n(-c4ccc5oc6ccccc6c5c4)c3cc21 ; CC1(C)c2ccccc2-c2cc3c4ccccc4n(-c4ccc5c(c4)C4(CCCC4)c4ccccc4-5)c3cc21 ; CC1(C)c2ccccc2-c2cc3c4ccccc4n(-c4ccc5c(c4)C4(CCc6ccccc64)c4ccccc4-5)c3cc21 ; CC1(C)c2ccccc2-c2cc3c4ccccc4n(-c4ccc5c(c4)C4(c6ccccc6-c6ccccc64)c4ccccc4-5)c3cc21]

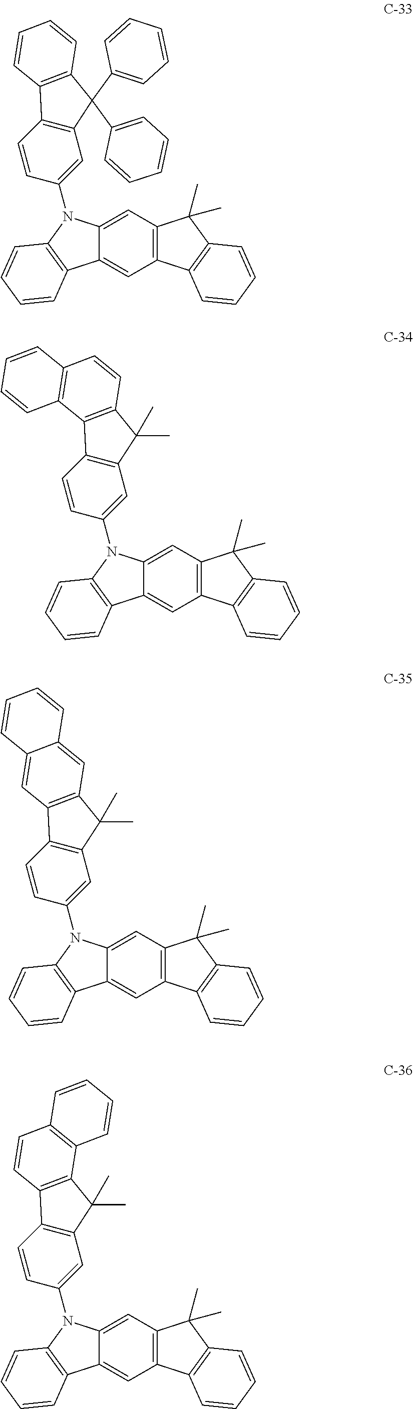

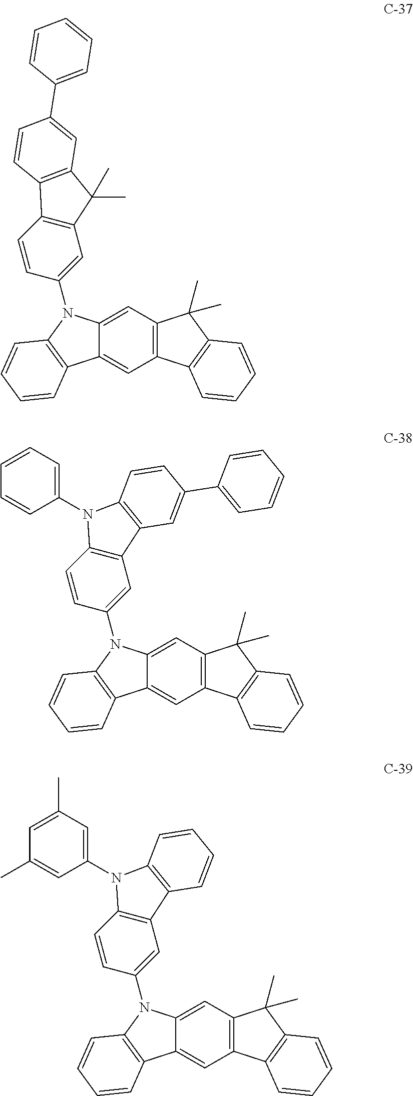

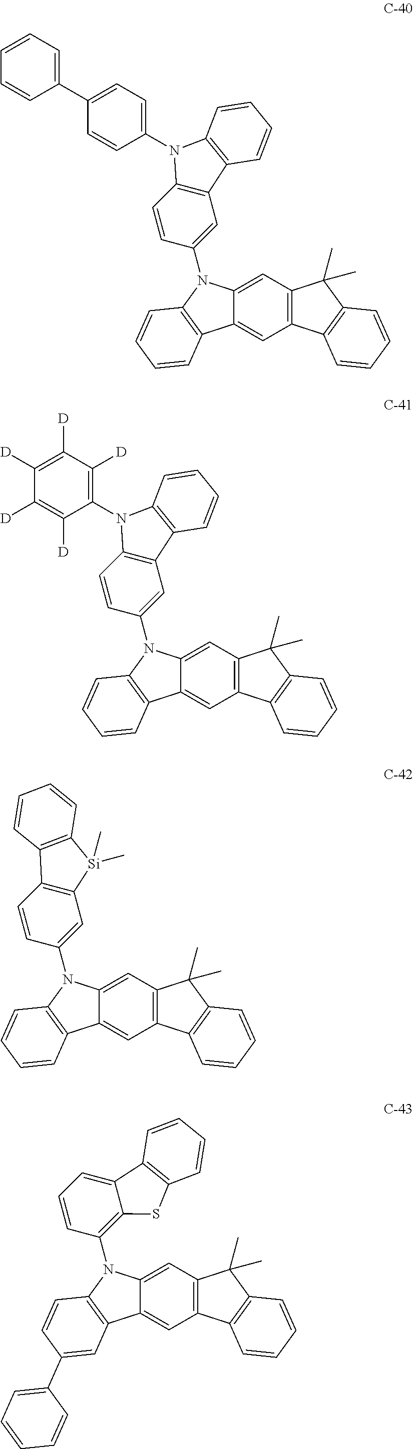 [SMILES: CC1(C)c2ccccc2-c2cc3c4ccccc4n(-c4ccc5c(c4)c4ccccc4n5-c4ccc(-c5ccccc5)cc4)c3cc21 ; [2H]c1c([2H])c([2H])c(-n2c3ccccc3c3cc(-n4c5ccccc5c5cc6c(cc54)C(C)(C)c4ccccc4-6)ccc32)c([2H])c1[2H] ; CC1(C)c2ccccc2-c2cc3c4ccccc4n(-c4ccc5c(c4)[Si](C)(C)c4ccccc4-5)c3cc21 ; CC1(C)c2ccccc2-c2cc3c4cc(-c5ccccc5)ccc4n(-c4cccc5c4sc4ccccc45)c3cc21]

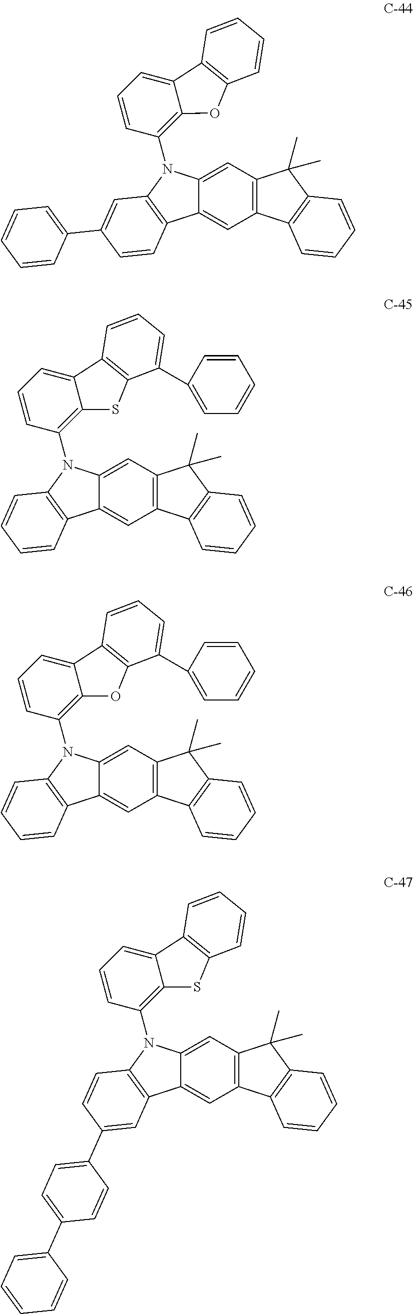 [SMILES: CC1(C)c2ccccc2-c2cc3c4ccc(-c5ccccc5)cc4n(-c4cccc5c4oc4ccccc45)c3cc21 ; CC1(C)c2ccccc2-c2cc3c4ccccc4n(-c4cccc5c4sc4c(-c6ccccc6)cccc45)c3cc21 ; CC1(C)c2ccccc2-c2cc3c4ccccc4n(-c4cccc5c4oc4c(-c6ccccc6)cccc45)c3cc21 ; CC1(C)c2ccccc2-c2cc3c4cc(-c5ccc(-c6ccccc6)cc5)ccc4n(-c4cccc5c4sc4ccccc45)c3cc21]

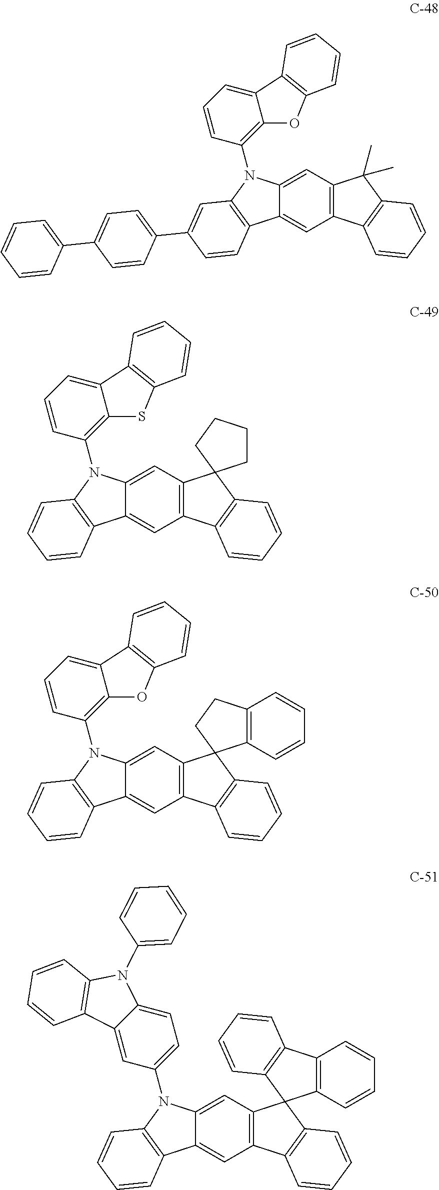 [SMILES: CC1(C)c2ccccc2-c2cc3c4ccc(-c5ccc(-c6ccccc6)cc5)cc4n(-c4cccc5c4oc4ccccc45)c3cc21 ; c1ccc2c(c1)-c1cc3c4ccccc4n(-c4cccc5c4sc4ccccc45)c3cc1C21CCCC1 ; c1ccc2c(c1)CCC21c2ccccc2-c2cc3c4ccccc4n(-c4cccc5c4oc4ccccc45)c3cc21 ; c1ccc(-n2c3ccccc3c3cc(-n4c5ccccc5c5cc6c(cc54)C4(c5ccccc5-c5ccccc54)c4ccccc4-6)ccc32)cc1]

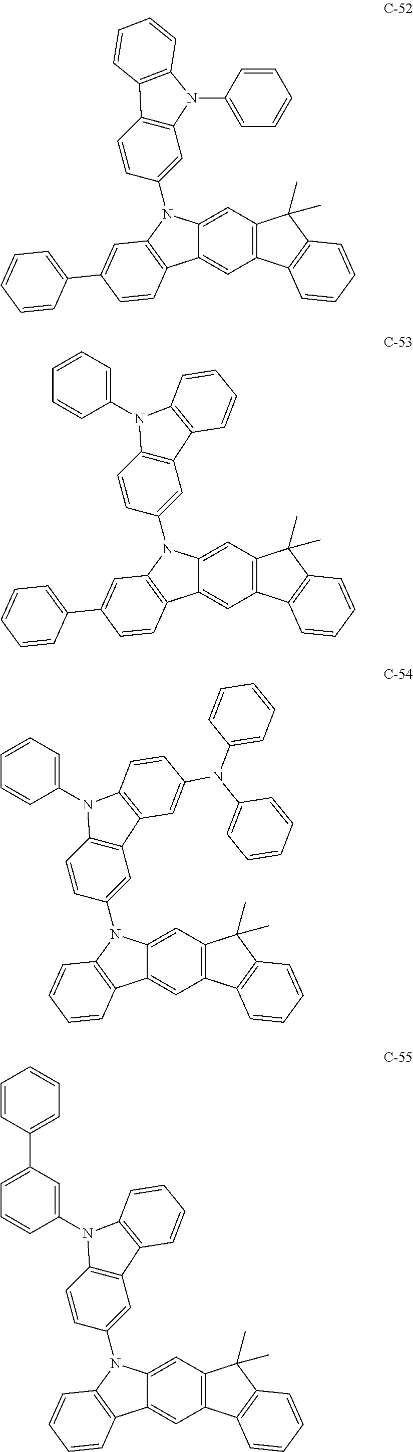 [SMILES: CC1(C)c2ccccc2-c2cc3c4ccc(-c5ccccc5)cc4n(-c4ccc5c6ccccc6n(-c6ccccc6)c5c4)c3cc21 ; CC1(C)c2ccccc2-c2cc3c4ccc(-c5ccccc5)cc4n(-c4ccc5c(c4)c4ccccc4n5-c4ccccc4)c3cc21 ; CC1(C)c2ccccc2-c2cc3c4ccccc4n(-c4ccc5c(c4)c4cc(N(c6ccccc6)c6ccccc6)ccc4n5-c4ccccc4)c3cc21 ; CC1(C)c2ccccc2-c2cc3c4ccccc4n(-c4ccc5c(c4)c4ccccc4n5-c4cccc(-c5ccccc5)c4)c3cc21]

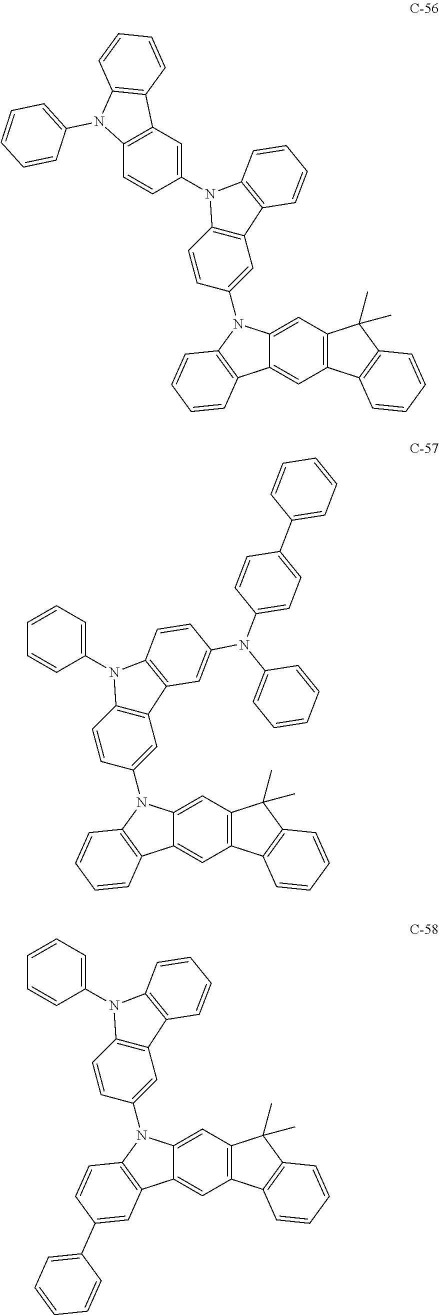 [SMILES: CC1(C)c2ccccc2-c2cc3c4ccccc4n(-c4ccc5c(c4)c4ccccc4n5-c4ccc5c(c4)c4ccccc4n5-c4ccccc4)c3cc21 ; CC1(C)c2ccccc2-c2cc3c4ccccc4n(-c4ccc5c(c4)c4cc(N(c6ccccc6)c6ccc(-c7ccccc7)cc6)ccc4n5-c4ccccc4)c3cc21 ; CC1(C)c2ccccc2-c2cc3c4cc(-c5ccccc5)ccc4n(-c4ccc5c(c4)c4ccccc4n5-c4ccccc4)c3cc21]

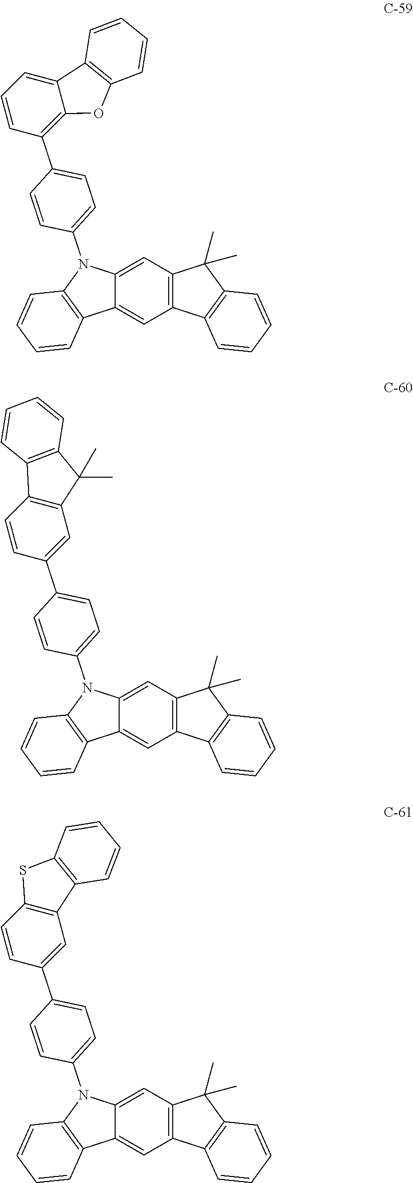

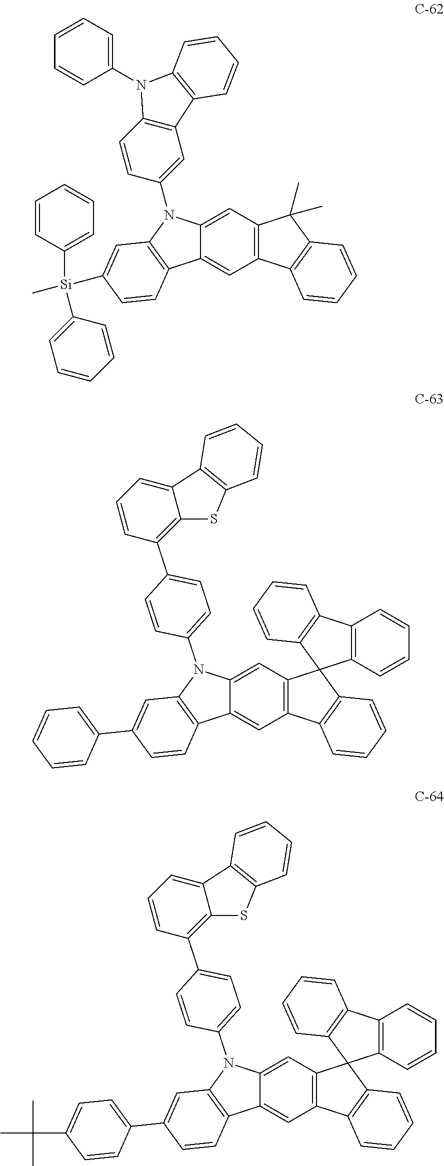 [SMILES: CC1(C)c2ccccc2-c2cc3c4ccc([Si](C)(c5ccccc5)c5ccccc5)cc4n(-c4ccc5c(c4)c4ccccc4n5-c4ccccc4)c3cc21 ; c1ccc(-c2ccc3c4cc5c(cc4n(-c4ccc(-c6cccc7c6sc6ccccc67)cc4)c3c2)C2(c3ccccc3-c3ccccc32)c2ccccc2-5)cc1 ; CC(C)(C)c1ccc(-c2ccc3c4cc5c(cc4n(-c4ccc(-c6cccc7c6sc6ccccc67)cc4)c3c2)C2(c3ccccc3-c3ccccc32)c2ccccc2-5)cc1]

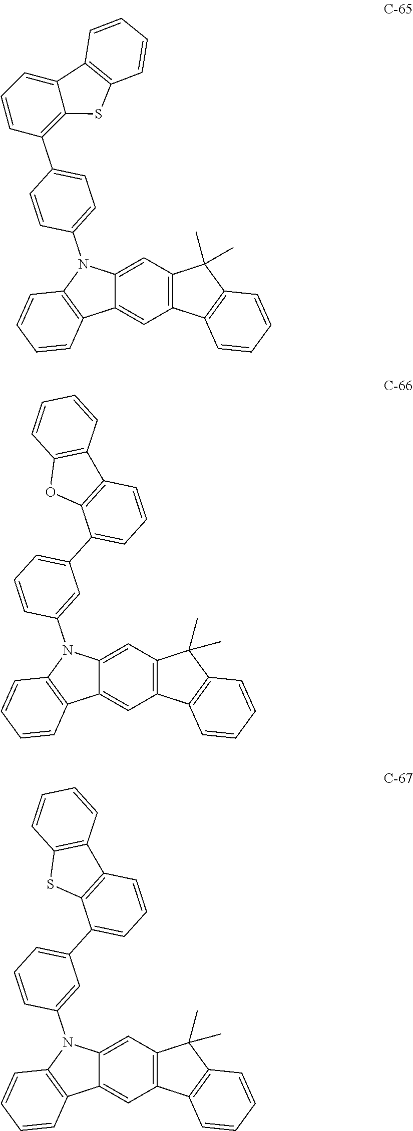 [SMILES: CC1(C)c2ccccc2-c2cc3c4ccccc4n(-c4ccc(-c5cccc6c5sc5ccccc56)cc4)c3cc21 ; CC1(C)c2ccccc2-c2cc3c4ccccc4n(-c4cccc(-c5cccc6c5oc5ccccc56)c4)c3cc21 ; CC1(C)c2ccccc2-c2cc3c4ccccc4n(-c4cccc(-c5cccc6c5sc5ccccc56)c4)c3cc21]

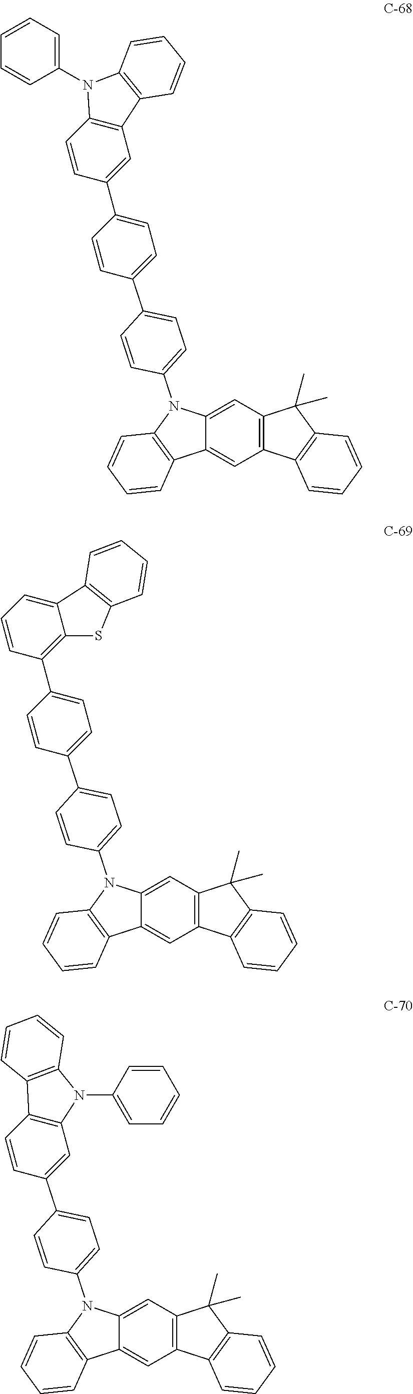 [SMILES: CC1(C)c2ccccc2-c2cc3c4ccccc4n(-c4ccc(-c5ccc(-c6ccc7c(c6)c6ccccc6n7-c6ccccc6)cc5)cc4)c3cc21 ; CC1(C)c2ccccc2-c2cc3c4ccccc4n(-c4ccc(-c5ccc(-c6cccc7c6sc6ccccc67)cc5)cc4)c3cc21 ; CC1(C)c2ccccc2-c2cc3c4ccccc4n(-c4ccc(-c5ccc6c7ccccc7n(-c7ccccc7)c6c5)cc4)c3cc21]

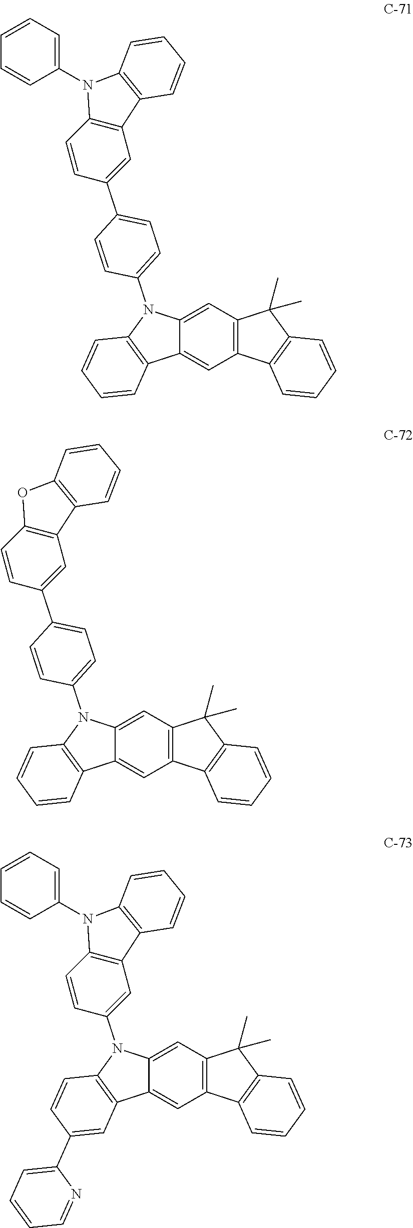 [SMILES: CC1(C)c2ccccc2-c2cc3c4ccccc4n(-c4ccc(-c5ccc6c(c5)c5ccccc5n6-c5ccccc5)cc4)c3cc21 ; CC1(C)c2ccccc2-c2cc3c4ccccc4n(-c4ccc(-c5ccc6oc7ccccc7c6c5)cc4)c3cc21 ; CC1(C)c2ccccc2-c2cc3c4cc(-c5ccccn5)ccc4n(-c4ccc5c(c4)c4ccccc4n5-c4ccccc4)c3cc21]

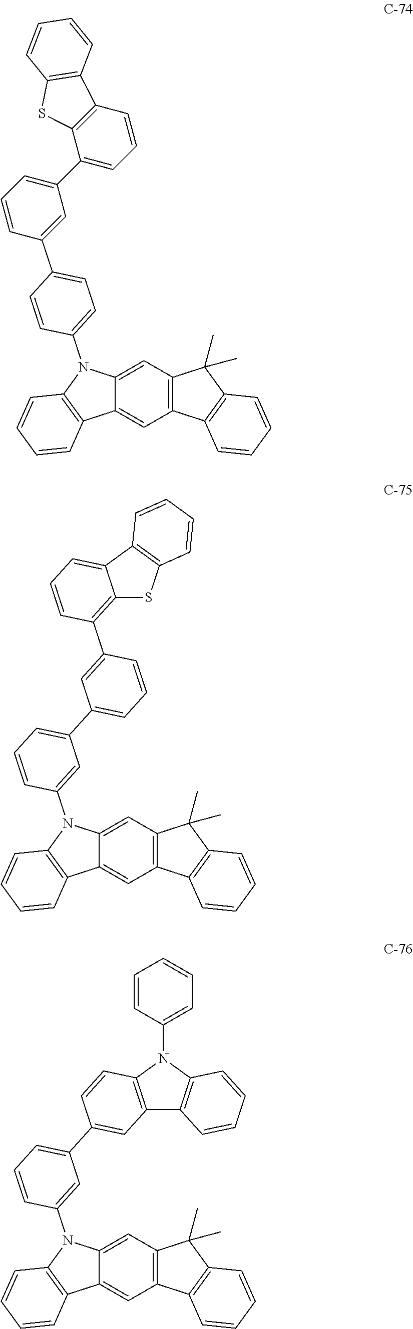 [SMILES: CC1(C)c2ccccc2-c2cc3c4ccccc4n(-c4ccc(-c5cccc(-c6cccc7c6sc6ccccc67)c5)cc4)c3cc21 ; CC1(C)c2ccccc2-c2cc3c4ccccc4n(-c4cccc(-c5cccc(-c6cccc7c6sc6ccccc67)c5)c4)c3cc21 ; CC1(C)c2ccccc2-c2cc3c4ccccc4n(-c4cccc(-c5ccc6c(c5)c5ccccc5n6-c5ccccc5)c4)c3cc21]

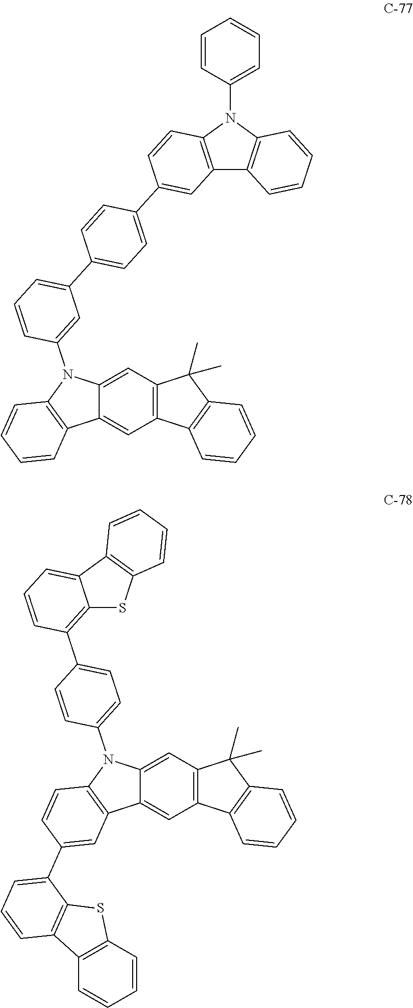 [SMILES: CC1(C)c2ccccc2-c2cc3c4ccccc4n(-c4cccc(-c5ccc(-c6ccc7c(c6)c6ccccc6n7-c6ccccc6)cc5)c4)c3cc21 ; CC1(C)c2ccccc2-c2cc3c4cc(-c5cccc6c5sc5ccccc56)ccc4n(-c4ccc(-c5cccc6c5sc5ccccc56)cc4)c3cc21]

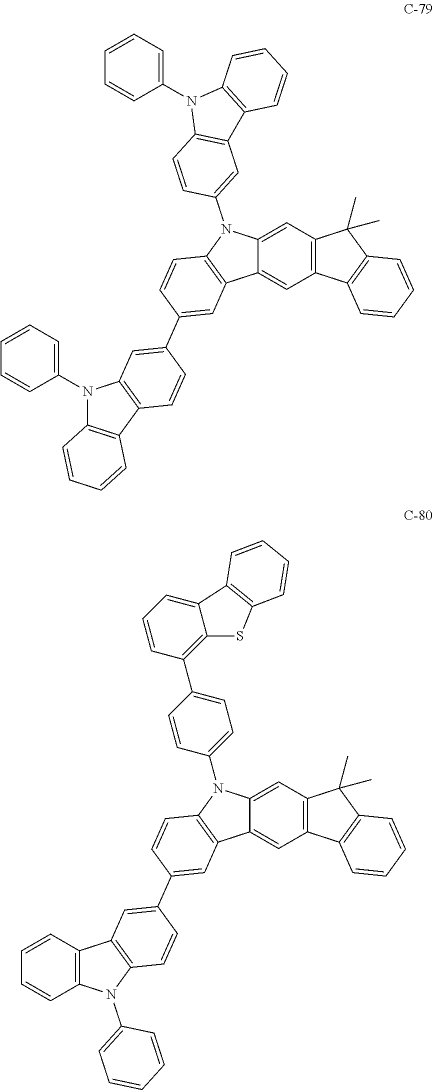 [SMILES: CC1(C)c2ccccc2-c2cc3c4cc(-c5ccc6c7ccccc7n(-c7ccccc7)c6c5)ccc4n(-c4ccc5c(c4)c4ccccc4n5-c4ccccc4)c3cc21 ; CC1(C)c2ccccc2-c2cc3c4cc(-c5ccc6c(c5)c5ccccc5n6-c5ccccc5)ccc4n(-c4ccc(-c5cccc6c5sc5ccccc56)cc4)c3cc21]

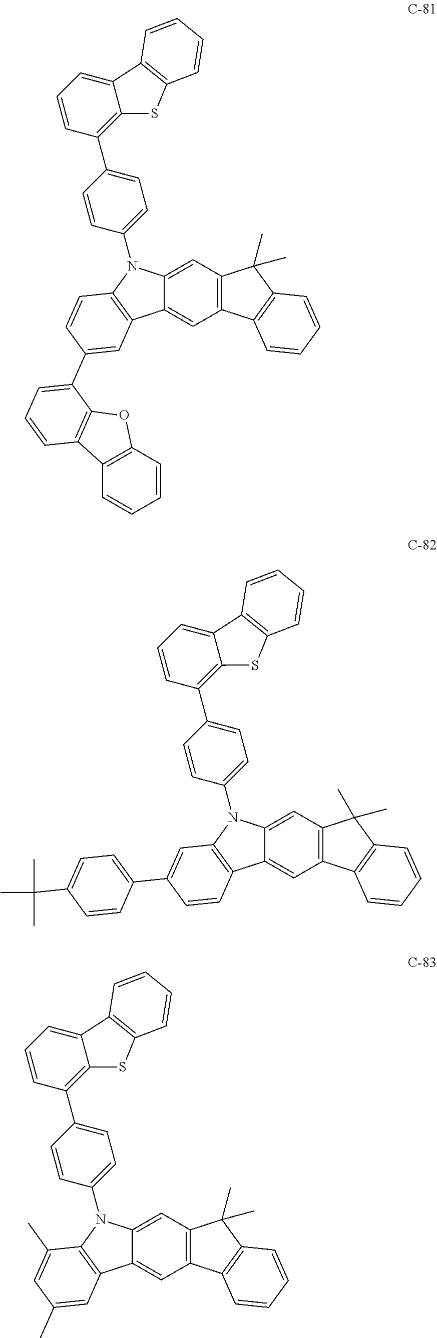 [SMILES: CC1(C)c2ccccc2-c2cc3c4cc(-c5cccc6c5oc5ccccc56)ccc4n(-c4ccc(-c5cccc6c5sc5ccccc56)cc4)c3cc21 ; CC(C)(C)c1ccc(-c2ccc3c4cc5c(cc4n(-c4ccc(-c6cccc7c6sc6ccccc67)cc4)c3c2)C(C)(C)c2ccccc2-5)cc1 ; Cc1cc(C)c2c(c1)c1cc3c(cc1n2-c1ccc(-c2cccc4c2sc2ccccc24)cc1)C(C)(C)c1ccccc1-3]

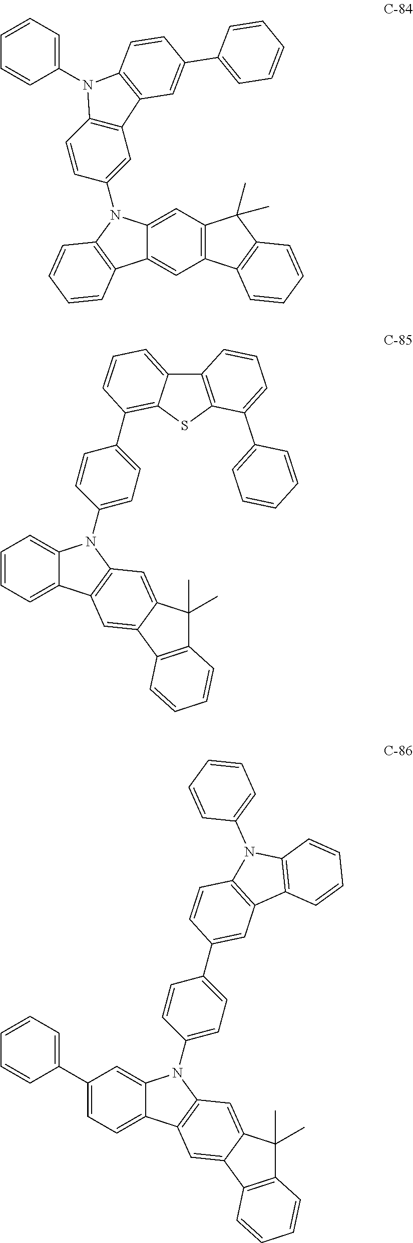 [SMILES: CC1(C)c2ccccc2-c2cc3c4ccccc4n(-c4ccc5c(c4)c4cc(-c6ccccc6)ccc4n5-c4ccccc4)c3cc21 ; CC1(C)c2ccccc2-c2cc3c4ccccc4n(-c4ccc(-c5cccc6c5sc5c(-c7ccccc7)cccc56)cc4)c3cc21 ; CC1(C)c2ccccc2-c2cc3c4ccc(-c5ccccc5)cc4n(-c4ccc(-c5ccc6c(c5)c5ccccc5n6-c5ccccc5)cc4)c3cc21]

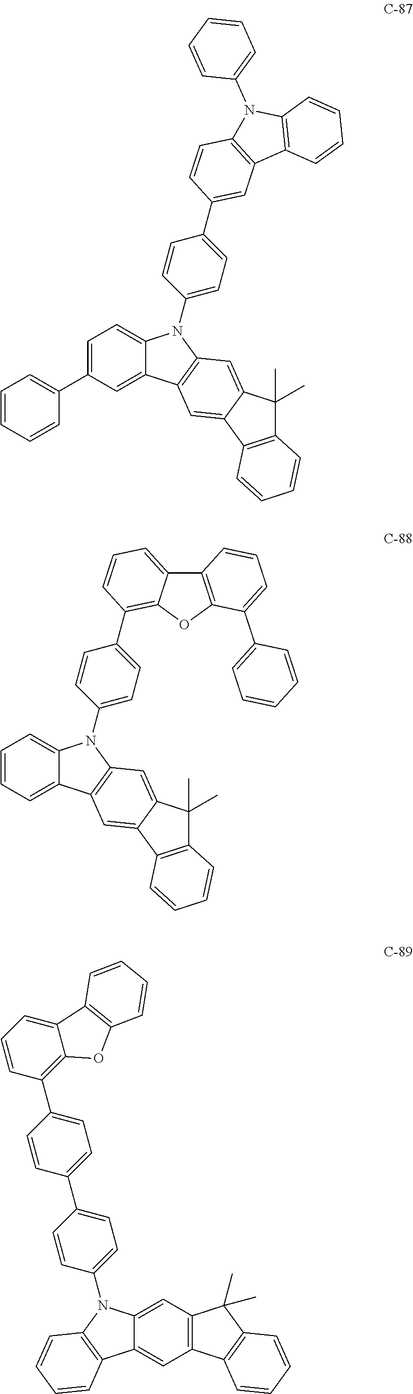 [SMILES: CC1(C)c2ccccc2-c2cc3c4cc(-c5ccccc5)ccc4n(-c4ccc(-c5ccc6c(c5)c5ccccc5n6-c5ccccc5)cc4)c3cc21 ; CC1(C)c2ccccc2-c2cc3c4ccccc4n(-c4ccc(-c5cccc6c5oc5c(-c7ccccc7)cccc56)cc4)c3cc21 ; CC1(C)c2ccccc2-c2cc3c4ccccc4n(-c4ccc(-c5ccc(-c6cccc7c6oc6ccccc67)cc5)cc4)c3cc21]

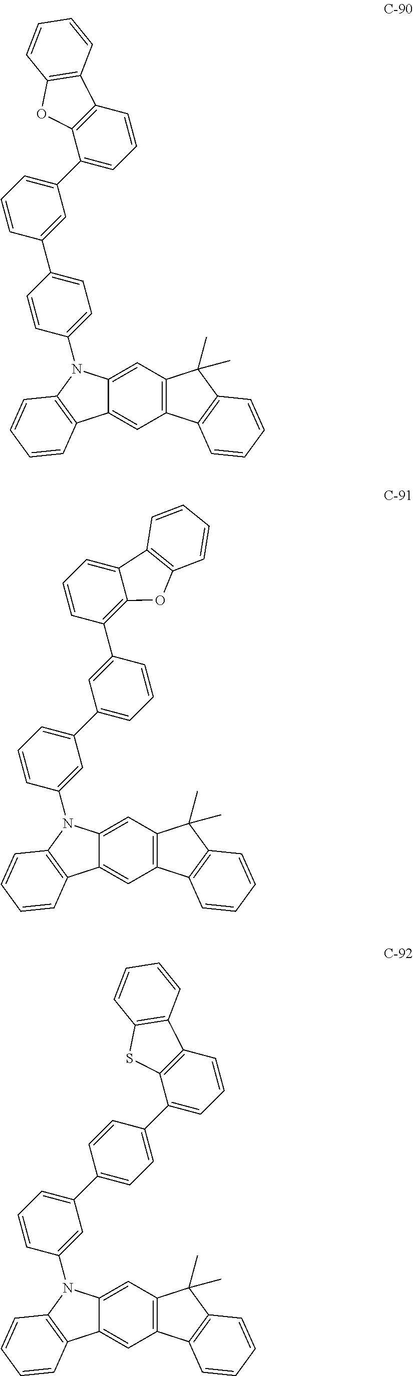 [SMILES: CC1(C)c2ccccc2-c2cc3c4ccccc4n(-c4ccc(-c5cccc(-c6cccc7c6oc6ccccc67)c5)cc4)c3cc21 ; CC1(C)c2ccccc2-c2cc3c4ccccc4n(-c4cccc(-c5cccc(-c6cccc7c6oc6ccccc67)c5)c4)c3cc21 ; CC1(C)c2ccccc2-c2cc3c4ccccc4n(-c4cccc(-c5ccc(-c6cccc7c6sc6ccccc67)cc5)c4)c3cc21]

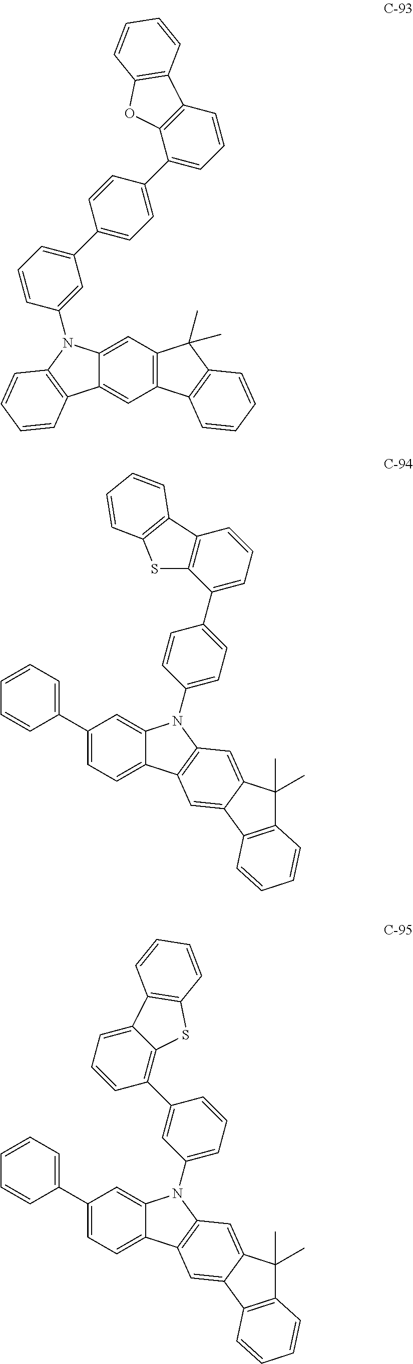 [SMILES: CC1(C)c2ccccc2-c2cc3c4ccccc4n(-c4cccc(-c5ccc(-c6cccc7c6oc6ccccc67)cc5)c4)c3cc21 ; CC1(C)c2ccccc2-c2cc3c4ccc(-c5ccccc5)cc4n(-c4ccc(-c5cccc6c5sc5ccccc56)cc4)c3cc21 ; CC1(C)c2ccccc2-c2cc3c4ccc(-c5ccccc5)cc4n(-c4cccc(-c5cccc6c5sc5ccccc56)c4)c3cc21]

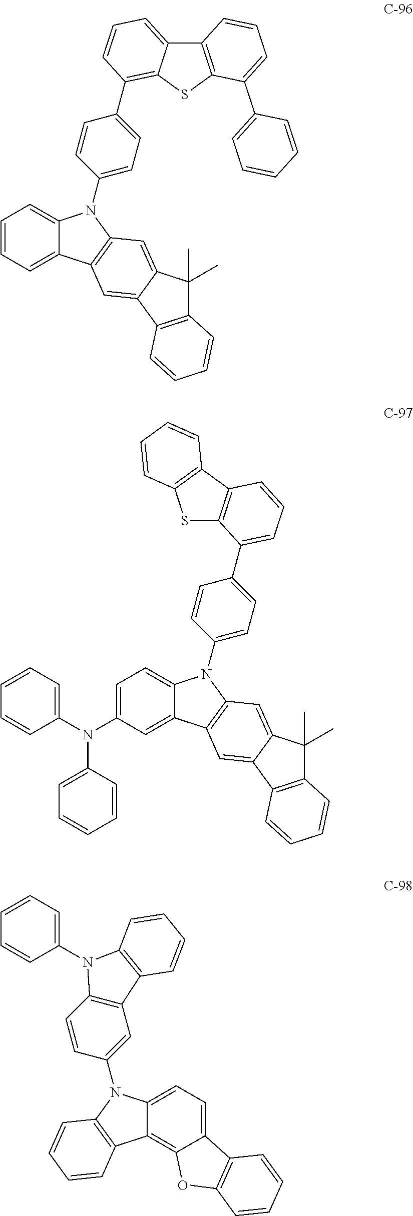

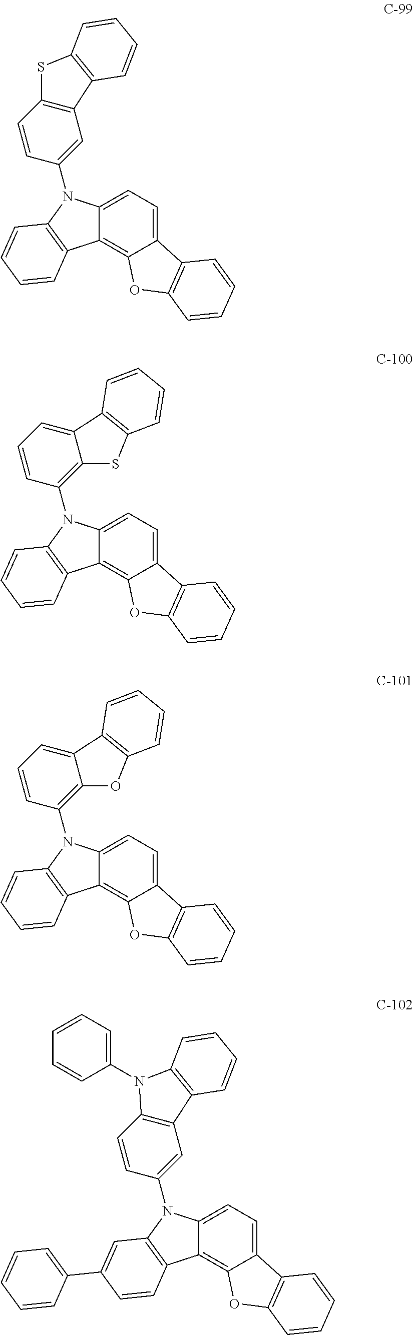 [SMILES: c1ccc2c(c1)oc1c2ccc2c1c1ccccc1n2-c1ccc2sc3ccccc3c2c1 ; c1ccc2c(c1)oc1c2ccc2c1c1ccccc1n2-c1cccc2c1sc1ccccc12 ; c1ccc2c(c1)oc1c(-n3c4ccccc4c4c5oc6ccccc6c5ccc43)cccc12 ; c1ccc(-c2ccc3c4c5oc6ccccc6c5ccc4n(-c4ccc5c(c4)c4ccccc4n5-c4ccccc4)c3c2)cc1]

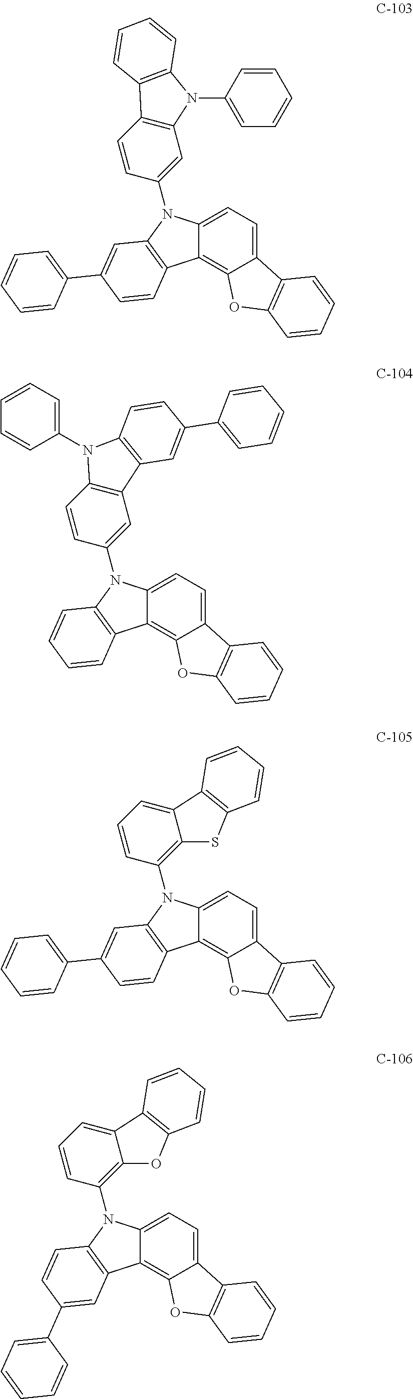

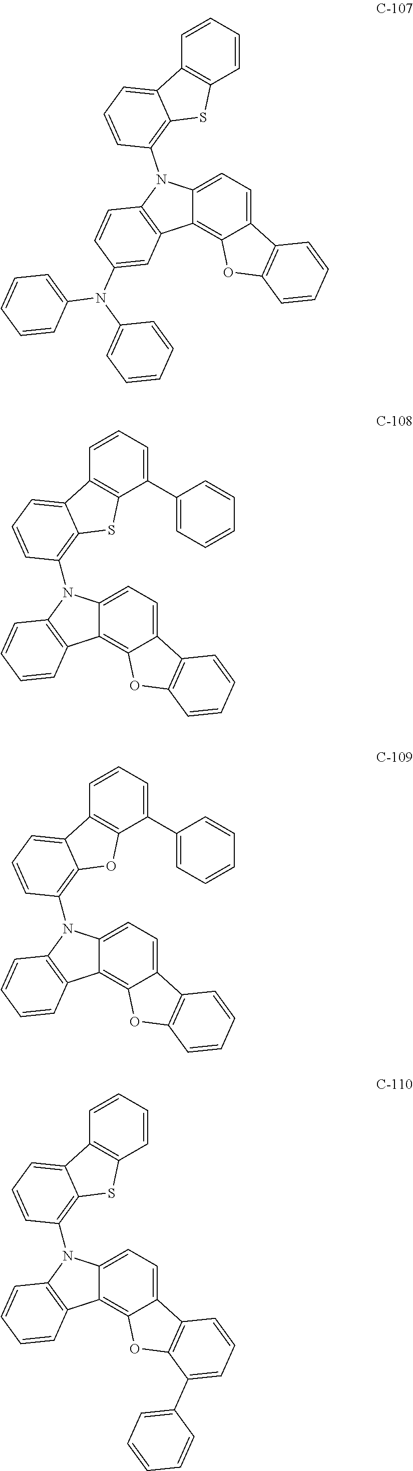 [SMILES: c1ccc(N(c2ccccc2)c2ccc3c(c2)c2c4oc5ccccc5c4ccc2n3-c2cccc3c2sc2ccccc23)cc1 ; c1ccc(-c2cccc3c2sc2c(-n4c5ccccc5c5c6oc7ccccc7c6ccc54)cccc23)cc1 ; c1ccc(-c2cccc3c2oc2c(-n4c5ccccc5c5c6oc7ccccc7c6ccc54)cccc23)cc1 ; c1ccc(-c2cccc3c2oc2c3ccc3c2c2ccccc2n3-c2cccc3c2sc2ccccc23)cc1]

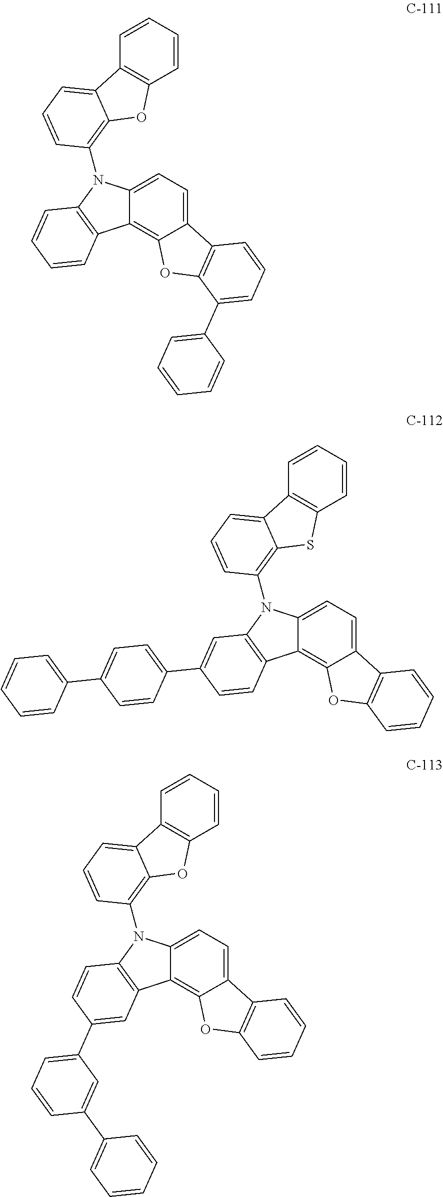 [SMILES: c1ccc(-c2cccc3c2oc2c3ccc3c2c2ccccc2n3-c2cccc3c2oc2ccccc23)cc1 ; c1ccc(-c2ccc(-c3ccc4c5c6oc7ccccc7c6ccc5n(-c5cccc6c5sc5ccccc56)c4c3)cc2)cc1 ; c1ccc(-c2cccc(-c3ccc4c(c3)c3c5oc6ccccc6c5ccc3n4-c3cccc4c3oc3ccccc34)c2)cc1]

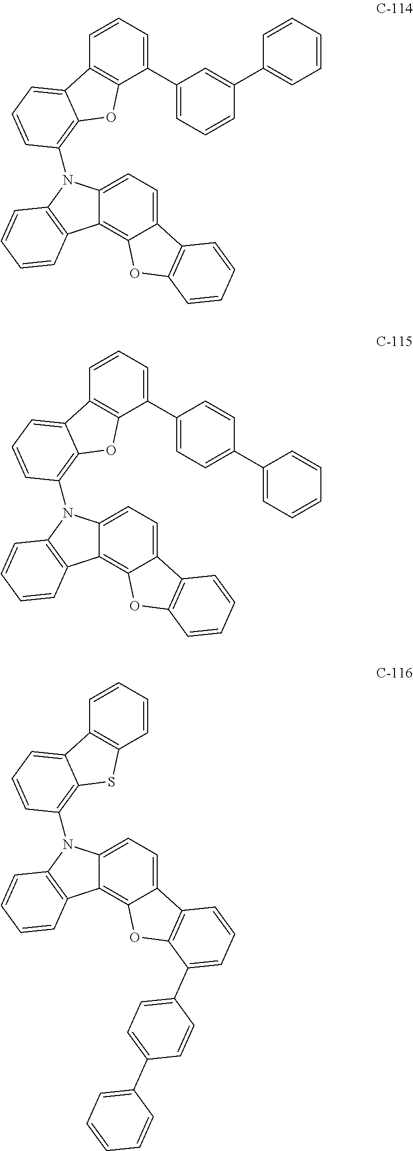 [SMILES: c1ccc(-c2cccc(-c3cccc4c3oc3c(-n5c6ccccc6c6c7oc8ccccc8c7ccc65)cccc34)c2)cc1 ; c1ccc(-c2ccc(-c3cccc4c3oc3c(-n5c6ccccc6c6c7oc8ccccc8c7ccc65)cccc34)cc2)cc1 ; c1ccc(-c2ccc(-c3cccc4c3oc3c4ccc4c3c3ccccc3n4-c3cccc4c3sc3ccccc34)cc2)cc1]

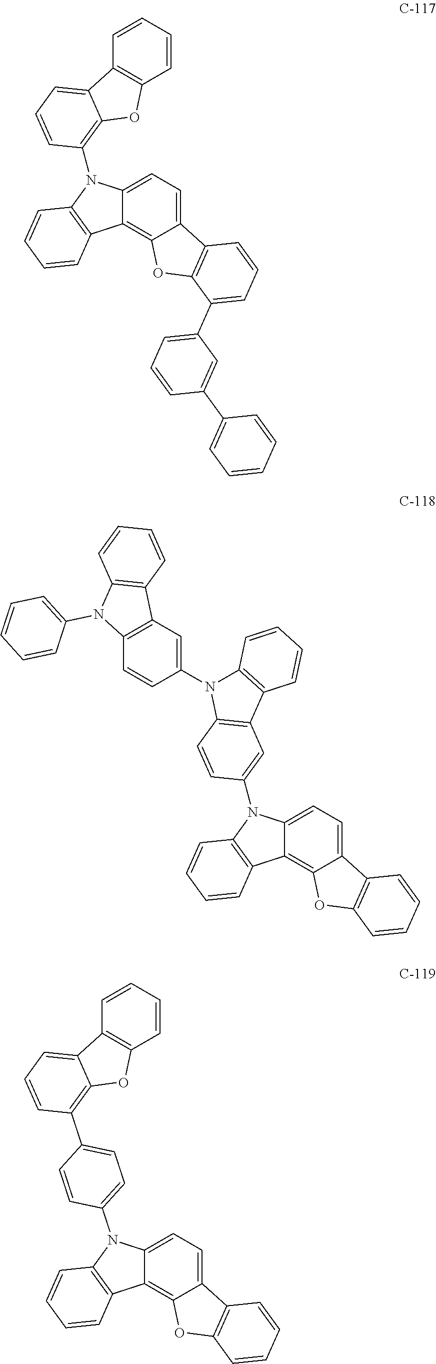 [SMILES: c1ccc(-c2cccc(-c3cccc4c3oc3c4ccc4c3c3ccccc3n4-c3cccc4c3oc3ccccc34)c2)cc1 ; c1ccc(-n2c3ccccc3c3cc(-n4c5ccccc5c5cc(-n6c7ccccc7c7c8oc9ccccc9c8ccc76)ccc54)ccc32)cc1 ; c1ccc2c(c1)oc1c(-c3ccc(-n4c5ccccc5c5c6oc7ccccc7c6ccc54)cc3)cccc12]

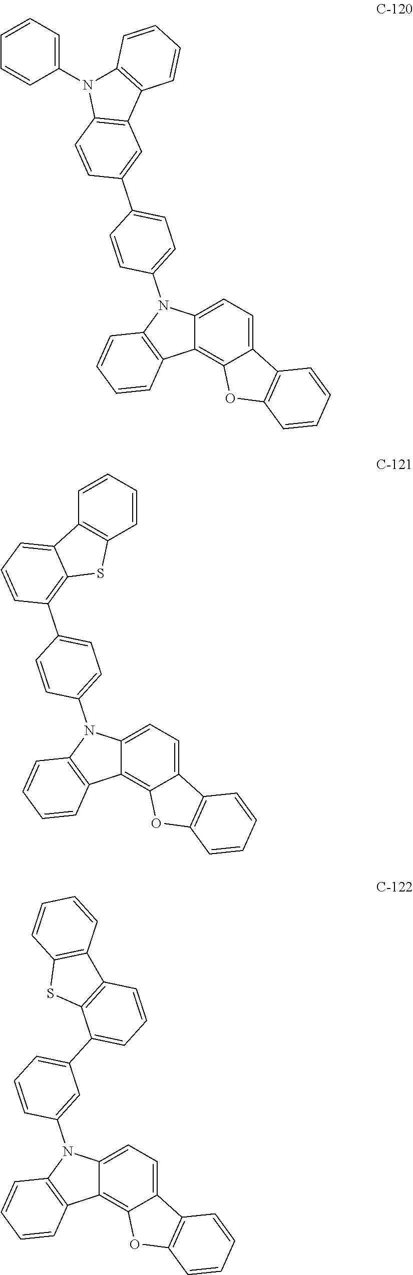 [SMILES: c1ccc(-n2c3ccccc3c3cc(-c4ccc(-n5c6ccccc6c6c7oc8ccccc8c7ccc65)cc4)ccc32)cc1 ; c1ccc2c(c1)oc1c2ccc2c1c1ccccc1n2-c1ccc(-c2cccc3c2sc2ccccc23)cc1 ; c1cc(-c2cccc3c2sc2ccccc23)cc(-n2c3ccccc3c3c4oc5ccccc5c4ccc32)c1]

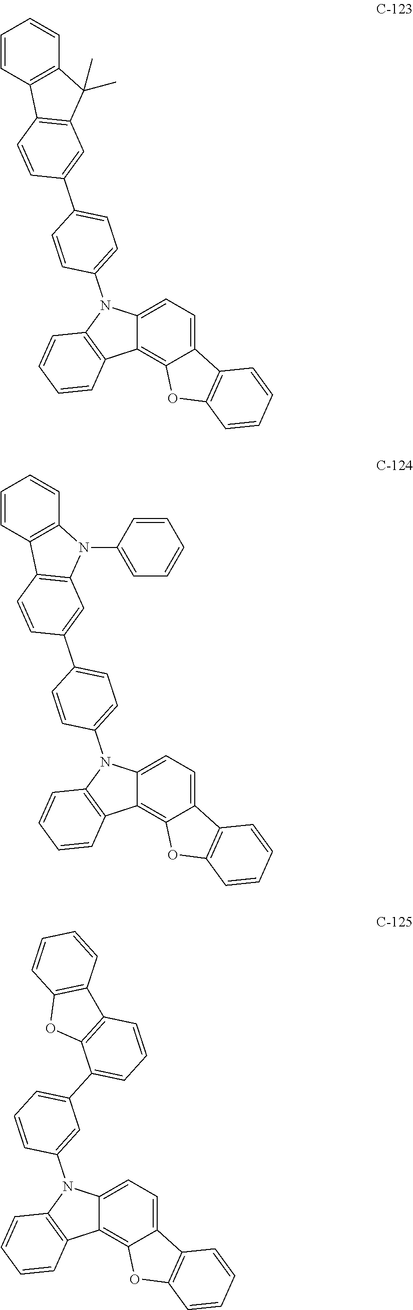 [SMILES: CC1(C)c2ccccc2-c2ccc(-c3ccc(-n4c5ccccc5c5c6oc7ccccc7c6ccc54)cc3)cc21 ; c1ccc(-n2c3ccccc3c3ccc(-c4ccc(-n5c6ccccc6c6c7oc8ccccc8c7ccc65)cc4)cc32)cc1 ; c1cc(-c2cccc3c2oc2ccccc23)cc(-n2c3ccccc3c3c4oc5ccccc5c4ccc32)c1]

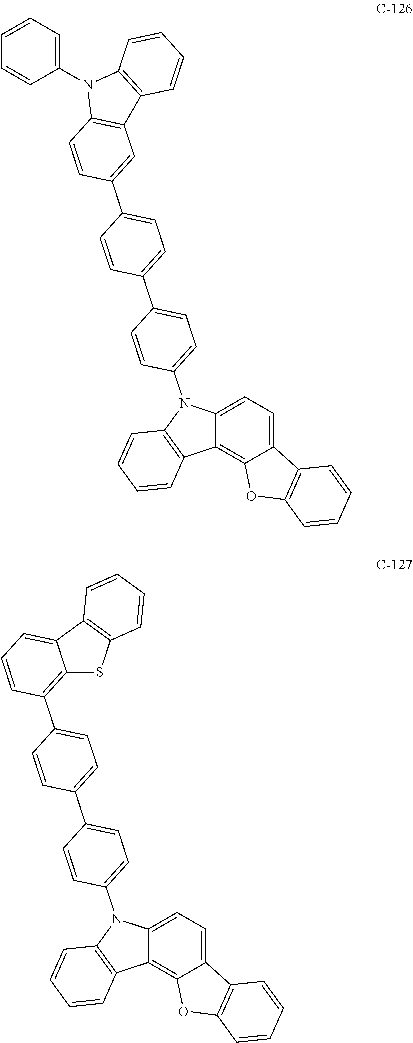 [SMILES: c1ccc(-n2c3ccccc3c3cc(-c4ccc(-c5ccc(-n6c7ccccc7c7c8oc9ccccc9c8ccc76)cc5)cc4)ccc32)cc1 ; c1ccc2c(c1)oc1c2ccc2c1c1ccccc1n2-c1ccc(-c2ccc(-c3cccc4c3sc3ccccc34)cc2)cc1]

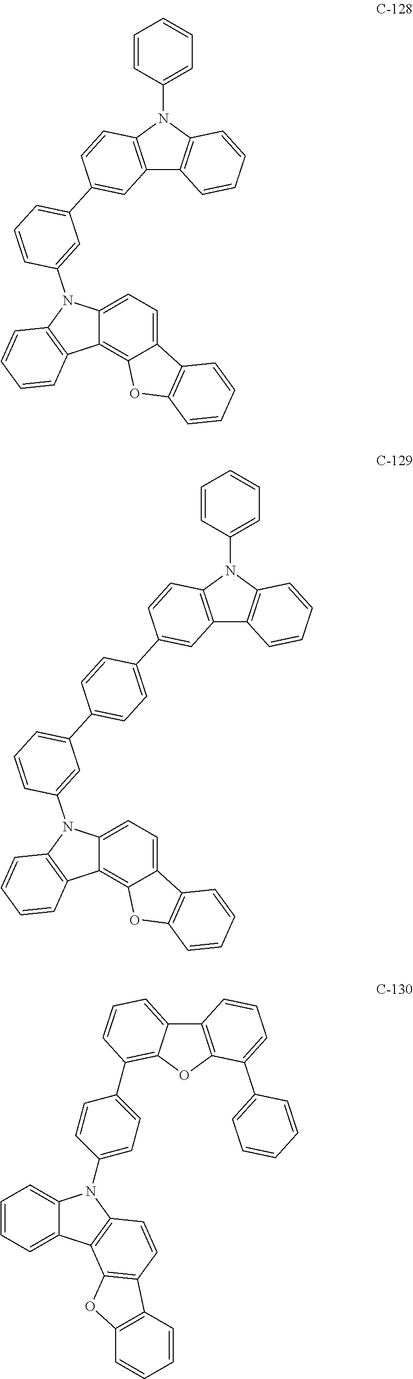 [SMILES: c1ccc(-n2c3ccccc3c3cc(-c4cccc(-n5c6ccccc6c6c7oc8ccccc8c7ccc65)c4)ccc32)cc1 ; c1ccc(-n2c3ccccc3c3cc(-c4ccc(-c5cccc(-n6c7ccccc7c7c8oc9ccccc9c8ccc76)c5)cc4)ccc32)cc1 ; c1ccc(-c2cccc3c2oc2c(-c4ccc(-n5c6ccccc6c6c7oc8ccccc8c7ccc65)cc4)cccc23)cc1]

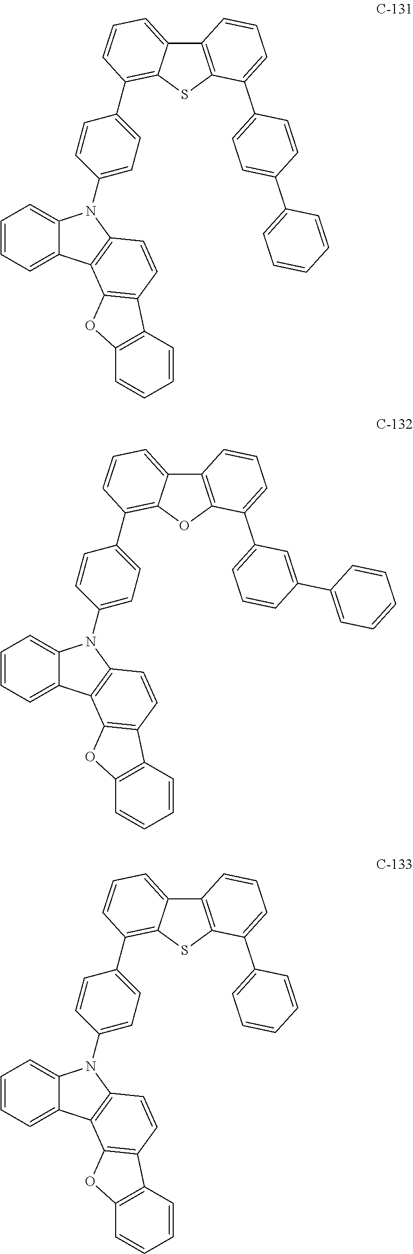

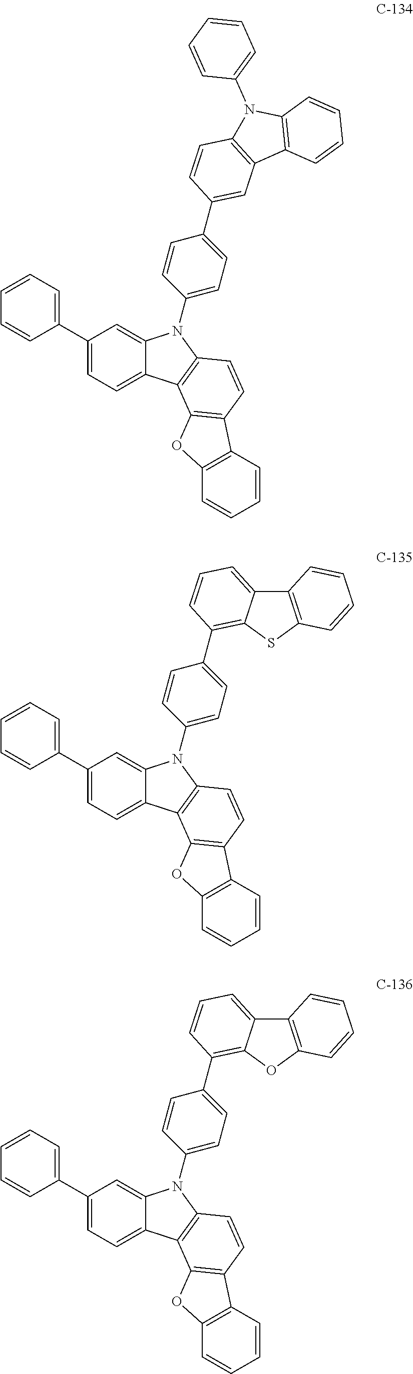 [SMILES: c1ccc(-c2ccc3c4c5oc6ccccc6c5ccc4n(-c4ccc(-c5ccc6c(c5)c5ccccc5n6-c5ccccc5)cc4)c3c2)cc1 ; c1ccc(-c2ccc3c4c5oc6ccccc6c5ccc4n(-c4ccc(-c5cccc6c5sc5ccccc56)cc4)c3c2)cc1 ; c1ccc(-c2ccc3c4c5oc6ccccc6c5ccc4n(-c4ccc(-c5cccc6c5oc5ccccc56)cc4)c3c2)cc1]

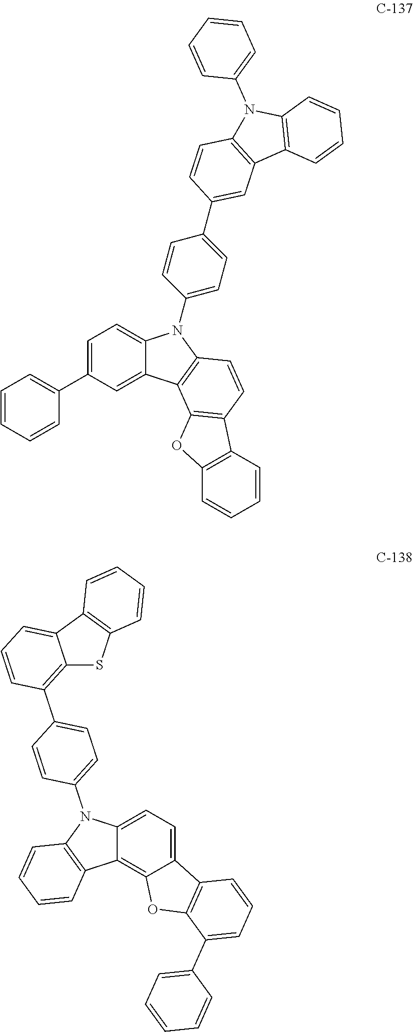 [SMILES: c1ccc(-c2ccc3c(c2)c2c4oc5ccccc5c4ccc2n3-c2ccc(-c3ccc4c(c3)c3ccccc3n4-c3ccccc3)cc2)cc1 ; c1ccc(-c2cccc3c2oc2c3ccc3c2c2ccccc2n3-c2ccc(-c3cccc4c3sc3ccccc34)cc2)cc1]

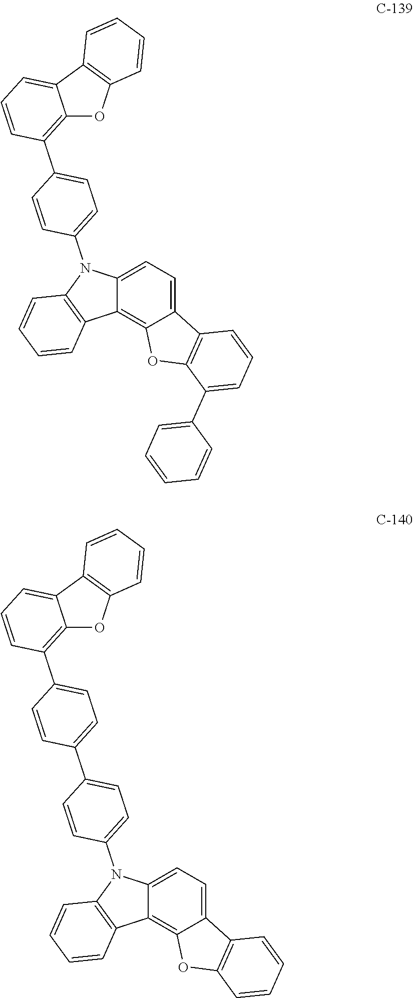 [SMILES: c1ccc(-c2cccc3c2oc2c3ccc3c2c2ccccc2n3-c2ccc(-c3cccc4c3oc3ccccc34)cc2)cc1 ; c1ccc2c(c1)oc1c(-c3ccc(-c4ccc(-n5c6ccccc6c6c7oc8ccccc8c7ccc65)cc4)cc3)cccc12]

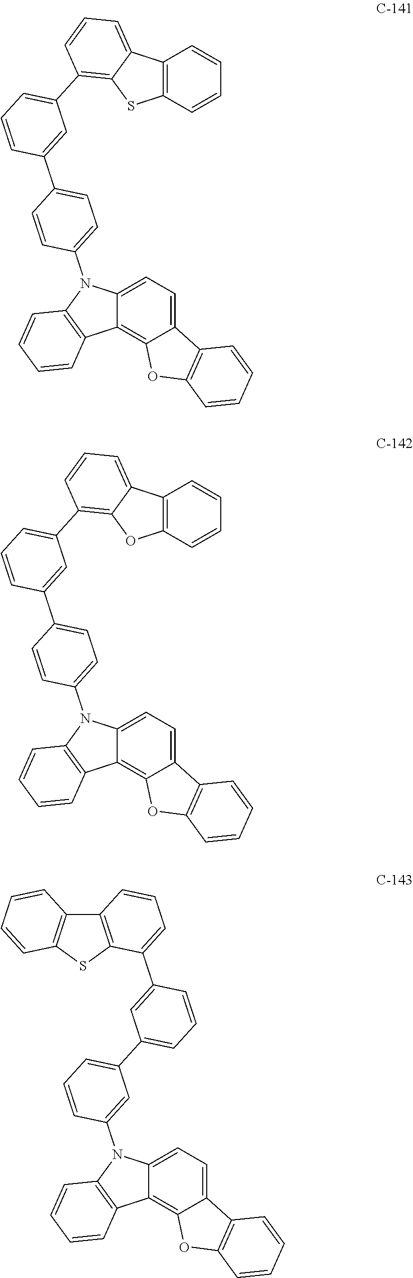 [SMILES: c1cc(-c2ccc(-n3c4ccccc4c4c5oc6ccccc6c5ccc43)cc2)cc(-c2cccc3c2sc2ccccc23)c1 ; c1cc(-c2ccc(-n3c4ccccc4c4c5oc6ccccc6c5ccc43)cc2)cc(-c2cccc3c2oc2ccccc23)c1 ; c1cc(-c2cccc(-n3c4ccccc4c4c5oc6ccccc6c5ccc43)c2)cc(-c2cccc3c2sc2ccccc23)c1]

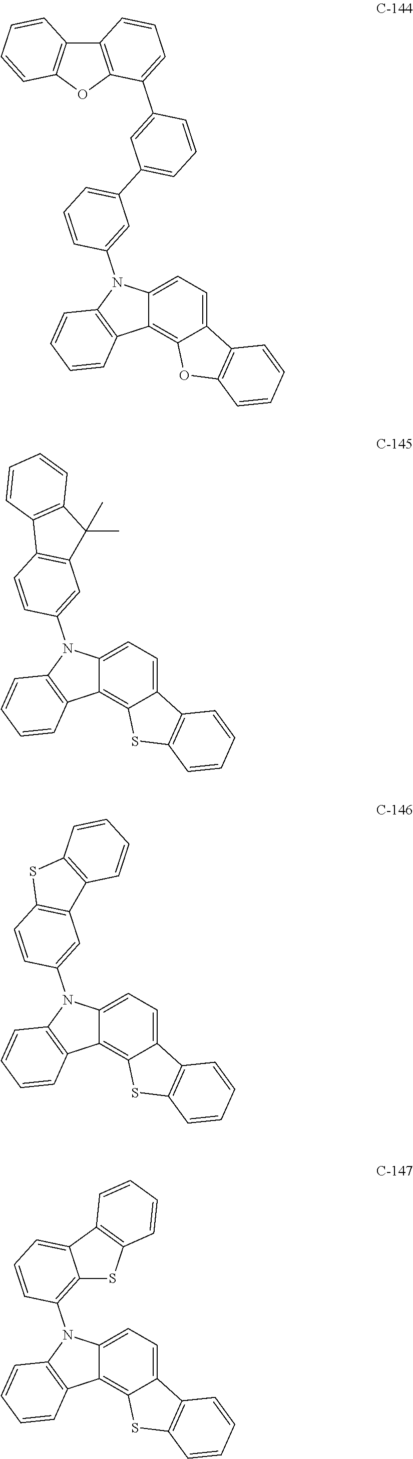 [SMILES: c1cc(-c2cccc(-n3c4ccccc4c4c5oc6ccccc6c5ccc43)c2)cc(-c2cccc3c2oc2ccccc23)c1 ; CC1(C)c2ccccc2-c2ccc(-n3c4ccccc4c4c5sc6ccccc6c5ccc43)cc21 ; c1ccc2c(c1)sc1ccc(-n3c4ccccc4c4c5sc6ccccc6c5ccc43)cc12 ; c1ccc2c(c1)sc1c(-n3c4ccccc4c4c5sc6ccccc6c5ccc43)cccc12]

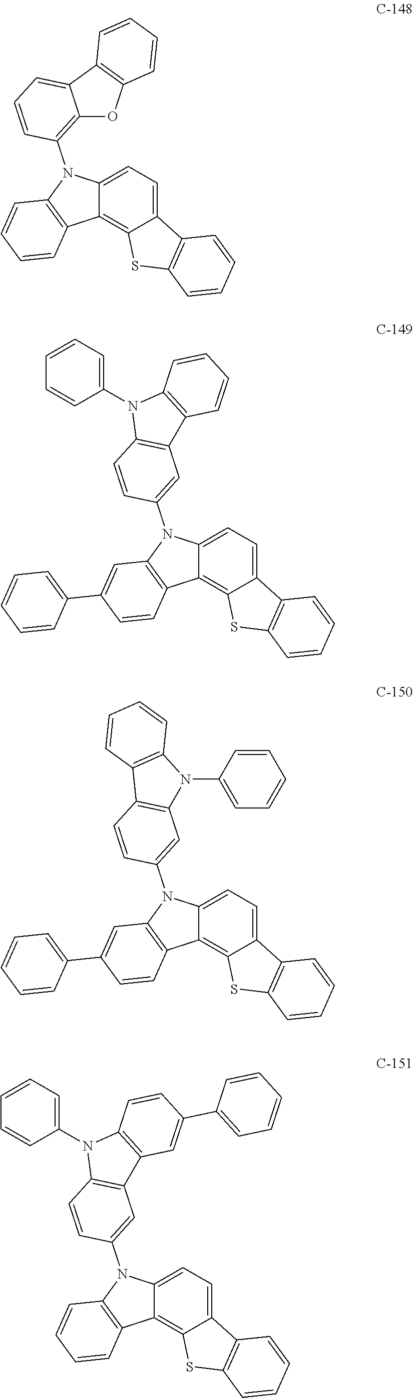 [SMILES: c1ccc2c(c1)oc1c(-n3c4ccccc4c4c5sc6ccccc6c5ccc43)cccc12 ; c1ccc(-c2ccc3c4c5sc6ccccc6c5ccc4n(-c4ccc5c(c4)c4ccccc4n5-c4ccccc4)c3c2)cc1 ; c1ccc(-c2ccc3c4c5sc6ccccc6c5ccc4n(-c4ccc5c6ccccc6n(-c6ccccc6)c5c4)c3c2)cc1 ; c1ccc(-c2ccc3c(c2)c2cc(-n4c5ccccc5c5c6sc7ccccc7c6ccc54)ccc2n3-c2ccccc2)cc1]

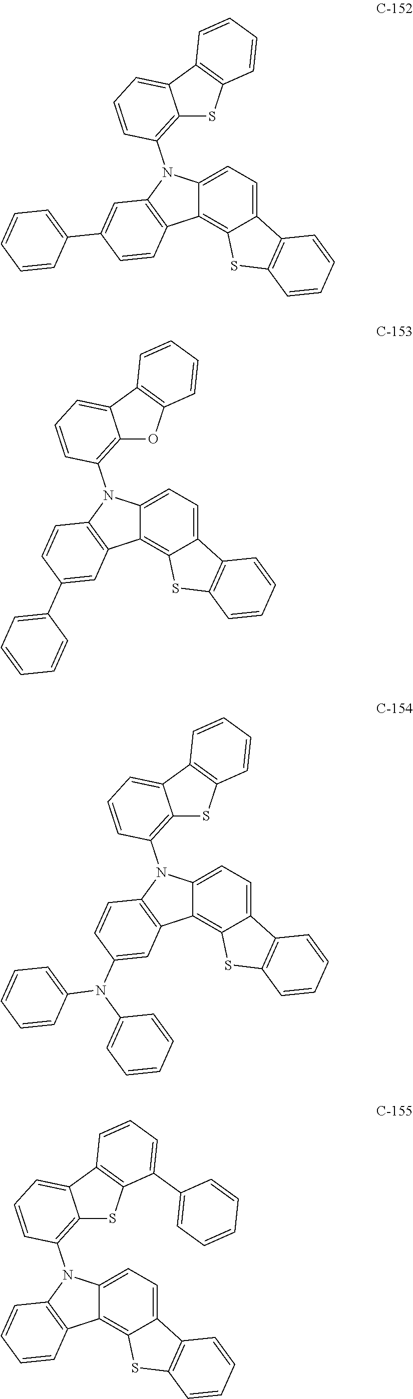

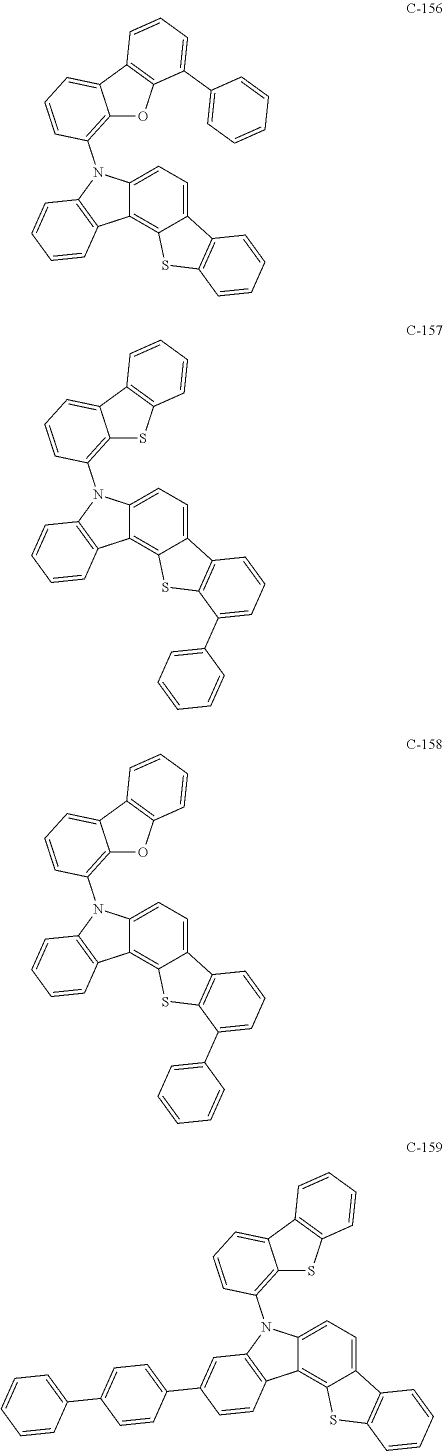 [SMILES: c1ccc(-c2cccc3c2oc2c(-n4c5ccccc5c5c6sc7ccccc7c6ccc54)cccc23)cc1 ; c1ccc(-c2cccc3c2sc2c3ccc3c2c2ccccc2n3-c2cccc3c2sc2ccccc23)cc1 ; c1ccc(-c2cccc3c2sc2c3ccc3c2c2ccccc2n3-c2cccc3c2oc2ccccc23)cc1 ; c1ccc(-c2ccc(-c3ccc4c5c6sc7ccccc7c6ccc5n(-c5cccc6c5sc5ccccc56)c4c3)cc2)cc1]

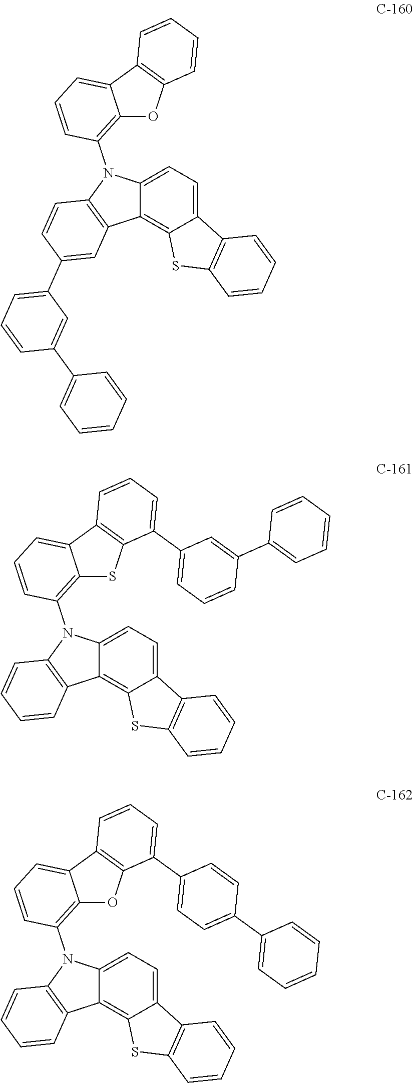 [SMILES: c1ccc(-c2cccc(-c3ccc4c(c3)c3c5sc6ccccc6c5ccc3n4-c3cccc4c3oc3ccccc34)c2)cc1 ; c1ccc(-c2cccc(-c3cccc4c3sc3c(-n5c6ccccc6c6c7sc8ccccc8c7ccc65)cccc34)c2)cc1 ; c1ccc(-c2ccc(-c3cccc4c3oc3c(-n5c6ccccc6c6c7sc8ccccc8c7ccc65)cccc34)cc2)cc1]

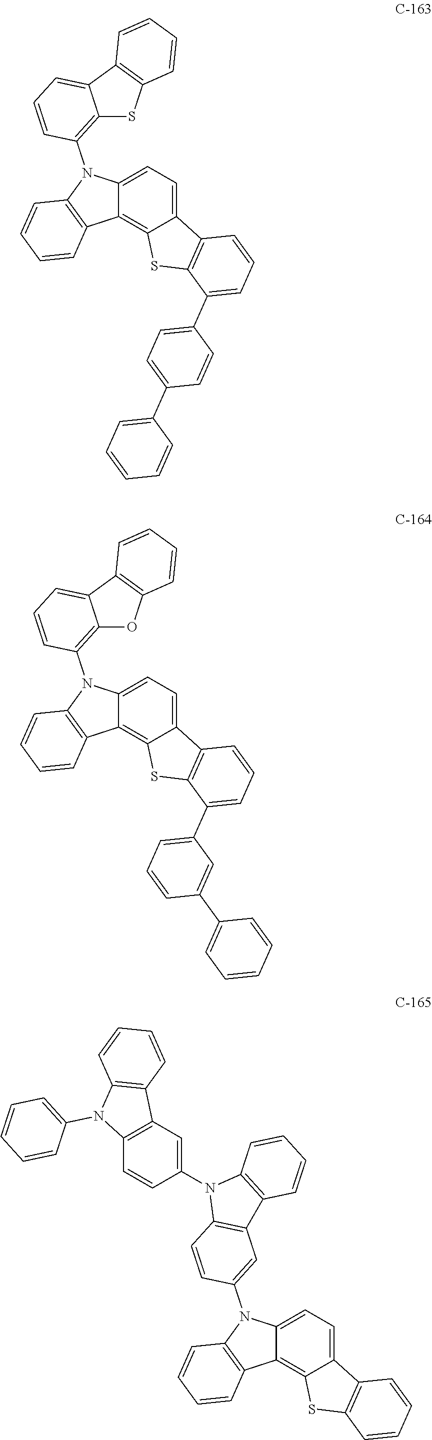 [SMILES: c1ccc(-c2ccc(-c3cccc4c3sc3c4ccc4c3c3ccccc3n4-c3cccc4c3sc3ccccc34)cc2)cc1 ; c1ccc(-c2cccc(-c3cccc4c3sc3c4ccc4c3c3ccccc3n4-c3cccc4c3oc3ccccc34)c2)cc1 ; c1ccc(-n2c3ccccc3c3cc(-n4c5ccccc5c5cc(-n6c7ccccc7c7c8sc9ccccc9c8ccc76)ccc54)ccc32)cc1]

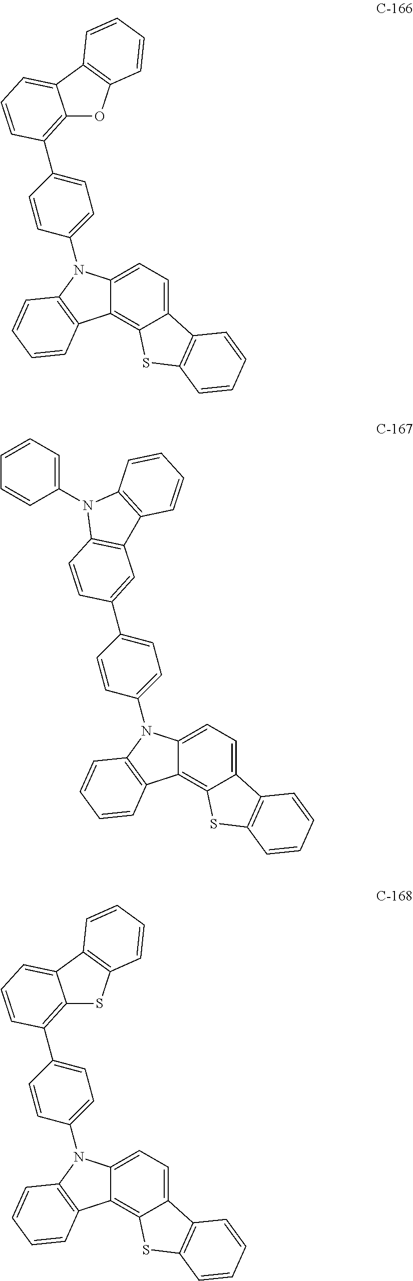 [SMILES: c1ccc2c(c1)oc1c(-c3ccc(-n4c5ccccc5c5c6sc7ccccc7c6ccc54)cc3)cccc12 ; c1ccc(-n2c3ccccc3c3cc(-c4ccc(-n5c6ccccc6c6c7sc8ccccc8c7ccc65)cc4)ccc32)cc1 ; c1ccc2c(c1)sc1c(-c3ccc(-n4c5ccccc5c5c6sc7ccccc7c6ccc54)cc3)cccc12]

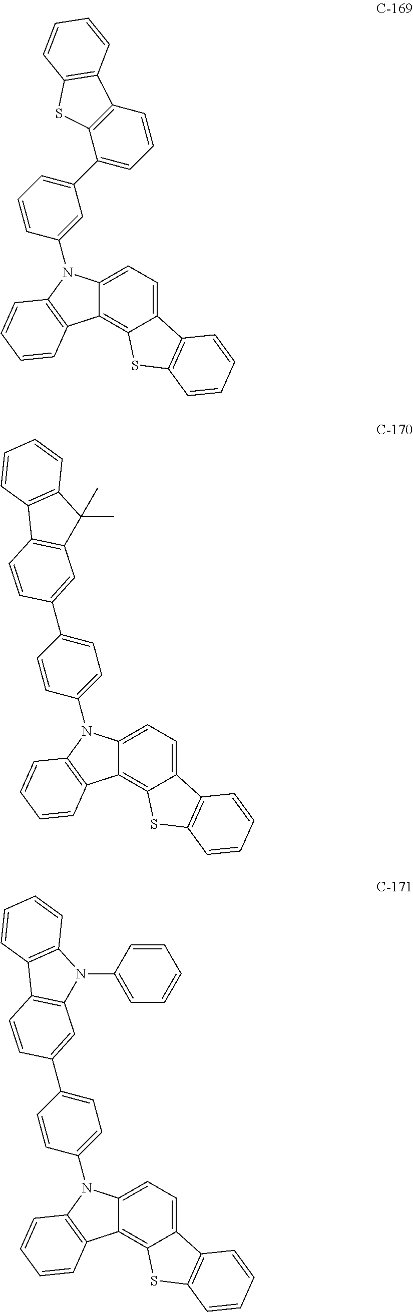 [SMILES: c1cc(-c2cccc3c2sc2ccccc23)cc(-n2c3ccccc3c3c4sc5ccccc5c4ccc32)c1 ; CC1(C)c2ccccc2-c2ccc(-c3ccc(-n4c5ccccc5c5c6sc7ccccc7c6ccc54)cc3)cc21 ; c1ccc(-n2c3ccccc3c3ccc(-c4ccc(-n5c6ccccc6c6c7sc8ccccc8c7ccc65)cc4)cc32)cc1]

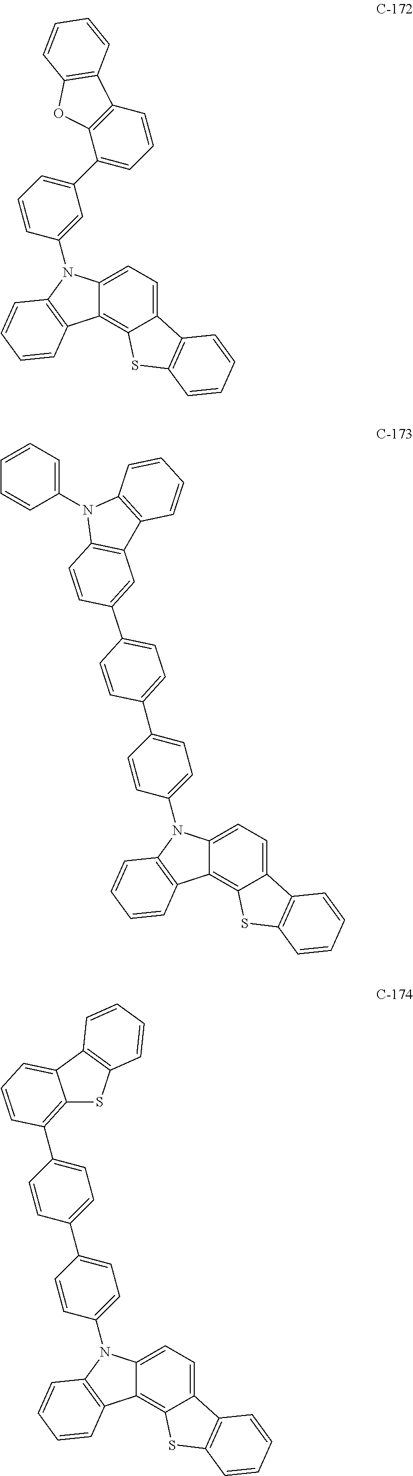 [SMILES: c1cc(-c2cccc3c2oc2ccccc23)cc(-n2c3ccccc3c3c4sc5ccccc5c4ccc32)c1 ; c1ccc(-n2c3ccccc3c3cc(-c4ccc(-c5ccc(-n6c7ccccc7c7c8sc9ccccc9c8ccc76)cc5)cc4)ccc32)cc1 ; c1ccc2c(c1)sc1c(-c3ccc(-c4ccc(-n5c6ccccc6c6c7sc8ccccc8c7ccc65)cc4)cc3)cccc12]

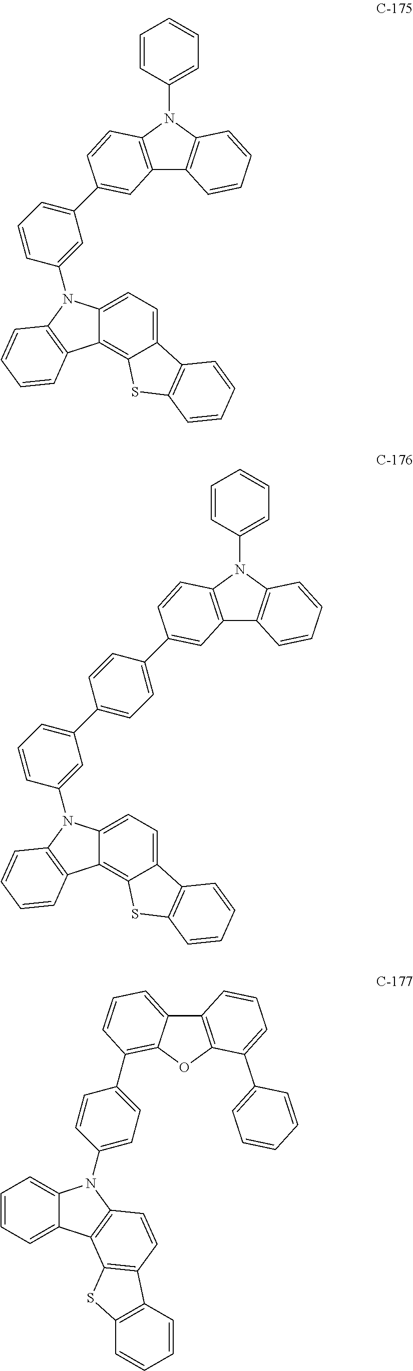 [SMILES: c1ccc(-n2c3ccccc3c3cc(-c4cccc(-n5c6ccccc6c6c7sc8ccccc8c7ccc65)c4)ccc32)cc1 ; c1ccc(-n2c3ccccc3c3cc(-c4ccc(-c5cccc(-n6c7ccccc7c7c8sc9ccccc9c8ccc76)c5)cc4)ccc32)cc1 ; c1ccc(-c2cccc3c2oc2c(-c4ccc(-n5c6ccccc6c6c7sc8ccccc8c7ccc65)cc4)cccc23)cc1]

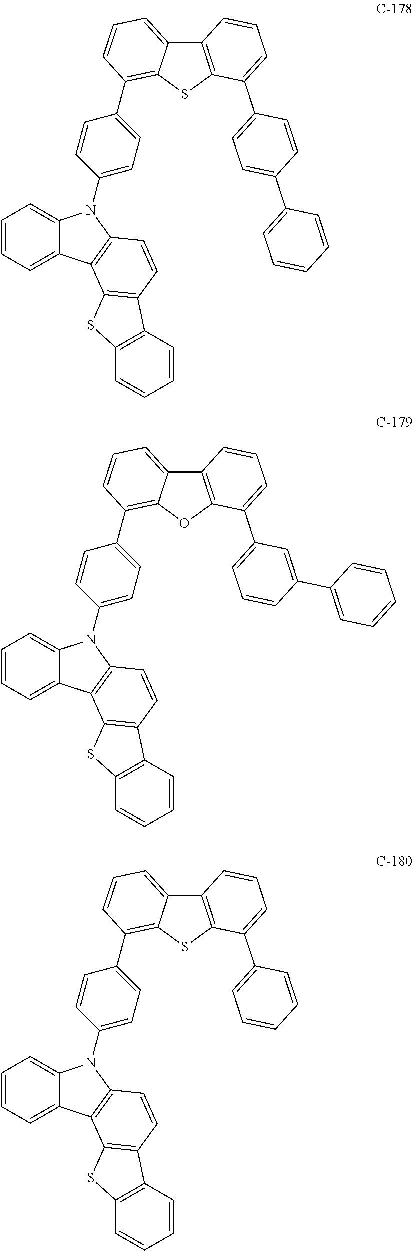

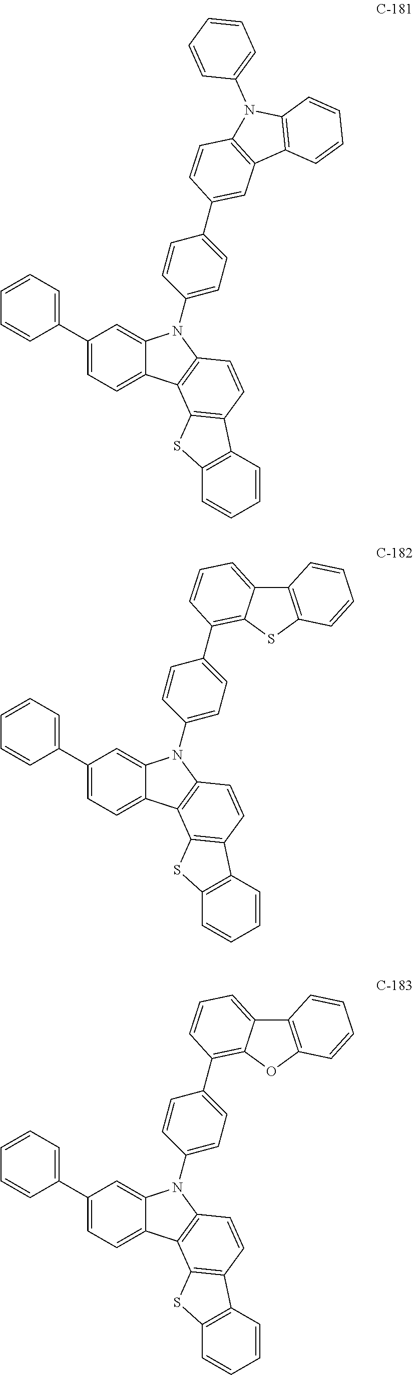

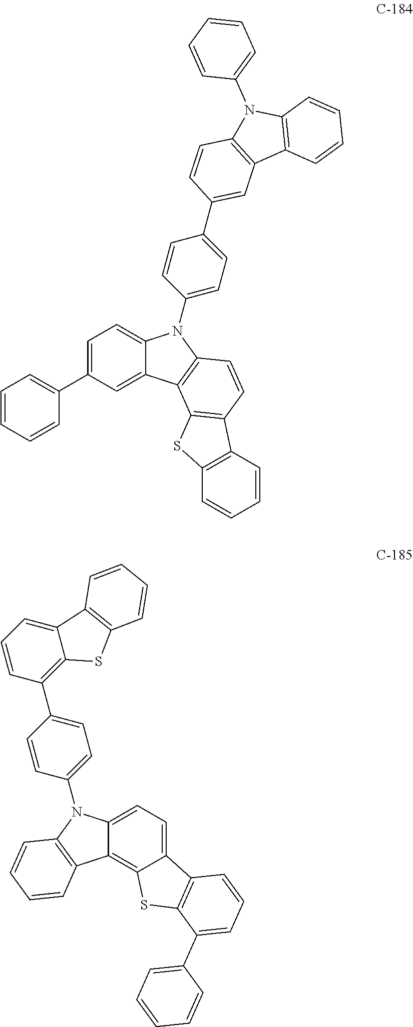 [SMILES: c1ccc(-c2ccc3c(c2)c2c4sc5ccccc5c4ccc2n3-c2ccc(-c3ccc4c(c3)c3ccccc3n4-c3ccccc3)cc2)cc1 ; c1ccc(-c2cccc3c2sc2c3ccc3c2c2ccccc2n3-c2ccc(-c3cccc4c3sc3ccccc34)cc2)cc1]

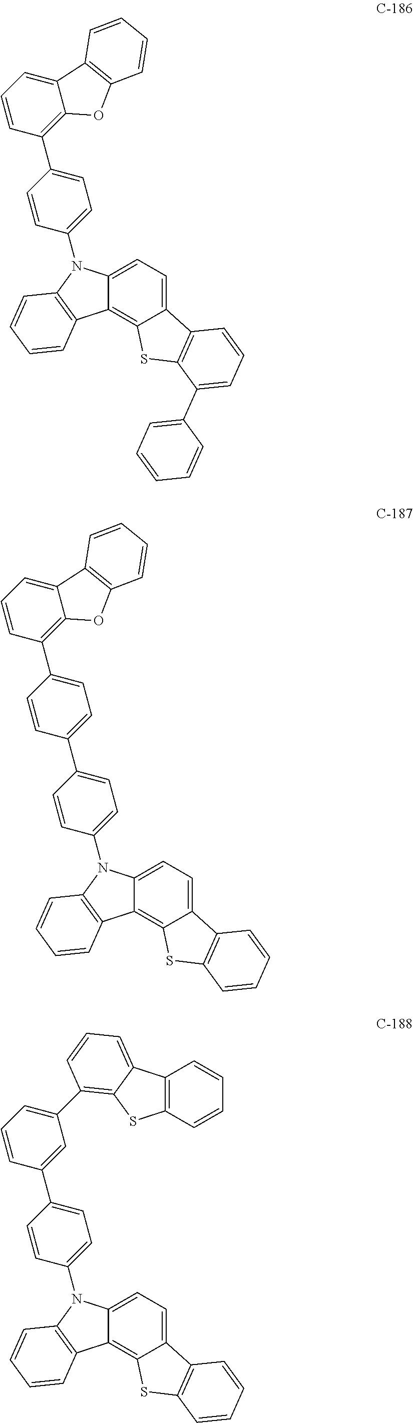 [SMILES: c1ccc(-c2cccc3c2sc2c3ccc3c2c2ccccc2n3-c2ccc(-c3cccc4c3oc3ccccc34)cc2)cc1 ; c1ccc2c(c1)oc1c(-c3ccc(-c4ccc(-n5c6ccccc6c6c7sc8ccccc8c7ccc65)cc4)cc3)cccc12 ; c1cc(-c2ccc(-n3c4ccccc4c4c5sc6ccccc6c5ccc43)cc2)cc(-c2cccc3c2sc2ccccc23)c1]

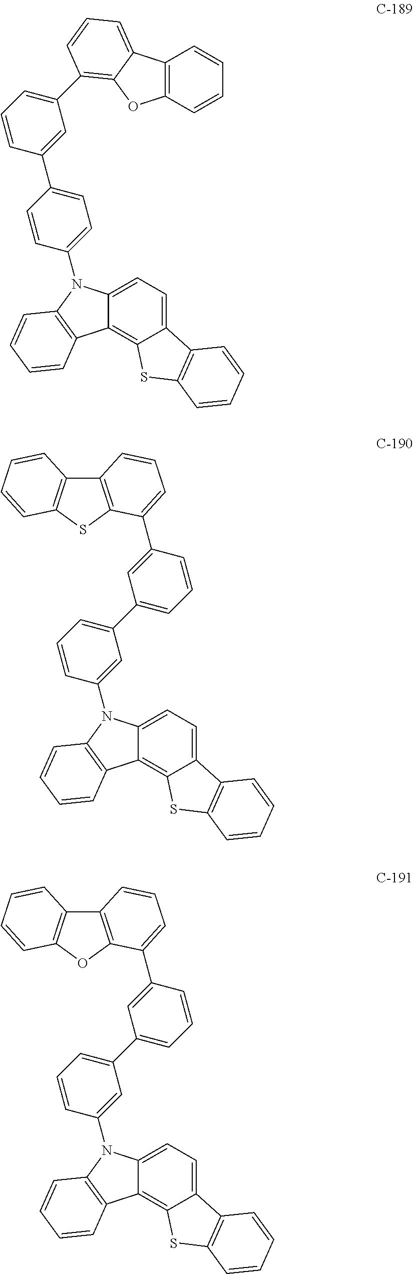 [SMILES: c1cc(-c2ccc(-n3c4ccccc4c4c5sc6ccccc6c5ccc43)cc2)cc(-c2cccc3c2oc2ccccc23)c1 ; c1cc(-c2cccc(-n3c4ccccc4c4c5sc6ccccc6c5ccc43)c2)cc(-c2cccc3c2sc2ccccc23)c1 ; c1cc(-c2cccc(-n3c4ccccc4c4c5sc6ccccc6c5ccc43)c2)cc(-c2cccc3c2oc2ccccc23)c1]

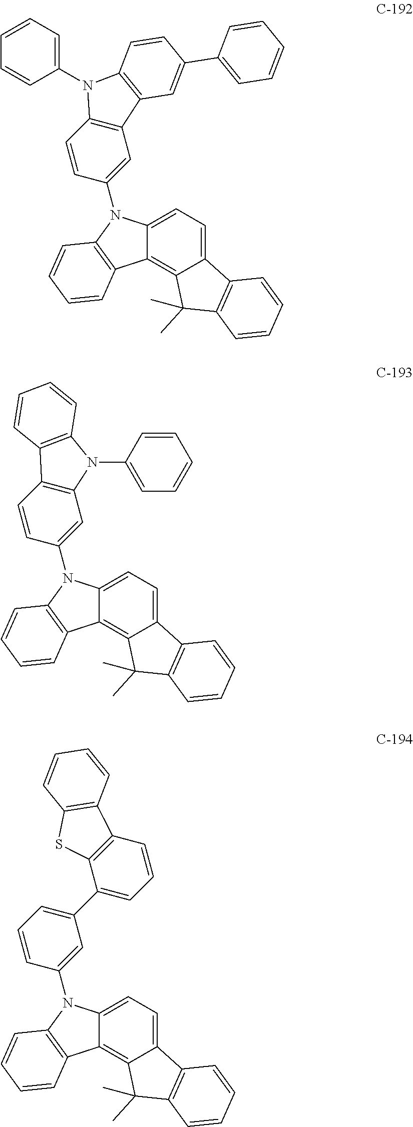 [SMILES: CC1(C)c2ccccc2-c2ccc3c(c21)c1ccccc1n3-c1ccc2c(c1)c1cc(-c3ccccc3)ccc1n2-c1ccccc1 ; CC1(C)c2ccccc2-c2ccc3c(c21)c1ccccc1n3-c1ccc2c3ccccc3n(-c3ccccc3)c2c1 ; CC1(C)c2ccccc2-c2ccc3c(c21)c1ccccc1n3-c1cccc(-c2cccc3c2sc2ccccc23)c1]

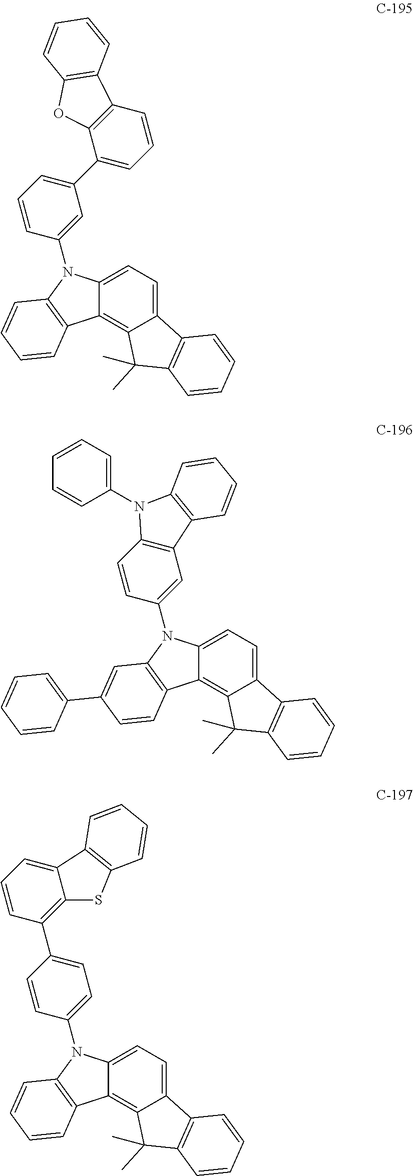 [SMILES: CC1(C)c2ccccc2-c2ccc3c(c21)c1ccccc1n3-c1cccc(-c2cccc3c2oc2ccccc23)c1 ; CC1(C)c2ccccc2-c2ccc3c(c21)c1ccc(-c2ccccc2)cc1n3-c1ccc2c(c1)c1ccccc1n2-c1ccccc1 ; CC1(C)c2ccccc2-c2ccc3c(c21)c1ccccc1n3-c1ccc(-c2cccc3c2sc2ccccc23)cc1]

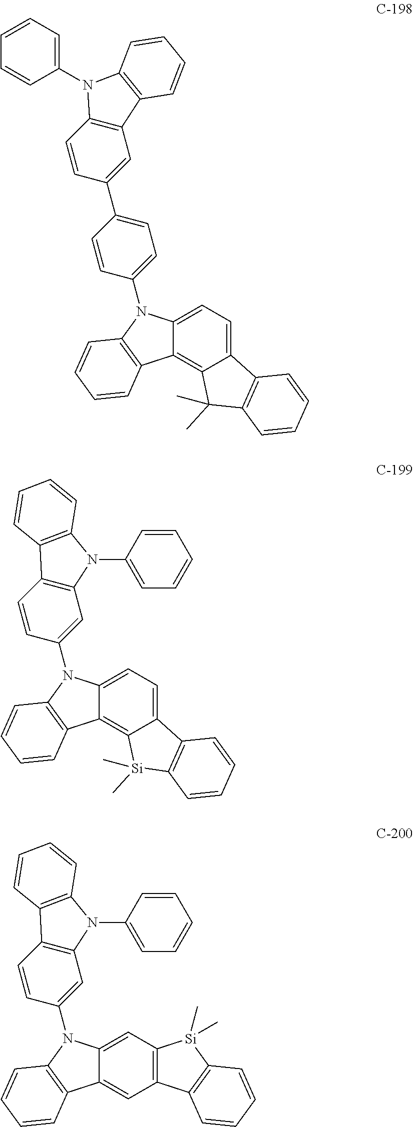 [SMILES: CC1(C)c2ccccc2-c2ccc3c(c21)c1ccccc1n3-c1ccc(-c2ccc3c(c2)c2ccccc2n3-c2ccccc2)cc1 ; C[Si]1(C)c2ccccc2-c2ccc3c(c21)c1ccccc1n3-c1ccc2c3ccccc3n(-c3ccccc3)c2c1 ; C[Si]1(C)c2ccccc2-c2cc3c4ccccc4n(-c4ccc5c6ccccc6n(-c6ccccc6)c5c4)c3cc21]

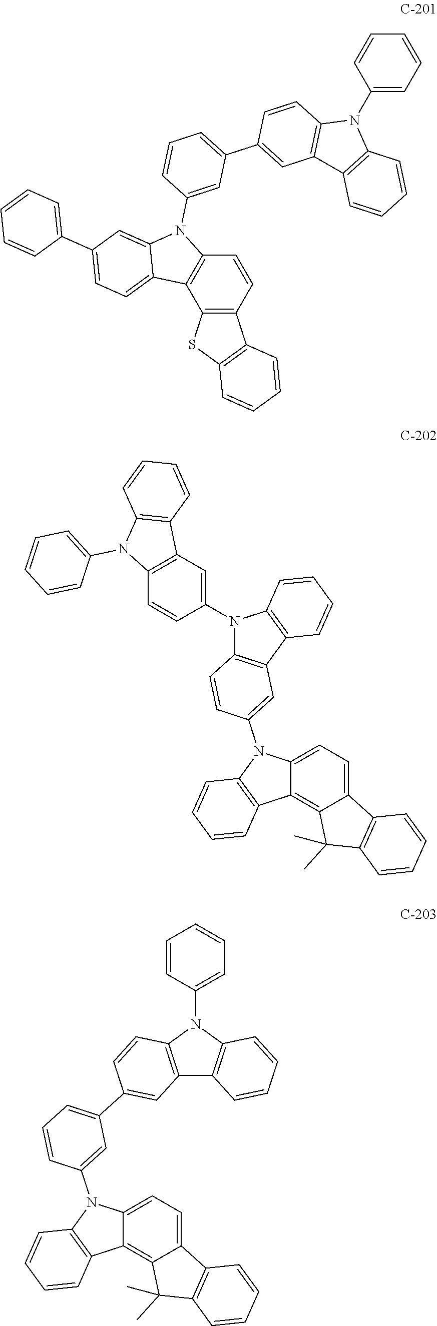 [SMILES: c1ccc(-c2ccc3c4c5sc6ccccc6c5ccc4n(-c4cccc(-c5ccc6c(c5)c5ccccc5n6-c5ccccc5)c4)c3c2)cc1 ; CC1(C)c2ccccc2-c2ccc3c(c21)c1ccccc1n3-c1ccc2c(c1)c1ccccc1n2-c1ccc2c(c1)c1ccccc1n2-c1ccccc1 ; CC1(C)c2ccccc2-c2ccc3c(c21)c1ccccc1n3-c1cccc(-c2ccc3c(c2)c2ccccc2n3-c2ccccc2)c1]

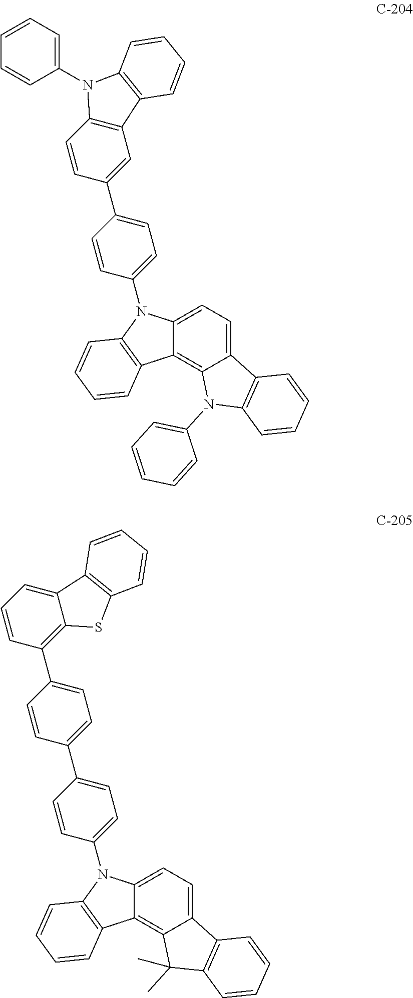 [SMILES: c1ccc(-n2c3ccccc3c3cc(-c4ccc(-n5c6ccccc6c6c5ccc5c7ccccc7n(-c7ccccc7)c56)cc4)ccc32)cc1 ; CC1(C)c2ccccc2-c2ccc3c(c21)c1ccccc1n3-c1ccc(-c2ccc(-c3cccc4c3sc3ccccc34)cc2)cc1]

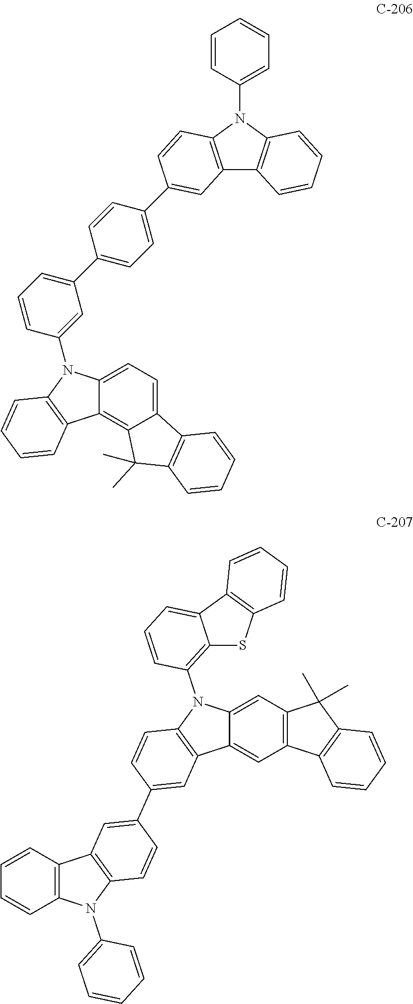 [SMILES: CC1(C)c2ccccc2-c2ccc3c(c21)c1ccccc1n3-c1cccc(-c2ccc(-c3ccc4c(c3)c3ccccc3n4-c3ccccc3)cc2)c1 ; CC1(C)c2ccccc2-c2cc3c4cc(-c5ccc6c(c5)c5ccccc5n6-c5ccccc5)ccc4n(-c4cccc5c4sc4ccccc45)c3cc21]

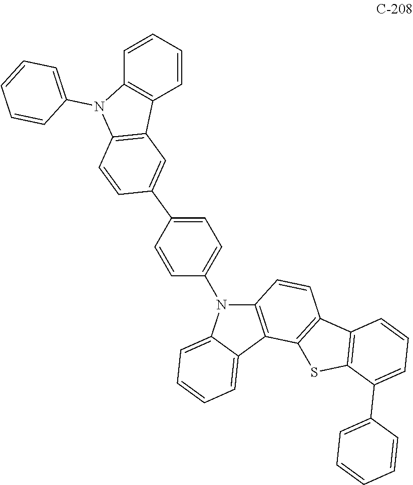 [SMILES: c1ccc(-c2cccc3c2sc2c3ccc3c2c2ccccc2n3-c2ccc(-c3ccc4c(c3)c3ccccc3n4-c3ccccc3)cc2)cc1]

The organic electroluminescent compounds of the present invention can be prepared by a synthetic method known to a person skilled in the art. For example, they can be prepared according to the following reaction schemes.

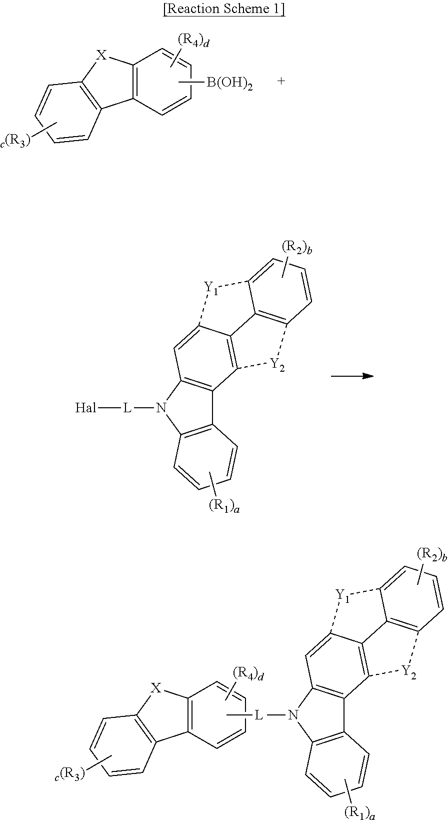

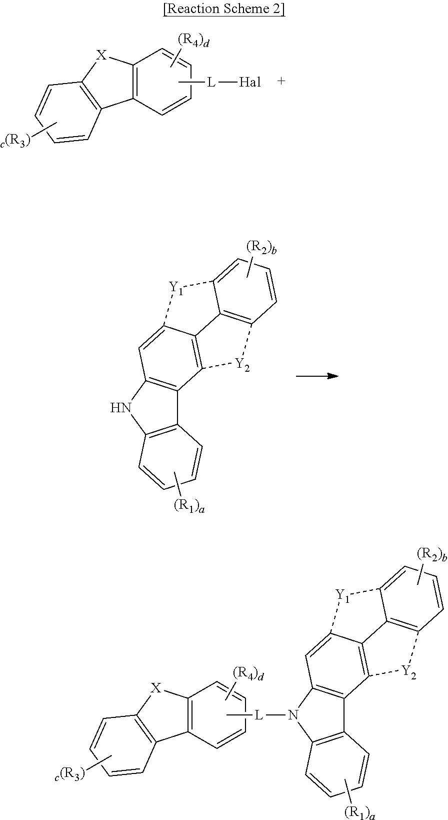

wherein L, X, Y₁, Y₂, R₁ to R₄, a, b, c, and d are as defined in formula 1 above, and Hal represents a halogen.

In addition, the present invention provides an organic electroluminescent material comprising the organic electroluminescent compound of formula 1, and an organic electroluminescent device comprising the material.

The above material can be comprised of the organic electroluminescent compound according to the present invention alone, or can further include conventional materials generally used in organic electroluminescent materials.

Said organic electroluminescent device comprises a first electrode, a second electrode, and at least one organic layer between said first and second electrodes. Said organic layer may comprise at least one organic electroluminescent compound of formula 1 according to the present invention.

One of the first and second electrodes is an anode, and the other is a cathode. The organic layer comprises a light-emitting layer, and at least one layer selected from the group consisting of a hole injection layer, a hole transport layer, an electron transport layer, an electron injection layer, an interlayer, a hole blocking layer and an electron blocking layer.

The organic electroluminescent compound according to the present invention can be comprised in the light-emitting layer and/or the hole transport layer. Where used in the hole transport layer, the organic electroluminescent compound according to the present invention can be comprised as a hole transport material. Where used in the light-emitting layer, the compound can be comprised as a host material. Preferably, the light-emitting layer can further comprise at least one dopant.

When the organic electroluminescent compound according to the present invention is comprised as a host material in the light-emitting layer (first host material), another compound can be comprised as a second host material, wherein the ratio of the first host material to the second host material can be in the range of 1:99 to 99:1.

The host material other than the organic electroluminescent compound according to the present invention can be from any of the known phosphorescent hosts. Specifically, the phosphorescent host selected from the group consisting of the compounds of formula 7 to 11 below is preferable in view of luminous efficiency.

H-(Cz-L₄)ₕ-M (7)

H-(Cz)₁-₄-M (8)

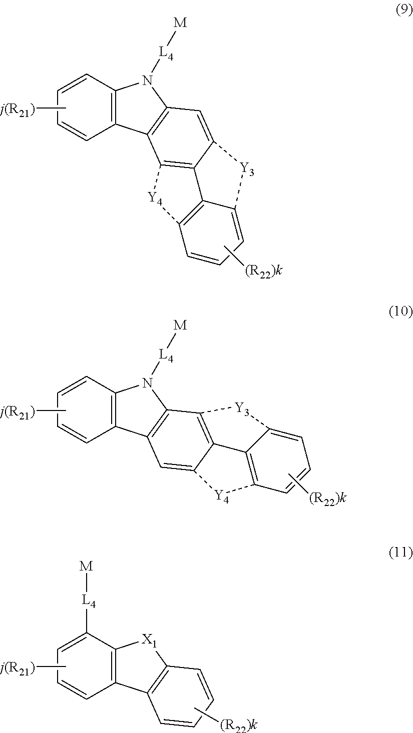

wherein Cz represents the following structure;

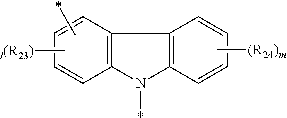

X₁ represents —O— or —S—;

R₂₁ to R₂₄ each independently represent hydrogen, deuterium, a halogen, a substituted or unsubstituted (C1-C30)alkyl group, a substituted of unsubstituted (C6-C30)aryl group, a substituted or unsubstituted 5- to 30-membered heteroaryl group, or R₂₅R₂₆R₂₇Si—;

R₂₅ to R₂₇ each independently represent a substituted or unsubstituted (C1-C30)alkyl group, or a substituted or unsubstituted (C6-C30)aryl group;

L₄ represents a single bond, a substituted or unsubstituted (C6-C30)arylene group, or a substituted or unsubstituted 5- to 30-membered heteroarylene group;

M represents a substituted or unsubstituted (C6-C30)aryl group, or a substituted or unsubstituted 5- to 30-membered heteroaryl group;

Y₃ and Y₄ each independently represent —O—, —S—, —N(R₃₁)— or —C(R₃₂)(R₃₃)—, provided that Y₃ and Y₄ do not simultaneously exist;

R₃₁ to R₃₃ each independently represent a substituted or unsubstituted (C1-C30)alkyl group, a substituted or unsubstituted (C6-C30)aryl group, or a substituted or unsubstituted 5- to 30-membered heteroaryl group, and R₃₂ and R₃₃ may be the same or different;

h and i each independently represent an integer of 1 to 3;

j, k, l and m each independently represent an integer of 0 to 4; and where h, i, j, k, l or m is an integer of 2 or more, each of (Cz-L₄), each of (Cz), each of R₂₁, each of R₂₂, each of R₂₃ or each of R₂₄ may be the same or different.

Specifically, preferable examples of the host material are as follows:

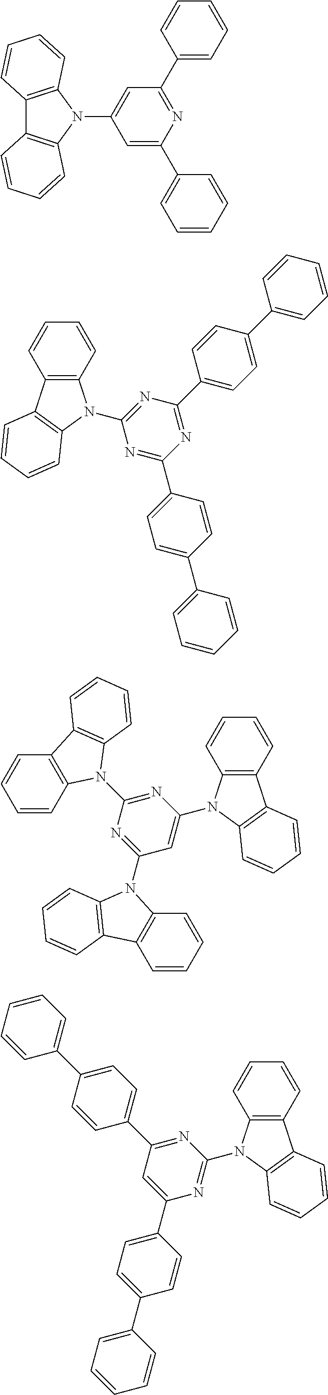 [SMILES: c1ccc(-c2cc(-n3c4ccccc4c4ccccc43)cc(-c3ccccc3)n2)cc1 ; c1ccc(-c2ccc(-c3nc(-c4ccc(-c5ccccc5)cc4)nc(-n4c5ccccc5c5ccccc54)n3)cc2)cc1 ; c1ccc2c(c1)c1ccccc1n2-c1cc(-n2c3ccccc3c3ccccc32)nc(-n2c3ccccc3c3ccccc32)n1 ; c1ccc(-c2ccc(-c3cc(-c4ccc(-c5ccccc5)cc4)nc(-n4c5ccccc5c5ccccc54)n3)cc2)cc1]

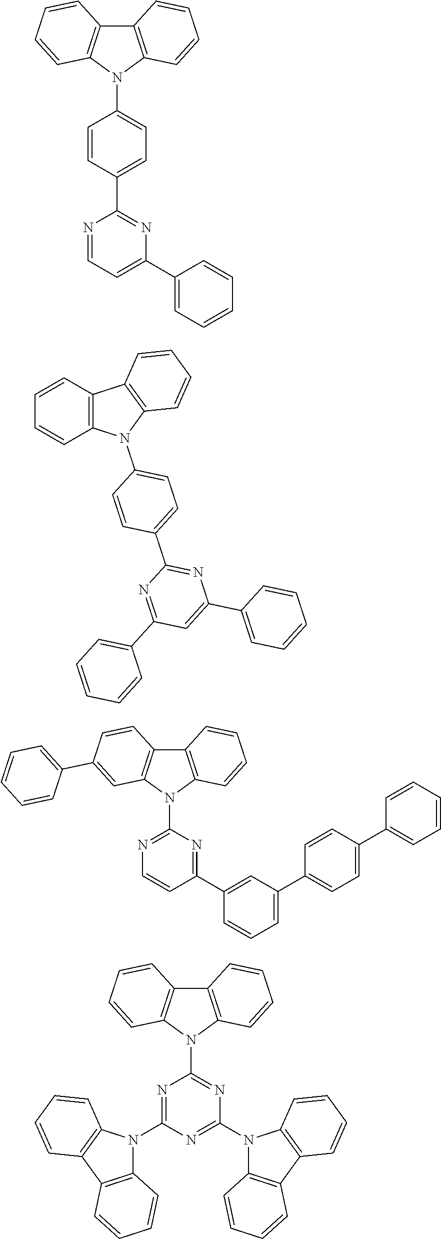

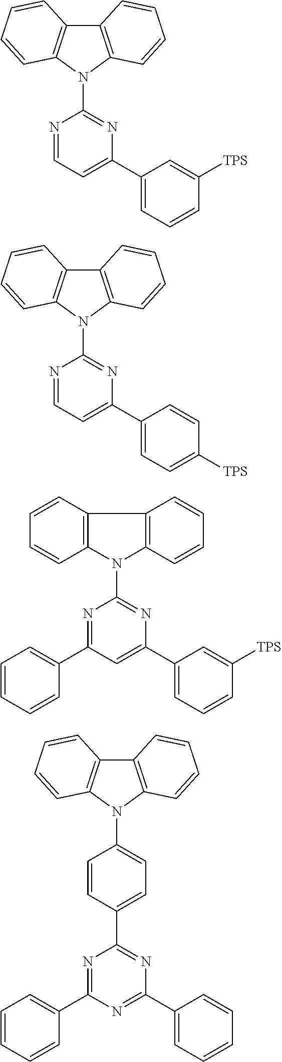

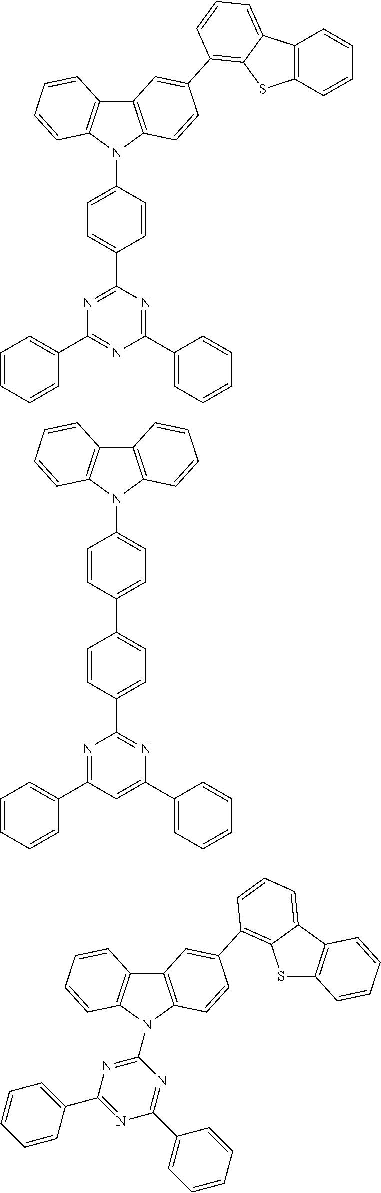

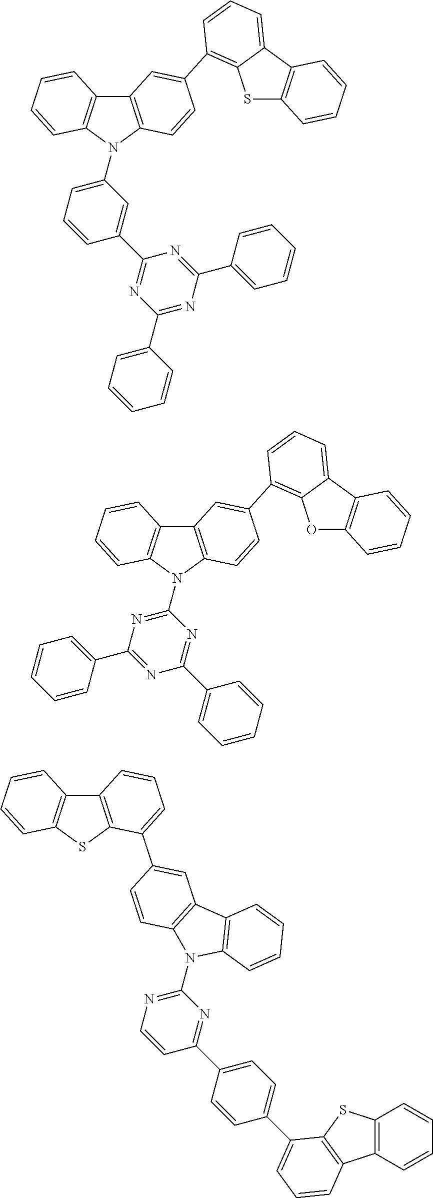 [SMILES: c1ccc(-c2nc(-c3ccccc3)nc(-c3cccc(-n4c5ccccc5c5cc(-c6cccc7c6sc6ccccc67)ccc54)c3)n2)cc1 ; c1ccc(-c2nc(-c3ccccc3)nc(-n3c4ccccc4c4cc(-c5cccc6c5oc5ccccc56)ccc43)n2)cc1 ; c1ccc2c(c1)sc1c(-c3ccc(-c4ccnc(-n5c6ccccc6c6cc(-c7cccc8c7sc7ccccc78)ccc65)n4)cc3)cccc12]

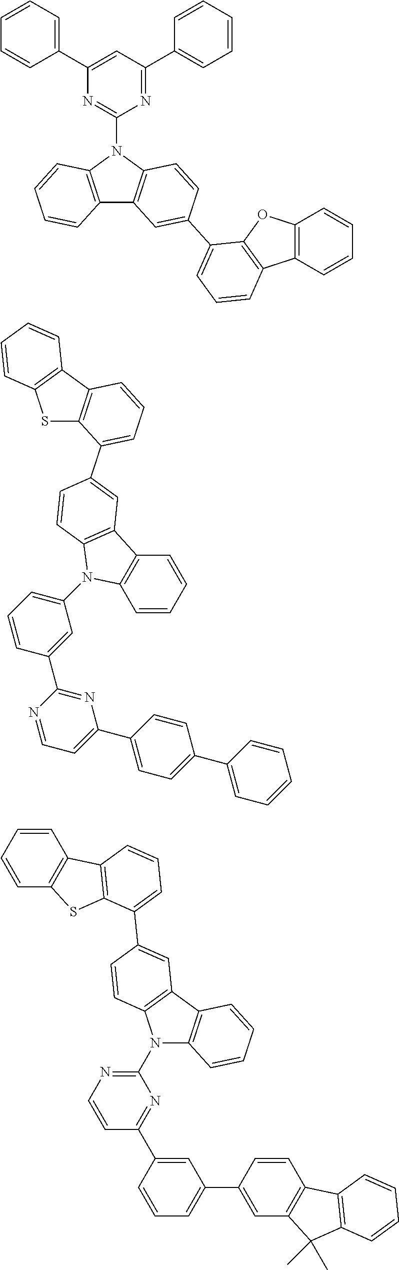 [SMILES: c1ccc(-c2cc(-c3ccccc3)nc(-n3c4ccccc4c4cc(-c5cccc6c5oc5ccccc56)ccc43)n2)cc1 ; c1ccc(-c2ccc(-c3ccnc(-c4cccc(-n5c6ccccc6c6cc(-c7cccc8c7sc7ccccc78)ccc65)c4)n3)cc2)cc1 ; CC1(C)c2ccccc2-c2ccc(-c3cccc(-c4ccnc(-n5c6ccccc6c6cc(-c7cccc8c7sc7ccccc78)ccc65)n4)c3)cc21]

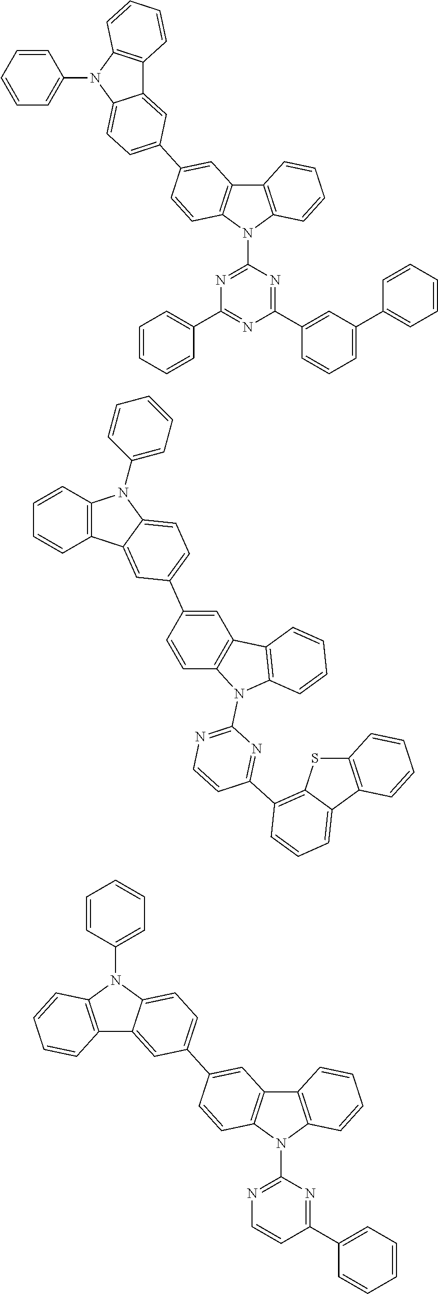

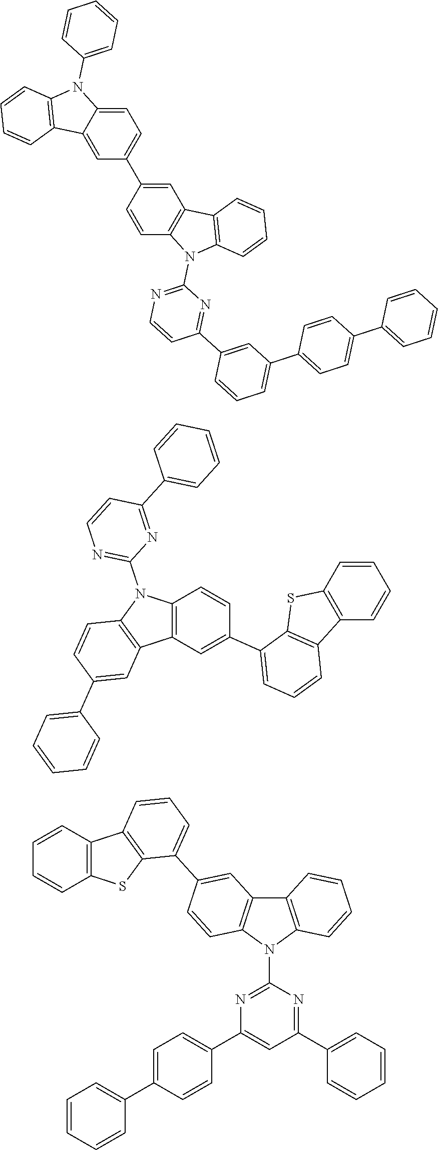

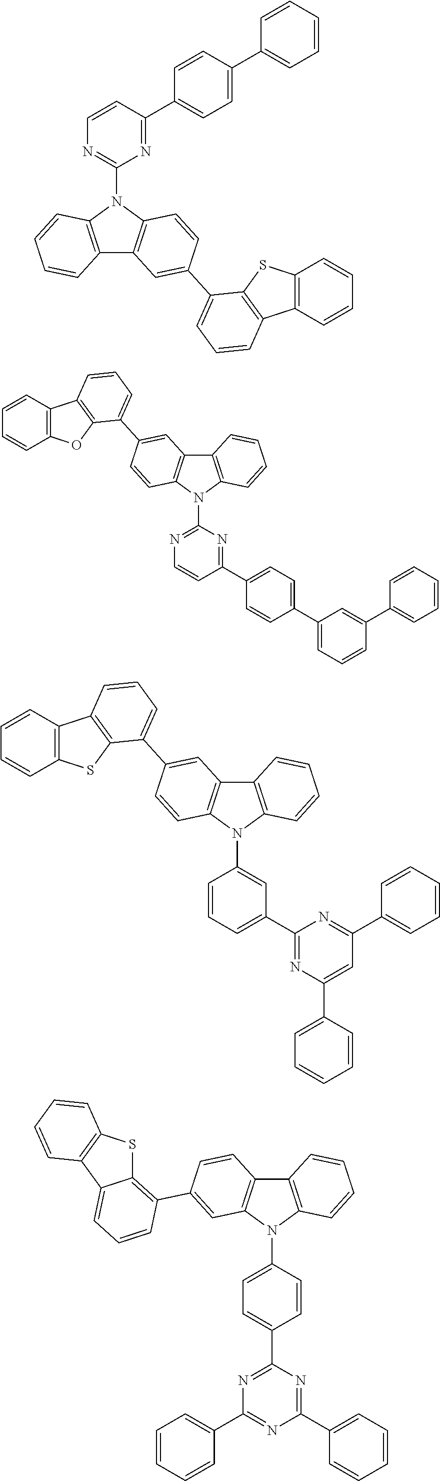 [SMILES: c1ccc(-c2ccc(-c3ccnc(-n4c5ccccc5c5cc(-c6cccc7c6sc6ccccc67)ccc54)n3)cc2)cc1 ; c1ccc(-c2cccc(-c3ccc(-c4ccnc(-n5c6ccccc6c6cc(-c7cccc8c7oc7ccccc78)ccc65)n4)cc3)c2)cc1 ; c1ccc(-c2cc(-c3ccccc3)nc(-c3cccc(-n4c5ccccc5c5cc(-c6cccc7c6sc6ccccc67)ccc54)c3)n2)cc1 ; c1ccc(-c2nc(-c3ccccc3)nc(-c3ccc(-n4c5ccccc5c5ccc(-c6cccc7c6sc6ccccc67)cc54)cc3)n2)cc1]

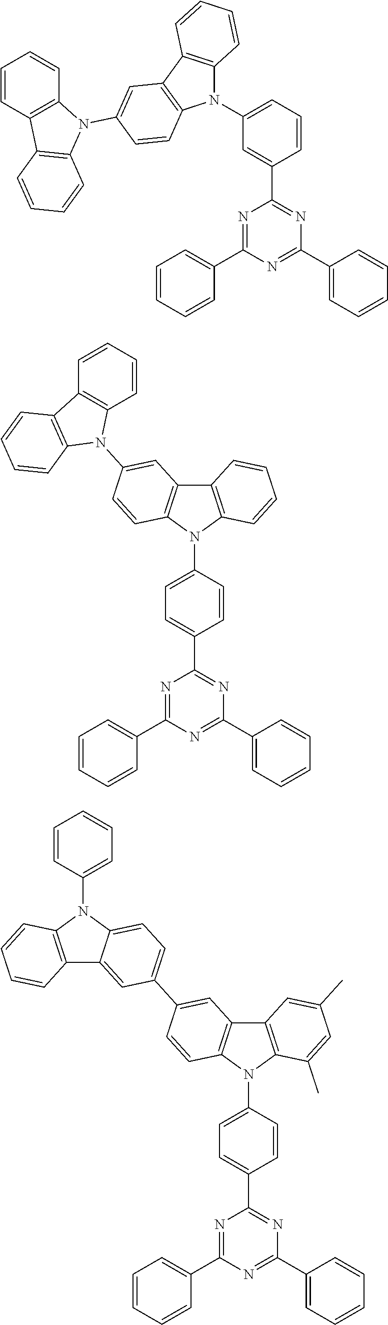

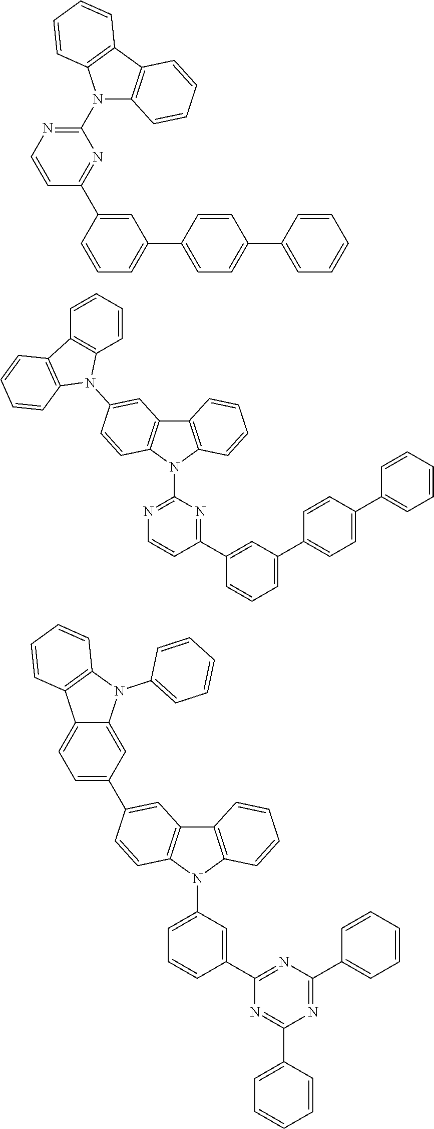

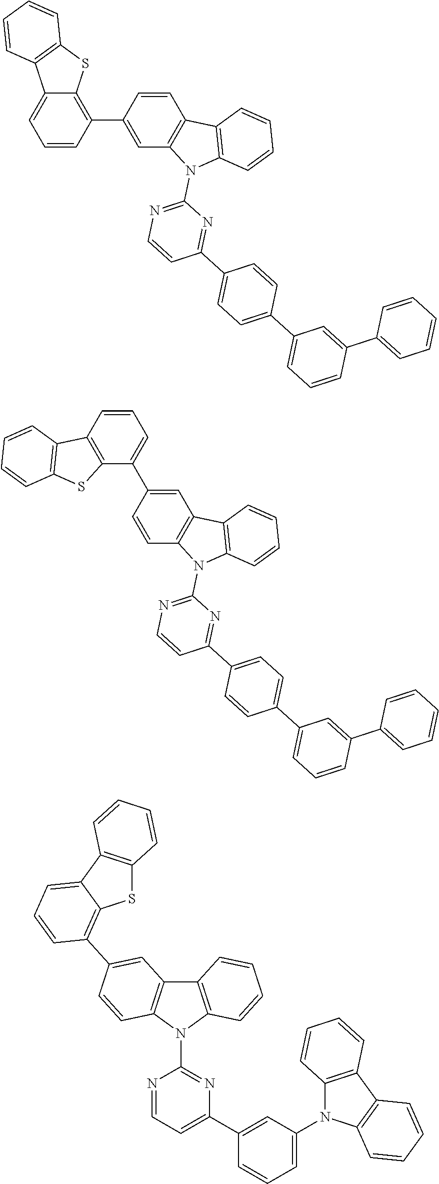 [SMILES: c1ccc(-c2cccc(-c3ccc(-c4ccnc(-n5c6ccccc6c6ccc(-c7cccc8c7sc7ccccc78)cc65)n4)cc3)c2)cc1 ; c1ccc(-c2cccc(-c3ccc(-c4ccnc(-n5c6ccccc6c6cc(-c7cccc8c7sc7ccccc78)ccc65)n4)cc3)c2)cc1 ; c1cc(-c2ccnc(-n3c4ccccc4c4cc(-c5cccc6c5sc5ccccc56)ccc43)n2)cc(-n2c3ccccc3c3ccccc32)c1]

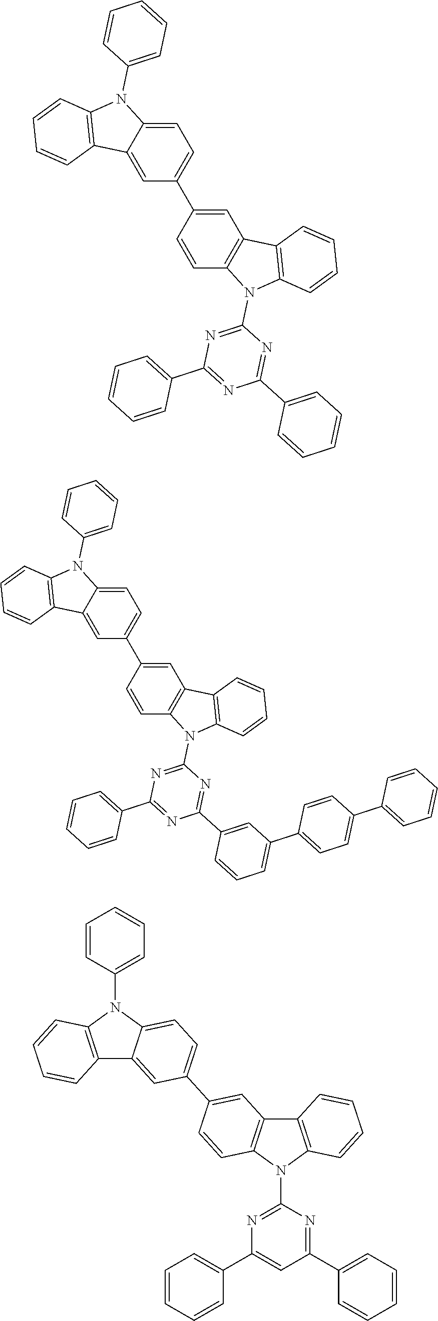 [SMILES: c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2ccc(-c3cccc(-c4nc(-c5ccccc5)nc(-n5c6ccccc6c6cc(-c7ccc8c(c7)c7ccccc7n8-c7ccccc7)ccc65)n4)c3)cc2)cc1 ; c1ccc(-c2cc(-c3ccccc3)nc(-n3c4ccccc4c4cc(-c5ccc6c(c5)c5ccccc5n6-c5ccccc5)ccc43)n2)cc1]

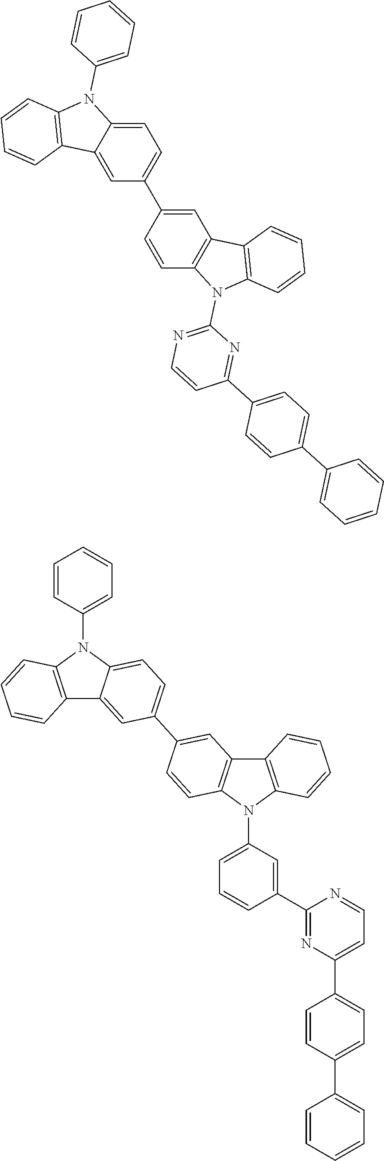 [SMILES: c1ccc(-c2ccc(-c3ccnc(-n4c5ccccc5c5cc(-c6ccc7c(c6)c6ccccc6n7-c6ccccc6)ccc54)n3)cc2)cc1 ; c1ccc(-c2ccc(-c3ccnc(-c4cccc(-n5c6ccccc6c6cc(-c7ccc8c(c7)c7ccccc7n8-c7ccccc7)ccc65)c4)n3)cc2)cc1]

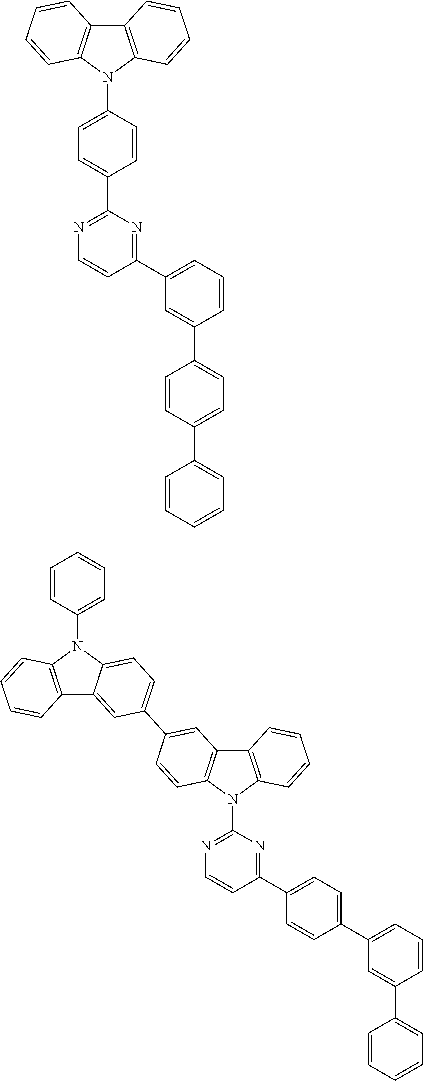 [SMILES: c1ccc(-c2ccc(-c3cccc(-c4ccnc(-c5ccc(-n6c7ccccc7c7ccccc76)cc5)n4)c3)cc2)cc1 ; c1ccc(-c2cccc(-c3ccc(-c4ccnc(-n5c6ccccc6c6cc(-c7ccc8c(c7)c7ccccc7n8-c7ccccc7)ccc65)n4)cc3)c2)cc1]

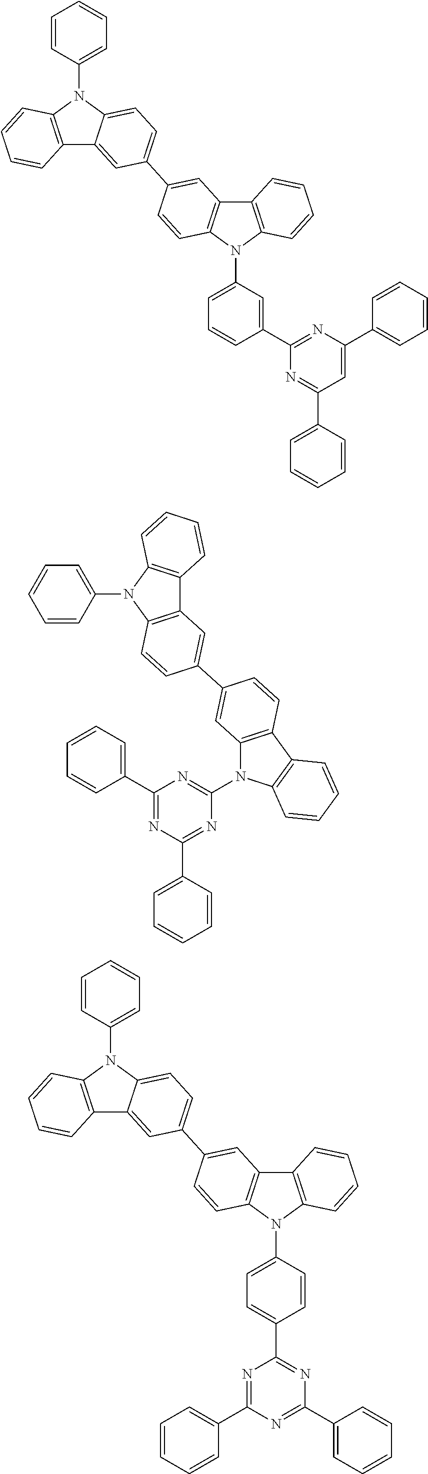 [SMILES: c1ccc(-c2cc(-c3ccccc3)nc(-c3cccc(-n4c5ccccc5c5cc(-c6ccc7c(c6)c6ccccc6n7-c6ccccc6)ccc54)c3)n2)cc1 ; c1ccc(-c2nc(-c3ccccc3)nc(-n3c4ccccc4c4ccc(-c5ccc6c(c5)c5ccccc5n6-c5ccccc5)cc43)n2)cc1 ; c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1]

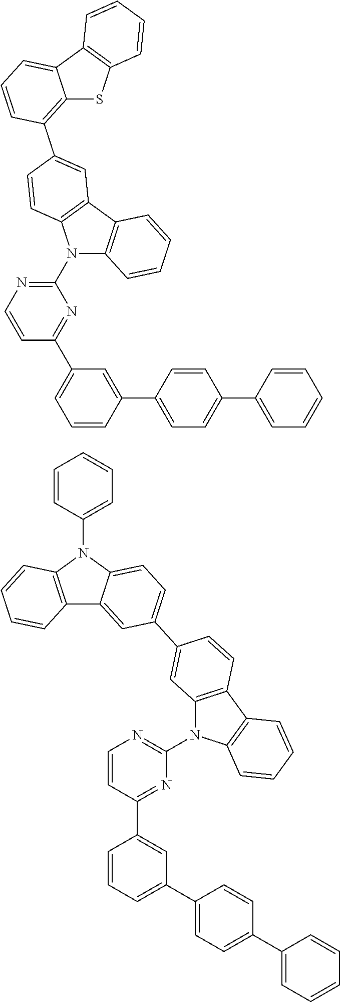

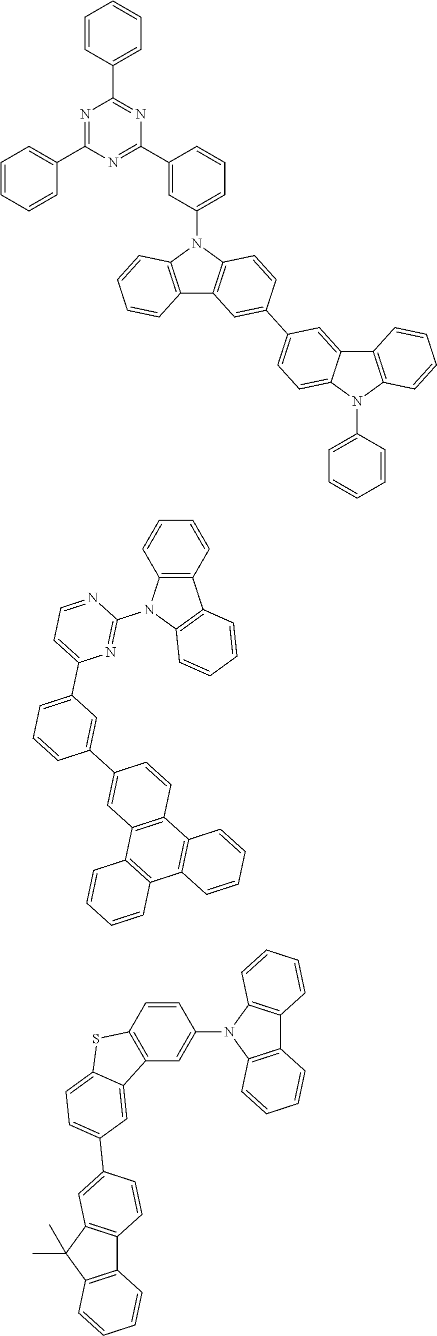 [SMILES: c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1 ; c1cc(-c2ccc3c4ccccc4c4ccccc4c3c2)cc(-c2ccnc(-n3c4ccccc4c4ccccc43)n2)c1 ; CC1(C)c2ccccc2-c2ccc(-c3ccc4sc5ccc(-n6c7ccccc7c7ccccc76)cc5c4c3)cc21]

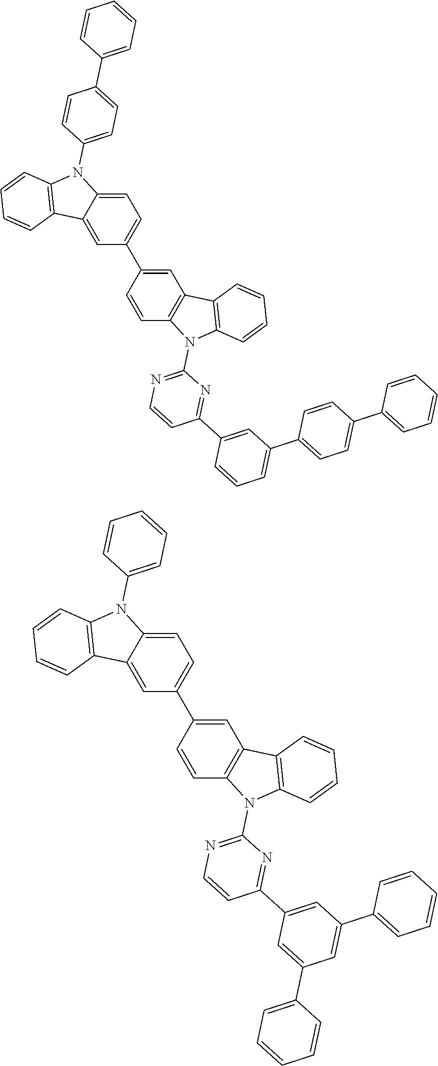 [SMILES: c1ccc(-c2ccc(-c3cccc(-c4ccnc(-n5c6ccccc6c6cc(-c7ccc8c(c7)c7ccccc7n8-c7ccc(-c8ccccc8)cc7)ccc65)n4)c3)cc2)cc1 ; c1ccc(-c2cc(-c3ccccc3)cc(-c3ccnc(-n4c5ccccc5c5cc(-c6ccc7c(c6)c6ccccc6n7-c6ccccc6)ccc54)n3)c2)cc1]

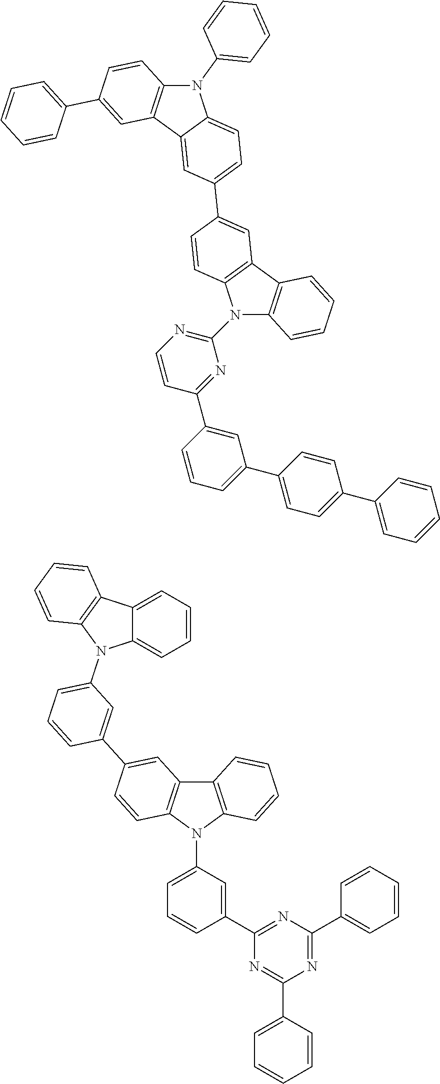 [SMILES: c1ccc(-c2ccc(-c3cccc(-c4ccnc(-n5c6ccccc6c6cc(-c7ccc8c(c7)c7cc(-c9ccccc9)ccc7n8-c7ccccc7)ccc65)n4)c3)cc2)cc1 ; c1ccc(-c2nc(-c3ccccc3)nc(-c3cccc(-n4c5ccccc5c5cc(-c6cccc(-n7c8ccccc8c8ccccc87)c6)ccc54)c3)n2)cc1]

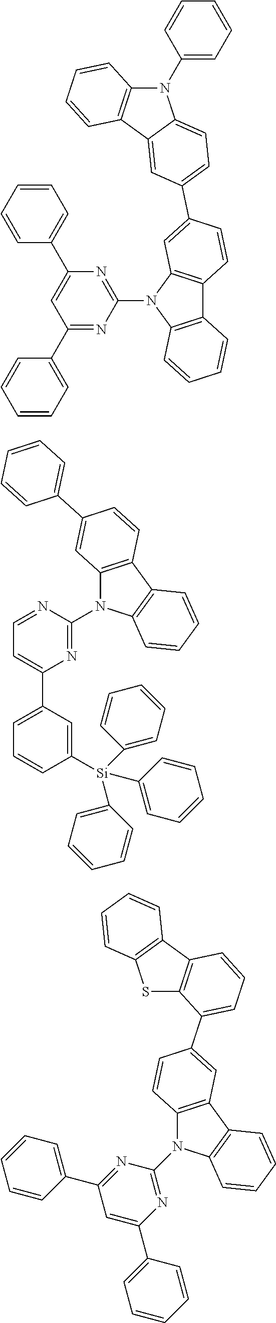

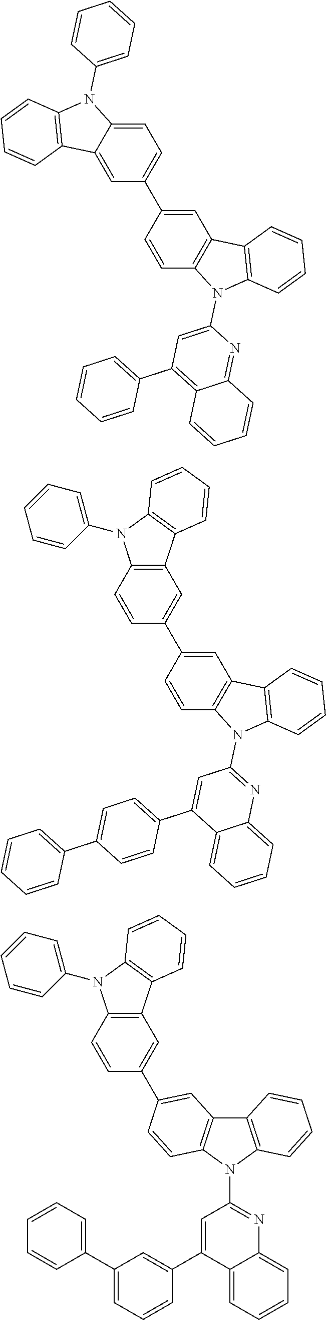

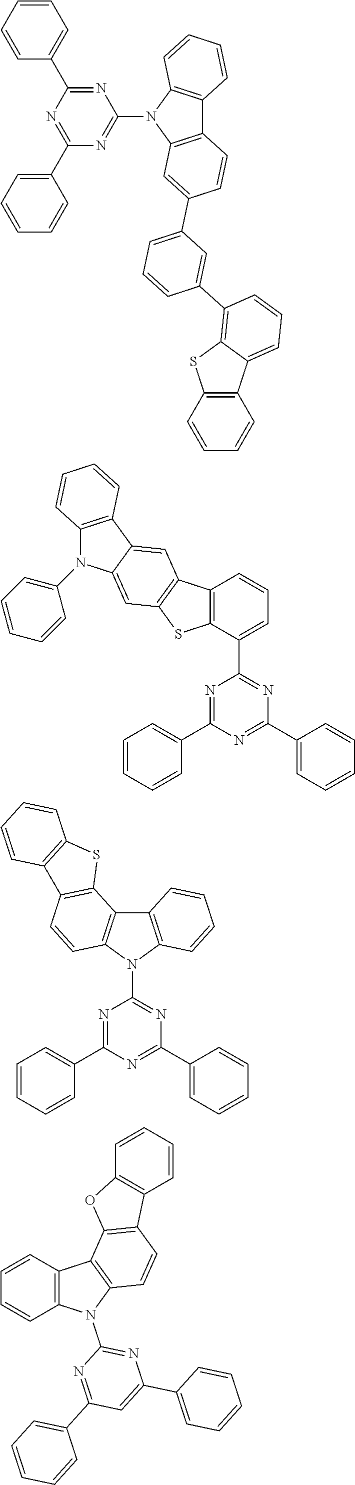 [SMILES: c1ccc(-c2nc(-c3ccccc3)nc(-n3c4ccccc4c4ccc(-c5cccc(-c6cccc7c6sc6ccccc67)c5)cc43)n2)cc1 ; c1ccc(-c2nc(-c3ccccc3)nc(-c3cccc4c3sc3cc5c(cc34)c3ccccc3n5-c3ccccc3)n2)cc1 ; c1ccc(-c2nc(-c3ccccc3)nc(-n3c4ccccc4c4c5sc6ccccc6c5ccc43)n2)cc1 ; c1ccc(-c2cc(-c3ccccc3)nc(-n3c4ccccc4c4c5oc6ccccc6c5ccc43)n2)cc1]

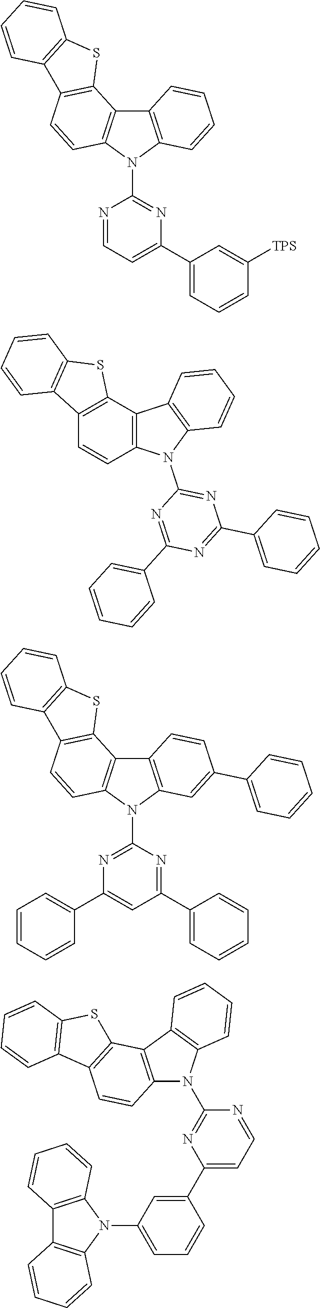

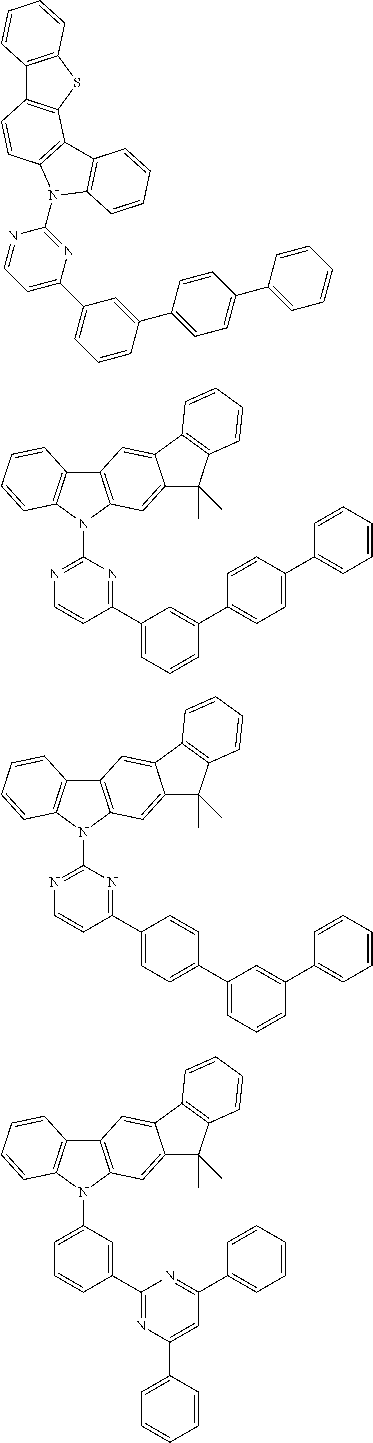

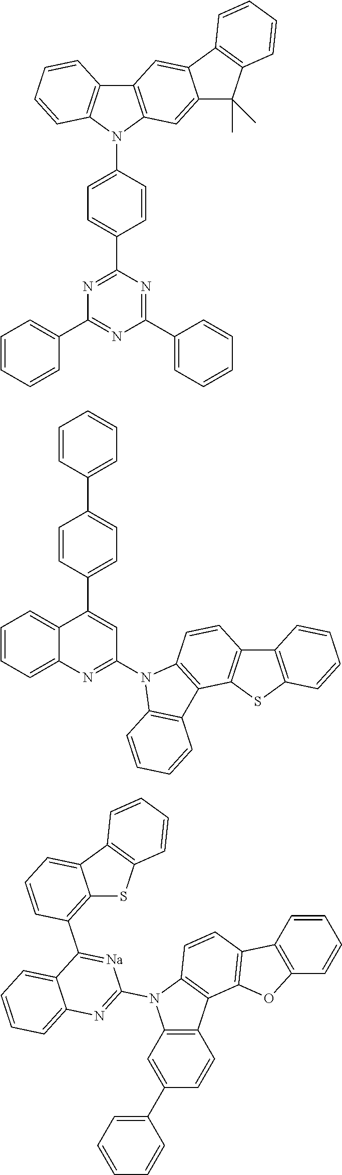

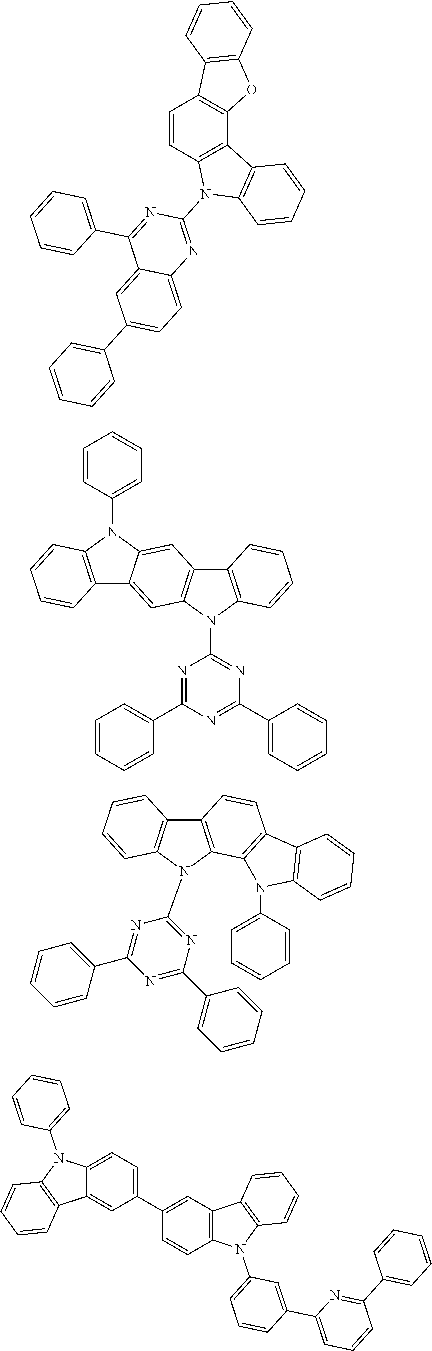

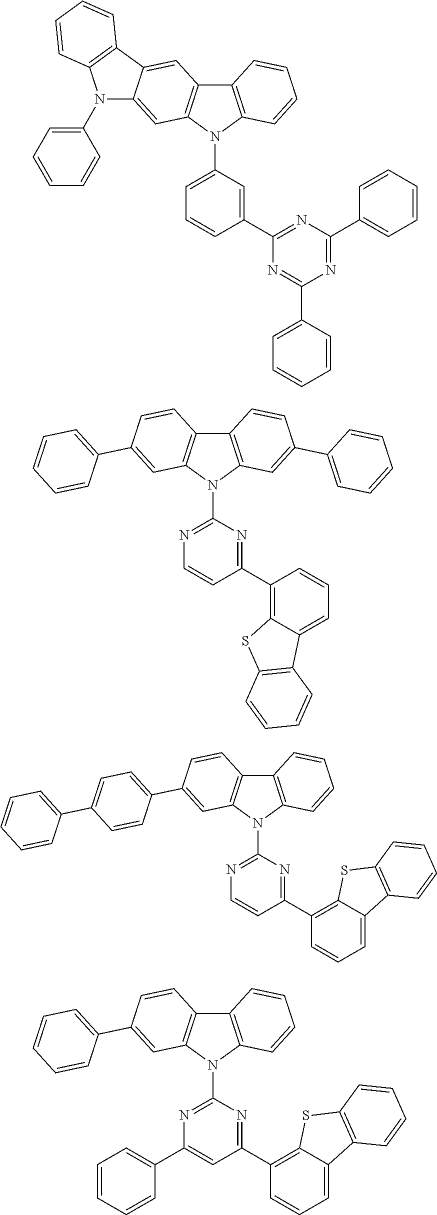

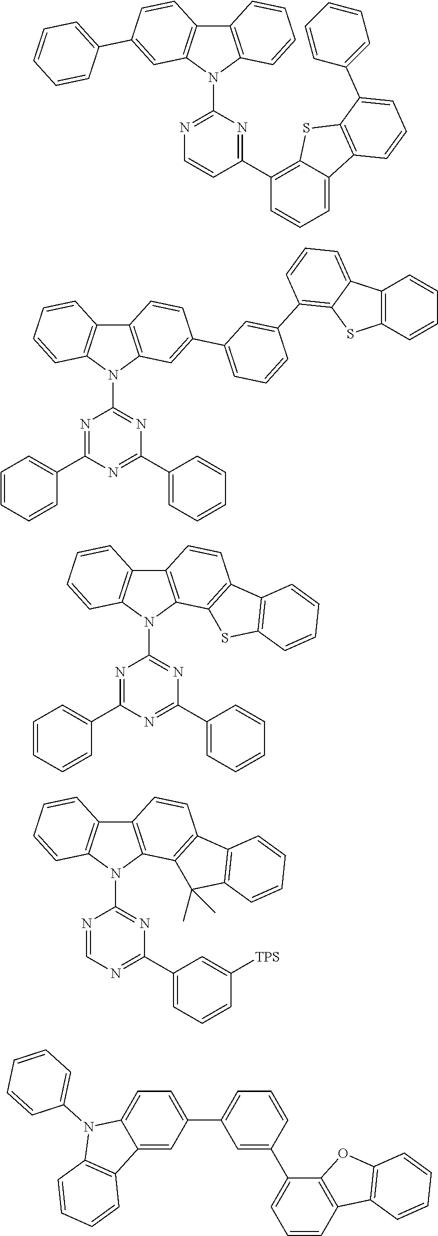

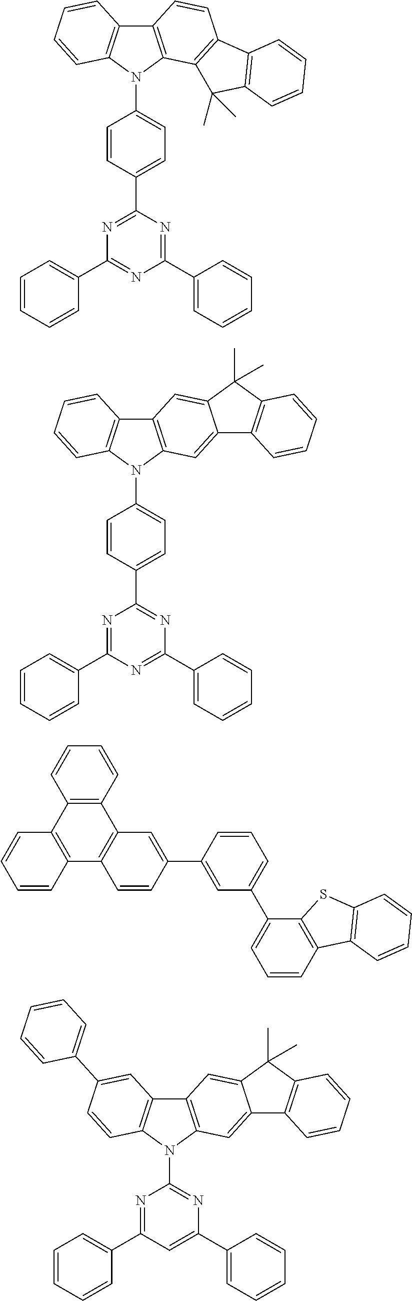

According to the present invention, the dopant comprised in the manufacture of the organic electroluminescent device is preferably one or more phosphorescent dopants. These phosphorescent dopants are not limited, but preferably may be selected from complex compounds of iridium, osmium, copper and platinum; more preferably ortho-metallated complex compounds of iridium, osmium, copper and platinum; and even more preferably ortho-metallated iridium complex compounds.

Preferably, the above phosphorescent dopant may be selected from compounds represented by the following formulas 12 to 14.

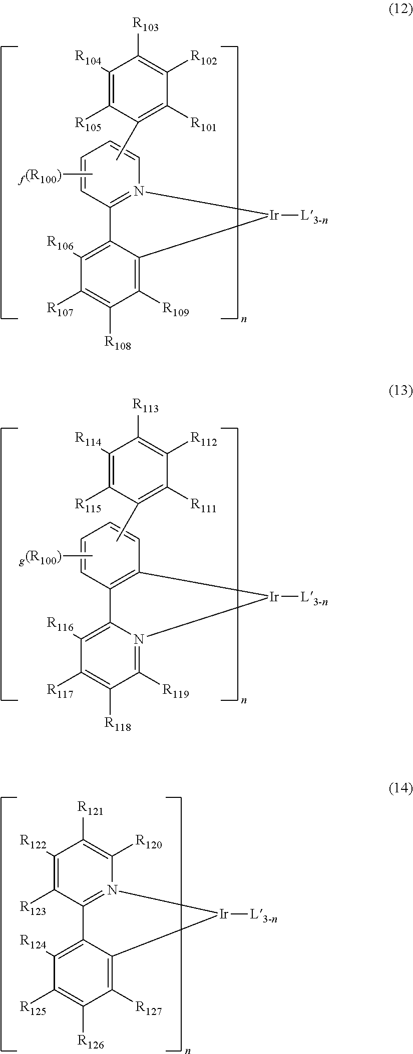

wherein L′ is selected from the following structures:

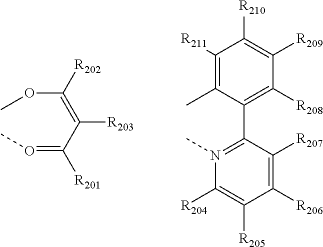

R₁₀₀ represents hydrogen, a substituted or unsubstituted (C1-C30)alkyl group, or a substituted or unsubstituted (C3-C30)cycloalkyl group;

R₁₀₁ to R₁₀₉, and R₁₁₁ to R₁₂₃ each independently represent hydrogen, deuterium, a halogen, a (C1-C30)alkyl group unsubstituted or substituted with halogen(s), a substituted or unsubstituted (C3-C30)cycloalkyl group, a cyano group, or a substituted or unsubstituted (C1-C30)alkoxy group; adjacent substituents of R₁₂₀ to R₁₂₃ may be linked to each other to form a fused ring, e.g. quinoline;

R₁₂₄ to R₁₂₇ each independently represent hydrogen, deuterium, a halogen, a substituted or unsubstituted (C1-C30)alkyl group, or a substituted or unsubstituted (C6-C30)aryl group; where R₁₂₄ to R₁₂₇ are aryl groups, adjacent substituents may be linked to each other to form a fused ring, e.g. fluorene;

R₂₀₁ to R₂₁₁ each independently represent hydrogen, deuterium, a halogen, a (C1-C30)alkyl group unsubstituted or substituted with halogen(s), or a substituted or unsubstituted (C3-C30)cycloalkyl group;

f and g each independently represent an integer of 1 to 3; where f or g is an integer of 2 or more, each of R₁₀₀ may be the same or different; and

n is an integer of 1 to 3.

The phosphorescent dopant materials include the following:

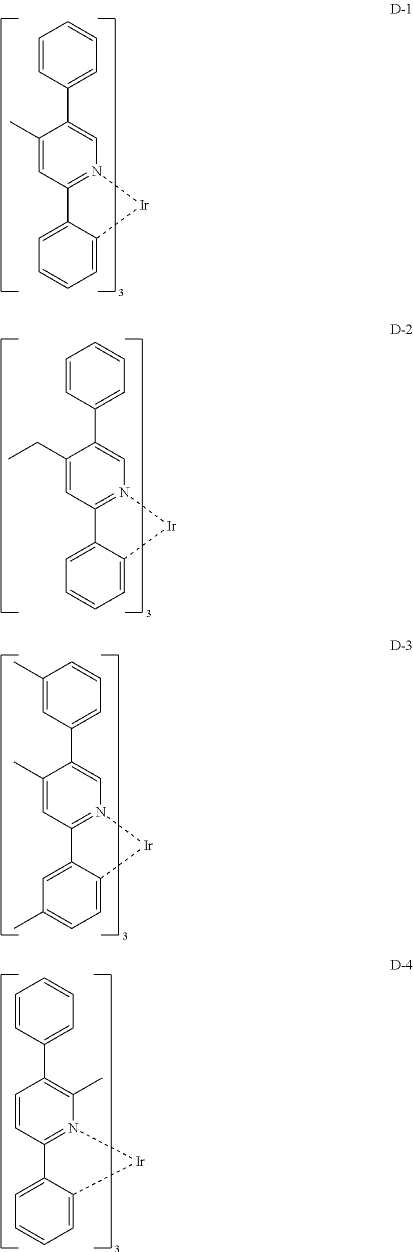

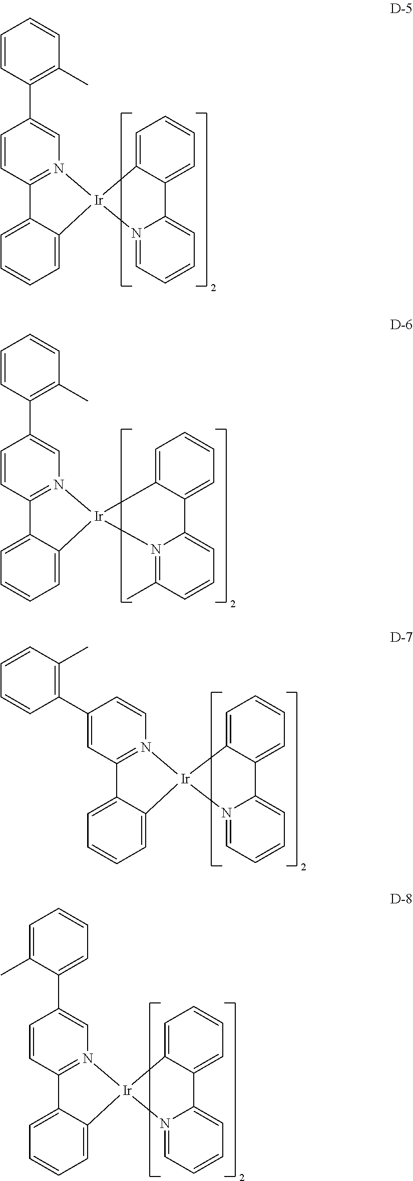

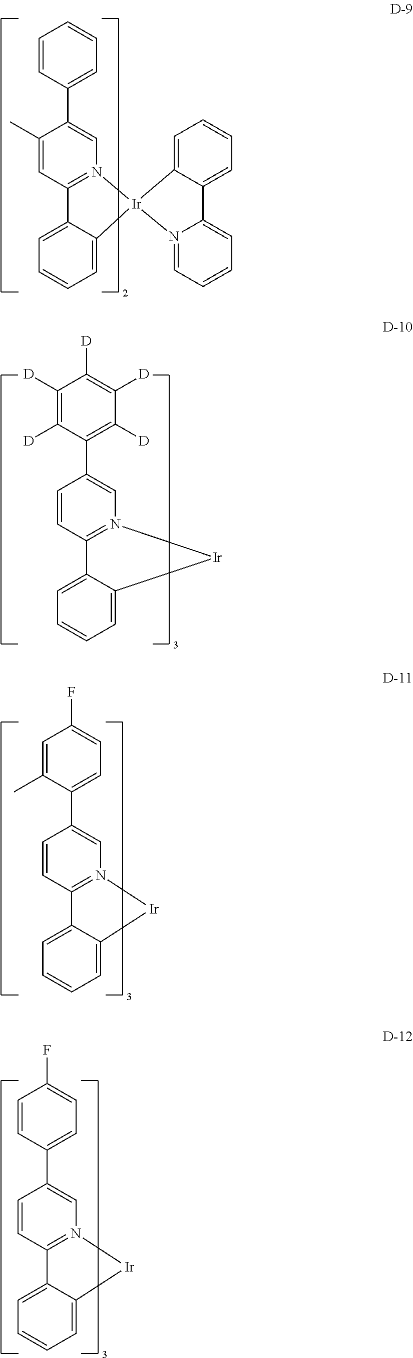

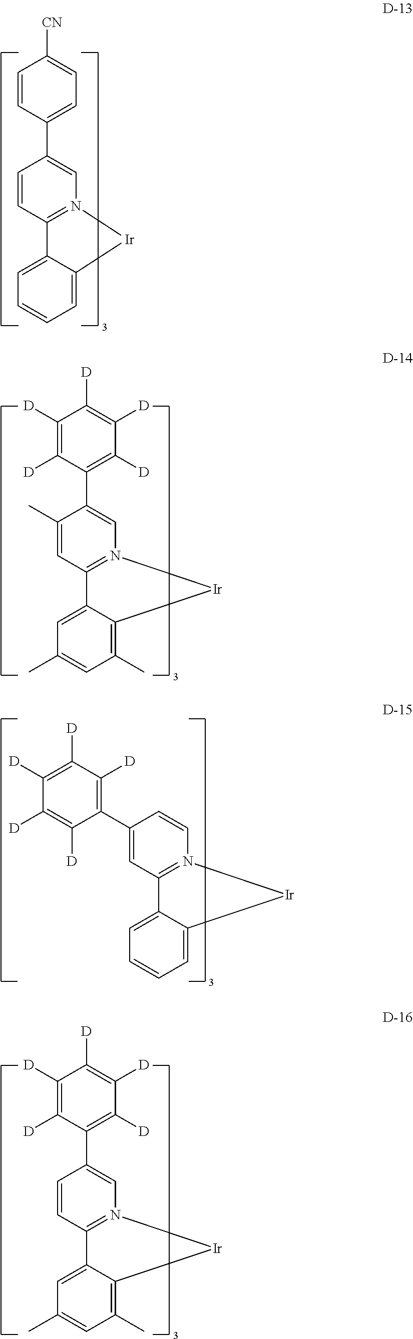

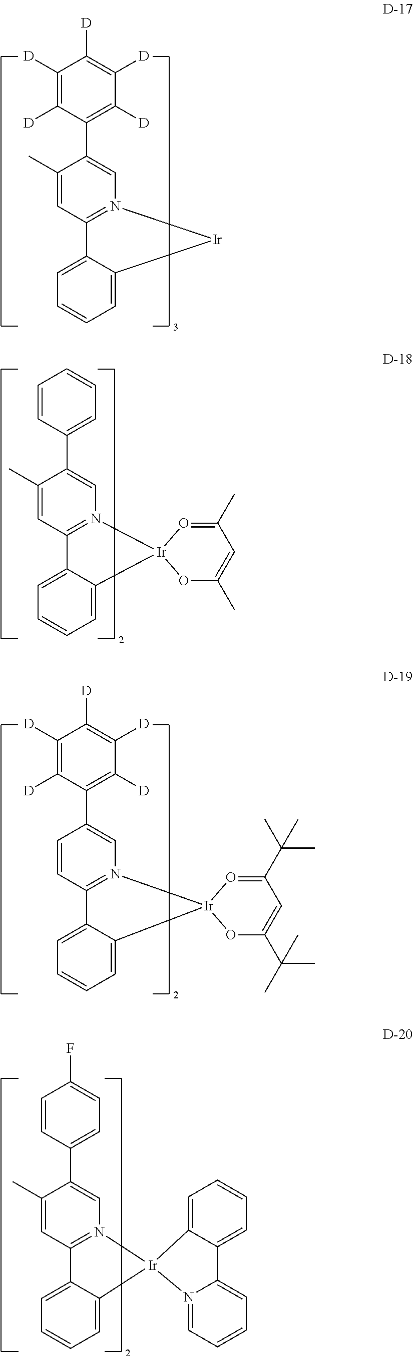

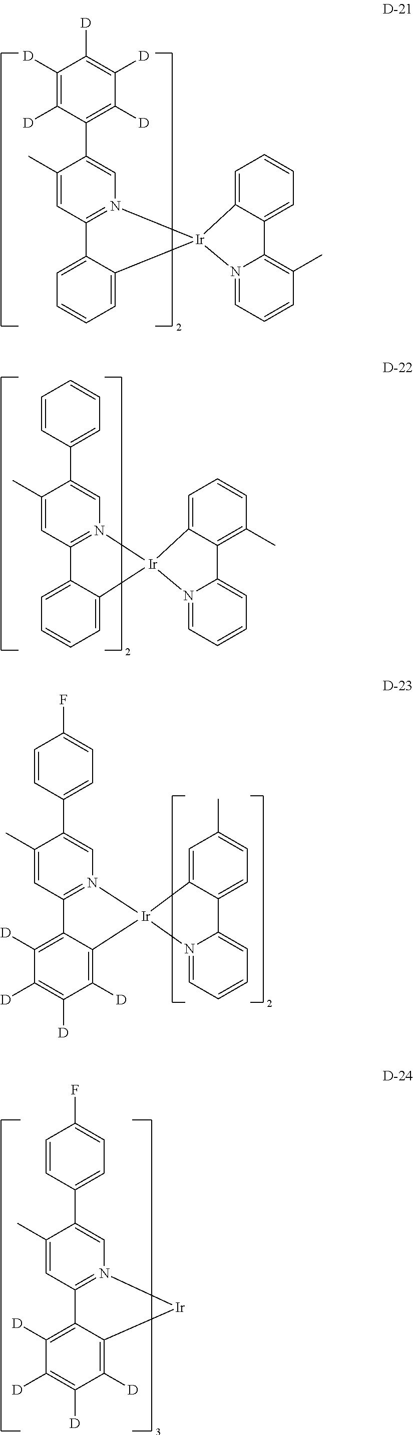

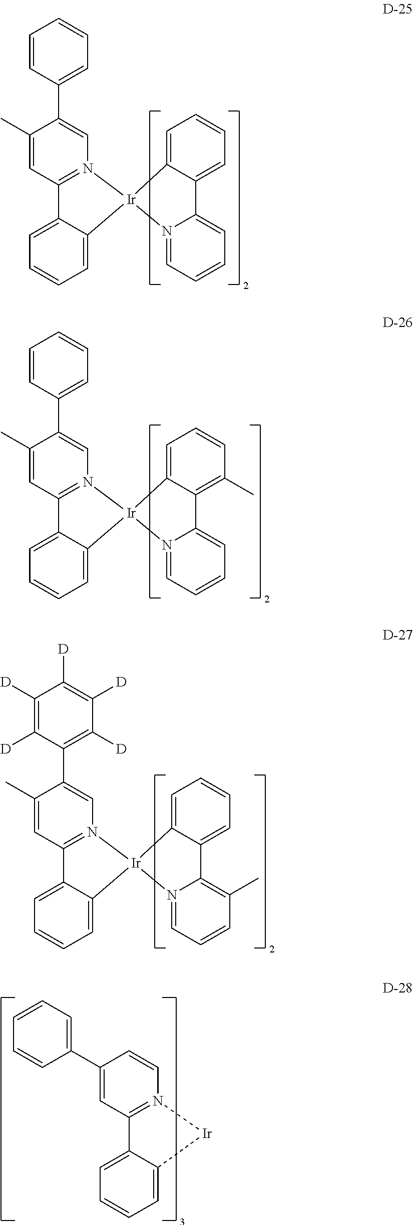

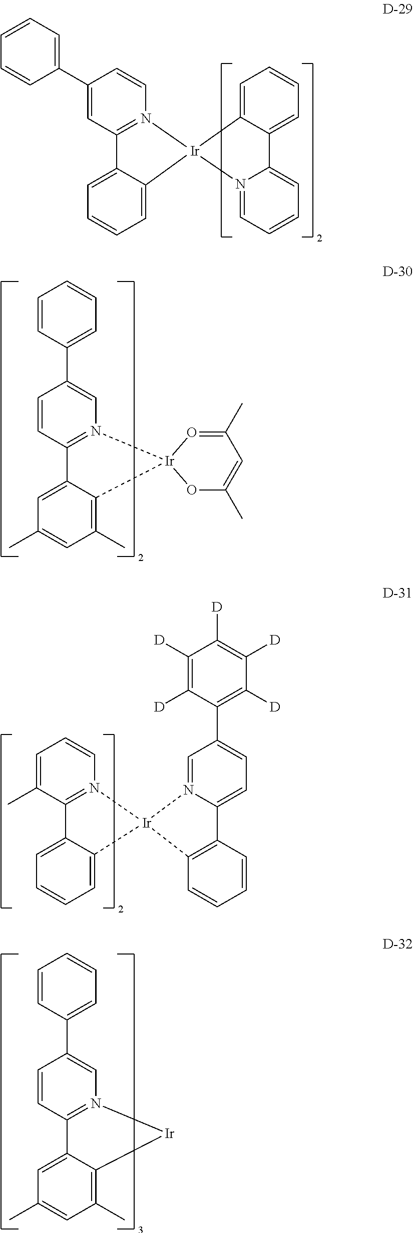

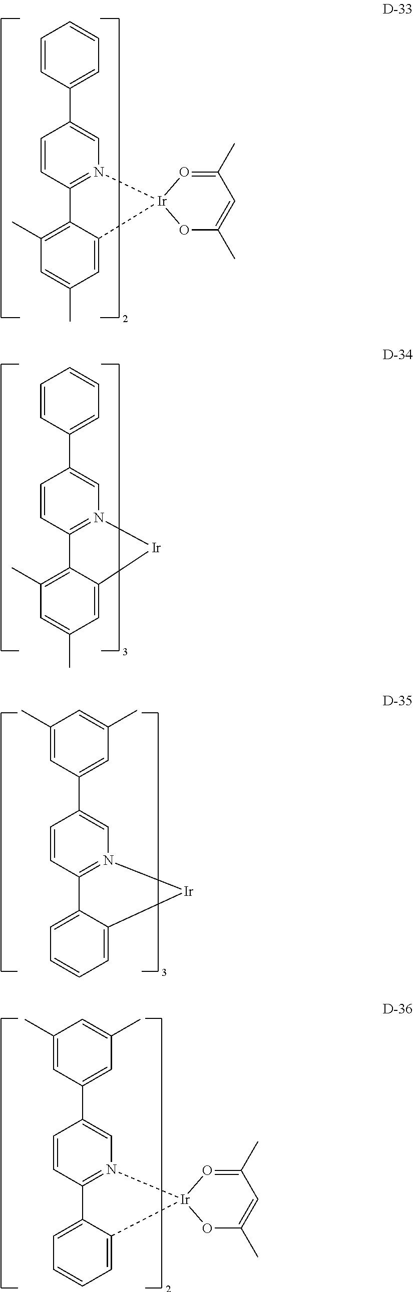

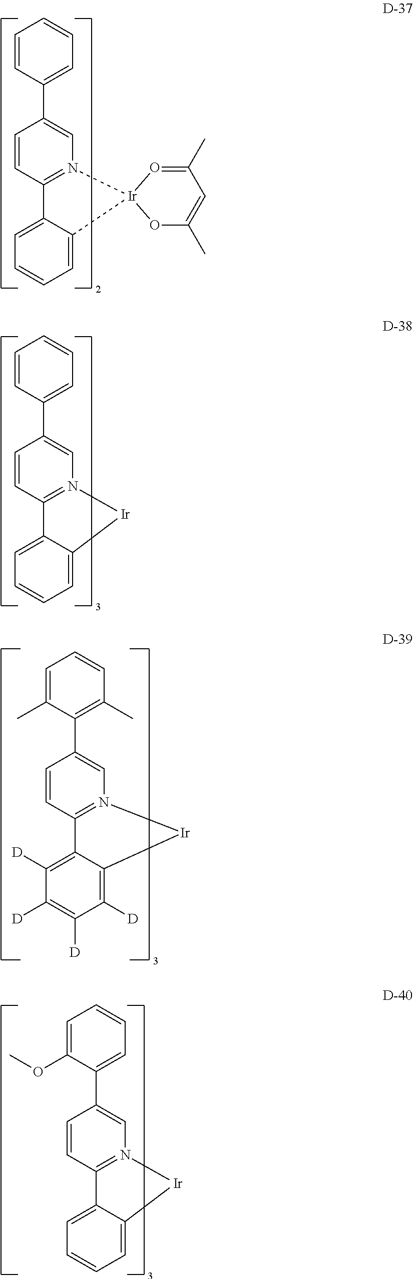

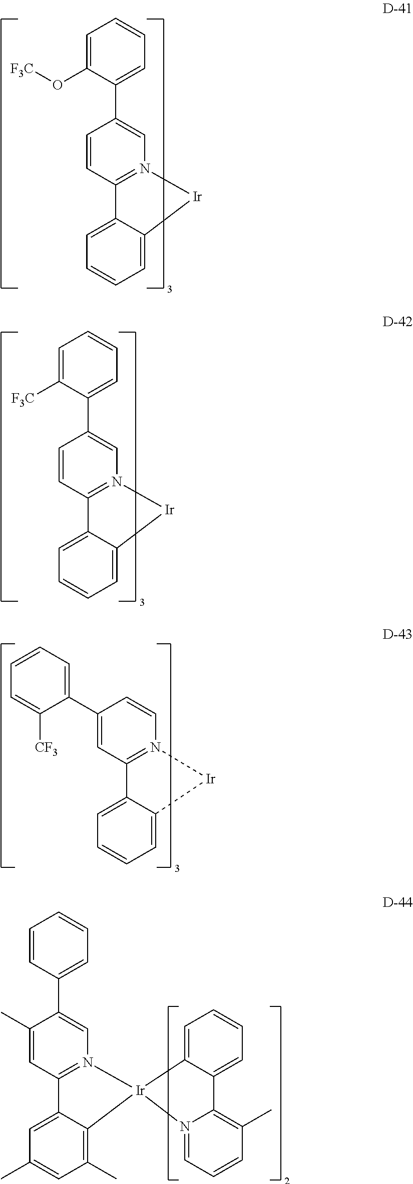

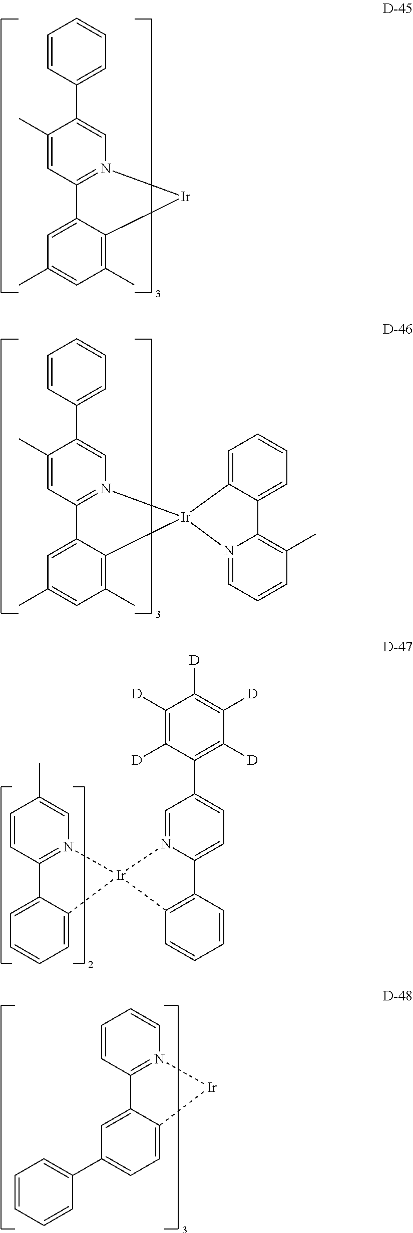

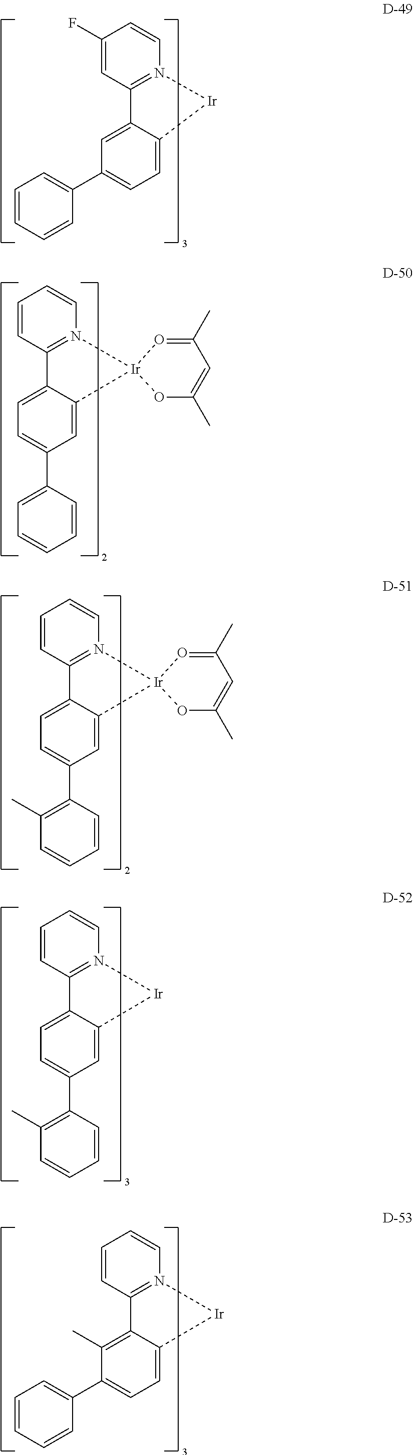

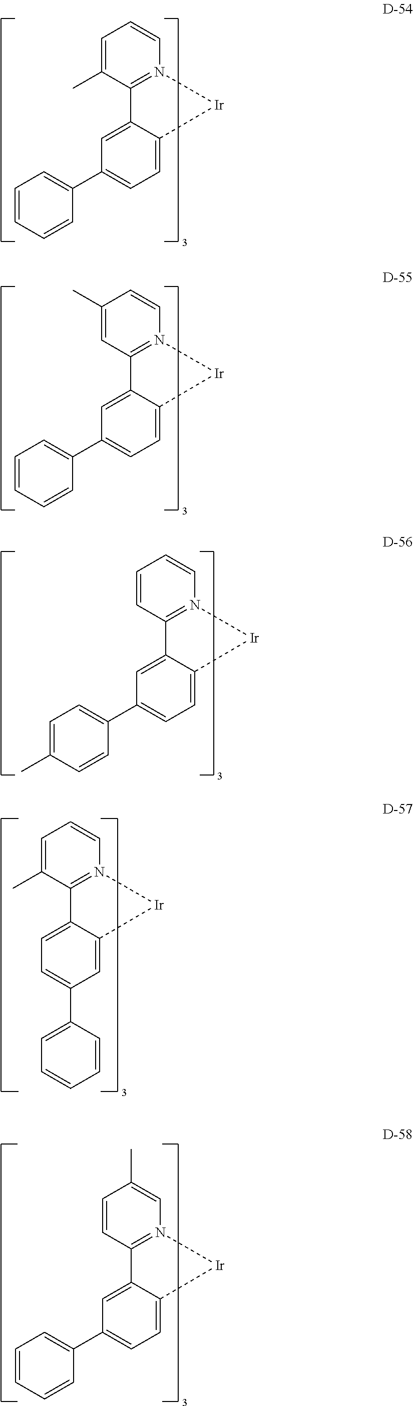

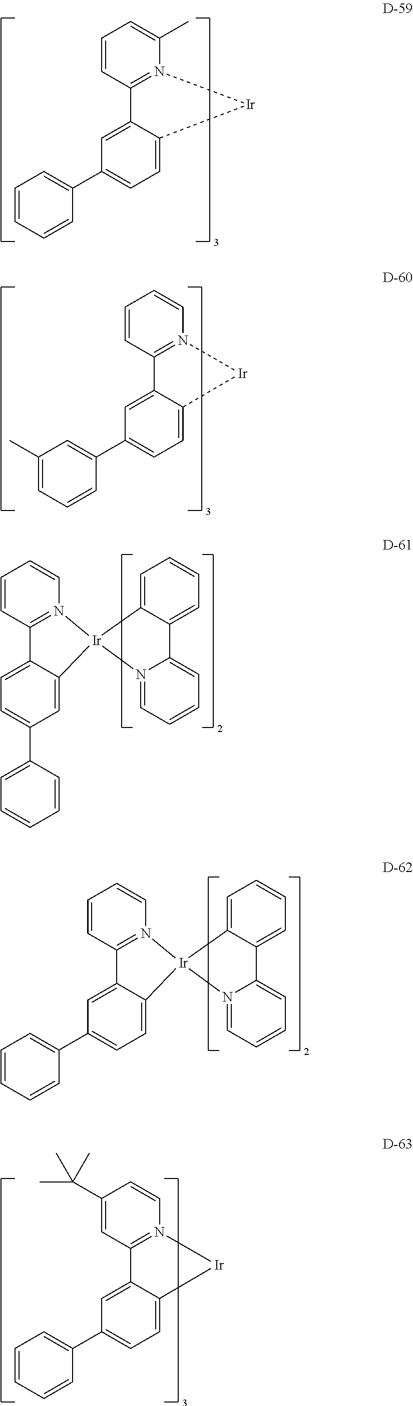

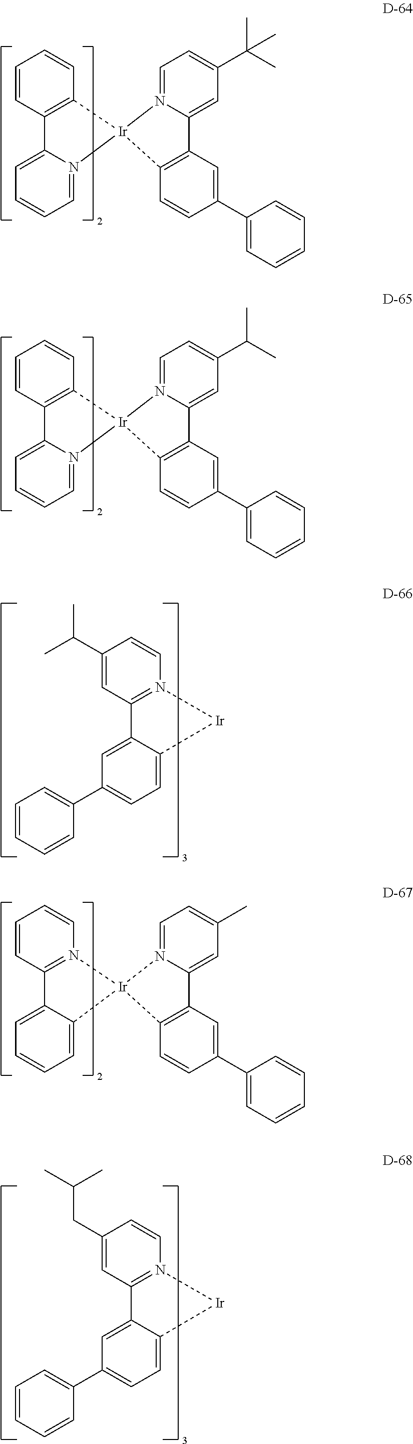

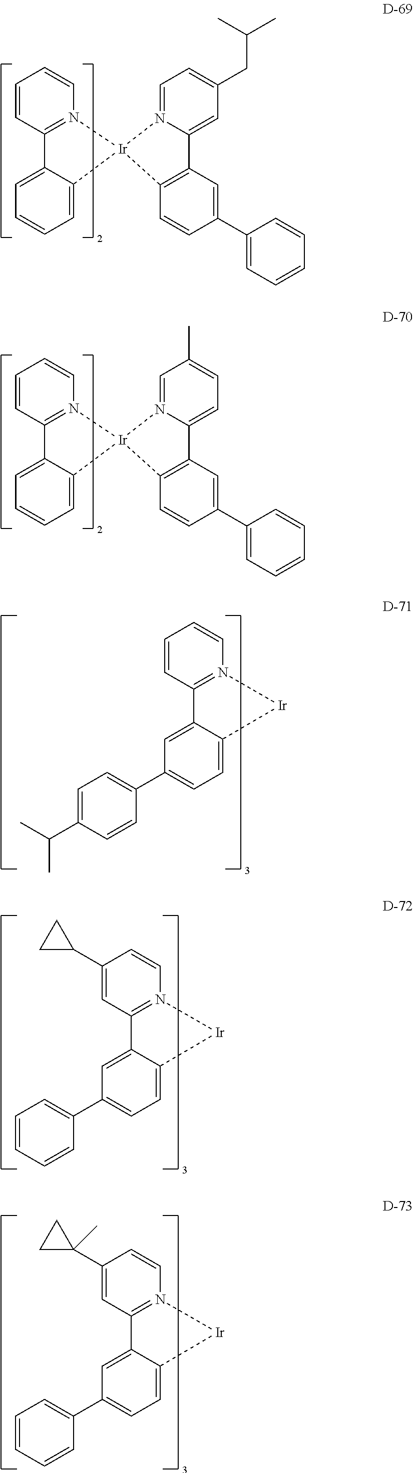

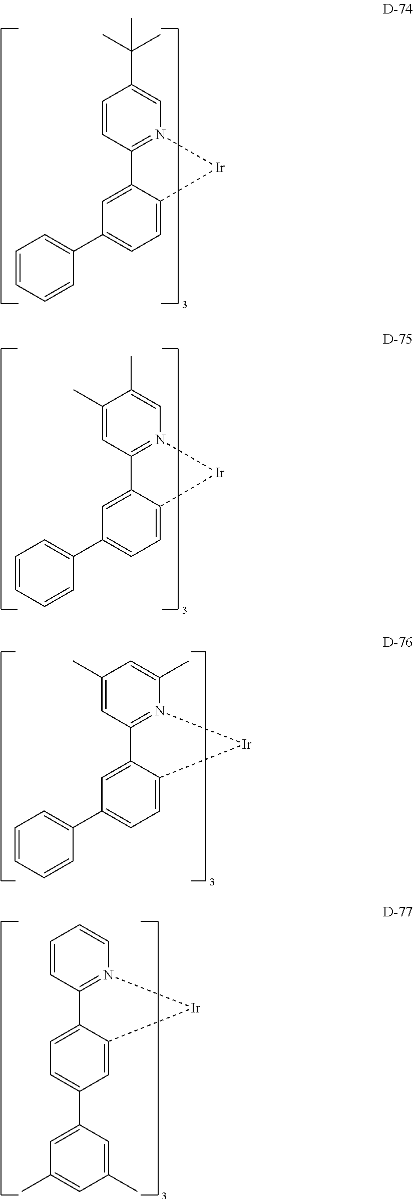

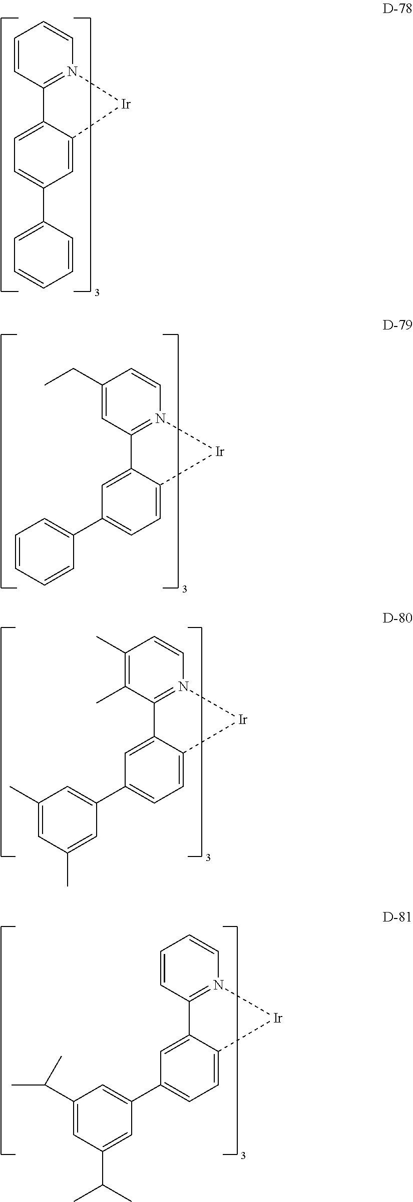

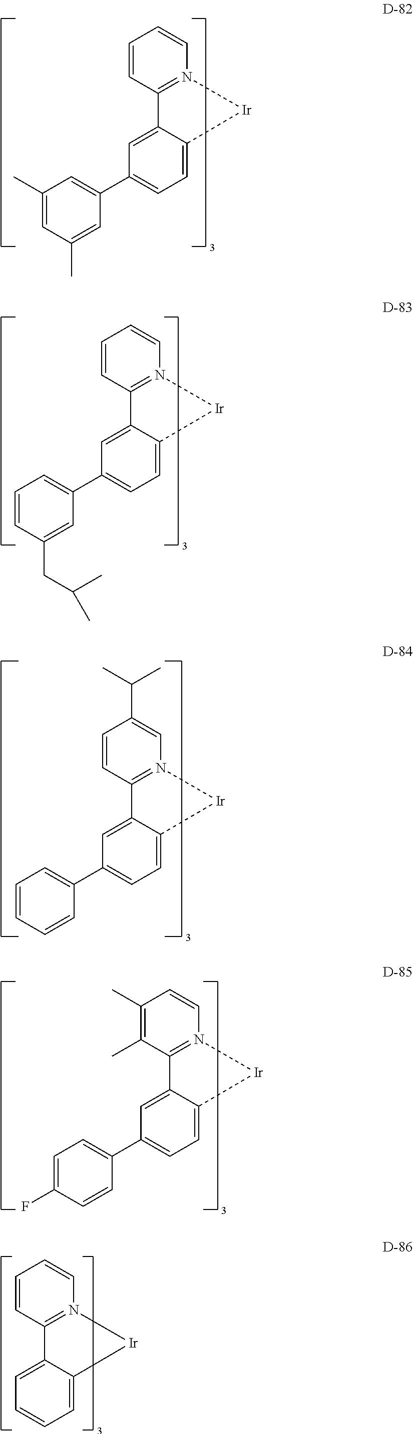

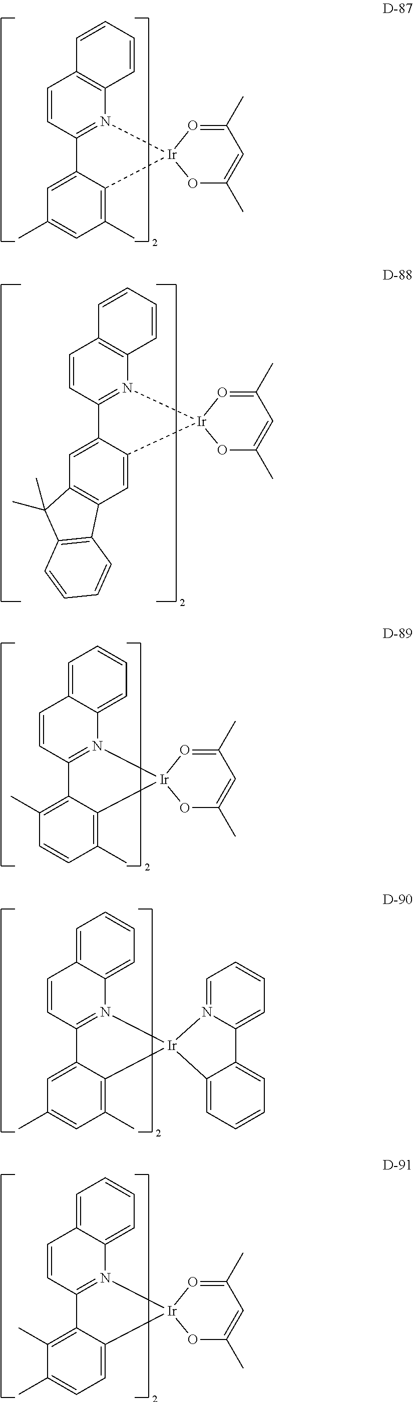

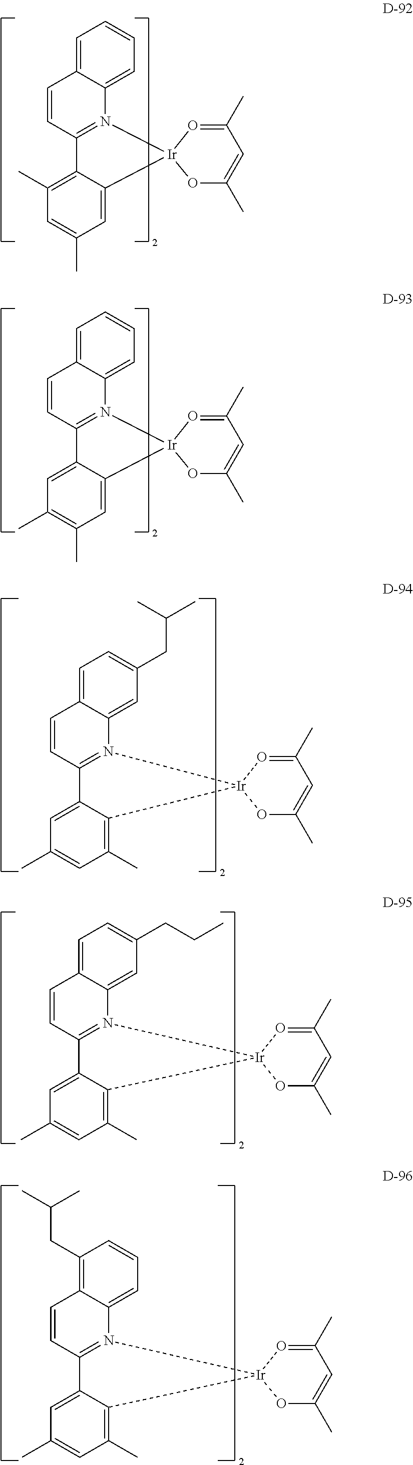

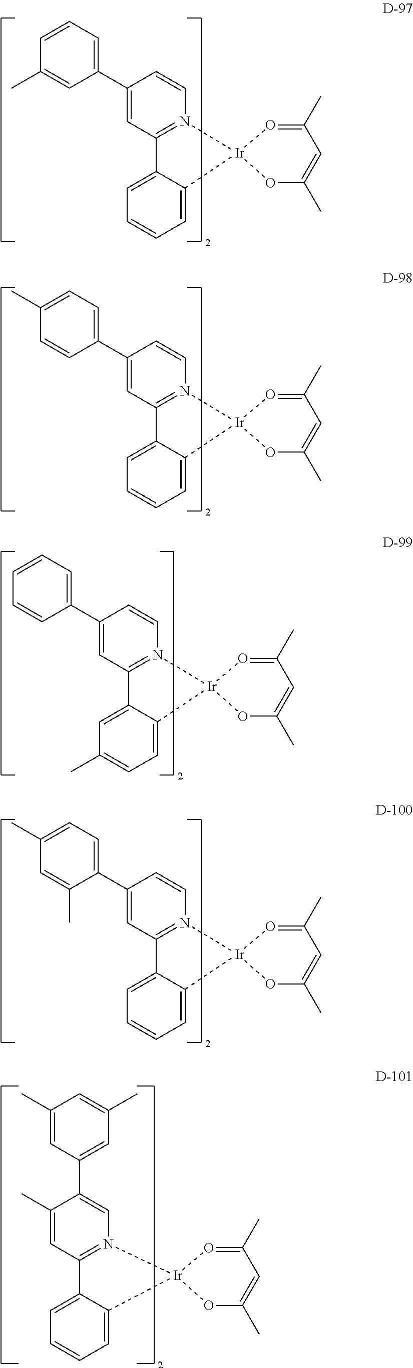

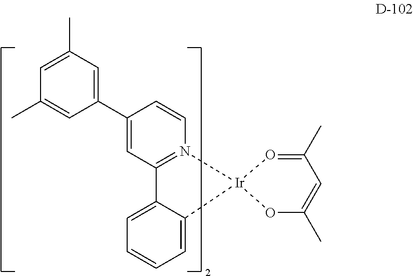

In another embodiment of the present invention, a material used for an organic electroluminescent device is provided. The material comprises the compound according to the present invention as a host material or a hole transport material.

In addition, the organic electroluminescent device according to the present invention comprises a first electrode, a second electrode, and at least one organic layer between said first and second electrodes. Said organic layer may comprise a light-emitting layer, and the light-emitting layer may comprise a material used for an organic electroluminescent device according to the present invention.

The organic electroluminescent device according to the present invention may further comprise, in addition to the organic electroluminescent compounds represented by formula 1, at least one compound selected from the group consisting of arylamine-based compounds and styrylarylamine-based compounds.

In the organic electroluminescent device according to the present invention, the organic layer may further comprise at least one metal selected from the group consisting of metals of Group 1, metals of Group 2, transition metals of the 4^{th} period, transition metals of the 5^{th} period, lanthanides and organic metals of d-transition elements of the Periodic Table, or at least one complex compound comprising said metal. The organic layer may further comprise at least one more light-emitting layer, and a charge generating layer.

In addition, the organic electroluminescent device according to the present invention may emit white light by further comprising at least one light-emitting layer which comprises a blue electroluminescent compound, a red electroluminescent compound or a green electroluminescent compound known in the field, besides the organic electroluminescent compound according to the present invention. Also, if needed, a yellow or orange light-emitting layer can be comprised in the device.

According to the present invention, at least one layer (hereinafter, “a surface layer”) selected from a chalcogenide layer, a metal halide layer and a metal oxide layer; may be preferably placed on an inner surface(s) of one or both electrode(s). Specifically, a chalcogenide(includes oxides) layer of silicon or aluminum is preferably placed on an anode surface of an electroluminescent medium layer, and a metal halide layer or a metal oxide layer is preferably placed on a cathode surface of an electroluminescent medium layer. Such a surface layer provides operation stability for the organic electroluminescent device. Preferably, said chalcogenide includes SiOₓ(1≦X≦2), AlOₓ(1≦X≦1.5), SiON, SiAlON, etc.; said metal halide includes LiF, MgF₂, CaF₂, a rare earth metal fluoride, etc.; and said metal oxide includes Cs₂O, Li₂O, MgO, SrO, BaO, CaO, etc.

Preferably, in the organic electroluminescent device according to the present invention, a mixed region of an electron transport compound and an reductive dopant, or a mixed region of a hole transport compound and an oxidative dopant may be placed on at least one surface of a pair of electrodes. In this case, the electron transport compound is reduced to an anion, and thus it becomes easier to inject and transport electrons from the mixed region to an electroluminescent medium. Further, the hole transport compound is oxidized to a cation, and thus it becomes easier to inject and transport holes from the mixed region to the electroluminescent medium. Preferably, the oxidative dopant includes various Lewis acids and acceptor compounds; and the reductive dopant includes alkali metals, alkali metal compounds, alkaline earth metals, rare-earth metals, and mixtures thereof. A reductive dopant layer may be employed as a charge generating layer to prepare an electroluminescent device having two or more electroluminescent layers and emitting white light.

In order to form each layer of the organic electroluminescent device according to the present invention, dry film-forming methods such as vacuum evaporation, sputtering, plasma and ion plating methods, or wet film-forming methods such as spin coating, dip coating, flow coating methods can be used.

When using a wet film-forming method, a thin film can be formed by dissolving or diffusing materials forming each layer into any suitable solvent such as ethanol, chloroform, tetrahydrofuran, dioxane, etc. The solvent can be any solvent where the materials forming each layer can be dissolved or diffused, and where there are no problems in film-formation capability.

Hereinafter, the organic electroluminescent compound, the preparation method of the compound, and the luminescent properties of the device comprising the compound of the present invention will be explained in detail with reference to the following examples:

### Example 1

### Preparation of Compound C-58

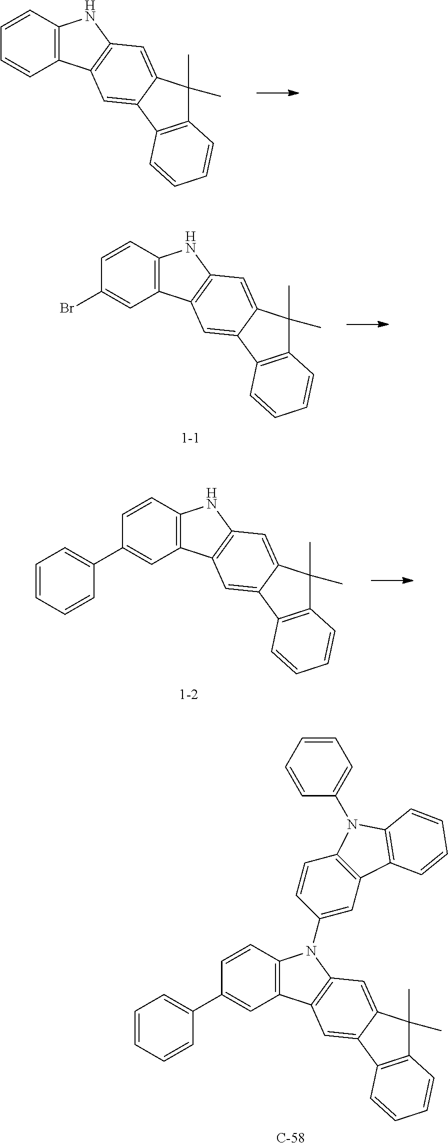

### Preparation of Compound 1-1

After mixing 1,3-dihydro-3,3-dimethylindeno[2,1-b]carbazole (10 g, 0.035 mol) and dimethylformamide (DMF) 500 mL, the mixture was stirred for 10 minutes at 0° C. Then, dissolving n-bromosuccinimide (NBS) (6.0 g, 0.03 mol) in DMF 350 mL, the solution was added to the above mixture, and the mixture was stirred for 6 hours at 0° C. After completing the reaction, the mixture was neutralized with distilled water, and then extracted with ethyl acetate (EA). The organic layer was dried with MgSO₄, and solvent was removed with a rotary evaporator. Then, the remaining product was purified by column chromatography using EA as a developing solvent to obtain compound 1-1 (10 g, 78%).

### Preparation of Compound 1-2

After mixing compound 1-1 (9.0 g, 0.024 mol), phenylboronic acid (3.6 g, 0.029 mol), Pd(PPh₃)₄ (1.4 g, 0.0012 mmol), K₂CO₃ (2 M, 0.37 mL), ethanol 37 mL, and toluene 75 mL, the mixture was heated to 120° C., and stirred for 4 hours. After completing the reaction, the mixture was washed with distilled water, and then extracted with EA. The organic layer was dried with MgSO₄, and solvent was removed with a rotary evaporator. Then, the remaining product was purified with a column to obtain compound 1-2 (5.9 g, 66%).

### Preparation of Compound C-58

After mixing compound 1-2 (5.9 g, 0.016 mol), 3-bromo-9-phenyl-9H-carbazole (6.3 g, 0.019 mol), Cul (1.5 g, 0.008 mol), K₃PO₄ (10.4 g, 0.049 mol), ethylene diamine (EDA) (1.1 mL, 0.016 mol), and toluene 150 mL, the mixture was heated to 120° C., and stirred for 12 hours. After completing the reaction, the mixture was washed with distilled water, and then extracted with EA. The organic layer was dried with MgSO₄, and solvent was removed with a rotary evaporator. Then, the remaining product was purified with a column to obtain compound C-58 (4.0 g, 40%).

### Example 2

### Preparation of Compound C-65

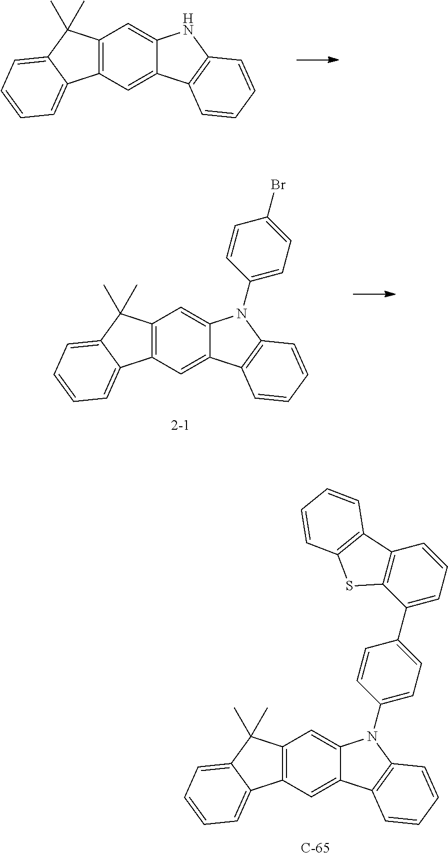

### Preparation of Compound 2-1

After mixing 1,3-dihydro-3,3-dimethylindeno[2,1-b]carbazole (5 g, 17.6 mmol), 4-bromoiodobenzene (12.5 g, 44 mmol), Cul (1.7 g, 8.8 mmol), K₃PO₄ (11 g, 53 mmol), EDA (2.4 mL, 35 mmol), and toluene 90 mL, the mixture was stirred for 18 hours at 120° C. After completing the reaction, the mixture was washed with distilled water, and then extracted with EA. The organic layer was dried with MgSO₄, and solvent was removed with a rotary evaporator. Then, the crude product was filtered through silica using methylene chloride (MC) to obtain, white solid, compound 2-1 (6.8 g, 88%).

### Preparation of Compound C-65

After mixing compound 2-1 (6.8 g, 15.5 mmol), dibenzo[b,d]thiophen-4-yl boronic acid (4.6 g, 20 mmol), Pd(PPh₃)₄ (896 mg, 0.77 mmol), K₂CO₃ (5.3 g, 38.8 mmol), toluene 80 mL, ethanol 20 mL, and distilled water 20 mL, the mixture was stirred for 4.5 hours at 120° C. After completing the reaction, the mixture was washed with distilled water, and then extracted with EA. The organic layer was dried with MgSO₄, and solvent was removed with a rotary evaporator. Then, the crude product was purified by column chromatography using MC and hexane as developing solvents, then recrystallized with toluene to obtain compound C-65 (6.2 g, 71%).

### Example 3

### Preparation of Compound C-71

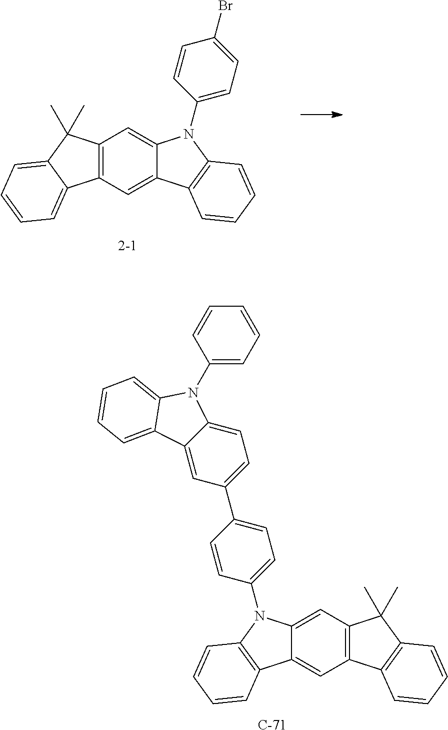

After mixing compound 2-1 (3.5 g, 0.007 mol), 9-phenyl-9H-carbazol-3-yl boronic acid (2.7 g, 0.009 mol), Pd(PPh₃)₄ (461 mg, 0.3 mmol), K₂CO₃ (2 M, 12 mL), ethanol 12 mL, and toluene 24 mL, the mixture was heated to 120° C., and stirred for 8 hours. After completing the reaction, the mixture was washed with distilled water, and then extracted with EA. The organic layer was dried with MgSO₄, and solvent was removed with a rotary evaporator. Then, the remaining product was purified with a column to obtain compound C-71 (2.0 g, 41%).

### Example 4

### Preparation of Compound C-98

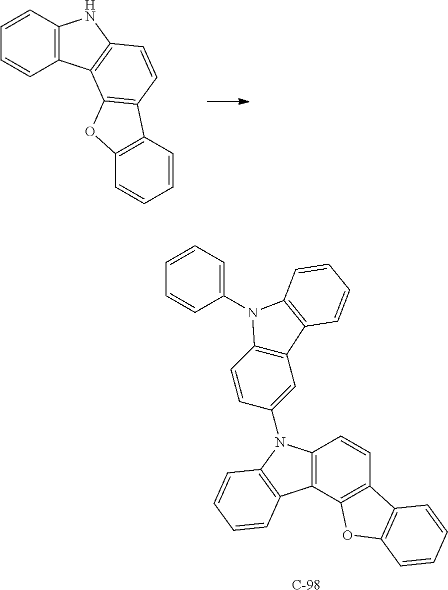

After mixing 5H-benzofuro[3,2-c]carbazole (6.0 g, 0.02 mol), 3-bromo-9-phenyl-9H-carbazole (9.7 g, 0.03 mol), Cul (1.9 g, 0.01 mol), K₃PO₄ (12.7 g, 0.06 mol), EDA (1.3 mL, 0.02 mol), and toluene 150 mL, the mixture was heated to 120° C., and stirred for 12 hours. After completing the reaction, the mixture was washed with distilled water, and then extracted with EA. The organic layer was dried with MgSO₄, and solvent was removed with a rotary evaporator. Then, the remaining product was purified with a column to obtain compound C-98 (6 g, 51%).

### Example 5

### Preparation of Compound C-165

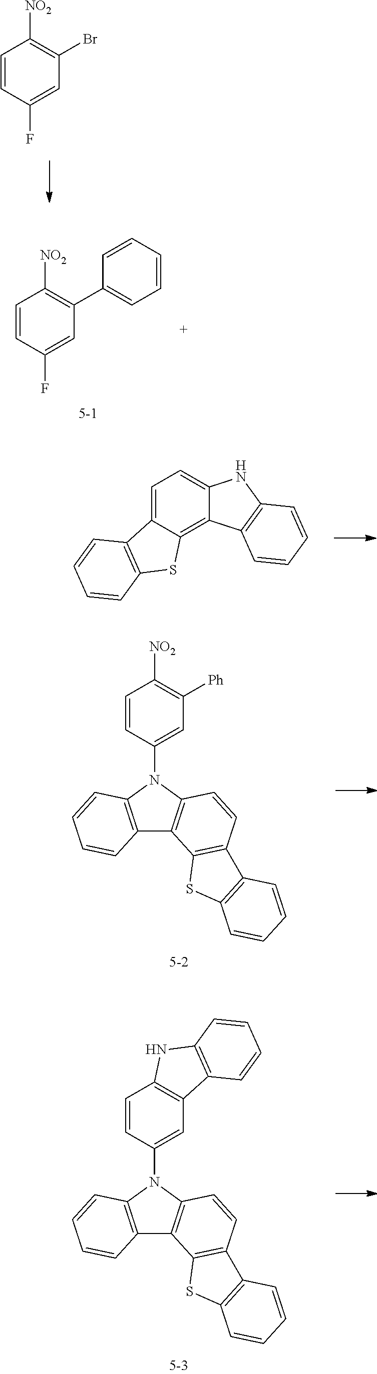 [SMILES: O=[N+]([O-])c1ccc(F)cc1Br ; O=[N+]([O-])c1ccc(F)cc1-c1ccccc1 ; c1ccc2c(c1)[nH]c1ccc3c4ccccc4sc3c12 ; O=[N+]([O-])c1ccc(-n2c3ccccc3c3c4sc5ccccc5c4ccc32)cc1-c1ccccc1 ; c1ccc2c(c1)[nH]c1ccc(-n3c4ccccc4c4c5sc6ccccc6c5ccc43)cc12]

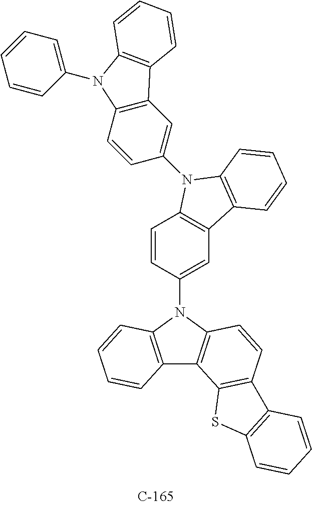 [SMILES: c1ccc(-n2c3ccccc3c3cc(-n4c5ccccc5c5cc(-n6c7ccccc7c7c8sc9ccccc9c8ccc76)ccc54)ccc32)cc1]

### Preparation of Compound 5-1

After mixing 2-bromo-4-fluoronitrobenzene (15 g, 68 mmol), phenyl boronic acid (9.1 g, 75 mmol), Pd(PPh₃)₄ (3.5 g, 2.72 mmol), Na₂CO₃ (18 g, 170 mmol), toluene 270 mL, ethanol 90 mL, and distilled water 90 mL, the mixture was stirred for 2 hours at 100° C. After completing the reaction, the mixture was washed with distilled water, and then extracted with EA. The organic layer was dried with MgSO₄, and solvent was removed with a rotary evaporator. Then, the remaining product was purified by column chromatography using MC and hexane as developing solvents to obtain compound 5-1 (9.2 g, 62%).

### Preparation of Compound 5-2

After mixing 5H-[1]benzothieno[3,2-c]carbazole (8.8 g, 40.5 mmol) and DMF 180 mL, NaH (1.9 g, 60% dispersion in mineral oil, 49 mmol) was added to the mixture while stirring, and then the mixture was stirred for 30 minutes. Then, a solution in which compound 5-1 (11 g, 16.5 mmol) dissolved in DMF 20 mL, was slowly added dropwise to the reaction mixture. Then, the mixture was stirred for 4 hours at room temperature. After completing the reaction, the mixture was washed with distilled water, and then extracted with EA. The organic layer was dried with MgSO₄, and solvent was removed with a rotary evaporator. Then, the remaining product was purified by column chromatography using MC and hexane as developing solvents to obtain, yellow solid, compound 5-2 (19 g, 100%).

### Preparation of Compound 5-3

After mixing compound 5-2 (19 g, 40.3 mmol), P(OEt)₃ 80 mL, and 1,2-dichlorobenzene 120 mL, the mixture was stirred for 3 hours at 140° C. Then, after vacuum distillation of the crude product, the product was purified by column chromatography using MC and hexane as developing solvents to obtain compound 5-3 (12 g, 68%).

### Preparation of Compound C-165

After mixing compound 5-3 (10 g, 22.8 mmol), 3-bromo-9-phenylcarbazole (8 g, 25 mmol), Cul (2 g, 11.4 mmol), EDA (1.5 mL, 22.8 mmol), K₃PO₄ (12 g, 57 mmol), and toluene 200 mL, the mixture was stirred at 120° C. overnight. After completing the reaction, the mixture was washed with distilled water, and then extracted with EA. The organic layer was dried with MgSO₄, and solvent was removed with a rotary evaporator. Then, the remaining product was purified by column chromatography using MC and hexane as developing solvents to obtain compound C-165 (11 g, 71%).

### Example 6

### Preparation of Compound C-167

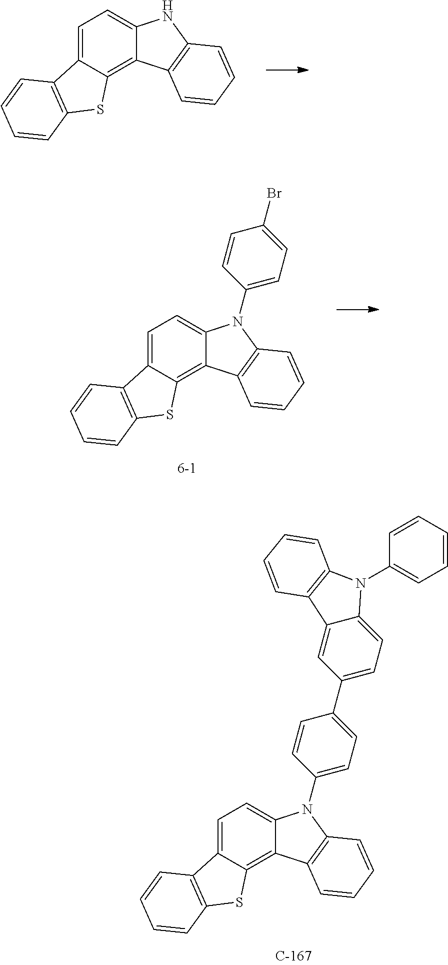 [SMILES: c1ccc2c(c1)[nH]c1ccc3c4ccccc4sc3c12 ; Brc1ccc(-n2c3ccccc3c3c4sc5ccccc5c4ccc32)cc1 ; c1ccc(-n2c3ccccc3c3cc(-c4ccc(-n5c6ccccc6c6c7sc8ccccc8c7ccc65)cc4)ccc32)cc1]

### Preparation of Compound 6-1

After mixing 5H-[1]benzothieno[3,2-c]carbazole (10 g, 36.6 mmol), iodo-4-bromobenzene (20 g, 73.2 mmol), Cul (3.5 g, 18.3 mmol), EDA (4.5 mL, 73.2 mmol), K₃PO₄ (19.4 g, 91.5 mmol), and toluene 200 mL, the mixture was stirred at 120° C. overnight. After completing the reaction, the mixture was washed with distilled water, and then extracted with EA. The organic layer was dried with MgSO₄, and solvent was removed with a rotary evaporator. Then, the remaining product was purified by column chromatography using MC and hexane as developing solvents to obtain compound 6-1 (7.7 g, 49%).

### Preparation of Compound C-167

After mixing compound 6-1 (3.5 g, 9 mmol), 9-phenyl-9H-carbazol-3-yl boronic acid (2.6 g, 8 mmol), Pd(PPh₃)₄ (280 mg, 0.2 mmol), Na₂CO₃ (2.56 g, 24 mmol), toluene 60 mL, ethanol 12 mL, and distilled water 12 mL, the mixture was stirred for 1.5 hours at 110° C. After completing the reaction, the mixture was washed with distilled water, and then extracted with EA. The organic layer was dried with MgSO₄, and solvent was removed with a rotary evaporator. Then, the crude product was purified by column chromatography using MC and hexane as developing solvents, then recrystallized with toluene to obtain compound C-167 (3.9 g, 75%).

The organic electroluminescent compounds according to the present invention, in table 1 below, were prepared by the synthetic methods of above examples 1 to 6, and methods similar to them. Physical properties of the compounds such as yield, MS/EIMS, UV, PL, and melting point are listed in table 1 below.

TABLE 1

| | | MS/EIMS | | UV | PL | |
|---|---|---|---|---|---|---|
| Compound | Yield (%) | Found | Calculated | (nm) | (nm) | Mp (° C.) |
| C-58 | 54 | 600.89 | 600.75 | 312 | 380 | 190 |
| C-65 | 71 | 541.33 | 541.70 | 308 | 389 | 230 |
| C-68 | 55 | 676.65 | 676.84 | 356 | 387 | 288 |
| C-71 | 62 | 600.23 | 600.75 | 310 | 388 | 286 |
| C-76 | 73 | 600.25 | 600.75 | 324 | 389 | 182 |
| C-77 | 52 | 676.46 | 676.84 | 308 | 387 | 128 |
| C-98 | 66 | 497.91 | 498.57 | 310 | 382 | 140 |
| C-120 | 71 | 575.31 | 574.67 | 312 | 382 | 199 |
| C-165 | 68 | 679.55 | 679.83 | 308 | 383 | 241 |
| C-167 | 75 | 590.45 | 590.73 | 302 | 387 | 175 |
| C-204 | 65 | 648.22 | 649.78 | 310 | 386 | 267 |

### Device Example 1

### Production of an OLED Device Using the Compound According to the Present Invention

An OLED device was produced using the compound according to the present invention. A transparent electrode indium tin oxide (ITO) thin film (15 Ω/sg) on a glass substrate for an organic light-emitting diode (OLED) device (Samsung Corning, Republic of Korea) was subjected to an ultrasonic washing with trichloroethylene, acetone, ethanol and distilled water, sequentially, and then was stored in isopropanol. Then, the ITO substrate was mounted on a substrate holder of a vacuum vapor depositing apparatus. N¹,N^{1′}-([1,1′-biphenyl]-4,4′-diyl)bis(N¹-(naphthalen-1-yl)-N⁴,N⁴-diphenylbenzen-1,4-diamine) was introduced into a cell of said vacuum vapor depositing apparatus, and then the pressure in the chamber of said apparatus was controlled to 10⁻⁶ torr. Thereafter, an electric current was applied to the cell to evaporate the above introduced material, thereby forming a hole injection layer having a thickness of 60 nm on the ITO substrate. Then, organic electroluminescent compound C-65 of the present invention was introduced into another cell of said vacuum vapor depositing apparatus, and was evaporated by applying an electric current to the cell, thereby forming a hole transport layer having a thickness of 20 nm on the hole injection layer. Thereafter, 9-(3-(4,6-diphenyl-1,3,5-triazin-2-yl)phenyl)-9′-phenyl-9H,9′H-3,3′-bicarbazole was introduced into one cell of the vacuum vapor depositing apparatus, as a host material, and tris(4-methyl-2,5-diphenylpyridine) iridium (compound D-5) was introduced into another cell as a dopant. The two materials were evaporated at different rates and were deposited in a doping amount of 15 wt % based on the total amount of the host and dopant to form a light-emitting layer having a thickness of 30 nm on the hole transport layer. Then, 2-(4-(9,10-di(naphthalen-2-yl)anthracen-2-yl)phenyl)-1-phenyl-1H-benzo[d]imidazole was introduced into one cell and lithium quinolate was introduced into another cell. The two materials were evaporated at the same rate and were deposited in a doping amount of 50 wt % each to form an electron transport layer having a thickness of 30 nm on the light-emitting layer. Then, after depositing lithium quinolate as an electron injection layer having a thickness of 2 nm on the electron transport layer, an Al cathode having a thickness of 150 nm was deposited by another vacuum vapor deposition apparatus on the electron injection layer. Thus, an OLED device was produced. All the materials used for producing the OLED device were purified by vacuum sublimation at 10⁻⁶ torr prior to use.

The produced OLED device showed a green emission having a luminance of 4675 cd/m² and a current density of 11.3 mA/cm².

### Device Example 2

### Production of an OLED Device Using the Compound According to the Present Invention

An OLED device was produced in the same manner as in Device Example 1, except for using compound C-68 as a hole transport material.

The produced OLED device showed a green emission having a luminance of 8000 cd/m² and a current density of 17.5 mA/cm².

### Device Example 3

### Production of an OLED Device Using the Compound According to the Present Invention

An OLED device was produced in the same manner as in Device Example 1, except for using compound C-71 as a hole transport material.

The produced OLED device showed a green emission having a luminance of 2200 cd/m² and a current density of 4.79 mA/cm².

### Device Example 4

### Production of an OLED Device Using the Compound According to the Present Invention

An OLED device was produced in the same manner as in Device Example 1, except for using compound C-58 as a hole transport material, and 9-phenyl-10-(4-phenylnaphthalen-1-yl)anthracene, and (E)-9,9-dimethyl-7-(4-(naphthalen-2-yl(phenyl)amino)styryl)-N,N-diphenyl-9H-fluorene-2-amine as host materials.

The produced OLED device showed a blue emission having a luminance of 4000 cd/m² and a current density of 55.6 mA/cm².

### Device Example 5

### Production of an OLED Device Using the Compound According to the Present Invention

An OLED device was produced in the same manner as in Device Example 4, except for using compound C-76 as a hole transport material.

The produced OLED device showed a blue emission having a luminance of 1500 cd/m² and a current density of 22.7 mA/cm².

### Device Example 6

### Production of an OLED Device Using the Compound According to the Present Invention

An OLED device was produced in the same manner as in Device Example 1, except for using compound C-77 as a hole transport material.

The produced OLED device showed a green emission having a luminance of 2030 cd/m² and a current density of 4.3 mA/cm².

### Device Example 7

### Production of an OLED Device Using the Compound According to the Present Invention

An OLED device was produced in the same manner as in Device Example 4, except for using compound C-98 as a hole transport material.

The produced OLED device showed a blue emission having a luminance of 2500 cd/m² and a current density of 37.9 mA/cm².

### Device Example 8

### Production of an OLED Device Using the Compound According to the Present Invention

An OLED device was produced in the same manner as in Device Example 1, except for using compound C-120 as a hole transport material.

The produced OLED device showed a green emission having a luminance of 5050 cd/m² and a current density of 11.0 mA/cm².

### Device Example 9

### Production of an OLED Device Using the Compound According to the Present Invention

An OLED device was produced in the same manner as in Device Example 1, except for using compound C-165 as a hole transport material.

The produced OLED device showed a green emission having a luminance of 3030 cd/m² and a current density of 7.0 mA/cm².

### Device Example 10

### Production of an OLED Device Using the Compound According to the Present Invention

An OLED device was produced in the same manner as in Device Example 1, except for using compound C-167 as a hole transport material.

The produced OLED device showed a green emission having a luminance of 5995 cd/m² and a current density of 13.4 mA/cm².

### Device Example 11

### Production of an OLED Device Using the Compound According to the Present Invention

An OLED device was produced in the same manner as in Device Example 1, except for using compound C-204 as a hole transport material.

The produced OLED device showed a green emission having a luminance of 3030 cd/m² and a current density of 7.3 mA/cm².

### Device Example 12

### Production of an OLED Device Using the Compound According to the Present Invention

An OLED device was produced in the same manner as in Device Example 1, except for evaporating N,N′-di(4-biphenyl)-N,N′-di(4-biphenyl)-4,4′-diaminobiphenyl as a hole transport material to form a hole transport layer having a thickness of 20 nm; depositing two materials—compound C-65, and 9-(4,6-di(biphenyl-4-yl)-1,3,5-triazin-2-yl)-9H-carbazole from each cell and were evaporated at the same rate in a doping amount of 50 wt % each to be used as a host material; and doping tris(4-methyl-2,5-diphenylpyridine) iridium (compound D-5) in a doping amount of 15 wt % based on the total amount of the host and dopant to form a light-emitting layer having a thickness of 30 nm on the hole transport layer.

The produced OLED device showed a green emission having a luminance of 2200 cd/m² and a current density of 5.5 mA/cm².

### Comparative Example 1

### Production of an OLED Device Using Conventional Electroluminescent Compounds

An OLED device was produced in the same manner as in Device Example 1, except for evaporating N,N′-di(4-biphenyl)-N,N′-di(4-biphenyl)-4,4′-diaminobiphenyl as a hole transport material to form a hole transport layer having a thickness of 20 nm; using 4,4′-N,N′-dicarbazole-biphenyl as a host material, tris(2-phenylpyridine)iridium (compound D-4) as a dopant to form a light-emitting layer having a thickness of 30 nm on the hole transport layer; and depositing aluminum(III)bis(2-methyl-8-quinolinato)4-phenylphenolate to form a hole blocking layer having a thickness of 10 nm.

The produced OLED device showed a green emission having a luminance of 1110 cd/m² and a current density of 3.20 mA/cm².

### Comparative Example 2

### Production of an OLED Device Using Conventional Electroluminescent Compounds

An OLED device was produced in the same manner as in Device Example 1, except for evaporating N,N′-di(4-biphenyl)-N,N′-di(4-biphenyl)-4,4′-diaminobiphenyl as a hole transport material to form a hole transport layer having a thickness of 20 nm; and using 9-phenyl-10-(4-phenylnaphthalen-1-yl)anthracene as a host material, (E)-7-(4-(diphenylamino)styryl)-9,9-dimethyl-N,N-diphenyl-9H-fluorene-2-amine as a dopant to form a light-emitting layer having a thickness of 30 nm on the hole transport layer.

The produced OLED device showed a blue emission having a luminance of 5050 cd/m² and a current density of 91.8 mA/cm².

It is verified that the organic electroluminescent compounds according to the present invention have superior luminous efficiency over conventional materials. In addition, the organic electroluminescent devices using the compounds according to the present invention have superior luminous characteristics.

1. An organic electroluminescent compound represented by the following formula 1: 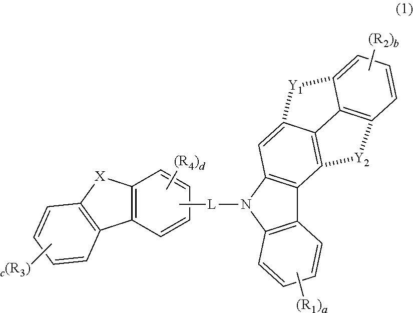
wherein
L represents a single bond, or a substituted or unsubstituted (C6-C30)arylene group;
X represents —O—, —S—, —N(R₅)—, —C(R₆)(R₇)— or —Si(R₈)(R₉)—;
Y₁ and Y₂ each independently represent —O—, —S—, —C(R₁₀)(R₁₁)—, —Si(R₁₂)(R₁₃)— or —N(R₁₄)—, provided that Y₁ and Y₂ do not simultaneously exist;
R₁ to R₄ each independently represent hydrogen, deuterium, a halogen, a substituted or unsubstituted (C1-C30)alkyl group, a substituted or unsubstituted (C6-C30)aryl group, a substituted or unsubstituted 3- to 30-membered heteroaryl group, —NR₁₅R₁₆, or —SiR₁₇R₁₈R₁₉; or are linked to an adjacent substituent(s) to form a mono- or polycyclic, 3- to 30-membered alicyclic or aromatic ring whose carbon atom(s) may be replaced with at least one hetero atom selected from nitrogen, oxygen and sulfur;
R₅ to R₁₄, and R₁₅ to R₁₉ each independently represent hydrogen, deuterium, a halogen, a substituted or unsubstituted (C1-C30)alkyl group, a substituted or unsubstituted (C6-C30)aryl group, or a substituted or unsubstituted 3- to 30-membered heteroaryl group; or are linked to an adjacent substituent(s) to form a mono- or polycyclic, 3- to 30-membered alicyclic or aromatic ring whose carbon atom(s) may be replaced with at least one hetero atom selected from nitrogen, oxygen and sulfur;
a, b and c each independently represent an integer of 1 to 4; where a, b or c is an integer of 2 or more, each of R₁, R₂ and R₃ may be the same or different;
d represents an integer of 1 to 3; where d is an integer of 2 or more, each of R₄ may be the same or different; and
the heteroaryl group contains at least one hetero atom selected from B, N, O, S, P(═O), Si and P.

2. The organic electroluminescent compound according to claim 1, wherein the compound represented by the following formula 1 is represented by any one of formulae 2 to 6. 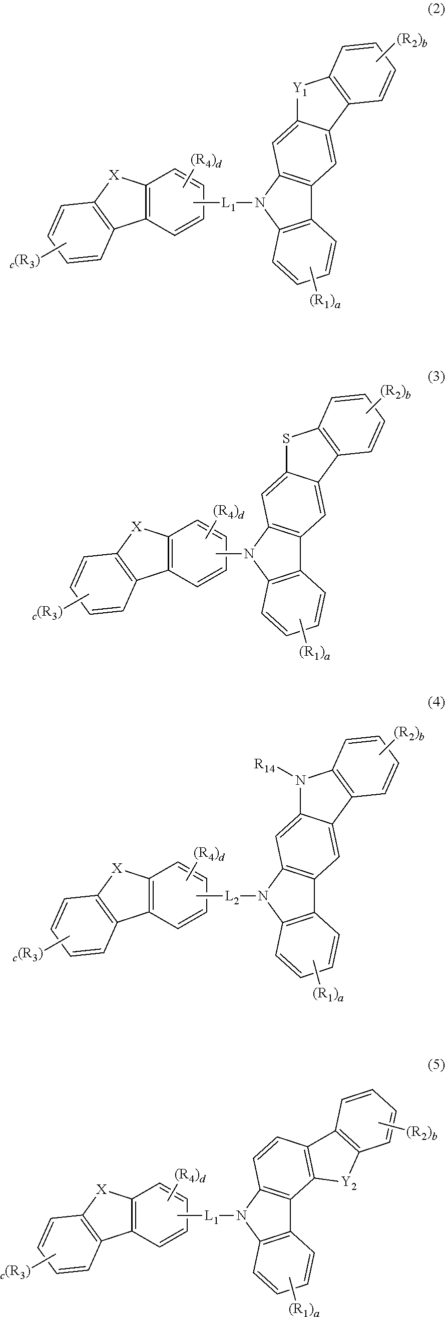 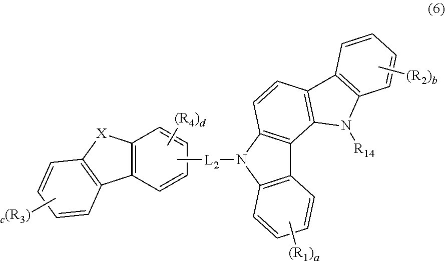
wherein
Y₁ represents —O—, —C(R₁₀)(R₁₁)— or —Si(R₁₂)(R₁₃)—;
L₁ represents a single bond, or a substituted or unsubstituted (C6-C30)arylene group;
L₂ represents a substituted or unsubstituted (C6-C30)arylene group;
Y₂ represents —O—, —S—, —C(R₁₀)(R₁₁)— or —Si(R₁₂)(R₁₃)—; and
X, R₁ to R₄, R₁₄, a, b, c and d are as defined in claim 1.

3. The organic electroluminescent compound according to claim 1, wherein in L, R₁ to R₄, R₅ to R₁₄, and R₁₅ to R₁₉, the substituents of the substituted groups each independently are at least one selected from the group consisting of deuterium; a halogen; a (C1-C30)alkyl group; a halo(C1-C30)alkyl group; a (C6-C30)aryl group unsubstituted or substituted with a 3- to 30-membered heteroaryl group; a 3- to 30-membered heteroaryl group unsubstituted or substituted with a (C6-C30)aryl group; a (C3-C30)cycloalkyl group; a 5- to 7-membered heterocycloalkyl group; a tri(C1-C30)alkylsilyl group; a tri(C6-C30)arylsilyl group; a di(C1-C30)alkyl(C6-C30)arylsilyl group; a (C1-C30)alkyl di(C6-C30)arylsilyl group; a (C2-C30)alkenyl group; a (C2-C30)alkynyl group; a cyano group; a carbazolyl group; a di(C1-C30)alkylamino group; a di(C6-C30)arylamino group; a (C1-C30)alkyl(C6-C30)arylamino group; a di(C6-C30)arylboronyl group; a di(C1-C30)alkylboronyl group; a (C1-C30)alkyl(C6-C30)arylboronyl group; a (C6-C30)aryl(C1-C30)alkyl group; a (C1-C30)alkyl(C6-C30)aryl group; a carboxyl group; a nitro group; and a hydroxyl group.

4. The organic electroluminescent compound according to claim 2, wherein L₁ represents a single bond, or a (C6-C30)arylene group;
L₂ represents a (C6-C30)arylene group;
X represents —O—, —S—, —N(R₅)—, —C(R₆)(R₇)— or —Si(R₈)(R₉)—;
R₁ to R₄ each independently represent hydrogen, deuterium, a halogen, a (C1-C30)alkyl group, a substituted or unsubstituted (C6-C30)aryl group, a substituted or unsubstituted 3- to 30-membered heteroaryl group, —NR₁₅R₁₆, or —SiR₁₇R₁₈R₁₉; or are linked to an adjacent substituent(s) to form a mono- or polycyclic, 3- to 30-membered alicyclic or aromatic ring whose carbon atom(s) may be replaced with at least one hetero atom selected from nitrogen, oxygen and sulfur;
R₅ to R₁₄ each independently represent a (C1-C30)alkyl group, a substituted or unsubstituted (C6-C30)aryl group, or a substituted or unsubstituted 3- to 30-membered heteroaryl group; or R₆ and R₇, R₁₀ and R₁₁ are linked to each other to form a mono- or polycyclic, 3- to 30-membered alicyclic or aromatic ring;
R₁₅ to R₁₉ each independently represent a (C1-C30)alkyl group, a (C6-C30)aryl group, or a 3- to 30-membered heteroaryl group; and
the arylene group in L₁ and L₂, and the alkyl, aryl, and heteroaryl groups in R₁ to R₄, R₅ to R₁₄, and R₁₅ to R₁₉ can be further substituted with at least one selected from the group consisting of deuterium; a halogen; a (C1-C30)alkyl group; a halo(C1-C30)alkyl group; a (C6-C30)aryl group unsubstituted or substituted with a 3- to 30-membered heteroaryl group; a 3- to 30-membered heteroaryl group unsubstituted or substituted with a (C6-C30)aryl group; a (C3-C30)cycloalkyl group; a (C6-C30)aryl(C1-C30)alkyl group; and a (C1-C30)alkyl(C6-C30)aryl group.

5. The organic electroluminescent compound according to claim 1, wherein the compound represented by formula 1 is selected from the group consisting of:

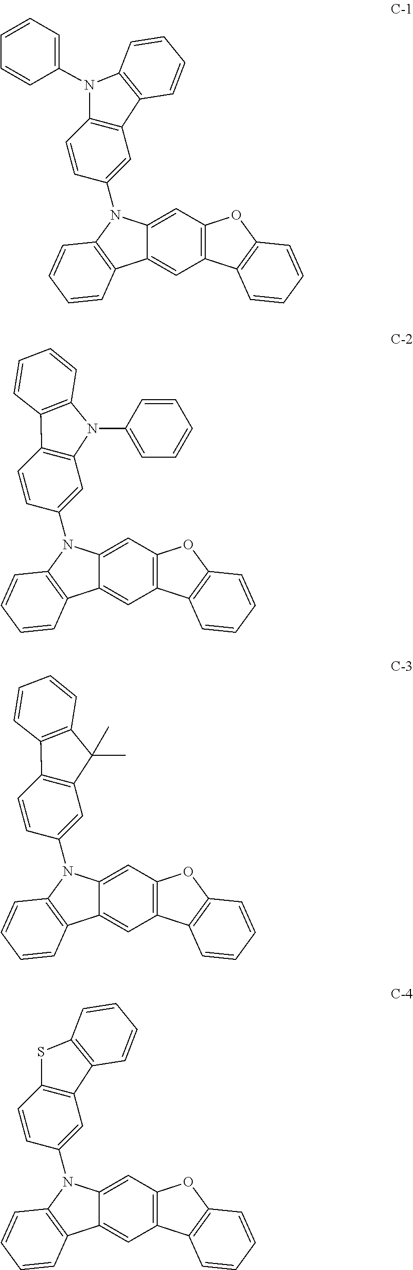 [SMILES: c1ccc(-n2c3ccccc3c3cc(-n4c5ccccc5c5cc6c(cc54)oc4ccccc46)ccc32)cc1 ; c1ccc(-n2c3ccccc3c3ccc(-n4c5ccccc5c5cc6c(cc54)oc4ccccc46)cc32)cc1 ; CC1(C)c2ccccc2-c2ccc(-n3c4ccccc4c4cc5c(cc43)oc3ccccc35)cc21 ; c1ccc2c(c1)oc1cc3c(cc12)c1ccccc1n3-c1ccc2sc3ccccc3c2c1]

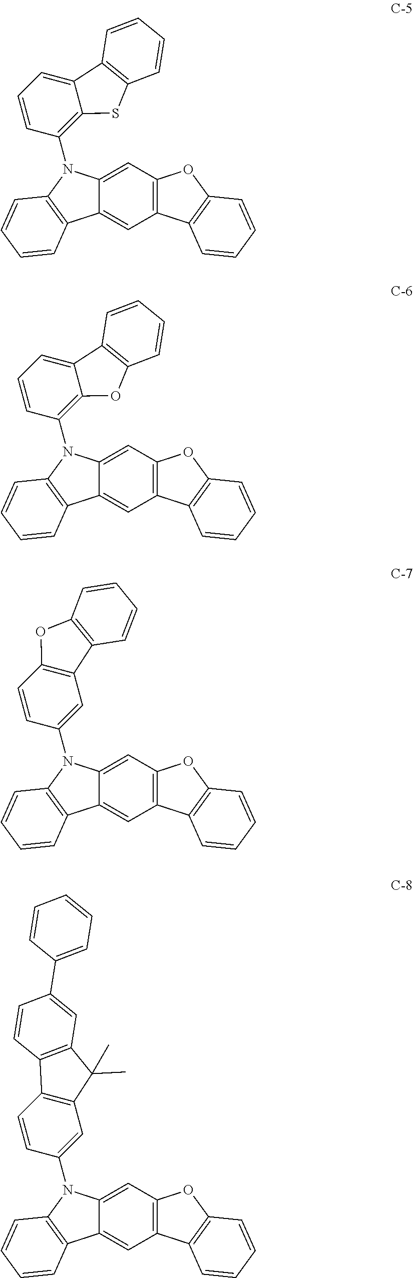 [SMILES: c1ccc2c(c1)oc1cc3c(cc12)c1ccccc1n3-c1cccc2c1sc1ccccc12 ; c1ccc2c(c1)oc1cc3c(cc12)c1ccccc1n3-c1cccc2c1oc1ccccc12 ; c1ccc2c(c1)oc1ccc(-n3c4ccccc4c4cc5c(cc43)oc3ccccc35)cc12 ; CC1(C)c2cc(-c3ccccc3)ccc2-c2ccc(-n3c4ccccc4c4cc5c(cc43)oc3ccccc35)cc21]

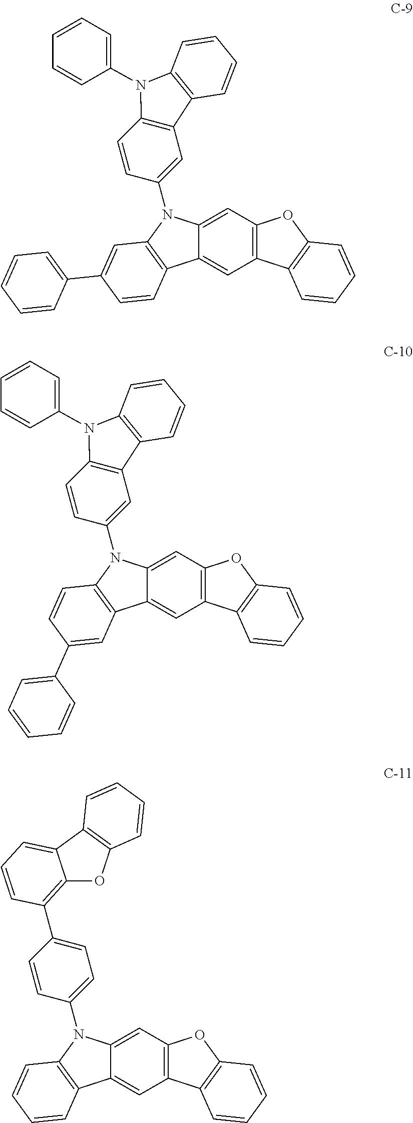 [SMILES: c1ccc(-c2ccc3c4cc5c(cc4n(-c4ccc6c(c4)c4ccccc4n6-c4ccccc4)c3c2)oc2ccccc25)cc1 ; c1ccc(-c2ccc3c(c2)c2cc4c(cc2n3-c2ccc3c(c2)c2ccccc2n3-c2ccccc2)oc2ccccc24)cc1 ; c1ccc2c(c1)oc1cc3c(cc12)c1ccccc1n3-c1ccc(-c2cccc3c2oc2ccccc23)cc1]

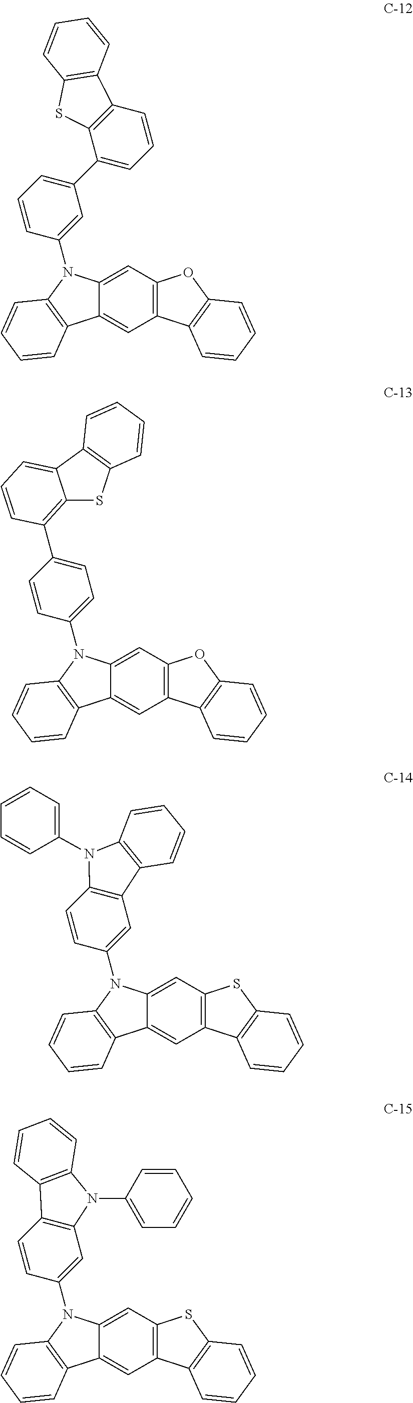

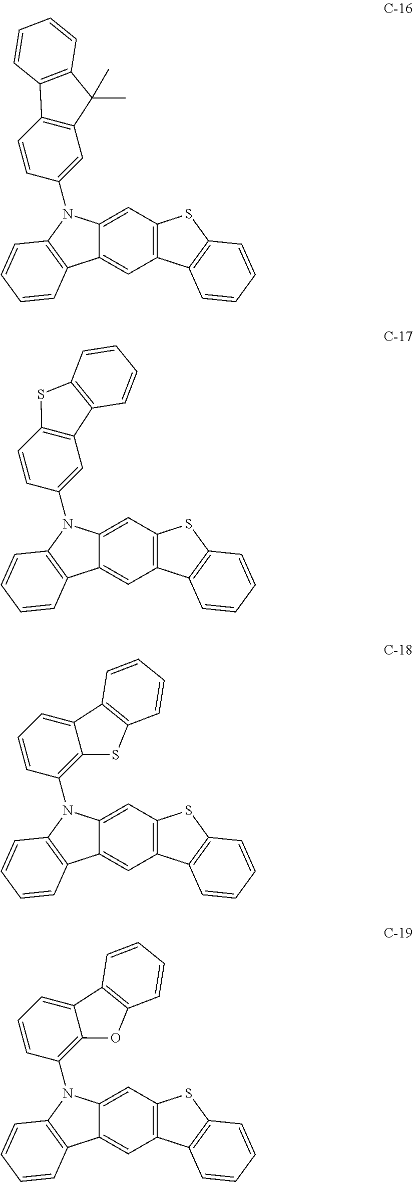 [SMILES: CC1(C)c2ccccc2-c2ccc(-n3c4ccccc4c4cc5c(cc43)sc3ccccc35)cc21 ; c1ccc2c(c1)sc1ccc(-n3c4ccccc4c4cc5c(cc43)sc3ccccc35)cc12 ; c1ccc2c(c1)sc1cc3c(cc12)c1ccccc1n3-c1cccc2c1sc1ccccc12 ; c1ccc2c(c1)oc1c(-n3c4ccccc4c4cc5c(cc43)sc3ccccc35)cccc12]

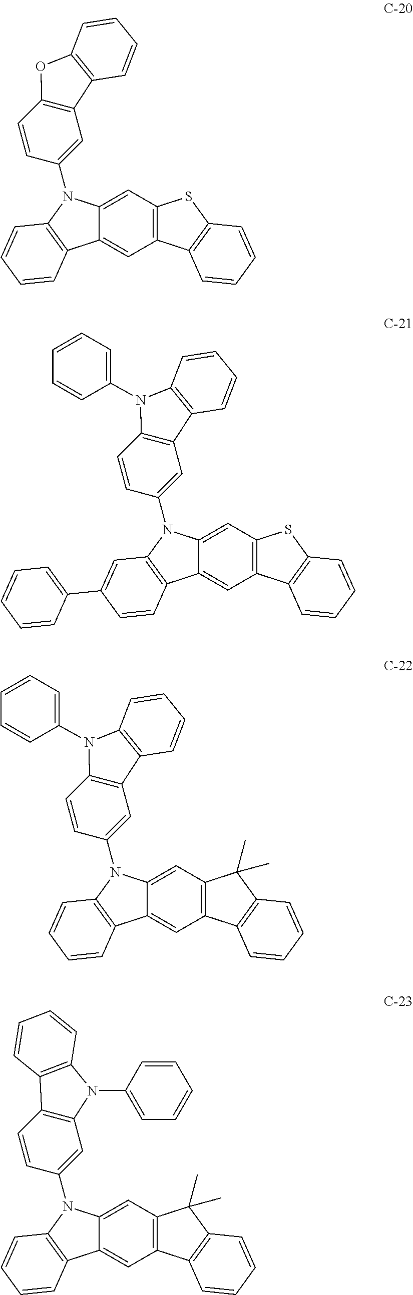 [SMILES: c1ccc2c(c1)oc1ccc(-n3c4ccccc4c4cc5c(cc43)sc3ccccc35)cc12 ; c1ccc(-c2ccc3c4cc5c(cc4n(-c4ccc6c(c4)c4ccccc4n6-c4ccccc4)c3c2)sc2ccccc25)cc1 ; CC1(C)c2ccccc2-c2cc3c4ccccc4n(-c4ccc5c(c4)c4ccccc4n5-c4ccccc4)c3cc21 ; CC1(C)c2ccccc2-c2cc3c4ccccc4n(-c4ccc5c6ccccc6n(-c6ccccc6)c5c4)c3cc21]

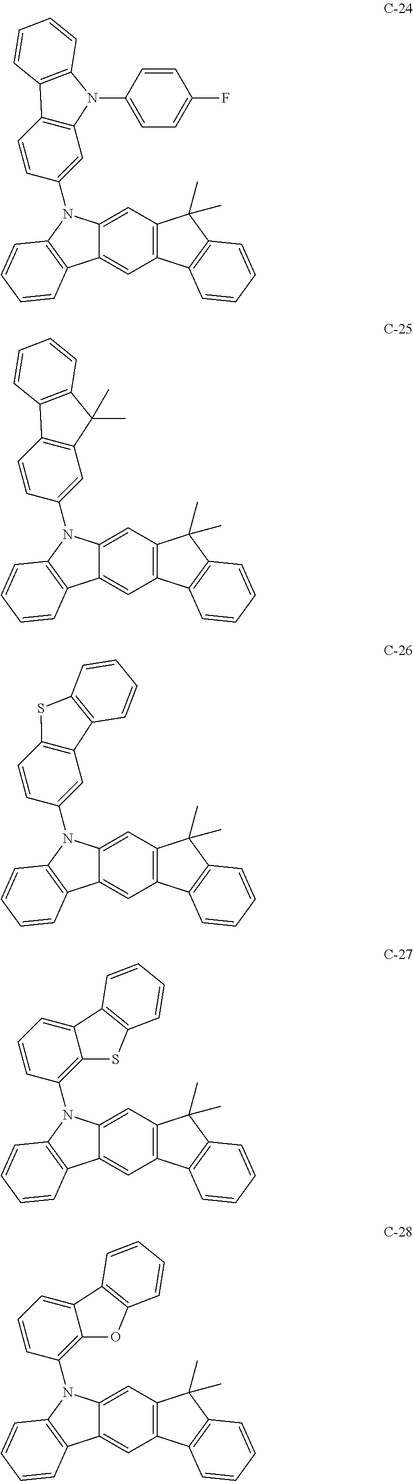

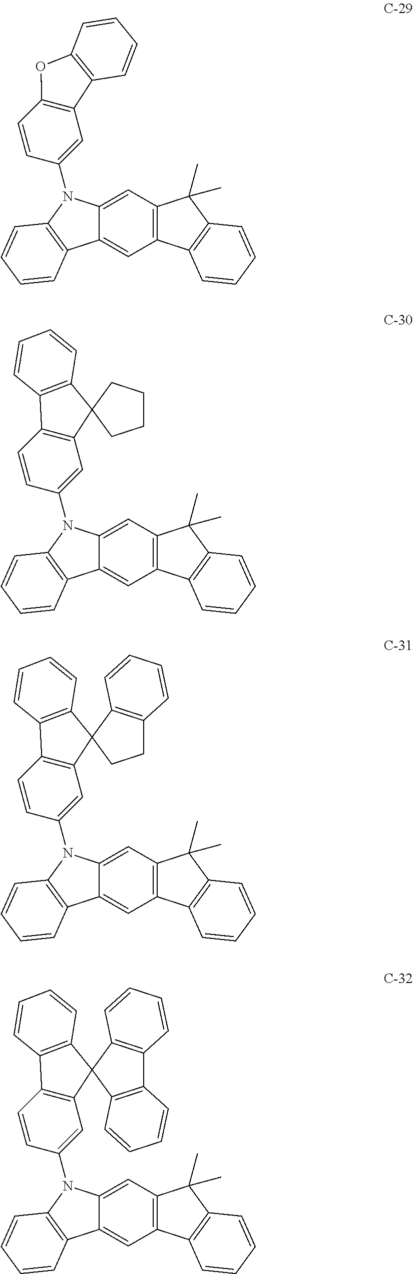 [SMILES: CC1(C)c2ccccc2-c2cc3c4ccccc4n(-c4ccc5oc6ccccc6c5c4)c3cc21 ; CC1(C)c2ccccc2-c2cc3c4ccccc4n(-c4ccc5c(c4)C4(CCCC4)c4ccccc4-5)c3cc21 ; CC1(C)c2ccccc2-c2cc3c4ccccc4n(-c4ccc5c(c4)C4(CCc6ccccc64)c4ccccc4-5)c3cc21 ; CC1(C)c2ccccc2-c2cc3c4ccccc4n(-c4ccc5c(c4)C4(c6ccccc6-c6ccccc64)c4ccccc4-5)c3cc21]

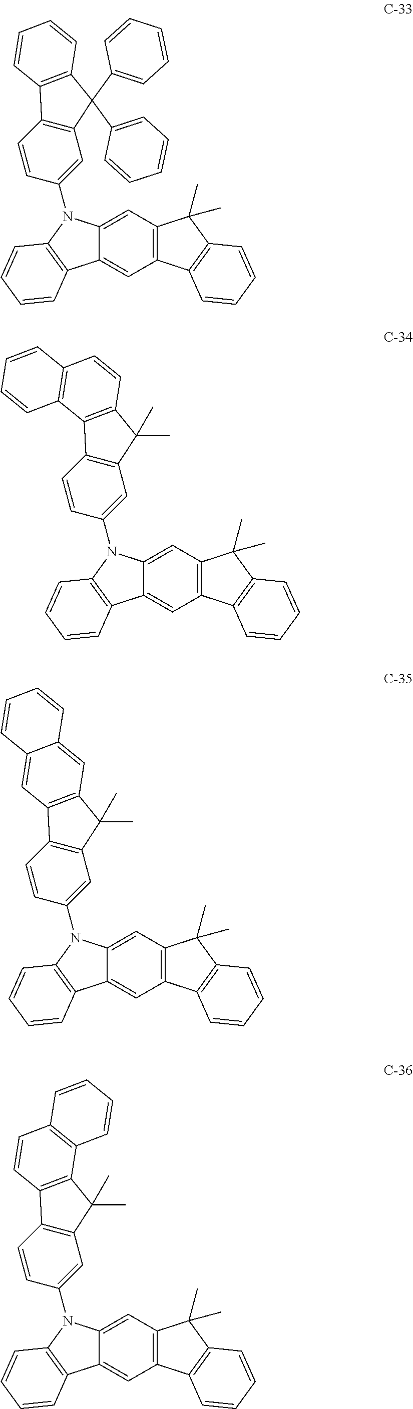

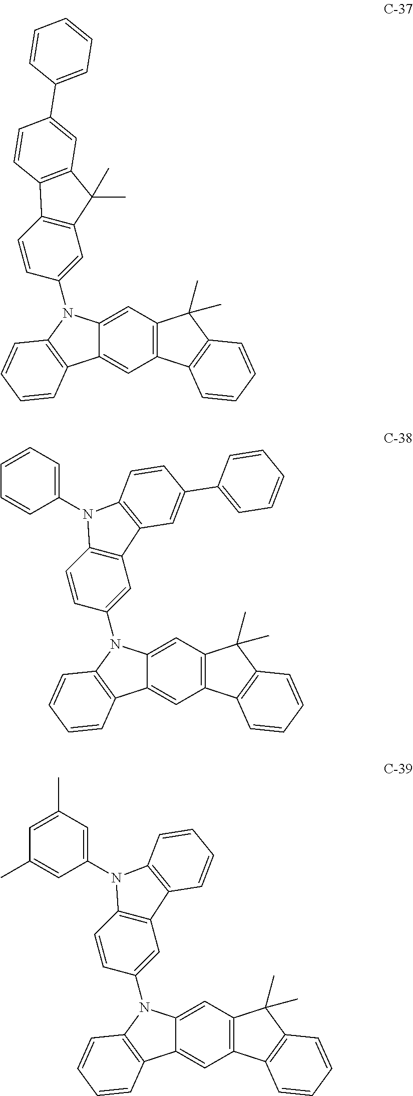

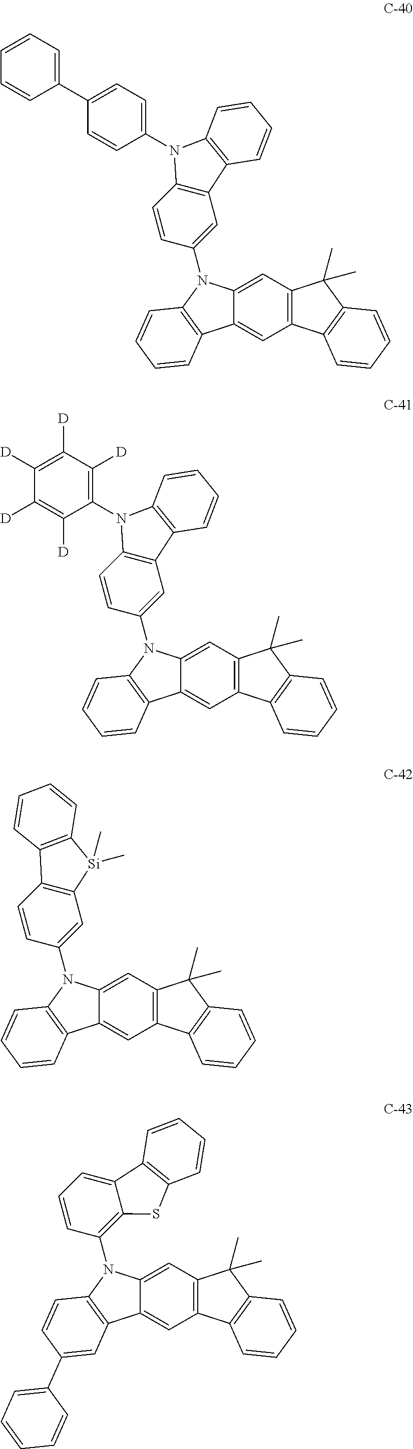 [SMILES: CC1(C)c2ccccc2-c2cc3c4ccccc4n(-c4ccc5c(c4)c4ccccc4n5-c4ccc(-c5ccccc5)cc4)c3cc21 ; [2H]c1c([2H])c([2H])c(-n2c3ccccc3c3cc(-n4c5ccccc5c5cc6c(cc54)C(C)(C)c4ccccc4-6)ccc32)c([2H])c1[2H] ; CC1(C)c2ccccc2-c2cc3c4ccccc4n(-c4ccc5c(c4)[Si](C)(C)c4ccccc4-5)c3cc21 ; CC1(C)c2ccccc2-c2cc3c4cc(-c5ccccc5)ccc4n(-c4cccc5c4sc4ccccc45)c3cc21]

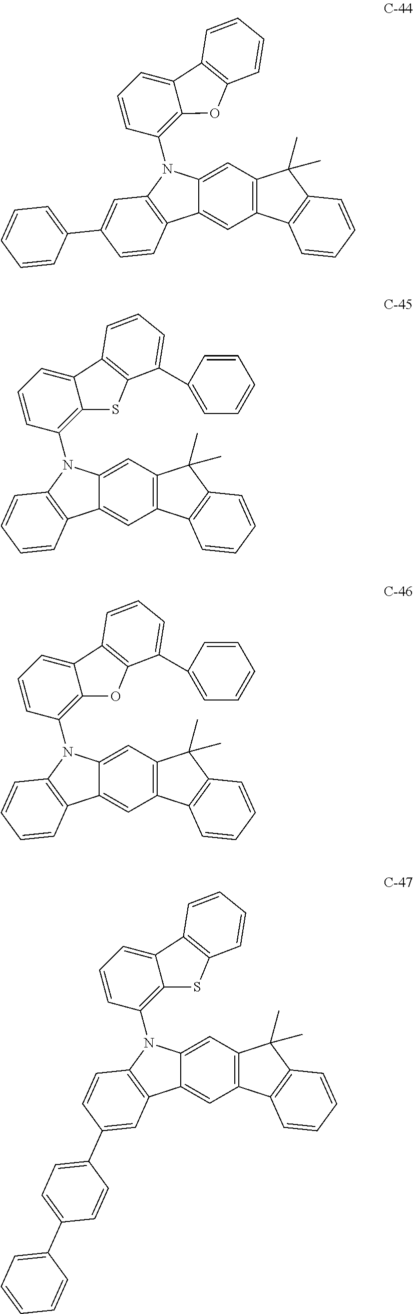 [SMILES: CC1(C)c2ccccc2-c2cc3c4ccc(-c5ccccc5)cc4n(-c4cccc5c4oc4ccccc45)c3cc21 ; CC1(C)c2ccccc2-c2cc3c4ccccc4n(-c4cccc5c4sc4c(-c6ccccc6)cccc45)c3cc21 ; CC1(C)c2ccccc2-c2cc3c4ccccc4n(-c4cccc5c4oc4c(-c6ccccc6)cccc45)c3cc21 ; CC1(C)c2ccccc2-c2cc3c4cc(-c5ccc(-c6ccccc6)cc5)ccc4n(-c4cccc5c4sc4ccccc45)c3cc21]

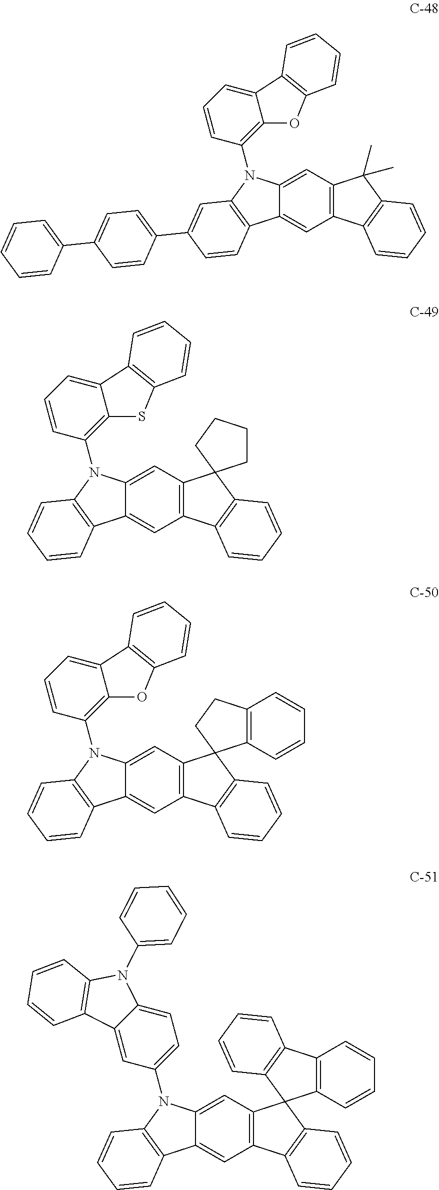 [SMILES: CC1(C)c2ccccc2-c2cc3c4ccc(-c5ccc(-c6ccccc6)cc5)cc4n(-c4cccc5c4oc4ccccc45)c3cc21 ; c1ccc2c(c1)-c1cc3c4ccccc4n(-c4cccc5c4sc4ccccc45)c3cc1C21CCCC1 ; c1ccc2c(c1)CCC21c2ccccc2-c2cc3c4ccccc4n(-c4cccc5c4oc4ccccc45)c3cc21 ; c1ccc(-n2c3ccccc3c3cc(-n4c5ccccc5c5cc6c(cc54)C4(c5ccccc5-c5ccccc54)c4ccccc4-6)ccc32)cc1]

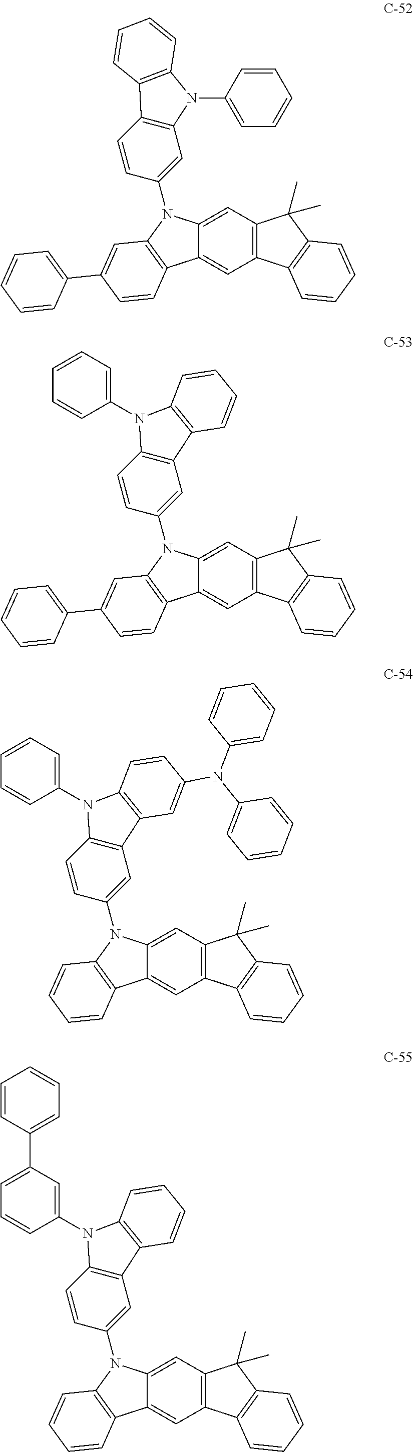 [SMILES: CC1(C)c2ccccc2-c2cc3c4ccc(-c5ccccc5)cc4n(-c4ccc5c6ccccc6n(-c6ccccc6)c5c4)c3cc21 ; CC1(C)c2ccccc2-c2cc3c4ccc(-c5ccccc5)cc4n(-c4ccc5c(c4)c4ccccc4n5-c4ccccc4)c3cc21 ; CC1(C)c2ccccc2-c2cc3c4ccccc4n(-c4ccc5c(c4)c4cc(N(c6ccccc6)c6ccccc6)ccc4n5-c4ccccc4)c3cc21 ; CC1(C)c2ccccc2-c2cc3c4ccccc4n(-c4ccc5c(c4)c4ccccc4n5-c4cccc(-c5ccccc5)c4)c3cc21]

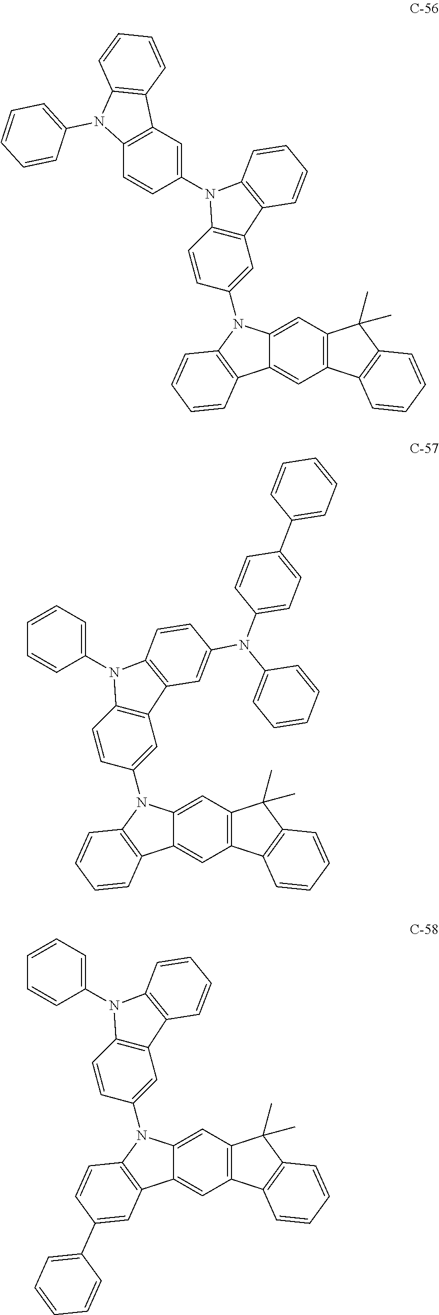 [SMILES: CC1(C)c2ccccc2-c2cc3c4ccccc4n(-c4ccc5c(c4)c4ccccc4n5-c4ccc5c(c4)c4ccccc4n5-c4ccccc4)c3cc21 ; CC1(C)c2ccccc2-c2cc3c4ccccc4n(-c4ccc5c(c4)c4cc(N(c6ccccc6)c6ccc(-c7ccccc7)cc6)ccc4n5-c4ccccc4)c3cc21 ; CC1(C)c2ccccc2-c2cc3c4cc(-c5ccccc5)ccc4n(-c4ccc5c(c4)c4ccccc4n5-c4ccccc4)c3cc21]

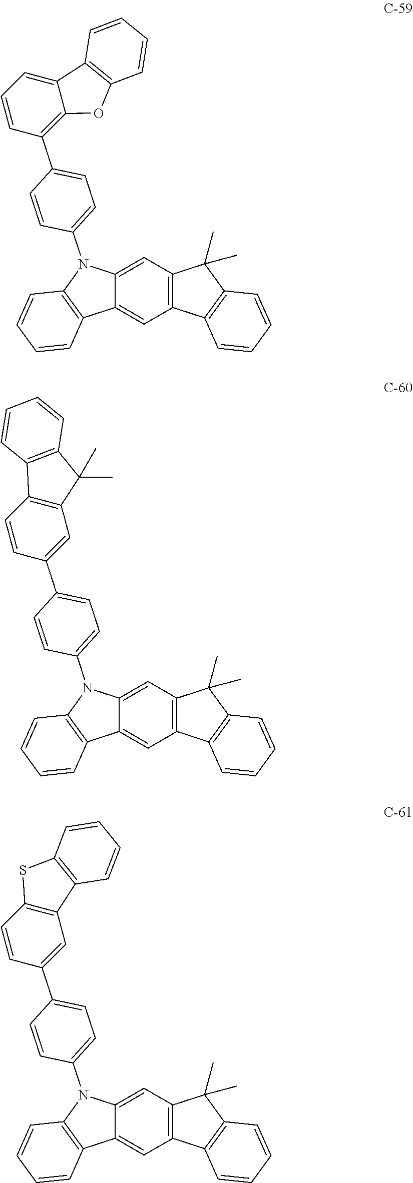

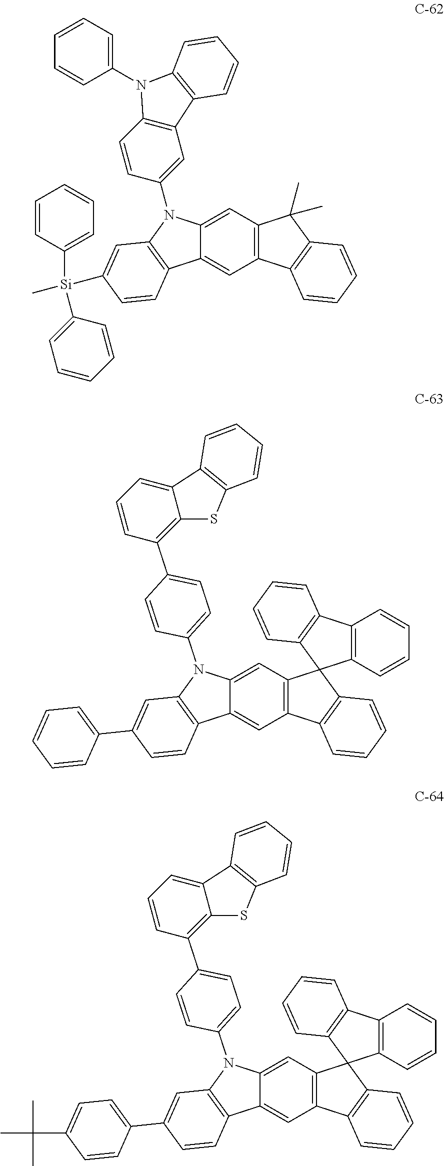 [SMILES: CC1(C)c2ccccc2-c2cc3c4ccc([Si](C)(c5ccccc5)c5ccccc5)cc4n(-c4ccc5c(c4)c4ccccc4n5-c4ccccc4)c3cc21 ; c1ccc(-c2ccc3c4cc5c(cc4n(-c4ccc(-c6cccc7c6sc6ccccc67)cc4)c3c2)C2(c3ccccc3-c3ccccc32)c2ccccc2-5)cc1 ; CC(C)(C)c1ccc(-c2ccc3c4cc5c(cc4n(-c4ccc(-c6cccc7c6sc6ccccc67)cc4)c3c2)C2(c3ccccc3-c3ccccc32)c2ccccc2-5)cc1]

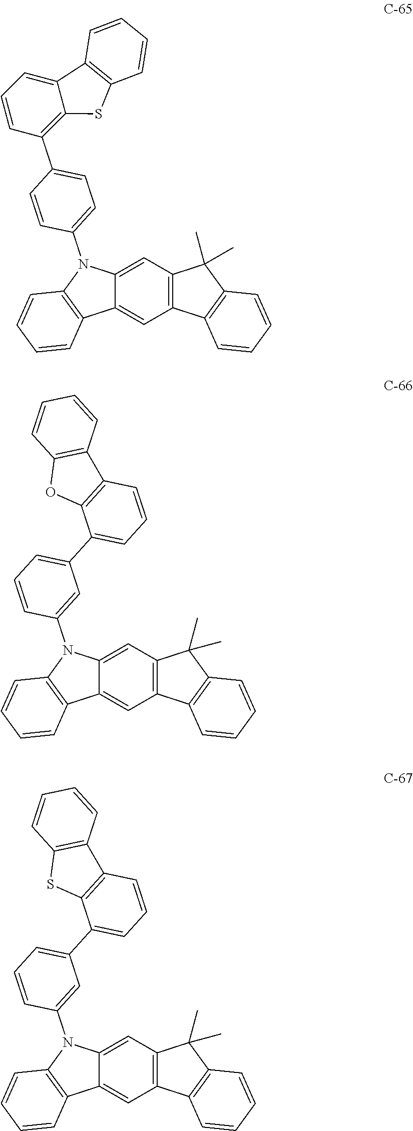 [SMILES: CC1(C)c2ccccc2-c2cc3c4ccccc4n(-c4ccc(-c5cccc6c5sc5ccccc56)cc4)c3cc21 ; CC1(C)c2ccccc2-c2cc3c4ccccc4n(-c4cccc(-c5cccc6c5oc5ccccc56)c4)c3cc21 ; CC1(C)c2ccccc2-c2cc3c4ccccc4n(-c4cccc(-c5cccc6c5sc5ccccc56)c4)c3cc21]

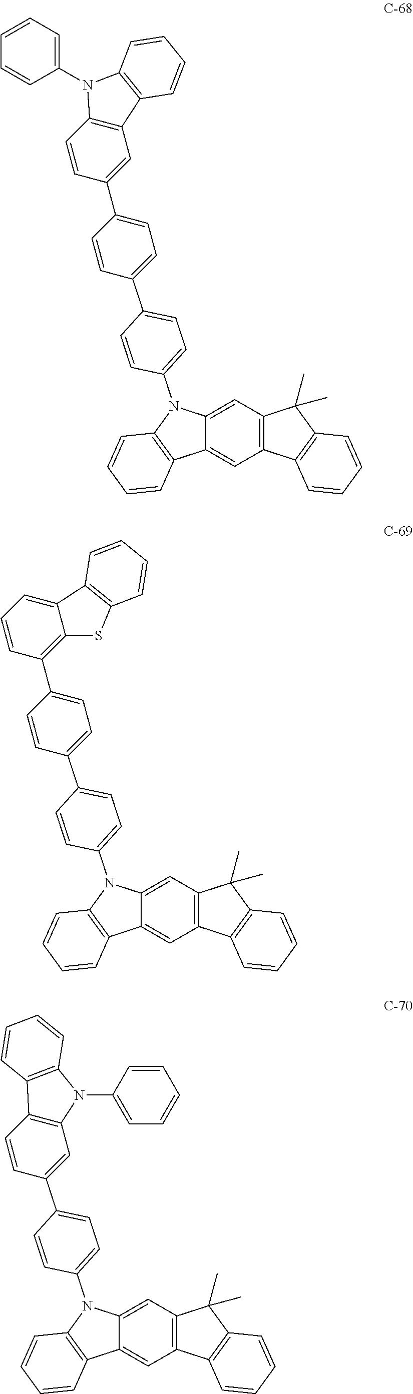 [SMILES: CC1(C)c2ccccc2-c2cc3c4ccccc4n(-c4ccc(-c5ccc(-c6ccc7c(c6)c6ccccc6n7-c6ccccc6)cc5)cc4)c3cc21 ; CC1(C)c2ccccc2-c2cc3c4ccccc4n(-c4ccc(-c5ccc(-c6cccc7c6sc6ccccc67)cc5)cc4)c3cc21 ; CC1(C)c2ccccc2-c2cc3c4ccccc4n(-c4ccc(-c5ccc6c7ccccc7n(-c7ccccc7)c6c5)cc4)c3cc21]

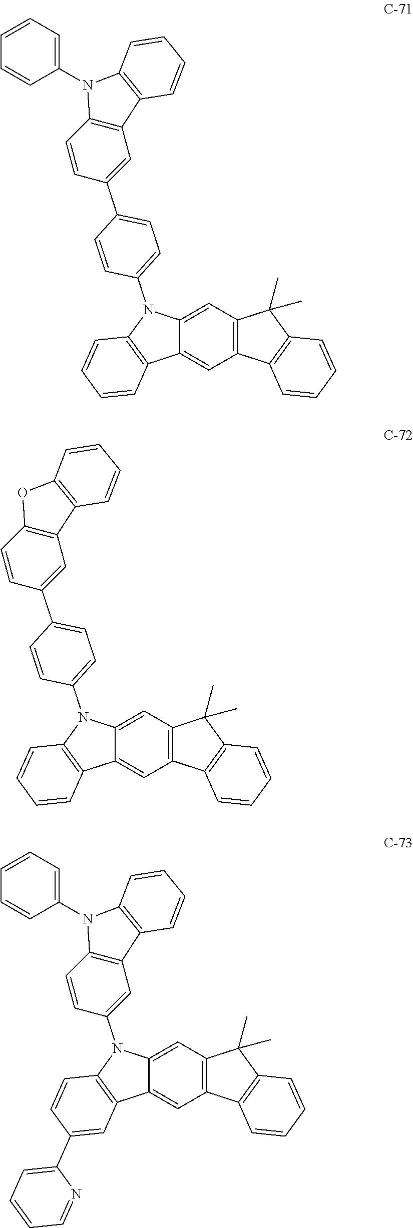 [SMILES: CC1(C)c2ccccc2-c2cc3c4ccccc4n(-c4ccc(-c5ccc6c(c5)c5ccccc5n6-c5ccccc5)cc4)c3cc21 ; CC1(C)c2ccccc2-c2cc3c4ccccc4n(-c4ccc(-c5ccc6oc7ccccc7c6c5)cc4)c3cc21 ; CC1(C)c2ccccc2-c2cc3c4cc(-c5ccccn5)ccc4n(-c4ccc5c(c4)c4ccccc4n5-c4ccccc4)c3cc21]

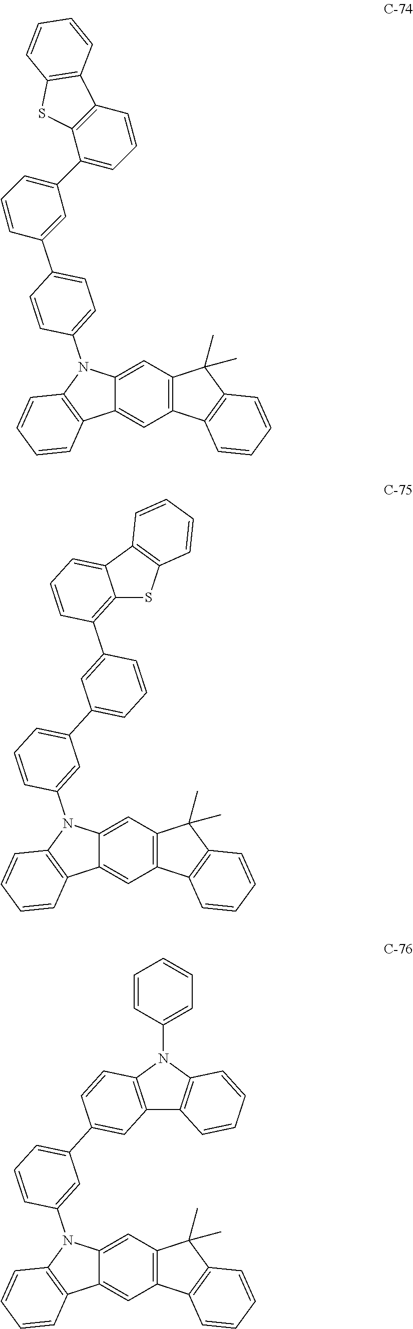 [SMILES: CC1(C)c2ccccc2-c2cc3c4ccccc4n(-c4ccc(-c5cccc(-c6cccc7c6sc6ccccc67)c5)cc4)c3cc21 ; CC1(C)c2ccccc2-c2cc3c4ccccc4n(-c4cccc(-c5cccc(-c6cccc7c6sc6ccccc67)c5)c4)c3cc21 ; CC1(C)c2ccccc2-c2cc3c4ccccc4n(-c4cccc(-c5ccc6c(c5)c5ccccc5n6-c5ccccc5)c4)c3cc21]

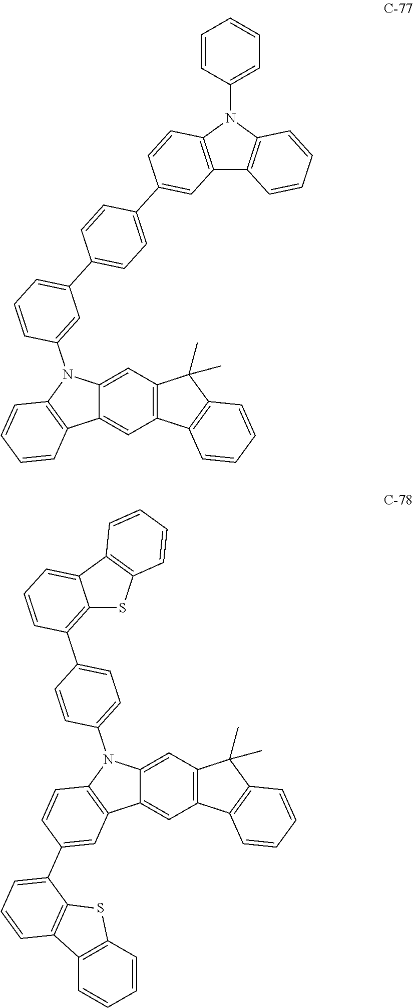 [SMILES: CC1(C)c2ccccc2-c2cc3c4ccccc4n(-c4cccc(-c5ccc(-c6ccc7c(c6)c6ccccc6n7-c6ccccc6)cc5)c4)c3cc21 ; CC1(C)c2ccccc2-c2cc3c4cc(-c5cccc6c5sc5ccccc56)ccc4n(-c4ccc(-c5cccc6c5sc5ccccc56)cc4)c3cc21]

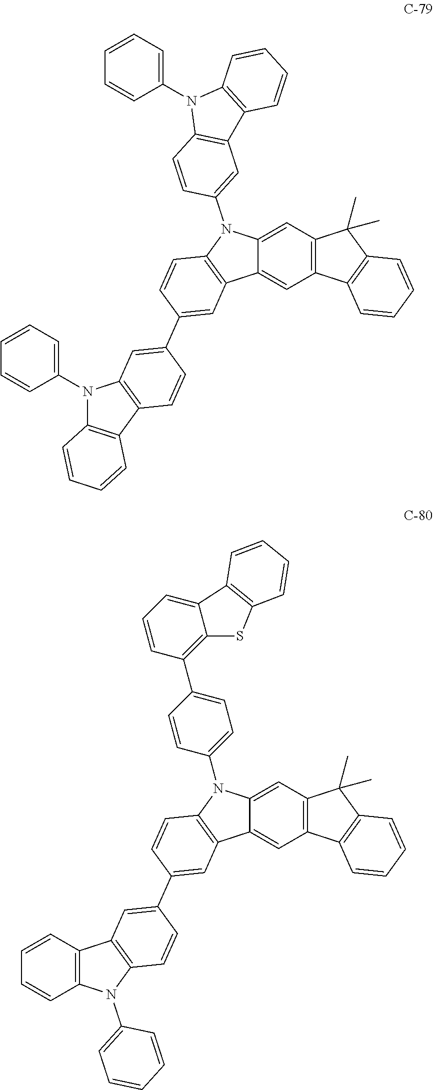 [SMILES: CC1(C)c2ccccc2-c2cc3c4cc(-c5ccc6c7ccccc7n(-c7ccccc7)c6c5)ccc4n(-c4ccc5c(c4)c4ccccc4n5-c4ccccc4)c3cc21 ; CC1(C)c2ccccc2-c2cc3c4cc(-c5ccc6c(c5)c5ccccc5n6-c5ccccc5)ccc4n(-c4ccc(-c5cccc6c5sc5ccccc56)cc4)c3cc21]

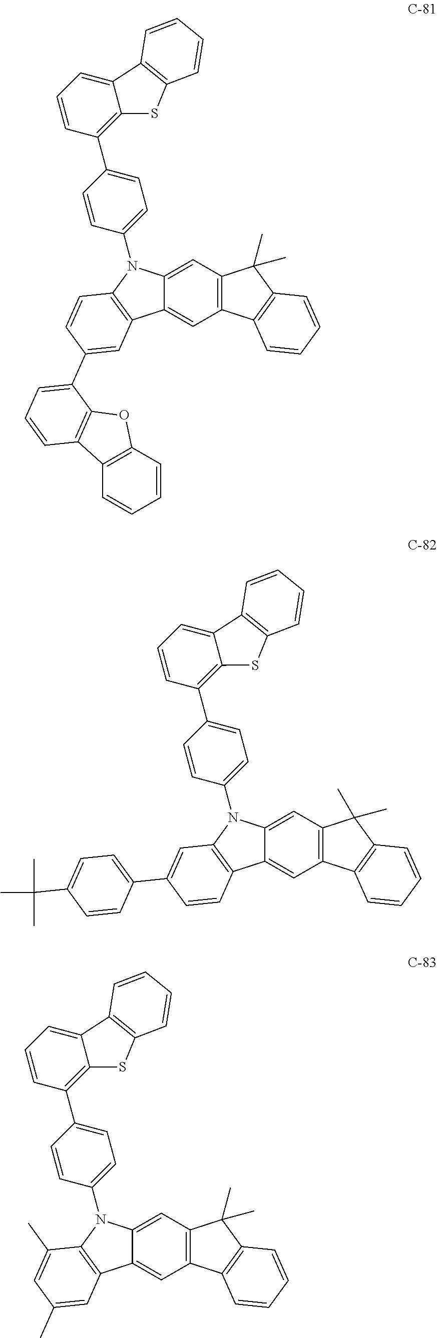 [SMILES: CC1(C)c2ccccc2-c2cc3c4cc(-c5cccc6c5oc5ccccc56)ccc4n(-c4ccc(-c5cccc6c5sc5ccccc56)cc4)c3cc21 ; CC(C)(C)c1ccc(-c2ccc3c4cc5c(cc4n(-c4ccc(-c6cccc7c6sc6ccccc67)cc4)c3c2)C(C)(C)c2ccccc2-5)cc1 ; Cc1cc(C)c2c(c1)c1cc3c(cc1n2-c1ccc(-c2cccc4c2sc2ccccc24)cc1)C(C)(C)c1ccccc1-3]

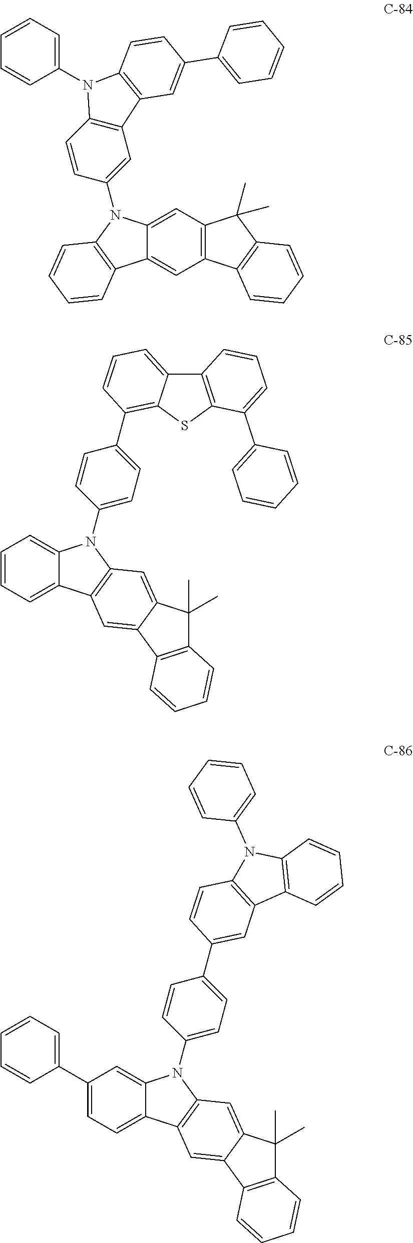 [SMILES: CC1(C)c2ccccc2-c2cc3c4ccccc4n(-c4ccc5c(c4)c4cc(-c6ccccc6)ccc4n5-c4ccccc4)c3cc21 ; CC1(C)c2ccccc2-c2cc3c4ccccc4n(-c4ccc(-c5cccc6c5sc5c(-c7ccccc7)cccc56)cc4)c3cc21 ; CC1(C)c2ccccc2-c2cc3c4ccc(-c5ccccc5)cc4n(-c4ccc(-c5ccc6c(c5)c5ccccc5n6-c5ccccc5)cc4)c3cc21]

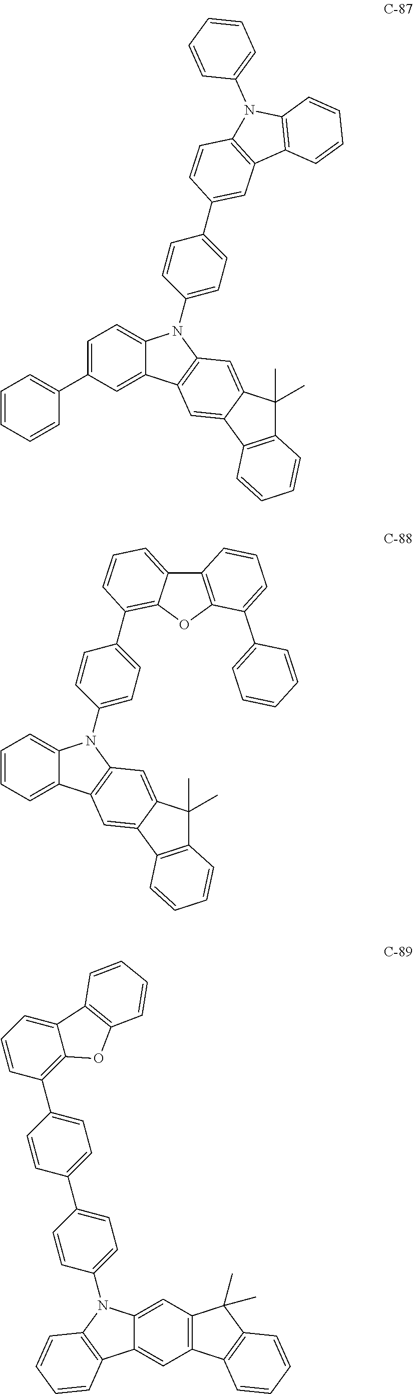 [SMILES: CC1(C)c2ccccc2-c2cc3c4cc(-c5ccccc5)ccc4n(-c4ccc(-c5ccc6c(c5)c5ccccc5n6-c5ccccc5)cc4)c3cc21 ; CC1(C)c2ccccc2-c2cc3c4ccccc4n(-c4ccc(-c5cccc6c5oc5c(-c7ccccc7)cccc56)cc4)c3cc21 ; CC1(C)c2ccccc2-c2cc3c4ccccc4n(-c4ccc(-c5ccc(-c6cccc7c6oc6ccccc67)cc5)cc4)c3cc21]

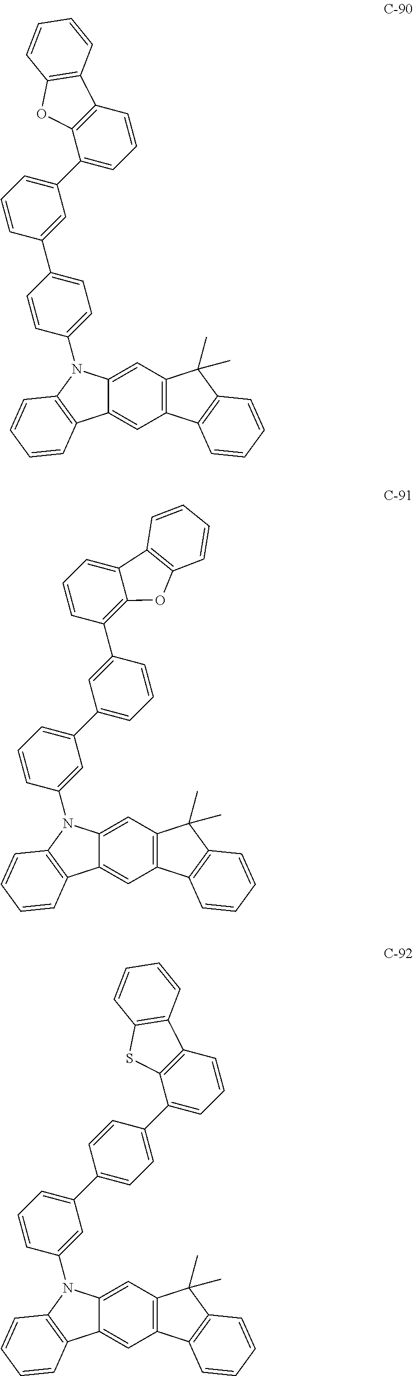 [SMILES: CC1(C)c2ccccc2-c2cc3c4ccccc4n(-c4ccc(-c5cccc(-c6cccc7c6oc6ccccc67)c5)cc4)c3cc21 ; CC1(C)c2ccccc2-c2cc3c4ccccc4n(-c4cccc(-c5cccc(-c6cccc7c6oc6ccccc67)c5)c4)c3cc21 ; CC1(C)c2ccccc2-c2cc3c4ccccc4n(-c4cccc(-c5ccc(-c6cccc7c6sc6ccccc67)cc5)c4)c3cc21]

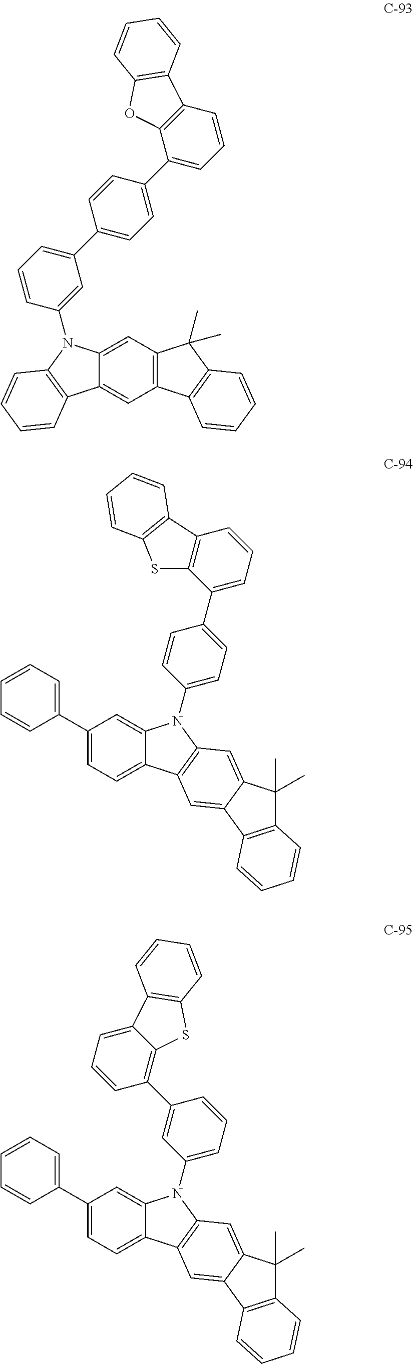 [SMILES: CC1(C)c2ccccc2-c2cc3c4ccccc4n(-c4cccc(-c5ccc(-c6cccc7c6oc6ccccc67)cc5)c4)c3cc21 ; CC1(C)c2ccccc2-c2cc3c4ccc(-c5ccccc5)cc4n(-c4ccc(-c5cccc6c5sc5ccccc56)cc4)c3cc21 ; CC1(C)c2ccccc2-c2cc3c4ccc(-c5ccccc5)cc4n(-c4cccc(-c5cccc6c5sc5ccccc56)c4)c3cc21]

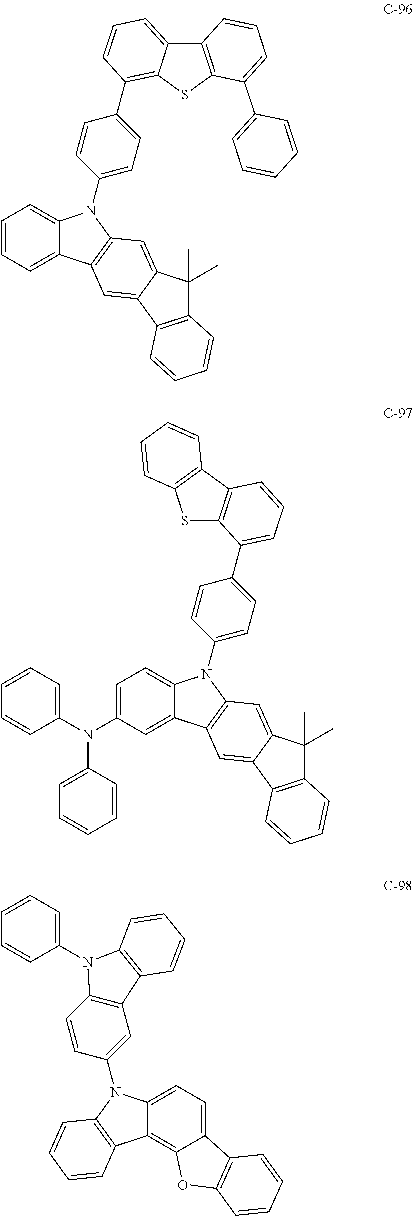

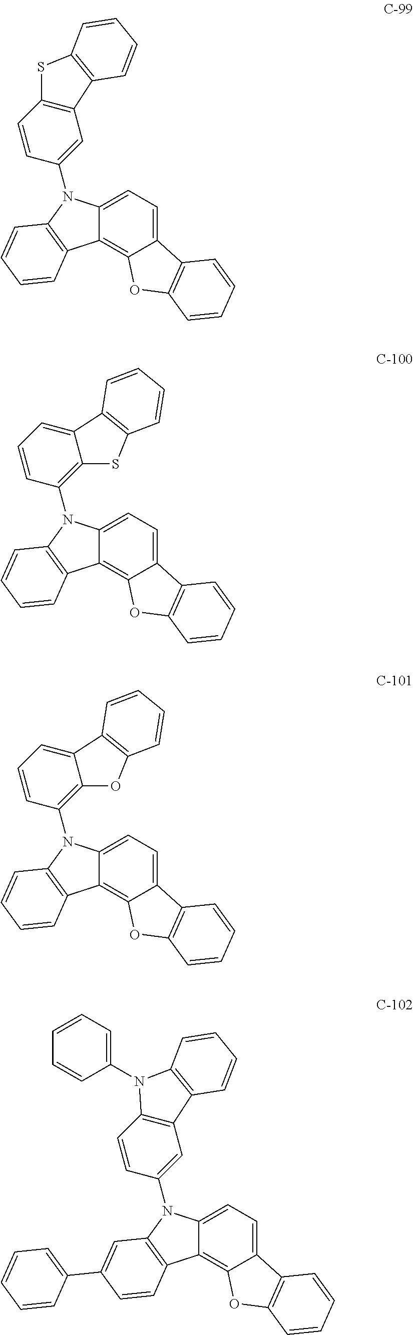 [SMILES: c1ccc2c(c1)oc1c2ccc2c1c1ccccc1n2-c1ccc2sc3ccccc3c2c1 ; c1ccc2c(c1)oc1c2ccc2c1c1ccccc1n2-c1cccc2c1sc1ccccc12 ; c1ccc2c(c1)oc1c(-n3c4ccccc4c4c5oc6ccccc6c5ccc43)cccc12 ; c1ccc(-c2ccc3c4c5oc6ccccc6c5ccc4n(-c4ccc5c(c4)c4ccccc4n5-c4ccccc4)c3c2)cc1]

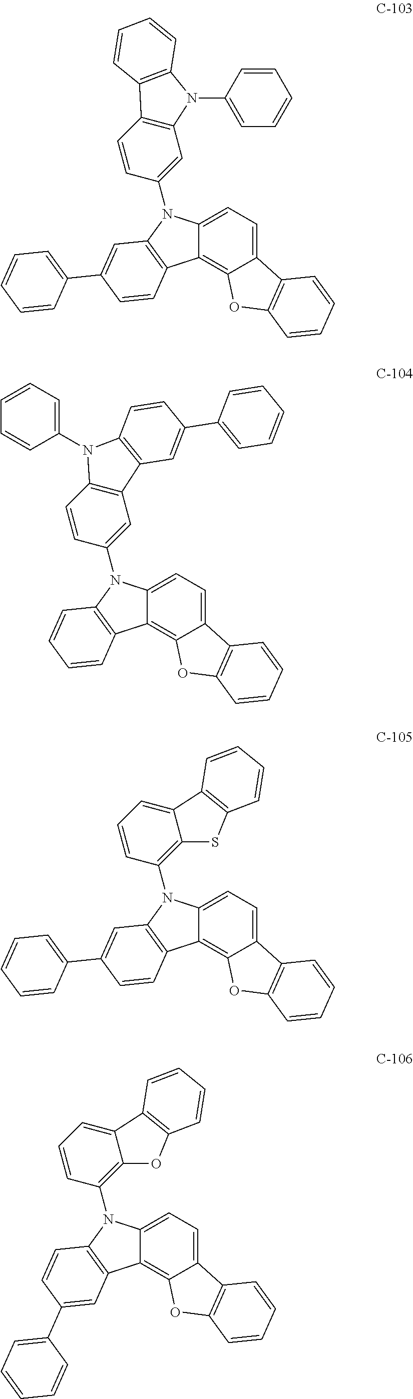

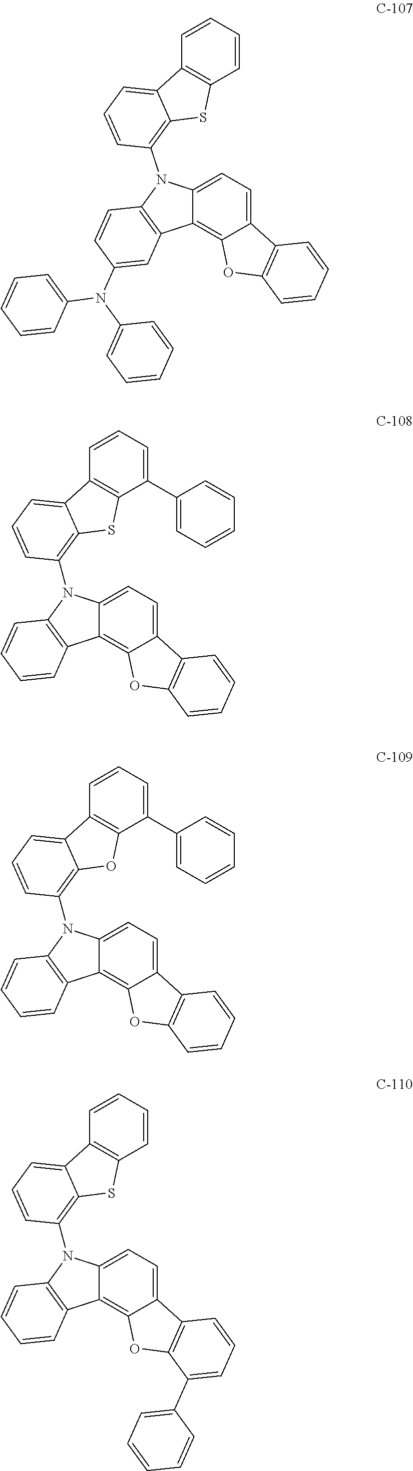 [SMILES: c1ccc(N(c2ccccc2)c2ccc3c(c2)c2c4oc5ccccc5c4ccc2n3-c2cccc3c2sc2ccccc23)cc1 ; c1ccc(-c2cccc3c2sc2c(-n4c5ccccc5c5c6oc7ccccc7c6ccc54)cccc23)cc1 ; c1ccc(-c2cccc3c2oc2c(-n4c5ccccc5c5c6oc7ccccc7c6ccc54)cccc23)cc1 ; c1ccc(-c2cccc3c2oc2c3ccc3c2c2ccccc2n3-c2cccc3c2sc2ccccc23)cc1]

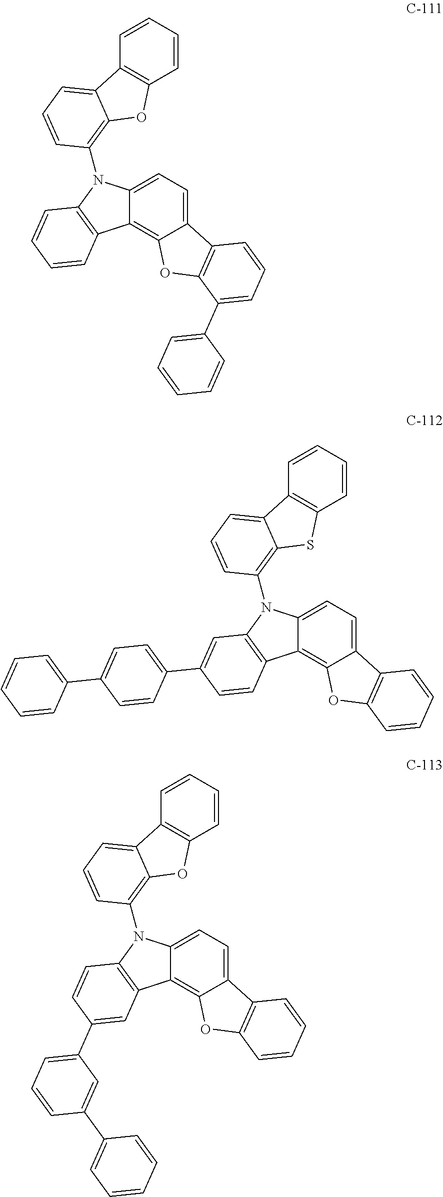 [SMILES: c1ccc(-c2cccc3c2oc2c3ccc3c2c2ccccc2n3-c2cccc3c2oc2ccccc23)cc1 ; c1ccc(-c2ccc(-c3ccc4c5c6oc7ccccc7c6ccc5n(-c5cccc6c5sc5ccccc56)c4c3)cc2)cc1 ; c1ccc(-c2cccc(-c3ccc4c(c3)c3c5oc6ccccc6c5ccc3n4-c3cccc4c3oc3ccccc34)c2)cc1]

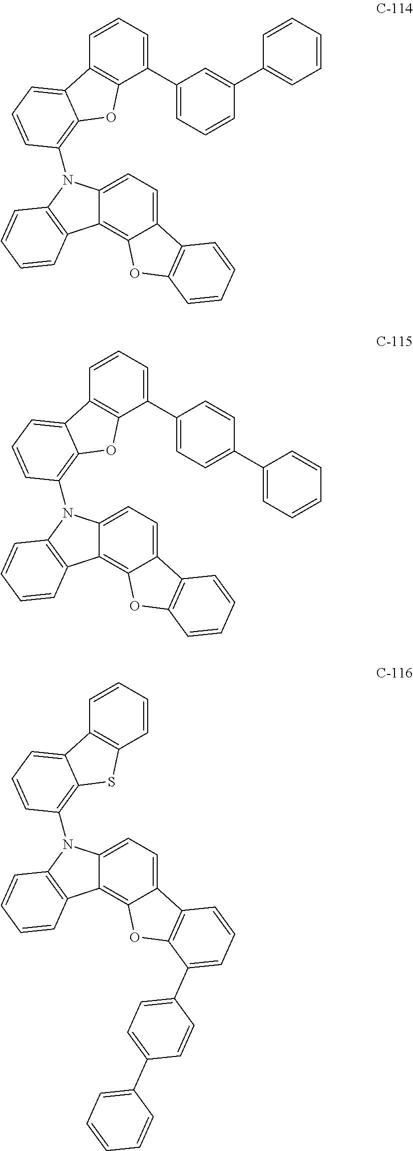 [SMILES: c1ccc(-c2cccc(-c3cccc4c3oc3c(-n5c6ccccc6c6c7oc8ccccc8c7ccc65)cccc34)c2)cc1 ; c1ccc(-c2ccc(-c3cccc4c3oc3c(-n5c6ccccc6c6c7oc8ccccc8c7ccc65)cccc34)cc2)cc1 ; c1ccc(-c2ccc(-c3cccc4c3oc3c4ccc4c3c3ccccc3n4-c3cccc4c3sc3ccccc34)cc2)cc1]

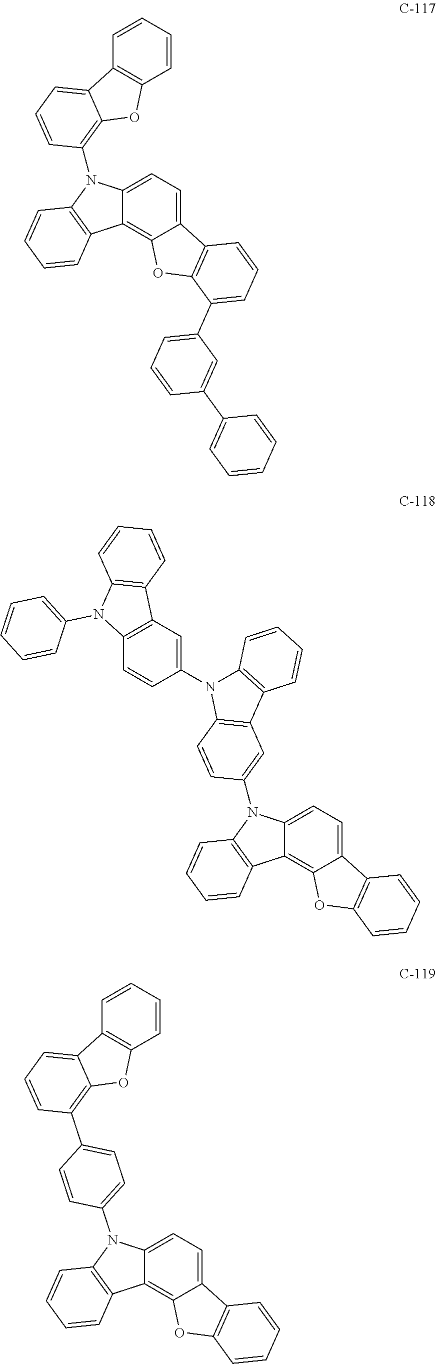 [SMILES: c1ccc(-c2cccc(-c3cccc4c3oc3c4ccc4c3c3ccccc3n4-c3cccc4c3oc3ccccc34)c2)cc1 ; c1ccc(-n2c3ccccc3c3cc(-n4c5ccccc5c5cc(-n6c7ccccc7c7c8oc9ccccc9c8ccc76)ccc54)ccc32)cc1 ; c1ccc2c(c1)oc1c(-c3ccc(-n4c5ccccc5c5c6oc7ccccc7c6ccc54)cc3)cccc12]

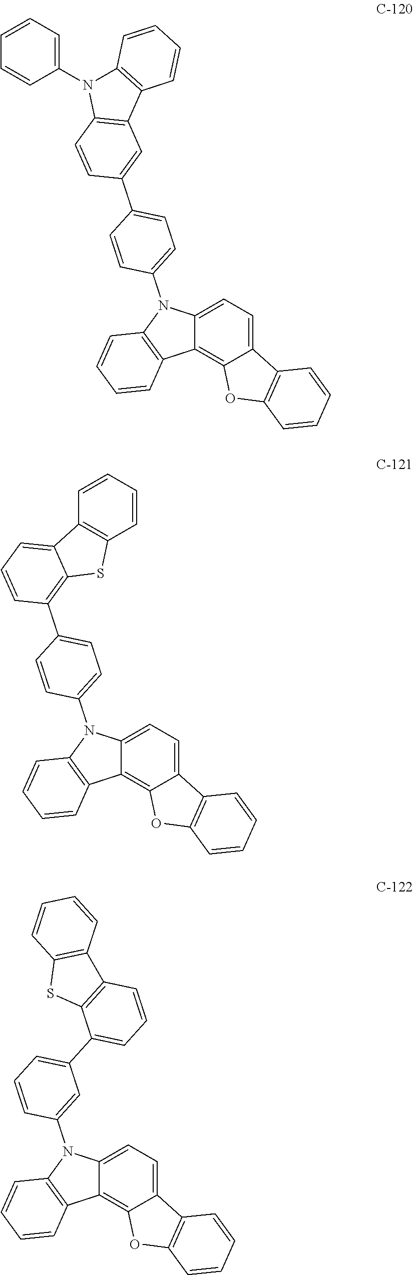 [SMILES: c1ccc(-n2c3ccccc3c3cc(-c4ccc(-n5c6ccccc6c6c7oc8ccccc8c7ccc65)cc4)ccc32)cc1 ; c1ccc2c(c1)oc1c2ccc2c1c1ccccc1n2-c1ccc(-c2cccc3c2sc2ccccc23)cc1 ; c1cc(-c2cccc3c2sc2ccccc23)cc(-n2c3ccccc3c3c4oc5ccccc5c4ccc32)c1]

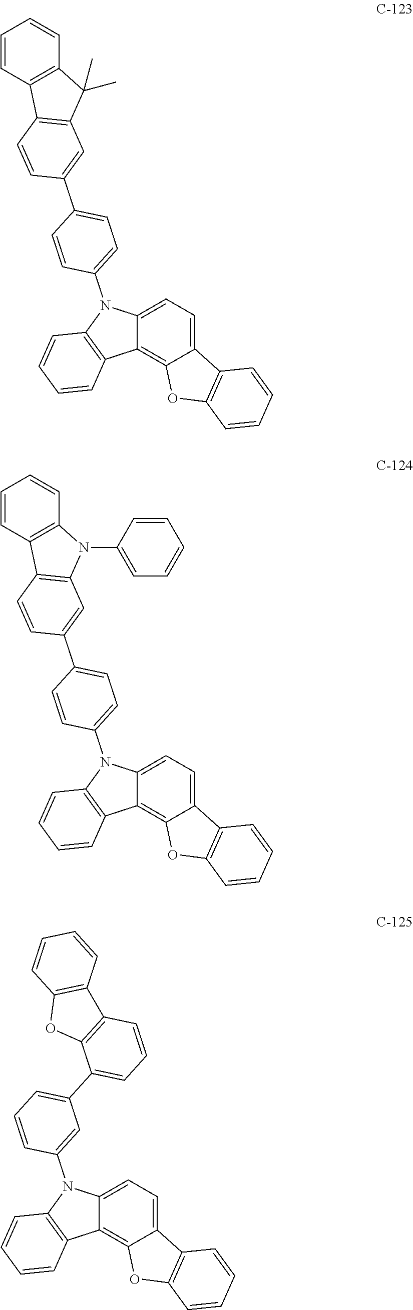 [SMILES: CC1(C)c2ccccc2-c2ccc(-c3ccc(-n4c5ccccc5c5c6oc7ccccc7c6ccc54)cc3)cc21 ; c1ccc(-n2c3ccccc3c3ccc(-c4ccc(-n5c6ccccc6c6c7oc8ccccc8c7ccc65)cc4)cc32)cc1 ; c1cc(-c2cccc3c2oc2ccccc23)cc(-n2c3ccccc3c3c4oc5ccccc5c4ccc32)c1]

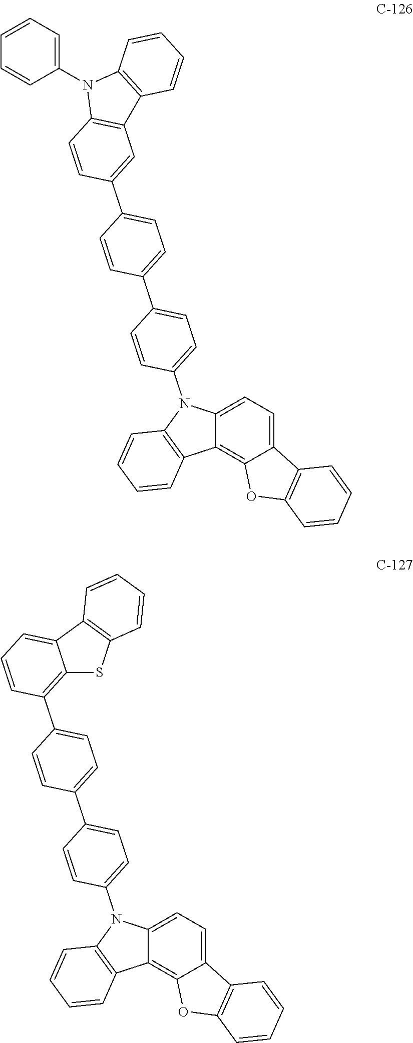 [SMILES: c1ccc(-n2c3ccccc3c3cc(-c4ccc(-c5ccc(-n6c7ccccc7c7c8oc9ccccc9c8ccc76)cc5)cc4)ccc32)cc1 ; c1ccc2c(c1)oc1c2ccc2c1c1ccccc1n2-c1ccc(-c2ccc(-c3cccc4c3sc3ccccc34)cc2)cc1]

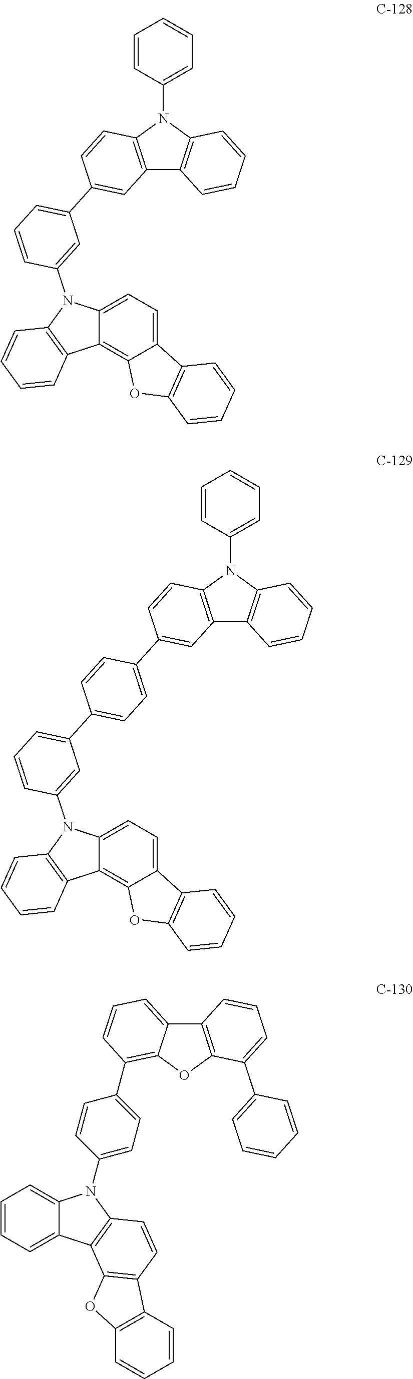 [SMILES: c1ccc(-n2c3ccccc3c3cc(-c4cccc(-n5c6ccccc6c6c7oc8ccccc8c7ccc65)c4)ccc32)cc1 ; c1ccc(-n2c3ccccc3c3cc(-c4ccc(-c5cccc(-n6c7ccccc7c7c8oc9ccccc9c8ccc76)c5)cc4)ccc32)cc1 ; c1ccc(-c2cccc3c2oc2c(-c4ccc(-n5c6ccccc6c6c7oc8ccccc8c7ccc65)cc4)cccc23)cc1]

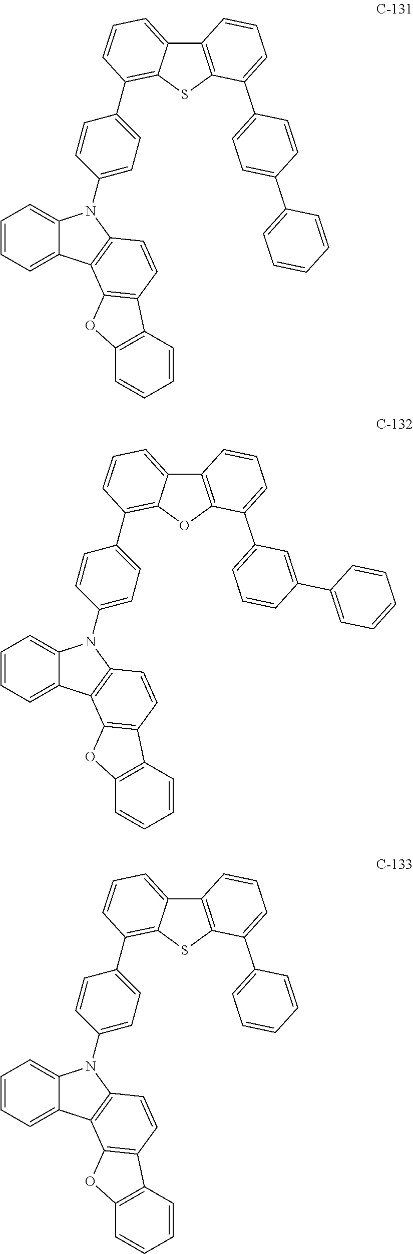

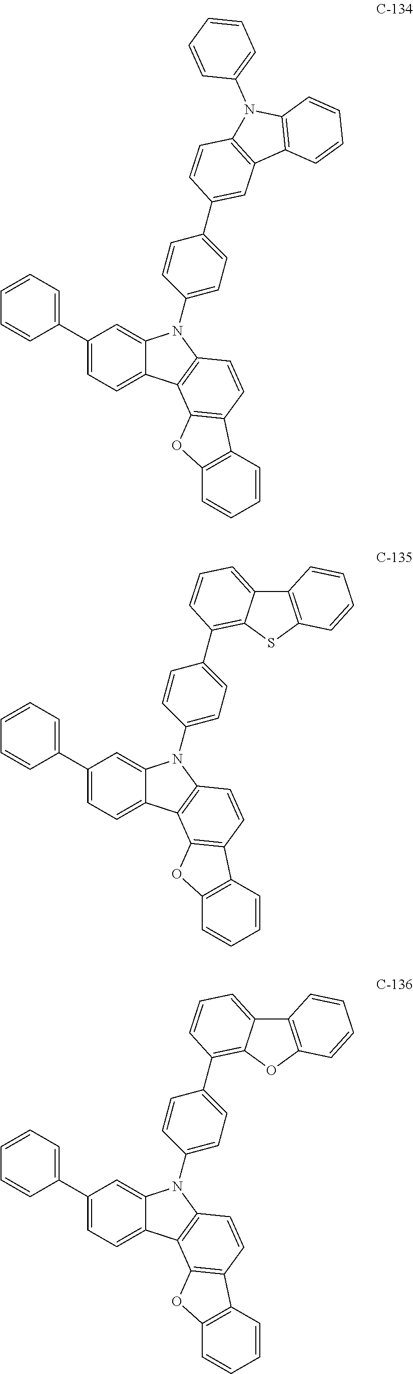 [SMILES: c1ccc(-c2ccc3c4c5oc6ccccc6c5ccc4n(-c4ccc(-c5ccc6c(c5)c5ccccc5n6-c5ccccc5)cc4)c3c2)cc1 ; c1ccc(-c2ccc3c4c5oc6ccccc6c5ccc4n(-c4ccc(-c5cccc6c5sc5ccccc56)cc4)c3c2)cc1 ; c1ccc(-c2ccc3c4c5oc6ccccc6c5ccc4n(-c4ccc(-c5cccc6c5oc5ccccc56)cc4)c3c2)cc1]

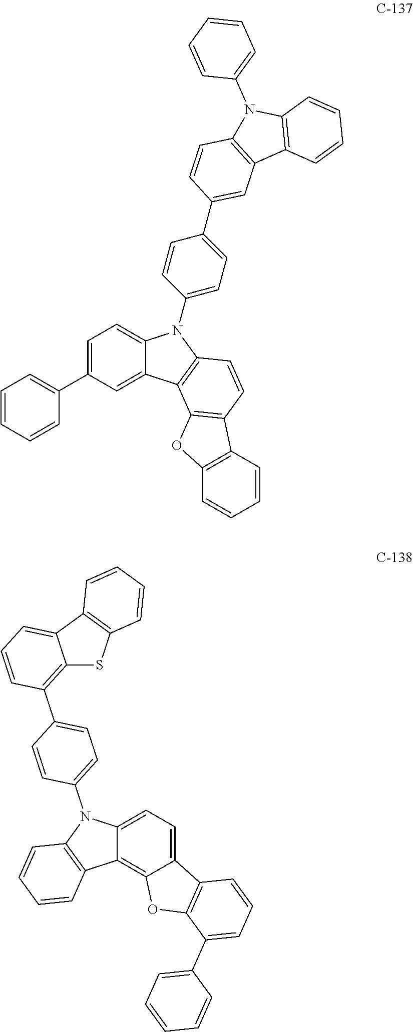 [SMILES: c1ccc(-c2ccc3c(c2)c2c4oc5ccccc5c4ccc2n3-c2ccc(-c3ccc4c(c3)c3ccccc3n4-c3ccccc3)cc2)cc1 ; c1ccc(-c2cccc3c2oc2c3ccc3c2c2ccccc2n3-c2ccc(-c3cccc4c3sc3ccccc34)cc2)cc1]

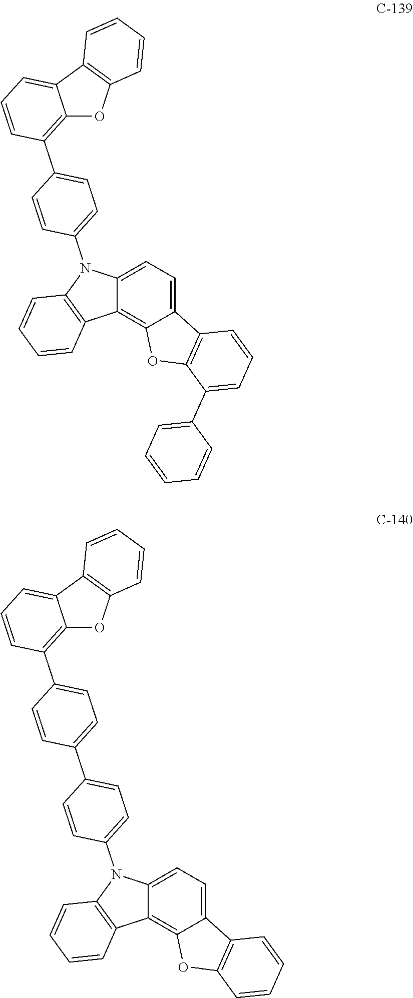 [SMILES: c1ccc(-c2cccc3c2oc2c3ccc3c2c2ccccc2n3-c2ccc(-c3cccc4c3oc3ccccc34)cc2)cc1 ; c1ccc2c(c1)oc1c(-c3ccc(-c4ccc(-n5c6ccccc6c6c7oc8ccccc8c7ccc65)cc4)cc3)cccc12]

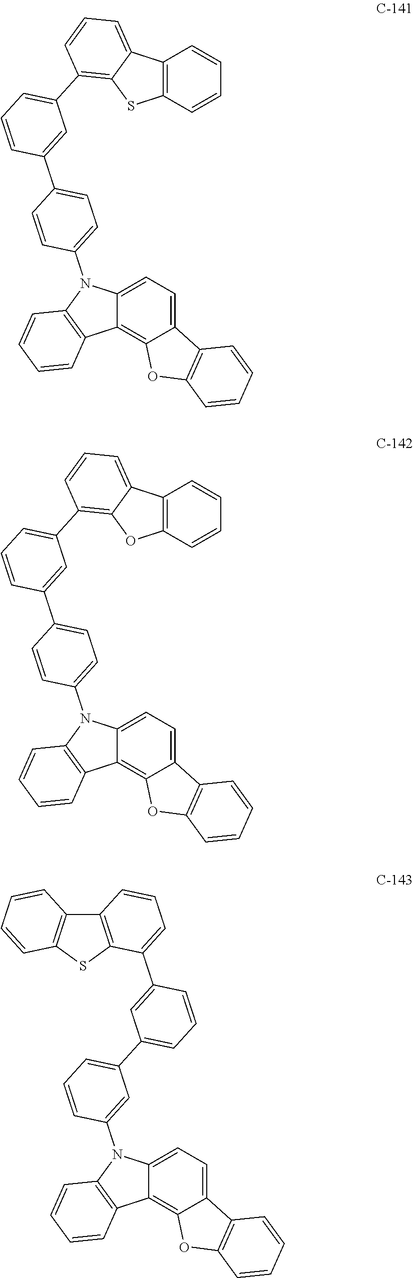 [SMILES: c1cc(-c2ccc(-n3c4ccccc4c4c5oc6ccccc6c5ccc43)cc2)cc(-c2cccc3c2sc2ccccc23)c1 ; c1cc(-c2ccc(-n3c4ccccc4c4c5oc6ccccc6c5ccc43)cc2)cc(-c2cccc3c2oc2ccccc23)c1 ; c1cc(-c2cccc(-n3c4ccccc4c4c5oc6ccccc6c5ccc43)c2)cc(-c2cccc3c2sc2ccccc23)c1]

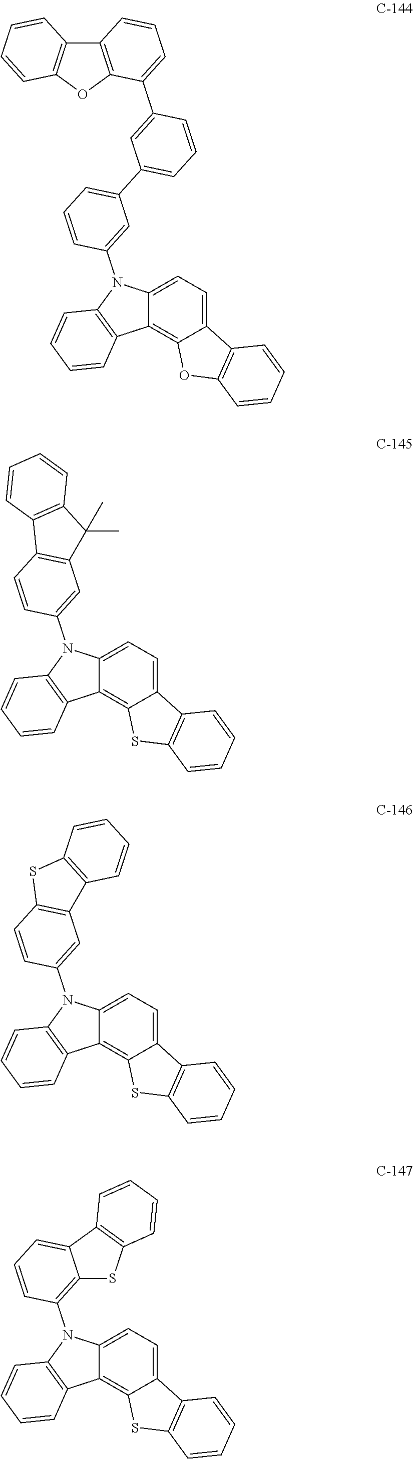 [SMILES: c1cc(-c2cccc(-n3c4ccccc4c4c5oc6ccccc6c5ccc43)c2)cc(-c2cccc3c2oc2ccccc23)c1 ; CC1(C)c2ccccc2-c2ccc(-n3c4ccccc4c4c5sc6ccccc6c5ccc43)cc21 ; c1ccc2c(c1)sc1ccc(-n3c4ccccc4c4c5sc6ccccc6c5ccc43)cc12 ; c1ccc2c(c1)sc1c(-n3c4ccccc4c4c5sc6ccccc6c5ccc43)cccc12]

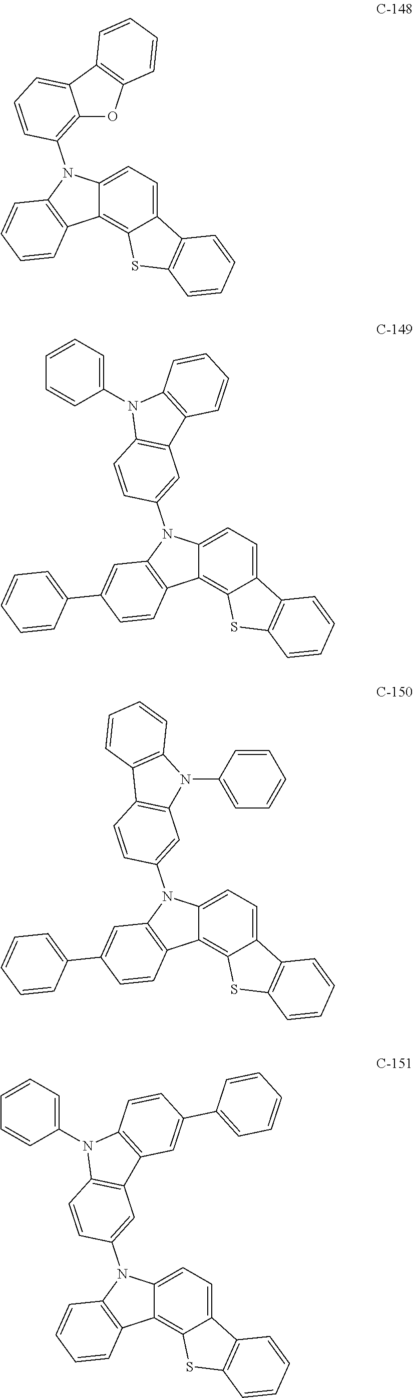 [SMILES: c1ccc2c(c1)oc1c(-n3c4ccccc4c4c5sc6ccccc6c5ccc43)cccc12 ; c1ccc(-c2ccc3c4c5sc6ccccc6c5ccc4n(-c4ccc5c(c4)c4ccccc4n5-c4ccccc4)c3c2)cc1 ; c1ccc(-c2ccc3c4c5sc6ccccc6c5ccc4n(-c4ccc5c6ccccc6n(-c6ccccc6)c5c4)c3c2)cc1 ; c1ccc(-c2ccc3c(c2)c2cc(-n4c5ccccc5c5c6sc7ccccc7c6ccc54)ccc2n3-c2ccccc2)cc1]

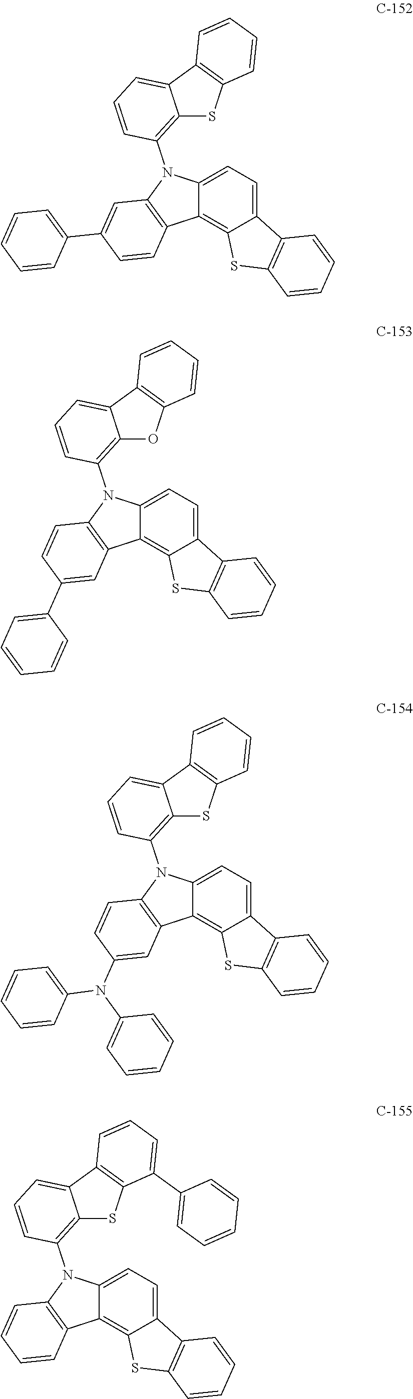

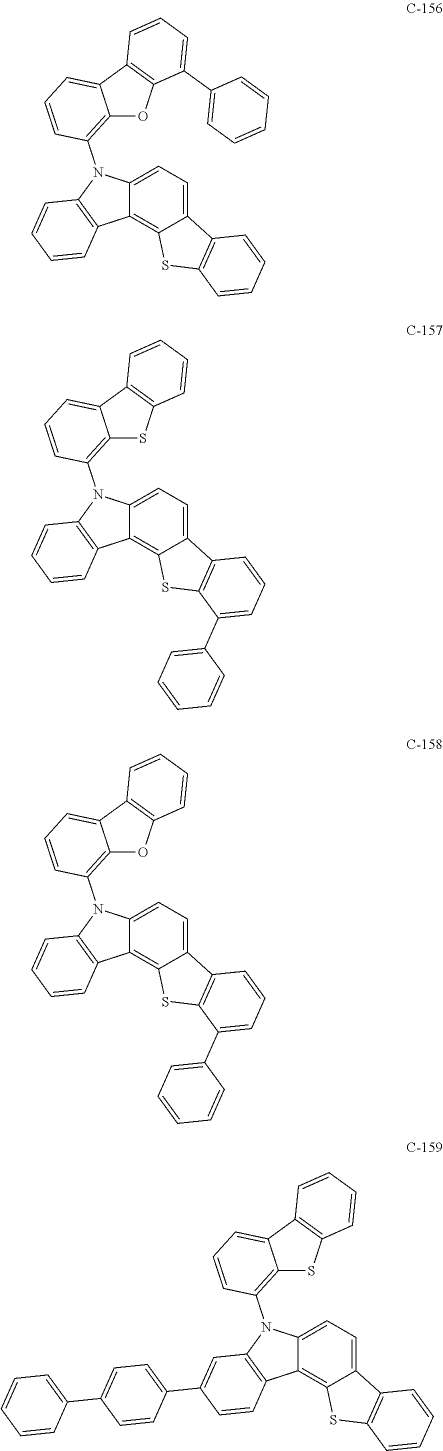 [SMILES: c1ccc(-c2cccc3c2oc2c(-n4c5ccccc5c5c6sc7ccccc7c6ccc54)cccc23)cc1 ; c1ccc(-c2cccc3c2sc2c3ccc3c2c2ccccc2n3-c2cccc3c2sc2ccccc23)cc1 ; c1ccc(-c2cccc3c2sc2c3ccc3c2c2ccccc2n3-c2cccc3c2oc2ccccc23)cc1 ; c1ccc(-c2ccc(-c3ccc4c5c6sc7ccccc7c6ccc5n(-c5cccc6c5sc5ccccc56)c4c3)cc2)cc1]

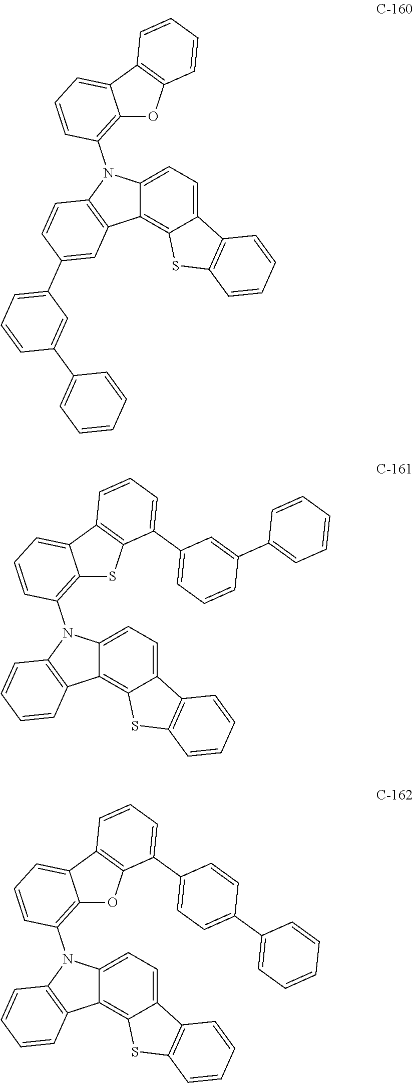 [SMILES: c1ccc(-c2cccc(-c3ccc4c(c3)c3c5sc6ccccc6c5ccc3n4-c3cccc4c3oc3ccccc34)c2)cc1 ; c1ccc(-c2cccc(-c3cccc4c3sc3c(-n5c6ccccc6c6c7sc8ccccc8c7ccc65)cccc34)c2)cc1 ; c1ccc(-c2ccc(-c3cccc4c3oc3c(-n5c6ccccc6c6c7sc8ccccc8c7ccc65)cccc34)cc2)cc1]

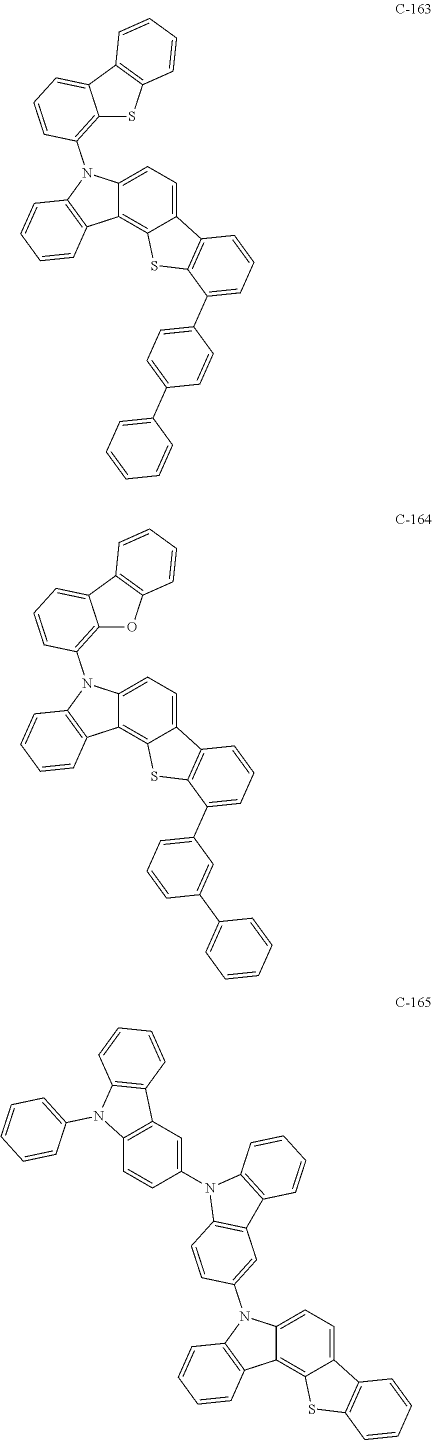 [SMILES: c1ccc(-c2ccc(-c3cccc4c3sc3c4ccc4c3c3ccccc3n4-c3cccc4c3sc3ccccc34)cc2)cc1 ; c1ccc(-c2cccc(-c3cccc4c3sc3c4ccc4c3c3ccccc3n4-c3cccc4c3oc3ccccc34)c2)cc1 ; c1ccc(-n2c3ccccc3c3cc(-n4c5ccccc5c5cc(-n6c7ccccc7c7c8sc9ccccc9c8ccc76)ccc54)ccc32)cc1]

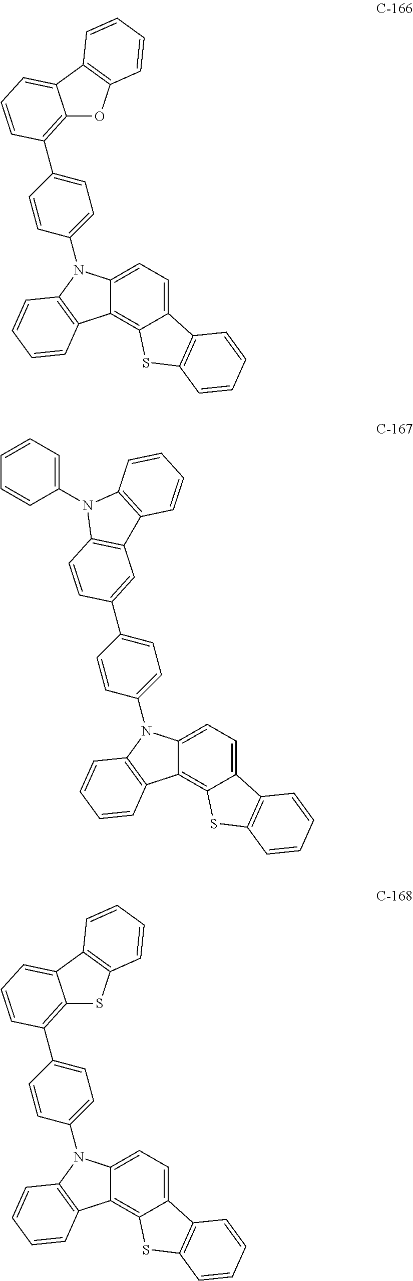 [SMILES: c1ccc2c(c1)oc1c(-c3ccc(-n4c5ccccc5c5c6sc7ccccc7c6ccc54)cc3)cccc12 ; c1ccc(-n2c3ccccc3c3cc(-c4ccc(-n5c6ccccc6c6c7sc8ccccc8c7ccc65)cc4)ccc32)cc1 ; c1ccc2c(c1)sc1c(-c3ccc(-n4c5ccccc5c5c6sc7ccccc7c6ccc54)cc3)cccc12]

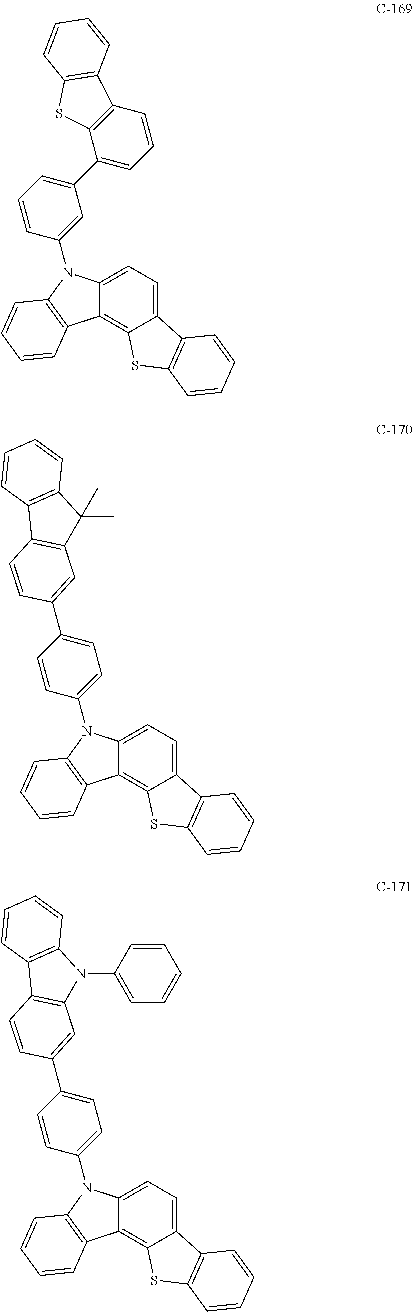 [SMILES: c1cc(-c2cccc3c2sc2ccccc23)cc(-n2c3ccccc3c3c4sc5ccccc5c4ccc32)c1 ; CC1(C)c2ccccc2-c2ccc(-c3ccc(-n4c5ccccc5c5c6sc7ccccc7c6ccc54)cc3)cc21 ; c1ccc(-n2c3ccccc3c3ccc(-c4ccc(-n5c6ccccc6c6c7sc8ccccc8c7ccc65)cc4)cc32)cc1]

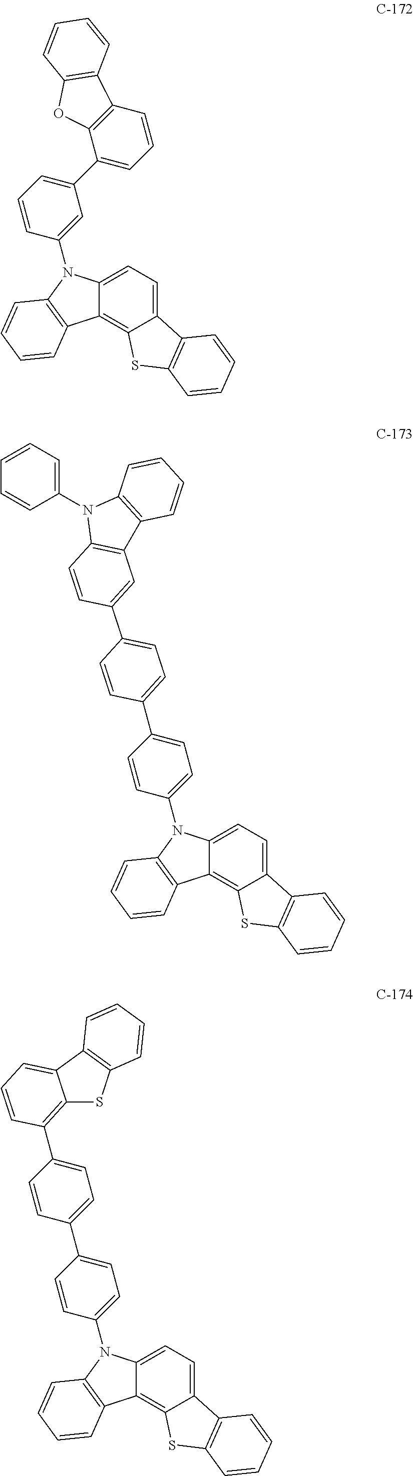 [SMILES: c1cc(-c2cccc3c2oc2ccccc23)cc(-n2c3ccccc3c3c4sc5ccccc5c4ccc32)c1 ; c1ccc(-n2c3ccccc3c3cc(-c4ccc(-c5ccc(-n6c7ccccc7c7c8sc9ccccc9c8ccc76)cc5)cc4)ccc32)cc1 ; c1ccc2c(c1)sc1c(-c3ccc(-c4ccc(-n5c6ccccc6c6c7sc8ccccc8c7ccc65)cc4)cc3)cccc12]

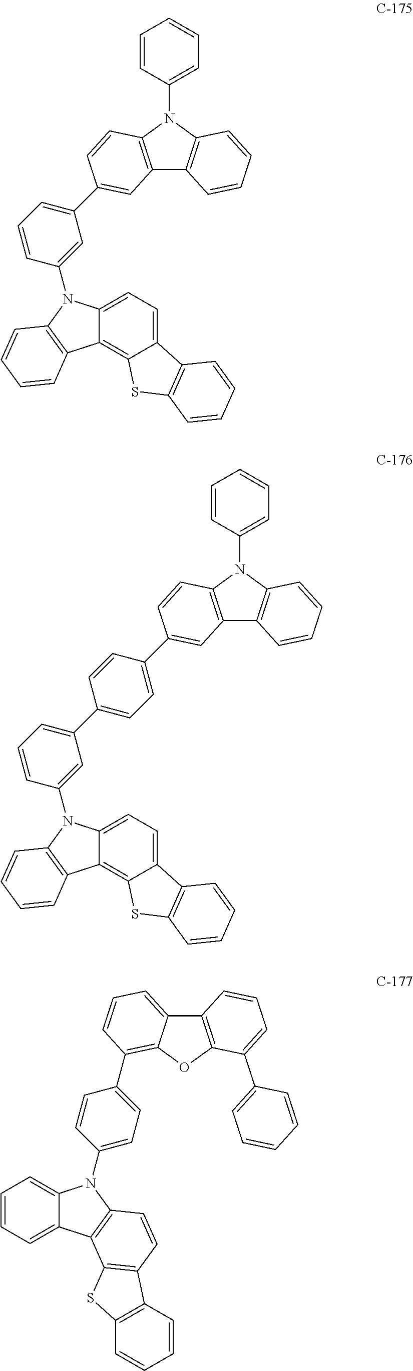 [SMILES: c1ccc(-n2c3ccccc3c3cc(-c4cccc(-n5c6ccccc6c6c7sc8ccccc8c7ccc65)c4)ccc32)cc1 ; c1ccc(-n2c3ccccc3c3cc(-c4ccc(-c5cccc(-n6c7ccccc7c7c8sc9ccccc9c8ccc76)c5)cc4)ccc32)cc1 ; c1ccc(-c2cccc3c2oc2c(-c4ccc(-n5c6ccccc6c6c7sc8ccccc8c7ccc65)cc4)cccc23)cc1]

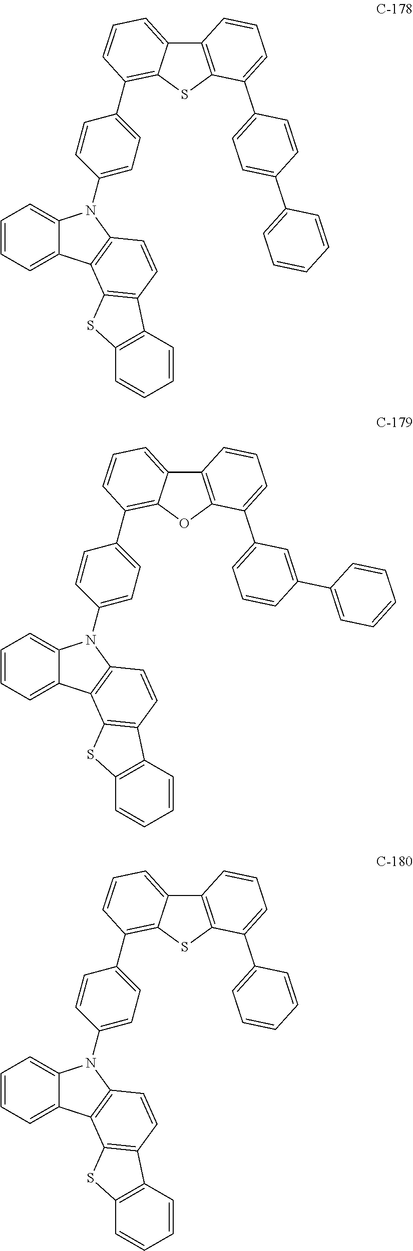

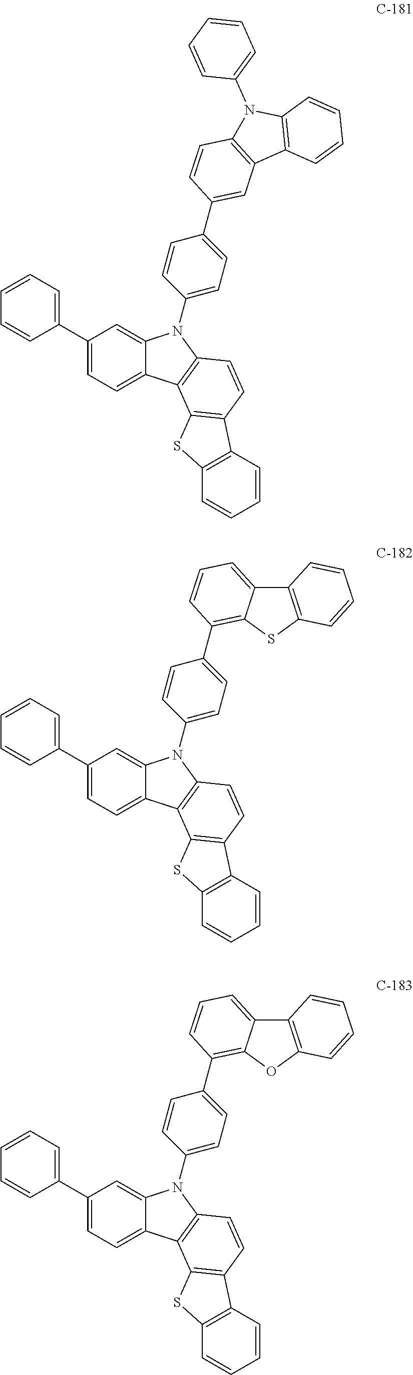

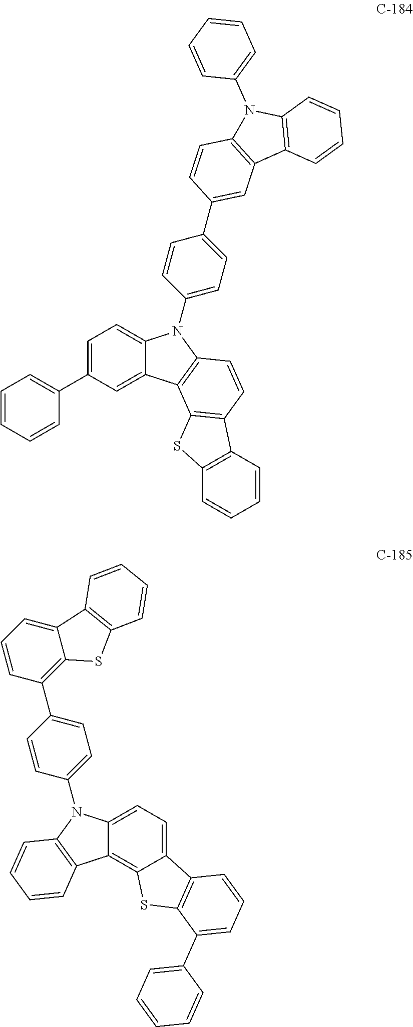 [SMILES: c1ccc(-c2ccc3c(c2)c2c4sc5ccccc5c4ccc2n3-c2ccc(-c3ccc4c(c3)c3ccccc3n4-c3ccccc3)cc2)cc1 ; c1ccc(-c2cccc3c2sc2c3ccc3c2c2ccccc2n3-c2ccc(-c3cccc4c3sc3ccccc34)cc2)cc1]

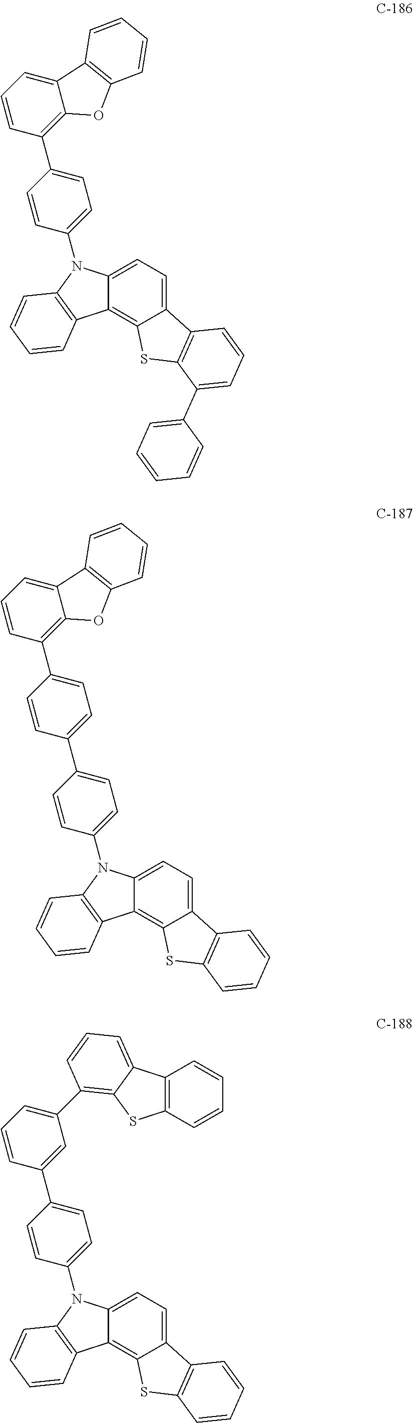 [SMILES: c1ccc(-c2cccc3c2sc2c3ccc3c2c2ccccc2n3-c2ccc(-c3cccc4c3oc3ccccc34)cc2)cc1 ; c1ccc2c(c1)oc1c(-c3ccc(-c4ccc(-n5c6ccccc6c6c7sc8ccccc8c7ccc65)cc4)cc3)cccc12 ; c1cc(-c2ccc(-n3c4ccccc4c4c5sc6ccccc6c5ccc43)cc2)cc(-c2cccc3c2sc2ccccc23)c1]

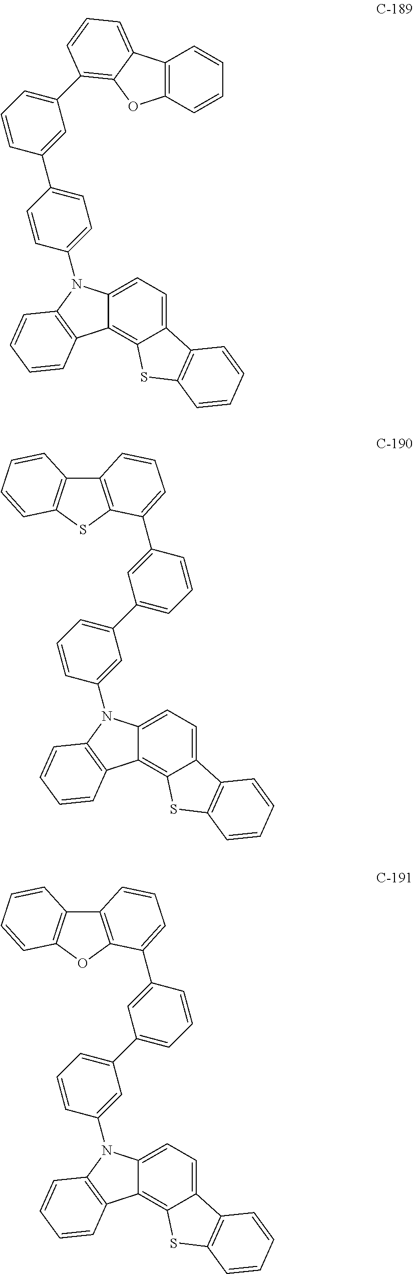 [SMILES: c1cc(-c2ccc(-n3c4ccccc4c4c5sc6ccccc6c5ccc43)cc2)cc(-c2cccc3c2oc2ccccc23)c1 ; c1cc(-c2cccc(-n3c4ccccc4c4c5sc6ccccc6c5ccc43)c2)cc(-c2cccc3c2sc2ccccc23)c1 ; c1cc(-c2cccc(-n3c4ccccc4c4c5sc6ccccc6c5ccc43)c2)cc(-c2cccc3c2oc2ccccc23)c1]

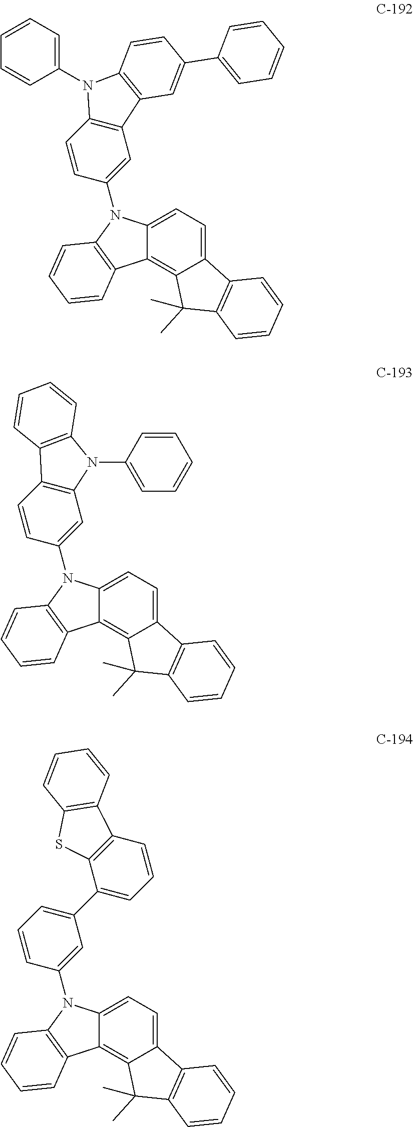 [SMILES: CC1(C)c2ccccc2-c2ccc3c(c21)c1ccccc1n3-c1ccc2c(c1)c1cc(-c3ccccc3)ccc1n2-c1ccccc1 ; CC1(C)c2ccccc2-c2ccc3c(c21)c1ccccc1n3-c1ccc2c3ccccc3n(-c3ccccc3)c2c1 ; CC1(C)c2ccccc2-c2ccc3c(c21)c1ccccc1n3-c1cccc(-c2cccc3c2sc2ccccc23)c1]

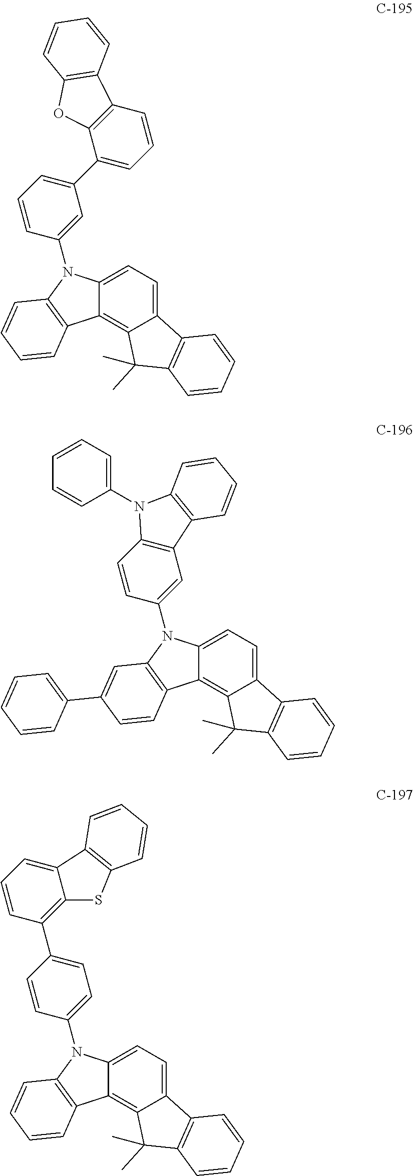 [SMILES: CC1(C)c2ccccc2-c2ccc3c(c21)c1ccccc1n3-c1cccc(-c2cccc3c2oc2ccccc23)c1 ; CC1(C)c2ccccc2-c2ccc3c(c21)c1ccc(-c2ccccc2)cc1n3-c1ccc2c(c1)c1ccccc1n2-c1ccccc1 ; CC1(C)c2ccccc2-c2ccc3c(c21)c1ccccc1n3-c1ccc(-c2cccc3c2sc2ccccc23)cc1]

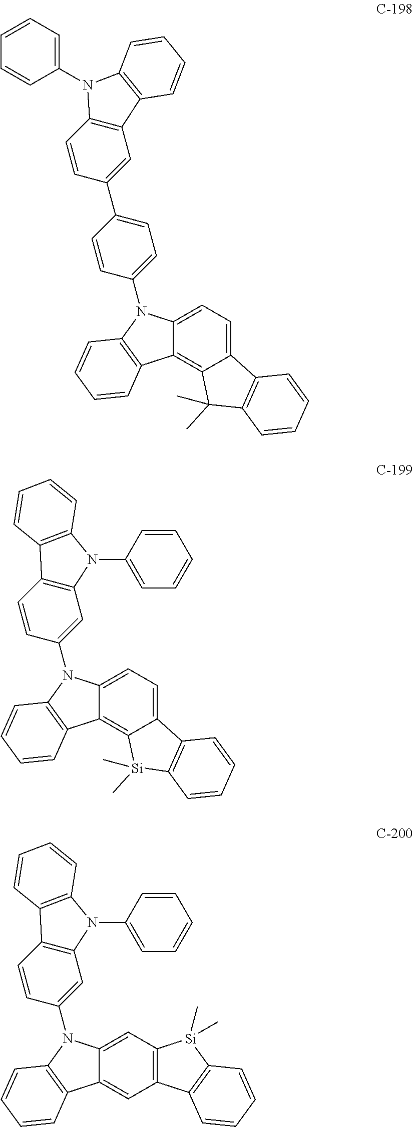 [SMILES: CC1(C)c2ccccc2-c2ccc3c(c21)c1ccccc1n3-c1ccc(-c2ccc3c(c2)c2ccccc2n3-c2ccccc2)cc1 ; C[Si]1(C)c2ccccc2-c2ccc3c(c21)c1ccccc1n3-c1ccc2c3ccccc3n(-c3ccccc3)c2c1 ; C[Si]1(C)c2ccccc2-c2cc3c4ccccc4n(-c4ccc5c6ccccc6n(-c6ccccc6)c5c4)c3cc21]

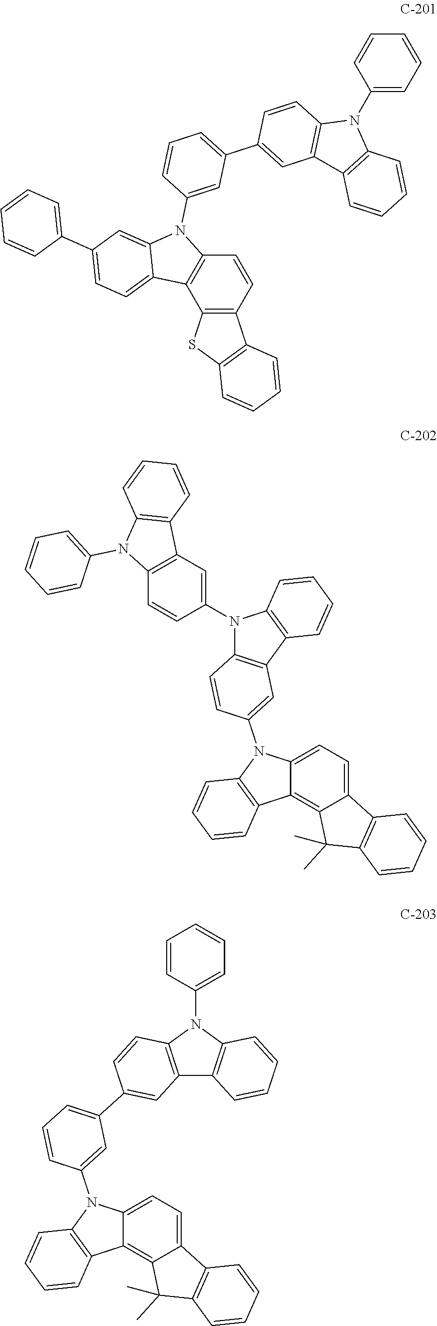 [SMILES: c1ccc(-c2ccc3c4c5sc6ccccc6c5ccc4n(-c4cccc(-c5ccc6c(c5)c5ccccc5n6-c5ccccc5)c4)c3c2)cc1 ; CC1(C)c2ccccc2-c2ccc3c(c21)c1ccccc1n3-c1ccc2c(c1)c1ccccc1n2-c1ccc2c(c1)c1ccccc1n2-c1ccccc1 ; CC1(C)c2ccccc2-c2ccc3c(c21)c1ccccc1n3-c1cccc(-c2ccc3c(c2)c2ccccc2n3-c2ccccc2)c1]

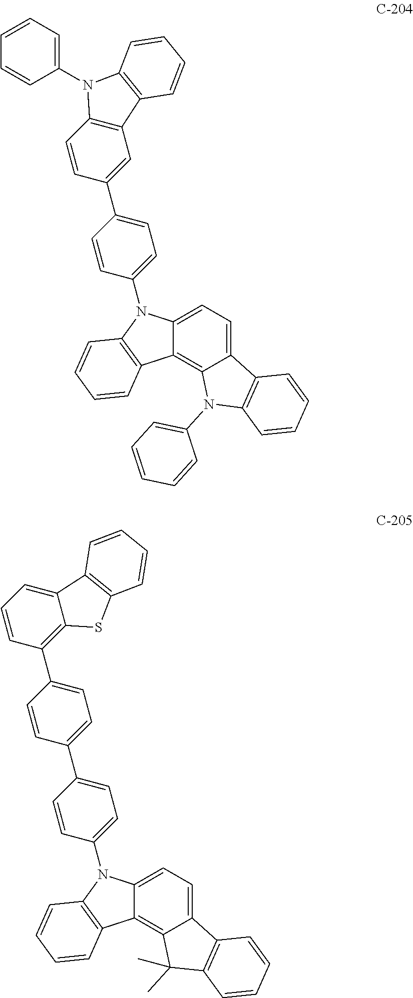 [SMILES: c1ccc(-n2c3ccccc3c3cc(-c4ccc(-n5c6ccccc6c6c5ccc5c7ccccc7n(-c7ccccc7)c56)cc4)ccc32)cc1 ; CC1(C)c2ccccc2-c2ccc3c(c21)c1ccccc1n3-c1ccc(-c2ccc(-c3cccc4c3sc3ccccc34)cc2)cc1]

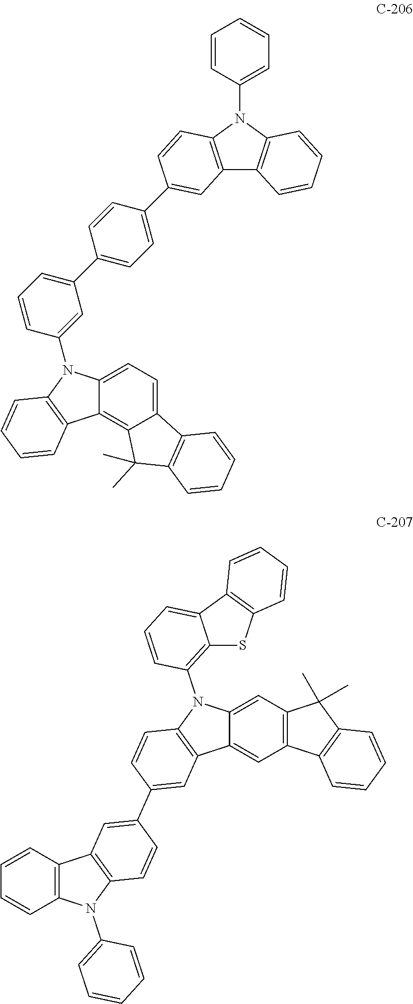 [SMILES: CC1(C)c2ccccc2-c2ccc3c(c21)c1ccccc1n3-c1cccc(-c2ccc(-c3ccc4c(c3)c3ccccc3n4-c3ccccc3)cc2)c1 ; CC1(C)c2ccccc2-c2cc3c4cc(-c5ccc6c(c5)c5ccccc5n6-c5ccccc5)ccc4n(-c4cccc5c4sc4ccccc45)c3cc21]

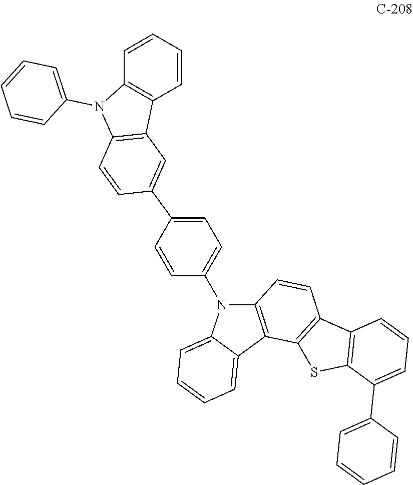 [SMILES: c1ccc(-c2cccc3c2sc2c3ccc3c2c2ccccc2n3-c2ccc(-c3ccc4c(c3)c3ccccc3n4-c3ccccc3)cc2)cc1]

6. An organic electroluminescent device comprising the compound according to claim 1.
